(19) United States
(12) Patent Application Publication
(10) Pub. No.: US 2024/0302744 A1
(43) Pub. Date: Sep. 12, 2024

(54) COMPOSITION FOR FORMING SILICON-CONTAINING UNDERLAYER FILM FOR INDUCED SELF-ORGANIZATION

(71) Applicant: NISSAN CHEMICAL CORPORATION, Tokyo (JP)

(72) Inventors: Shuhei SHIGAKI, Toyama-shi (JP); Ryuta MIZUOCHI, Toyama-shi (JP); Hikaru TOKUNAGA, Toyama-shi (JP)

(73) Assignee: NISSAN CHEMICAL CORPORATION, Tokyo (JP)

(21) Appl. No.: 18/285,141

(22) PCT Filed: Mar. 30, 2022
(86) PCT No.: PCT/JP2022/016259

§ 371 Date: Sep. 29, 2023

(30) Foreign Application Priority Data
Mar. 31, 2021 (JP) 2021-061781

(51) Int. Cl. G03F 7/075; G03F 7/11; H01L 21/027; H01L 21/308

(52) U.S. Cl. CPC G03F 7/0752; G03F 7/11; H01L 21/0275; H01L 21/3081; H01L 21/3086

(57) ABSTRACT

A silicon-containing underlayer film-forming composition that can form a self-assembled film wherein a desired vertical pattern is induced, and a pattern formation method using the composition. A composition for forming a silicon-containing underlayer film for a self-assembled film, the composition being characterized by including: a polysiloxane; and a solvent, but not including a strongly acidic additive.

### TECHNICAL FIELD

The present invention relates to a silicon-containing underlayer film-forming composition for forming an underlayer film for a self-assembled film, and a self-assembled pattern formation method using the composition.

### BACKGROUND ART

A thermosetting self-assembled film having a nanoscale repeating structure is known to have properties different from those of a common homogeneous film, and a proposal has been made for a self-assembled film formed from a block copolymer and having a nanoscale repeating structure.

For example, there has been disclosed a pattern formation method for forming a pattern on a block polymer layer by regularly aligning a plurality of segments constituting the block polymer (Patent Document 1).

There has also been disclosed a composition for forming a thermosetting self-assembled film, the composition containing a block copolymer, a crosslinking agent, and an organic solvent (Patent Document 2).

In recent years, a demand has arisen for the technique of processing a finer structure in association with further miniaturization of large-scale integrated circuits (LSI). In order to meet such a demand, attempts have been made to form a finer pattern by utilizing a phase-separated structure formed through self-assembly of a block copolymer prepared by bonding of polymers incompatible with one another. For example, there has been proposed a pattern formation method involving forming an underlayer film for facilitating alignment of a desired vertical pattern in a self-assembled film; forming, on the underlayer film, a self-assembled film containing a block copolymer prepared by bonding of two or more types of polymers; phase-separating the block copolymer in the self-assembled film; and selectively removing the phase of at least one polymer among the polymers constituting the block copolymer.

There have been disclosed, as a material for forming the aforementioned underlayer film, for example, an underlayer film-forming composition containing a polymer containing in the main chain a unit structure of a polycyclic aromatic vinyl compound (Patent Document 3), and a composition for forming an underlayer film for a self-assembled film, the composition containing a polymer having a unit structure containing in the main chain an aliphatic polycyclic structure of an aliphatic polycyclic compound (Patent Document 4).

There has also been disclosed that the aforementioned underlayer film is irradiated with ultraviolet rays or radioactive rays at a position overlapping with a target alignment position to thereby cause a change in the surface irregularities or surface energy (hydrophilicity/hydrophobicity) of the underlayer film so that a self-assembled pattern is aligned at the target position (see, for example, Patent Document 2).

In the field of semiconductor device production, a widely used substrate processing technique involves formation of a fine pattern on a substrate by lithography, and etching of the substrate according to the pattern. Fine patterning has been progressing in association with the progress of lithographic technology, and actinic rays of shorter wavelength have been used. Under this circumstance, a widely applied method involves disposing an underlayer film containing silicon, etc. (which is called “anti-reflective coating”) in order to reduce the influence of reflection of actinic rays from a semiconductor substrate (e.g., Patent Document 5).

### PRIOR ART DOCUMENTS

### Patent Documents

Patent Document 1: JP 2009-234114 A
Patent Document 2: JP 2011-122081 A
Patent Document 3: WO 2014/097993
Patent Document 4: WO 2015/041208
Patent Document 5: JP 2007-163846 A

### SUMMARY OF THE INVENTION

### Problems to be Solved by the Invention

Thus, a demand has arisen for a technique that achieves a desired self-assembled pattern (a pattern structure forming a self-assembled film (which may also be referred to as “microphase-separated structure”)); specifically, a technique for inducing the microphase-separated structure of a block copolymer-containing layer perpendicularly with respect to a substrate.

The present invention is directed to a silicon-containing underlayer film provided between a substrate and a self-assembled film containing a block copolymer, and an object of the present invention is to provide a composition for forming the underlayer film contributing to induction of the microphase-separated structure of the block copolymer-containing layer perpendicularly with respect to the substrate. The present invention is also directed to a self-assembled pattern formation method using the underlayer film-forming composition.

A first aspect of the present invention is a composition for forming a silicon-containing underlayer film for a self-assembled film, the composition being characterized by comprising:
[A] a polysiloxane; and
[B] a solvent, but not comprising a strongly acidic additive.

A second aspect of the present invention is the composition for forming a silicon-containing underlayer film for a self-assembled film according to the first aspect, wherein the strongly acidic additive is a strongly acidic additive having a first acid dissociation constant of 1 or less in water.

A third aspect of the present invention is the composition for forming a silicon-containing underlayer film for a self-assembled film according to the first aspect, wherein the strongly acidic additive is an acid generator.

A fourth aspect of the present invention is the composition for forming a silicon-containing underlayer film for a self-assembled film according to the first aspect, wherein the strongly acidic additive is a photoacid generator.

A fifth aspect of the present invention is the composition for forming a silicon-containing underlayer film for a self-assembled film according to the first aspect, wherein the composition is used for forming a self-assembled pattern.

A sixth aspect of the present invention is the composition for forming a silicon-containing underlayer film for a self-assembled film according to any one of the first to fifth aspects, wherein the polysiloxane [A] contains at least one selected from the group consisting of a hydrolysis condensate of a hydrolyzable silane containing at least one hydrolyzable silane of the following Formula (1):

R¹ₐSi(R²)₄₋ₐ (1)

(wherein R¹ is a group bonded to a silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, an amide group, an alkoxy group, a sulfonyl group, or a cyano group, or any combination of these; R² is a group or atom bonded to a silicon atom, and is each independently an alkoxy group, an aralkyloxy group, an acyloxy group, or a halogen atom; and a is an integer of 0 to 3), a modified hydrolysis condensate prepared by modification of at least some of silanol groups of the condensate of the hydrolyzable silane with an alcohol, a modified hydrolysis condensate prepared by protection of at least some of silanol groups of the condensate of the hydrolyzable silane with an acetal, and a product prepared by dehydration reaction between the condensate of the hydrolyzable silane and an alcohol.

A seventh aspect of the present invention is the composition for forming a silicon-containing underlayer film for a self-assembled film according to any one of the first to sixth aspects, wherein the composition further comprises a pH adjuster.

An eighth aspect of the present invention is the composition for forming a silicon-containing underlayer film for a self-assembled film according to any one of the first to seventh aspects, wherein the composition further comprises a surfactant.

A ninth aspect of the present invention is a production method for a substrate having a self-assembled pattern, the production method comprising:

a step of forming, on a substrate, an underlayer film for a self-assembled film from a composition for forming a silicon-containing underlayer film for a self-assembled film; and

a step of forming a self-assembled film above the underlayer film to thereby form a self-assembled pattern, characterized in that:

the composition for forming a silicon-containing underlayer film for a self-assembled film contains [A] a polysiloxane and [B] a solvent, but does not contain a strongly acidic additive.

A tenth aspect of the present invention is a production method for a substrate having a self-assembled pattern, the production method comprising:

a step of forming, on a substrate, an underlayer film for a self-assembled film from a composition for forming a silicon-containing underlayer film for a self-assembled film;

a step of forming a neutral film on the underlayer film for a self-assembled film; and

a step of forming a self-assembled film on the neutral film to thereby form a self-assembled pattern, characterized in that:

the composition for forming a silicon-containing underlayer film for a self-assembled film contains [A] a polysiloxane and [B] a solvent, but does not contain a strongly acidic additive.

An eleventh aspect of the present invention is a production method for a substrate having a self-assembled pattern, the production method comprising:

a step of forming, on a substrate, an underlayer film for a self-assembled film from a composition for forming a silicon-containing underlayer film for a self-assembled film;

a step of forming a neutral film on a portion of the underlayer film for a self-assembled film;

a step of forming a brush film on a portion of the underlayer film where the neutral film is not formed, to thereby form a template film for a self-assembled pattern from the neutral film and the brush film; and

a step of forming a self-assembled film on the template film for a self-assembled pattern, to thereby form a self-assembled pattern, characterized in that:

the composition for forming a silicon-containing underlayer film for a self-assembled film contains [A] a polysiloxane and [B] a solvent, but does not contain a strongly acidic additive.

A twelfth aspect of the present invention is a production method for a substrate having a self-assembled pattern, the production method comprising:

a step of forming an organic underlayer film on a substrate;

a step of forming, on the organic underlayer film, an underlayer film for a self-assembled film from a composition for forming a silicon-containing underlayer film for a self-assembled film;

a step of forming a neutral film on a portion of the underlayer film for a self-assembled film;

a step of forming a brush film on a portion of the underlayer film where the neutral film is not formed, to thereby form a template film for a self-assembled pattern from the neutral film and the brush film; and

a step of forming a self-assembled film on the template film for a self-assembled pattern, to thereby form a self-assembled pattern, characterized in that:

the composition for forming a silicon-containing underlayer film for a self-assembled film contains [A] a polysiloxane and [B] a solvent, but does not contain a strongly acidic additive.

A thirteenth aspect of the present invention is a production method for a substrate having a self-assembled pattern, the production method comprising:

a step of forming an organic underlayer film on a substrate;

a step of forming, on the organic underlayer film, an underlayer film for a self-assembled film from a composition for forming a silicon-containing underlayer film for a self-assembled film;

a step of forming a neutral film on the underlayer film for a self-assembled film;

a step of forming a resist film on the neutral film;

a step of irradiating the resist film with light, and developing the resist film, to thereby form a resist pattern;

a step of etching the neutral film by using the resist pattern as a mask;

a step of etching or stripping the resist pattern, to thereby pattern the neutral film on the underlayer film for a self-assembled film;

a step of forming a brush film on the underlayer film for a self-assembled film and on the patterned neutral film on the underlayer film;

a step of etching or stripping the brush film on the patterned neutral film, to thereby expose the neutral film and to form a template film for a self-assembled pattern including the neutral film and the brush film; and

a step of forming a self-assembled film on the template film for a self-assembled pattern, to thereby form a self-assembled pattern, characterized in that:

the composition for forming a silicon-containing underlayer film for a self-assembled film contains [A] a polysiloxane and [B] a solvent, but does not contain a strongly acidic additive.

A fourteenth aspect of the present invention is the production method for a substrate having a self-assembled pattern according to any one of the ninth to thirteenth aspects, wherein the production method is used for forming a self-assembled pattern by directed self-assembly (DSA).

A fifteenth aspect of the present invention is the production method for a substrate having a self-assembled pattern according to any one of the ninth to fourteenth aspects, wherein the strongly acidic additive is a photoacid generator.

A sixteenth aspect of the present invention is the production method for a substrate having a self-assembled pattern according to any one of the ninth to fifteenth aspects, wherein the polysiloxane [A] contains at least one selected from the group consisting of a hydrolysis condensate of a hydrolyzable silane containing at least one hydrolyzable silane of the following Formula (1):

R¹ₐSi(R²)₄₋ₐ (1)

(wherein R¹ is a group bonded to a silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, an amide group, an alkoxy group, a sulfonyl group, or a cyano group, or any combination of these; R² is a group or atom bonded to a silicon atom, and is each independently an alkoxy group, an aralkyloxy group, an acyloxy group, or a halogen atom; and a is an integer of 0 to 3), a modified hydrolysis condensate prepared by modification of at least some of silanol groups of the condensate of the hydrolyzable silane with an alcohol, a modified hydrolysis condensate prepared by protection of at least some of silanol groups of the condensate of the hydrolyzable silane with an acetal, and a product prepared by dehydration reaction between the condensate of the hydrolyzable silane and an alcohol.

A seventeenth aspect of the present invention is the production method for a substrate having a self-assembled pattern according to any one of the ninth to sixteenth aspects, wherein the composition for forming a silicon-containing underlayer film for a self-assembled film further contains a pH adjuster.

An eighteenth aspect of the present invention is the production method for a substrate having a self-assembled pattern according to any one of the ninth to seventeenth aspects, wherein the composition for forming a silicon-containing underlayer film for a self-assembled film further contains a surfactant.

A nineteenth aspect of the present invention is a semiconductor device production method comprising:
(1) a step of forming, on a substrate, an underlayer film from the composition for forming a silicon-containing underlayer film for a self-assembled film according to any one of claims 1 to 8;
(2) a step of forming a block copolymer-containing layer on the underlayer film;
(3) a step of phase-separating the block copolymer;
(4) a step of removing a portion of the phase-separated block copolymer; and
(5) a step of etching the substrate.

### Effects of the Invention

The present invention can provide a silicon-containing underlayer film-forming composition that can form a self-assembled film wherein a desired vertical pattern is induced.

### BRIEF DESCRIPTION OF THE DRAWINGS

FIG. 1 is a schematic view showing one embodiment of self-assembled pattern formation.

FIG. 2 shows the microphase-separated structures of self-assembled films prepared in Examples and Comparative Example.

### MODES FOR CARRYING OUT THE INVENTION

A lithographic technique known in the field of semiconductor device production can be used as one means for providing contrast to the surface irregularities or surface energy of an underlayer film of a self-assembled pattern so that the self-assembled pattern is aligned at the aforementioned target position, whereby the underlayer film can be patterned.

When the aforementioned underlayer film is patterned, a stepped portion is formed between the patterned portion of the underlayer film and an exposed portion (i.e., a portion not covered with the underlayer film) of a layer (e.g., a substrate) underlying the underlayer film, and the stepped portion may cause a misalignment of the self-assembled film.

When the layer underlying the patterned underlayer film is a silicon-containing film, an exposed portion of the silicon-containing film (i.e., a portion where the underlayer film is absent due to pattern alignment) exhibits high hydrophilicity caused by silanol groups contained in the silicon-containing film. However, if the hydrophilicity of the exposed portion is excessively high, when a self-assembled film is formed by use of the below-described block copolymer, the block copolymer may fail to be aligned in a desired vertical pattern, resulting in misalignment.

A method for eliminating problems regarding such a stepped portion and hydrophilicity/hydrophobicity involves embedding a polymer-containing brush material into the exposed portion of the silicon-containing film. The brush material is provided so as to prevent a self-assembled pattern from developing in a non-target portion. However, when the brush material is present on the aforementioned patterned underlayer film as the starting point for vertical alignment of the block copolymer of the self-assembled film, the brush material may cause misalignment of the self-assembled film.

The present inventors have conducted studies on the aforementioned problems, and as a result have found that excess leaching of an acidic additive contained in the aforementioned underlayer film or the silicon-containing film underlying the underlayer film hinders the hydrophilicity/hydrophobicity of the surface of the underlayer film, which causes adhesion of the aforementioned brush material onto the underlayer film, resulting in misalignment of the block copolymer forming the self-assembled film.

The present inventors have conducted studies on the composition of a silicon-containing film on the basis of the aforementioned finding, and have accomplished a silicon-containing underlayer film-forming composition that can form a self-assembled film wherein a desired vertical pattern is induced, and a pattern formation method using the composition.

The present invention will next be described.

### [Composition for Forming Silicon-Containing Underlayer Film]

The present invention is directed to a composition for forming a silicon-containing underlayer film that is provided below a self-assembled film; specifically, a composition for forming a silicon-containing underlayer film for a self-assembled film, characterized by containing [A] a polysiloxane and [B] a solvent as essential components, but not containing a strongly acidic additive.

Hereinafter, the composition for forming a silicon-containing underlayer film for a self-assembled film will be referred to simply as “silicon-containing underlayer film-forming composition.”

### [A] Polysiloxane

No particular limitation is imposed on the polysiloxane [A] used in the present invention, so long as it is a polymer having a siloxane bond.

The aforementioned polysiloxane may contain a modified polysiloxane wherein some of silanol groups are modified; for example, a modified polysiloxane wherein some of silanol groups are modified with an alcohol or protected with an acetal.

For example, the aforementioned polysiloxane may contain a hydrolysis condensate of a hydrolyzable silane, and may contain a modified polysiloxane wherein at least some of silanol groups of the hydrolysis condensate are modified with an alcohol or protected with an acetal. The aforementioned hydrolyzable silane corresponding to the hydrolysis condensate may contain one or more hydrolyzable silanes.

The aforementioned polysiloxane may have a structure having a cage-shaped, ladder-shaped, linear, or branched main chain. The aforementioned polysiloxane may be a commercially available polysiloxane.

In the present invention, the “hydrolysis condensate” (i.e., product of hydrolytic condensation) of the aforementioned hydrolyzable silane includes a polyorganosiloxane polymer which is a condensate prepared through complete condensation, and a polyorganosiloxane polymer which is a partial hydrolysis condensate prepared through incomplete condensation. Such a partial hydrolysis condensate is a polymer prepared through hydrolysis and condensation of a hydrolyzable silane compound, as in the case of a condensate prepared through complete condensation. However, the partial hydrolysis condensate contains remaining Si—OH groups, due to partial or incomplete hydrolysis and condensation of the silane compound. The silicon-containing underlayer film-forming composition of the present invention may contain, besides the hydrolysis condensate, an uncondensed hydrolysate (complete hydrolysate or partial hydrolysate) or a remaining monomer (hydrolyzable silane compound).

In the present specification, “hydrolyzable silane” may be referred to simply as “silane compound.”

The polysiloxane [A] may be, for example, a hydrolysis condensate of a hydrolyzable silane containing at least one hydrolyzable silane of the following Formula (1).

R¹ₐSi(R²)₄₋ₐ (1)

In Formula (1), R¹ is a group bonded to a silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, an amide group, an alkoxy group, a sulfonyl group, or a cyano group, or any combination of these.

In Formula (1), R² is a group or atom bonded to a silicon atom, and is each independently an alkoxy group, an aralkyloxy group, an acyloxy group, or a halogen atom.

In Formula (1), a is an integer of 0 to 3.

In Formula (1), the alkyl group is, for example, a linear or branched alkyl group having a carbon atom number of 1 to 10. Examples of the alkyl group include methyl group, ethyl group, n-propyl group, i-propyl group, n-butyl group, i-butyl group, s-butyl group, t-butyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, and 1-ethyl-2-methyl-n-propyl group.

The alkyl group may be a cyclic alkyl group. Examples of the cyclic alkyl group having a carbon atom number of 3 to 10 include cycloalkyl groups, such as cyclopropyl group, cyclobutyl group, 1-methyl-cyclopropyl group, 2-methyl-cyclopropyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, and 2-ethyl-3-methyl-cyclopropyl group; and bridged cyclic cycloalkyl groups, such as bicyclobutyl group, bicyclopentyl group, bicyclohexyl group, bicycloheptyl group, bicyclooctyl group, bicyclononyl group, and bicyclodecyl group.

The aryl group may be a phenyl group, a monovalent group derived from a condensed-ring aromatic hydrocarbon compound through removal of one hydrogen atom, or a monovalent group derived from a linked-ring aromatic hydrocarbon compound through removal of one hydrogen atom. No particular limitation is imposed on the carbon atom number of the aryl group, but the carbon atom number is preferably 40 or less, more preferably 30 or less, still more preferably 20 or less.

Examples of the aryl group include, but are not limited to, C₆₋₂₀ aryl groups, such as phenyl group, 1-naphthyl group, 2-naphthyl group, 1-anthryl group, 2-anthryl group, 9-anthryl group, 1-phenanthryl group, 2-phenanthryl group, 3-phenanthryl group, 4-phenanthryl group, 9-phenanthryl group, 1-naphthacenyl group, 2-naphthacenyl group, 5-naphthacenyl group, 2-chrysenyl group, 1-pyrenyl group, 2-pyrenyl group, pentacenyl group, benzopyrenyl group, triphenylenyl group, biphenyl-2-yl group (o-biphenylyl group), biphenyl-3-yl group (m-biphenylyl group), biphenyl-4-yl group (p-biphenylyl group), p-terphenyl-4-yl group, m-terphenyl-4-yl group, o-terphenyl-4-yl group, 1,1′-binaphthyl-2-yl group, and 2,2′-binaphthyl-1-yl group.

The aralkyl group is an alkyl group substituted with an aryl group, and specific examples of the aryl group and the alkyl group are the same as those described above. No particular limitation is imposed on the carbon atom number of the aralkyl group, but the carbon atom number is preferably 40 or less, more preferably 30 or less, still more preferably 20 or less.

Specific examples of the aralkyl group include, but are not limited to, phenylmethyl group (benzyl group), 2-phenylethylene group, 3-phenyl-n-propyl group, 4-phenyl-n-butyl group, 5-phenyl-n-pentyl group, 6-phenyl-n-hexyl group, 7-phenyl-n-heptyl group, 8-phenyl-n-octyl group, 9-phenyl-n-nonyl group, and 10-phenyl-n-decyl group.

The aforementioned halogenated alkyl group, halogenated aryl group, or halogenated aralkyl group is an alkyl group, aryl group, or aralkyl group substituted with one or more halogen atoms, and specific examples of the alkyl group, the aryl group, and the aralkyl group are the same as those described above.

Examples of the halogen atom include a fluorine atom, a chlorine atom, a bromine atom, and an iodine atom.

No particular limitation is imposed on the carbon atom number of the halogenated alkyl group, but the carbon atom number is preferably 40 or less, more preferably 30 or less, still more preferably 20 or less, much more preferably 10 or less.

Specific examples of the halogenated alkyl group include, but are not limited to, monofluoromethyl group, difluoromethyl group, trifluoromethyl group, bromodifluoromethyl group, 2-chloroethyl group, 2-bromoethyl group, 1,1-difluoroethyl group, 2,2,2-trifluoroethyl group, 1,1,2,2-tetrafluoroethyl group, 2-chloro-1,1,2-trifluoroethyl group, pentafluoroethyl group, 3-bromopropyl group, 2,2,3,3-tetrafluoropropyl group, 1,1,2,3,3,3-hexafluoropropyl group, 1,1,1,3,3,3-hexafluoropropan-2-yl group, 3-bromo-2-methylpropyl group, 4-bromobutyl group, and perfluoropentyl group.

No particular limitation is imposed on the carbon atom number of the halogenated aryl group, but the carbon atom number is preferably 40 or less, more preferably 30 or less, still more preferably 20 or less.

Specific examples of the halogenated aryl group include, but are not limited to, 2-fluorophenyl group, 3-fluorophenyl group, 4-fluorophenyl group, 2,3-difluorophenyl group, 2,4-difluorophenyl group, 2,5-difluorophenyl group, 2,6-difluorophenyl group, 3,4-difluorophenyl group, 3,5-difluorophenyl group, 2,3,4-trifluorophenyl group, 2,3,5-trifluorophenyl group, 2,3,6-trifluorophenyl group, 2,4,5-trifluorophenyl group, 2,4,6-trifluorophenyl group, 3,4,5-trifluorophenyl group, 2,3,4,5-tetrafluorophenyl group, 2,3,4,6-tetrafluorophenyl group, 2,3,5,6-tetrafluorophenyl group, pentafluorophenyl group, 2-fluoro-1-naphthyl group, 3-fluoro-1-naphthyl group, 4-fluoro-1-naphthyl group, 6-fluoro-1-naphthyl group, 7-fluoro-1-naphthyl group, 8-fluoro-1-naphthyl group, 4,5-difluoro-1-naphthyl group, 5,7-difluoro-1-naphthyl group, 5,8-difluoro-1-naphthyl group, 5,6,7,8-tetrafluoro-1-naphthyl group, heptafluoro-1-naphthyl group, 1-fluoro-2-naphthyl group, 5-fluoro-2-naphthyl group, 6-fluoro-2-naphthyl group, 7-fluoro-2-naphthyl group, 5,7-difluoro-2-naphthyl group, heptafluoro-2-naphthyl group, and groups prepared by arbitrary substitution of a fluorine atom (fluoro group) of any of the aforementioned groups with a chlorine atom (chloro group), a bromine atom (bromo group), or an iodine atom (iodo group).

No particular limitation is imposed on the carbon atom number of the halogenated aralkyl group, but the carbon atom number is preferably 40 or less, more preferably 30 or less, still more preferably 20 or less.

Specific examples of the halogenated aralkyl group include, but are not limited to, 2-fluorobenzyl group, 3-fluorobenzyl group, 4-fluorobenzyl group, 2,3-difluorobenzyl group, 2,4-difluorobenzyl group, 2,5-difluorobenzyl group, 2,6-difluorobenzyl group, 3,4-difluorobenzyl group, 3,5-difluorobenzyl group, 2,3,4-trifluorobenzyl group, 2,3,5-trifluorobenzyl group, 2,3,6-trifluorobenzyl group, 2,4,5-trifluorobenzyl group, 2,4,6-trifluorobenzyl group, 2,3,4,5-tetrafluorobenzyl group, 2,3,4,6-tetrafluorobenzyl group, 2,3,5,6-tetrafluorobenzyl group, 2,3,4,5,6-pentafluorobenzyl group, and groups prepared by arbitrary substitution of a fluorine atom (fluoro group) of any of the aforementioned groups with a chlorine atom (chloro group), a bromine atom (bromo group), or an iodine atom (iodo group).

The aforementioned alkoxyalkyl group, alkoxyaryl group, or alkoxyaralkyl group is an alkyl group, aryl group, or aralkyl group substituted with one or more alkoxy groups, and specific examples of the alkyl group, the aryl group, and the aralkyl group are the same as those described above.

The alkoxy group may be, for example, an alkoxy group having a linear, branched, or cyclic alkyl moiety having a carbon atom number of 1 to 20. Examples of the linear or branched alkoxy group include methoxy group, ethoxy group, n-propoxy group, i-propoxy group, n-butoxy group, i-butoxy group, s-butoxy group, t-butoxy group, n-pentyloxy group, 1-methyl-n-butoxy group, 2-methyl-n-butoxy group, 3-methyl-n-butoxy group, 1,1-dimethyl-n-propoxy group, 1,2-dimethyl-n-propoxy group, 2,2-dimethyl-n-propoxy group, 1-ethyl-n-propoxy group, n-hexyloxy group, 1-methyl-n-pentyloxy group, 2-methyl-n-pentyloxy group, 3-methyl-n-pentyloxy group, 4-methyl-n-pentyloxy group, 1,1-dimethyl-n-butoxy group, 1,2-dimethyl-n-butoxy group, 1,3-dimethyl-n-butoxy group, 2,2-dimethyl-n-butoxy group, 2,3-dimethyl-n-butoxy group, 3,3-dimethyl-n-butoxy group, 1-ethyl-n-butoxy group, 2-ethyl-n-butoxy group, 1,1,2-trimethyl-n-propoxy group, 1,2,2-trimethyl-n-propoxy group, 1-ethyl-1-methyl-n-propoxy group, and 1-ethyl-2-methyl-n-propoxy group. Examples of the cyclic alkoxy group include cyclopropoxy group, cyclobutoxy group, 1-methyl-cyclopropoxy group, 2-methyl-cyclopropoxy group, cyclopentyloxy group, 1-methyl-cyclobutoxy group, 2-methyl-cyclobutoxy group, 3-methyl-cyclobutoxy group, 1,2-dimethyl-cyclopropoxy group, 2,3-dimethyl-cyclopropoxy group, 1-ethyl-cyclopropoxy group, 2-ethyl-cyclopropoxy group, cyclohexyloxy group, 1-methyl-cyclopentyloxy group, 2-methyl-cyclopentyloxy group, 3-methyl-cyclopentyloxy group, 1-ethyl-cyclobutoxy group, 2-ethyl-cyclobutoxy group, 3-ethyl-cyclobutoxy group, 1,2-dimethyl-cyclobutoxy group, 1,3-dimethyl-cyclobutoxy group, 2,2-dimethyl-cyclobutoxy group, 2,3-dimethyl-cyclobutoxy group, 2,4-dimethyl-cyclobutoxy group, 3,3-dimethyl-cyclobutoxy group, 1-n-propyl-cyclopropoxy group, 2-n-propyl-cyclopropoxy group, 1-i-propyl-cyclopropoxy group, 2-i-propyl-cyclopropoxy group, 1,2,2-trimethyl-cyclopropoxy group, 1,2,3-trimethyl-cyclopropoxy group, 2,2,3-trimethyl-cyclopropoxy group, 1-ethyl-2-methyl-cyclopropoxy group, 2-ethyl-1-methyl-cyclopropoxy group, 2-ethyl-2-methyl-cyclopropoxy group, and 2-ethyl-3-methyl-cyclopropoxy group.

Specific examples of the aforementioned alkoxyalkyl group include, but are not limited to, lower (carbon atom number of about 5 or less) alkyloxy lower (carbon atom number of about 5 or less) alkyl groups, such as methoxymethyl group, ethoxymethyl group, 1-ethoxyethyl group, 2-ethoxyethyl group, and ethoxymethyl group.

Specific examples of the aforementioned alkoxyaryl group include, but are not limited to, 2-methoxyphenyl group, 3-methoxyphenyl group, 4-methoxyphenyl group, 2-(1-ethoxy)phenyl group, 3-(1-ethoxy)phenyl group, 4-(1-ethoxy)phenyl group, 2-(2-ethoxy)phenyl group, 3-(2-ethoxy)phenyl group, 4-(2-ethoxy)phenyl group, 2-methoxynaphthalen-1-yl group, 3-methoxynaphthalen-1-yl group, 4-methoxynaphthalen-1-yl group, 5-methoxynaphthalen-1-yl group, 6-methoxynaphthalen-1-yl group, and 7-methoxynaphthalen-1-yl group.

Specific examples of the aforementioned alkoxyaralkyl group include, but are not limited to, 3-(methoxyphenyl)benzyl group and 4-(methoxyphenyl)benzyl group.

The aforementioned alkenyl group may be, for example, a C₂₋₁₀ alkenyl group. Examples of the alkenyl group include ethenyl group (vinyl group), 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group, and 3-cyclohexenyl group. Other examples of the alkenyl group include bridged cyclic alkenyl groups such as bicycloheptenyl group (norbornyl group).

Examples of the substituent of the aforementioned alkyl group, aryl group, aralkyl group, halogenated alkyl group, halogenated aryl group, halogenated aralkyl group, alkoxyalkyl group, alkoxyaryl group, alkoxyaralkyl group, or alkenyl group include an alkyl group, an aryl group, an aralkyl group, a halogenated alkyl group, a halogenated aryl group, a halogenated aralkyl group, an alkoxyalkyl group, an aryloxy group, an alkoxyaryl group, an alkoxyaralkyl group, an alkenyl group, an alkoxy group, and an aralkyloxy group. Specific examples of these groups and preferred carbon atom numbers thereof are the same as those described above or below.

The aryloxy group described above as the substituent is a group wherein an aryl group is bonded to another group via an oxygen atom (—O—), and specific examples of the aryl group are the same as those described above. No particular limitation is imposed on the carbon atom number of the aryloxy group, but the carbon atom number is preferably 40 or less, more preferably 30 or less, still more preferably 20 or less. Specific examples of the aryloxy group include, but are not limited to, phenoxy group and naphthalen-2-yloxy group.

When two or more substituents are present, the substituents may be bonded together to form a ring.

Examples of the organic group containing an epoxy group include glycidoxymethyl group, glycidoxyethyl group, glycidoxypropyl group, glycidoxybutyl group, and epoxycyclohexyl group.

Examples of the organic group containing an acryloyl group include acryloylmethyl group, acryloylethyl group, and acryloylpropyl group.

Examples of the organic group containing a methacryloyl group include methacryloylmethyl group, methacryloylethyl group, and methacryloylpropyl group.

Examples of the organic group containing a mercapto group include ethylmercapto group, butylmercapto group, hexylmercapto group, octylmercapto group, and mercaptophenyl group.

Examples of the organic group containing an amino group include, but are not limited to, amino group, aminomethyl group, aminoethyl group, aminophenyl group, dimethylaminoethyl group, and dimethylaminopropyl group.

Examples of the organic group containing an alkoxy group include, but are not limited to, methoxymethyl group and methoxyethyl group. However, the organic group excludes a group wherein an alkoxy group is directly bonded to a silicon atom.

Examples of the organic group containing a sulfonyl group include, but are not limited to, sulfonylalkyl group and sulfonylaryl group.

Examples of the organic group containing a cyano group include cyanoethyl group, cyanopropyl group, cyanophenyl group, and thiocyanate group.

The aforementioned aralkyloxy group is a group derived from an aralkyl alcohol through removal of a hydrogen atom from the hydroxy group of the alcohol. Specific examples of the aralkyl group are the same as those described above.

No particular limitation is imposed on the carbon atom number of the aralkyloxy group, but the carbon atom number is, for example, 40 or less, preferably 30 or less, more preferably 20 or less.

Specific examples of the aralkyloxy group include, but are not limited to, phenylmethyloxy group (benzyloxy group), 2-phenylethyleneoxy group, 3-phenyl-n-propyloxy group, 4-phenyl-n-butyloxy group, 5-phenyl-n-pentyloxy group, 6-phenyl-n-hexyloxy group, 7-phenyl-n-heptyloxy group, 8-phenyl-n-octyloxy group, 9-phenyl-n-nonyloxy group, and 10-phenyl-n-decyloxy group.

The acyloxy group is a group derived from a carboxylic compound through removal of a hydrogen atom from the carboxyl group (—COOH) of the compound. Typical examples of the acyloxy group include, but are not limited to, an alkylcarbonyloxy group, an arylcarbonyloxy group, or an aralkylcarbonyloxy group, which is respectively derived from an alkylcarboxylic acid, an arylcarboxylic acid, or an aralkylcarboxylic acid through removal of a hydrogen atom from the carboxyl group of the acid. Specific examples of the alkyl group, the aryl group, and the aralkyl group of such alkylcarboxylic acid, arylcarboxylic acid, and aralkylcarboxylic acid are the same as those described above.

Specific examples of the acyloxy group include C₂₋₂₀ acyloxy groups, such as methylcarbonyloxy group, ethylcarbonyloxy group, n-propylcarbonyloxy group, i-propylcarbonyloxy group, n-butylcarbonyloxy group, i-butylcarbonyloxy group, s-butylcarbonyloxy group, t-butylcarbonyloxy group, n-pentylcarbonyloxy group, 1-methyl-n-butylcarbonyloxy group, 2-methyl-n-butylcarbonyloxy group, 3-methyl-n-butylcarbonyloxy group, 1,1-dimethyl-n-propylcarbonyloxy group, 1,2-dimethyl-n-propylcarbonyloxy group, 2,2-dimethyl-n-propylcarbonyloxy group, 1-ethyl-n-propylcarbonyloxy group, n-hexylcarbonyloxy group, 1-methyl-n-pentylcarbonyloxy group, 2-methyl-n-pentylcarbonyloxy group, 3-methyl-n-pentylcarbonyloxy group, 4-methyl-n-pentylcarbonyloxy group, 1,1-dimethyl-n-butylcarbonyloxy group, 1,2-dimethyl-n-butylcarbonyloxy group, 1,3-dimethyl-n-butylcarbonyloxy group, 2,2-dimethyl-n-butylcarbonyloxy group, 2,3-dimethyl-n-butylcarbonyloxy group, 3,3-dimethyl-n-butylcarbonyloxy group, 1-ethyl-n-butylcarbonyloxy group, 2-ethyl-n-butylcarbonyloxy group, 1,1,2-trimethyl-n-propylcarbonyloxy group, 1,2,2-trimethyl-n-propylcarbonyloxy group, 1-ethyl-1-methyl-n-propylcarbonyloxy group, 1-ethyl-2-methyl-n-propylcarbonyloxy group, phenylcarbonyloxy group, and tosylcarbonyloxy group.

Specific examples of the hydrolyzable silane of Formula (1) include, but are not limited to, tetramethoxysilane, tetrachlorosilane, tetraacetoxysilane, tetraethoxysilane, tetra-n-propoxysilane, tetra-i-propoxysilane, tetra-n-butoxysilane, methyltrimethoxysilane, methyltrichlorosilane, methyltriacetoxysilane, methyltriethoxysilane, methyltripropoxysilane, methyltributoxysilane, methyltriamyloxysilane, methyltriphenoxysilane, methyltribenzyloxysilane, methyltriphenethyloxysilane, glycidoxymethyltrimethoxysilane, glycidoxymethyltriethoxysilane, α-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltributoxysilane, γ-glycidoxypropyltriphenoxysilane, α-glycidoxybutyltrimethoxysilane, α-glycidoxybutyltriethoxysilane, β-glycidoxybutyltriethoxysilane, γ-glycidoxybutyltrimethoxysilane, γ-glycidoxybutyltriethoxysilane, δ-glycidoxybutyltrimethoxysilane, δ-glycidoxybutyltriethoxysilane, (3,4-epoxycyclohexyl)methyltrimethoxysilane, (3,4-epoxycyclohexyl)methyltriethoxysilane, β-(3,4-epoxycyclohexyl)ethyltrimethoxysilane, β-(3,4-epoxycyclohexyl)ethyltriethoxysilane, β-(3,4-epoxycyclohexyl)ethyltripropoxysilane, β-(3,4-epoxycyclohexyl)ethyltributoxysilane, β-(3,4-epoxycyclohexyl)ethyltriphenoxysilane, γ-(3,4-epoxycyclohexyl)propyltrimethoxysilane, γ-(3,4-epoxycyclohexyl)propyltriethoxysilane, δ-(3,4-epoxycyclohexyl)butyltrimethoxysilane, δ-(3,4-epoxycyclohexyl)butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylethyldimethoxysilane, α-glycidoxypropylmethyldimethoxysilane, α-glycidoxypropylmethyldiethoxysilane, β-glycidoxypropylmethyldimethoxysilane, β-glycidoxypropylethyldimethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylmethyldiphenoxysilane, γ-glycidoxypropylethyldimethoxysilane, γ-glycidoxypropylethyldiethoxysilane, γ-glycidoxypropylvinyldimethoxysilane, γ-glycidoxypropylvinyldiethoxysilane, ethyltrimethoxysilane, ethyltriethoxysilane, vinyltrimethoxysilane, vinyltriethoxysilane, vinyltrichlorosilane, vinyltriacetoxysilane, methylvinyldimethoxysilane, methylvinyldiethoxysilane, methylvinyldichlorosilane, methylvinyldiacetoxysilane, dimethylvinylmethoxysilane, dimethylvinylethoxysilane, dimethylvinylchlorosilane, dimethylvinylacetoxysilane, divinyldimethoxysilane, divinyldiethoxysilane, divinyldichlorosilane, divinyldiacetoxysilane, γ-glycidoxypropylvinyldimethoxysilane, γ-glycidoxypropylvinyldiethoxysilane, allyltrimethoxysilane, allyltriethoxysilane, allyltrichlorosilane, allyltriacetoxysilane, allylmethyldimethoxysilane, allylmethyldiethoxysilane, allylmethyldichlorosilane, allylmethyldiacetoxysilane, allyldimethylmethoxysilane, allyldimethylethoxysilane, allyldimethylchlorosilane, allyldimethylacetoxysilane, diallyldimethoxysilane, diallyldiethoxysilane, diallyldichlorosilane, diallyldiacetoxysilane, 3-allylaminopropyltrimethoxysilane, 3-allylaminopropyltriethoxysilane, p-styryltrimethoxysilane, phenyltrimethoxysilane, phenyltriethoxysilane, phenyltrichlorosilane, phenyltriacetoxysilane, phenylmethyldimethoxysilane, phenylmethyldiethoxysilane, phenylmethyldichlorosilane, phenylmethyldiacetoxysilane, phenyldimethylmethoxysilane, phenyldimethylethoxysilane, phenyldimethylchlorosilane, phenyldimethylacetoxysilane, diphenylmethylmethoxysilane, diphenylmethylethoxysilane, diphenylmethylchlorosilane, diphenylmethylacetoxysilane, diphenyldimethoxysilane, diphenyldiethoxysilane, diphenyldichlorosilane, diphenyldiacetoxysilane, triphenylmethoxysilane, triphenylethoxysilane, triphenylacetoxysilane, triphenylchlorosilane, 3-phenylaminopropyltrimethoxysilane, 3-phenylaminopropyltriethoxysilane, dimethoxymethyl-3-(3-phenoxypropylthiopropyl)silane, triethoxy((2-methoxy-4-(methoxymethyl)phenoxy)methyl)silane, benzyltrimethoxysilane, benzyltriethoxysilane, benzylmethyldimethoxysilane, benzylmethyldiethoxysilane, benzyldimethylmethoxysilane, benzyldimethylethoxysilane, benzyldimethylchlorosilane, phenethyltrimethoxysilane, phenethyltriethoxysilane, phenethyltrichlorosilane, phenethyltriacetoxysilane, phenethylmethyldimethoxysilane, phenethylmethyldiethoxysilane, phenethylmethyldichlorosilane, phenethylmethyldiacetoxysilane, methoxyphenyltrimethoxysilane, methoxyphenyltriethoxysilane, methoxyphenyltriacetoxysilane, methoxyphenyltrichlorosilane, methoxybenzyltrimethoxysilane, methoxybenzyltriethoxysilane, methoxybenzyltriacetoxysilane, methoxybenzyltrichlorosilane, methoxyphenethyltrimethoxysilane, methoxyphenethyltriethoxysilane, methoxyphenethyltriacetoxysilane, methoxyphenethyltrichlorosilane, ethoxyphenyltrimethoxysilane, ethoxyphenyltriethoxysilane, ethoxyphenyltriacetoxysilane, ethoxyphenyltrichlorosilane, ethoxybenzyltrimethoxysilane, ethoxybenzyltriethoxysilane, ethoxybenzyltriacetoxysilane, ethoxybenzyltrichlorosilane, i-propoxyphenyltrimethoxysilane, i-propoxyphenyltriethoxysilane, i-propoxyphenyltriacetoxysilane, i-propoxyphenyltrichlorosilane, i-propoxybenzyltrimethoxysilane, i-propoxybenzyltriethoxysilane, i-propoxybenzyltriacetoxysilane, i-propoxybenzyltrichlorosilane, t-butoxyphenyltrimethoxysilane, t-butoxyphenyltriethoxysilane, t-butoxyphenyltriacetoxysilane, t-butoxyphenyltrichlorosilane, t-butoxybenzyltrimethoxysilane, t-butoxybenzyltriethoxysilane, t-butoxybenzyltriacetoxysilane, t-butoxybenzyltrichlorosilane, methoxynaphthyltrimethoxysilane, methoxynaphthyltriethoxysilane, methoxynaphthyltriacetoxysilane, methoxynaphthyltrichlorosilane, ethoxynaphthyltrimethoxysilane, ethoxynaphthyltriethoxysilane, ethoxynaphthyltriacetoxysilane, ethoxynaphthyltrichlorosilane, γ-chloropropyltrimethoxysilane, γ-chloropropyltriethoxysilane, γ-chloropropyltriacetoxysilane, 3,3,3-trifluoropropyltrimethoxysilane, γ-methacryloxypropyltrimethoxysilane, γ-mercaptopropyltrimethoxysilane, γ-mercaptopropyltriethoxysilane, β-cyanoethyltriethoxysilane, thiocyanatopropyltriethoxysilane, chloromethyltrimethoxysilane, chloromethyltriethoxysilane, triethoxysilylpropyldiallyl isocyanurate, bicyclo[2,2,1]heptenyltriethoxysilane, benzenesulfonylpropyltriethoxysilane, benzenesulfonamidepropyltriethoxysilane, dimethylaminopropyltrimethoxysilane, dimethyldimethoxysilane, phenylmethyldimethoxysilane, dimethyldiethoxysilane, phenylmethyldiethoxysilane, γ-chloropropylmethyldimethoxysilane, γ-chloropropylmethyldiethoxysilane, dimethyldiacetoxysilane, γ-methacryloxypropylmethyldimethoxysilane, γ-methacryloxypropylmethyldiethoxysilane, γ-mercaptopropylmethyldimethoxysilane, γ-mercaptopropylmethyldiehoxysilane, methylvinyldimethoxysilane, methylvinyldiethoxysilane, and silanes of the following Formulae (A-1) to (A-41).

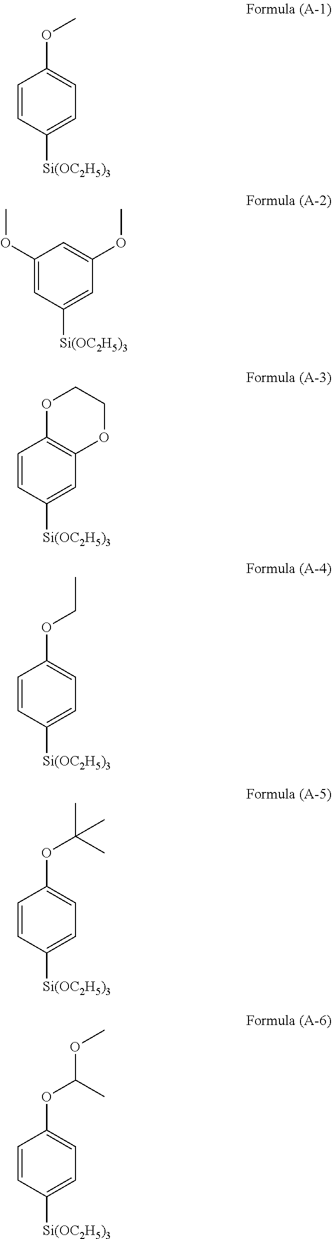

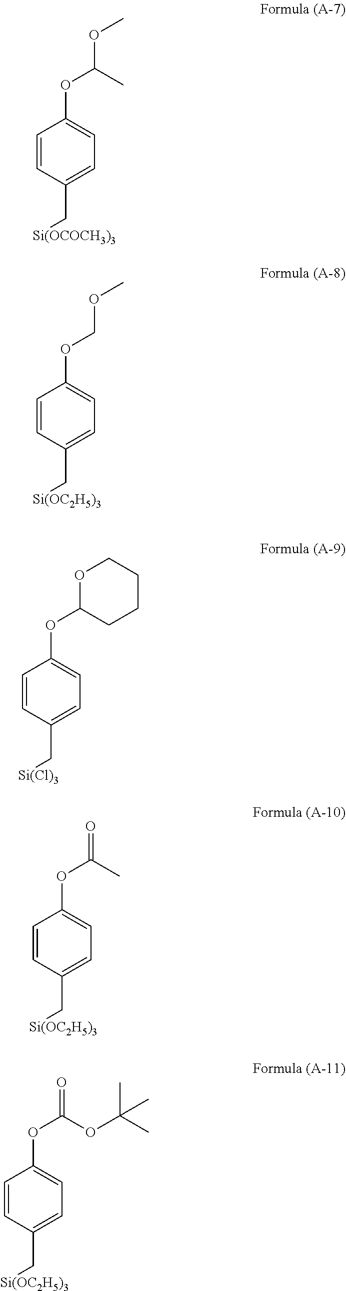

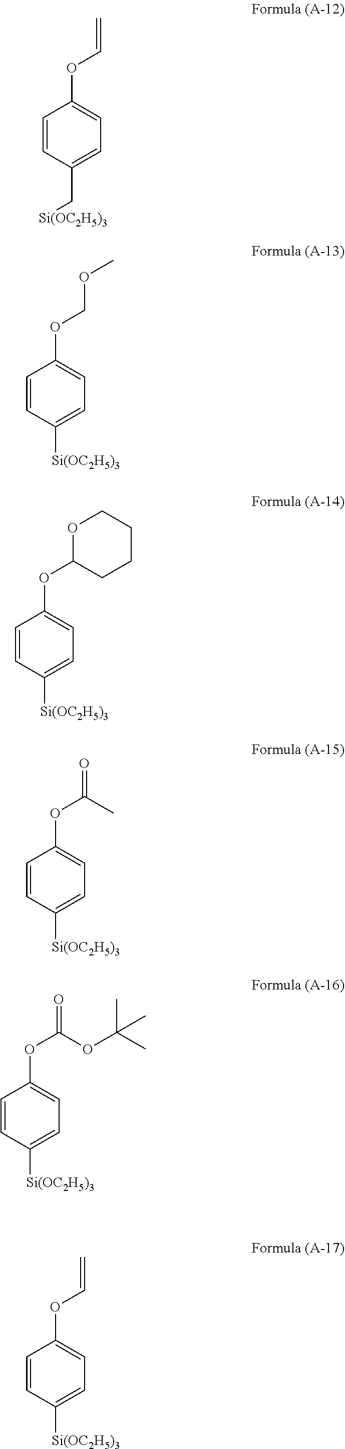

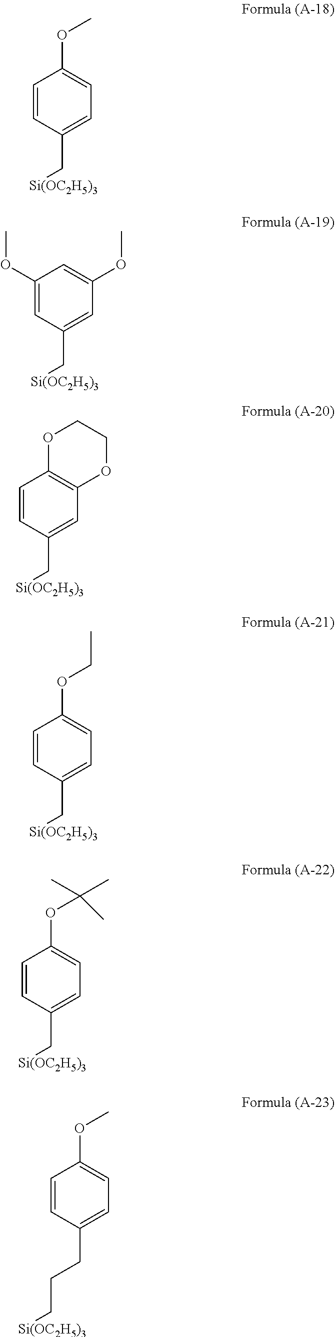

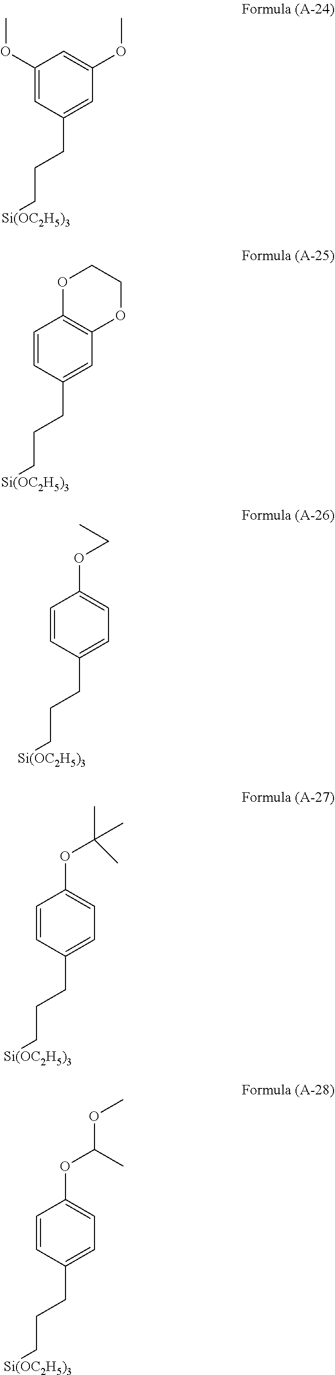

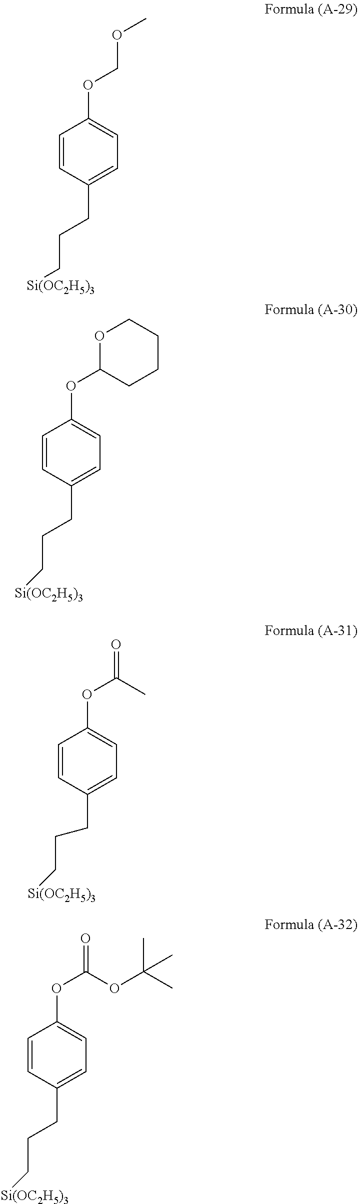

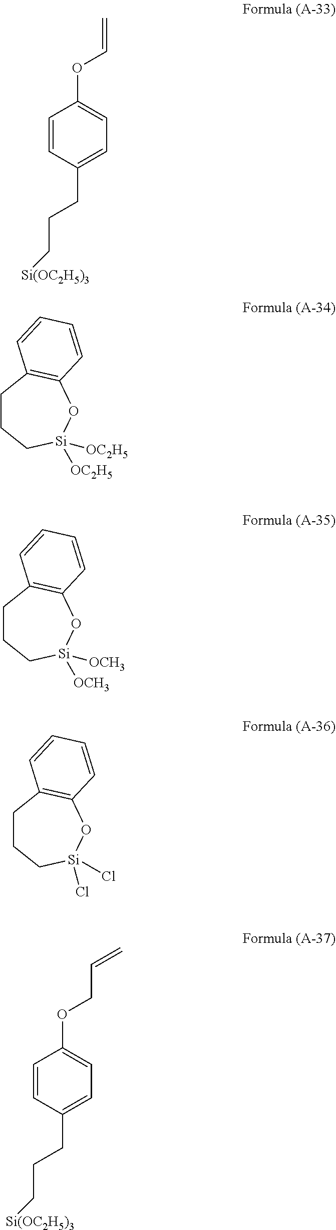

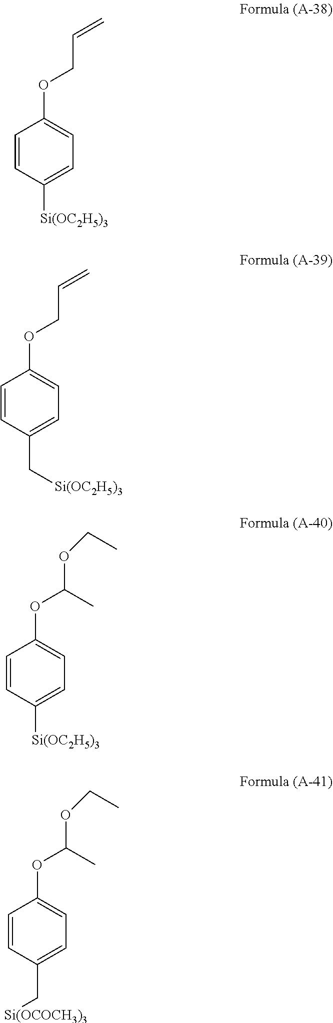

The polysiloxane [A] may be, for example, a hydrolysis condensate of a hydrolyzable silane containing a hydrolyzable silane of the following Formula (2) in addition to or in place of the hydrolyzable silane of Formula (1).

(R³_{b}Si(R⁴)_{3-b})₂R⁵_{c} (2)

In Formula (2), R³ is a group bonded to a silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, an amide group, an alkoxy group, a sulfonyl group, or a cyano group, or any combination of these.

In Formula (2), R⁴ is a group or atom bonded to a silicon atom, and is each independently an alkoxy group, an aralkyloxy group, an acyloxy group, or a halogen atom.

In Formula (2), R⁵ is a group bonded to a silicon atom, and is each independently an alkylene group or an arylene group.

In Formula (2), b is an integer of 0 or 1, and c is an integer of 0 or 1.

Specific examples of the groups of R³ and preferred carbon atom numbers thereof are the same as those described above regarding R¹.

Specific examples of the groups of R⁴ and preferred carbon atom numbers thereof are the same as those described above regarding R².

Specific examples of the alkylene group of R⁵ include, but are not limited to, alkylene groups, for example, linear alkylene groups such as methylene group, ethylene group, trimethylene group, tetramethylene group, pentamethylene group, hexamethylene group, heptamethylene group, octamethylene group, nonamethylene group, and decamethylene group, and branched alkylene groups such as 1-methyltrimethylene group, 2-methyltrimethylene group, 1,1-dimethylethylene group, 1-methyltetramethylene group, 2-methyltetramethylene group, 1,1-dimethyltrimethylene group, 1,2-dimethyltrimethylene group, 2,2-dimethyltrimethylene group, and 1-ethyltrimethylene group; and alkanetriyl groups such as methanetriyl group, ethane-1,1,2-triyl group, ethane-1,2,2-triyl group, ethane-2,2,2-triyl group, propane-1,1,1-triyl group, propane-1,1,2-triyl group, propane-1,2,3-triyl group, propane-1,2,2-triyl group, propane-1,1,3-triyl group, butane-1,1,1-triyl group, butane-1,1,2-triyl group, butane-1,1,3-triyl group, butane-1,2,3-triyl group, butane-1,2,4-triyl group, butane-1,2,2-triyl group, butane-2,2,3-triyl group, 2-methylpropane-1,1,1-triyl group, 2-methylpropane-1,1,2-triyl group, and 2-methylpropane-1,1,3-triyl group.

Specific examples of the arylene group include, but are not limited to, 1,2-phenylene group, 1,3-phenylene group, 1,4-phenylene group; groups derived from a condensed-ring aromatic hydrocarbon compound through removal of two hydrogen atoms on the aromatic ring, such as 1,5-naphthalenediyl group, 1,8-naphthalenediyl group, 2,6-naphthalenediyl group, 2,7-naphthalenediyl group, 1,2-anthracenediyl group, 1,3-anthracenediyl group, 1,4-anthracenediyl group, 1,5-anthracenediyl group, 1,6-anthracenediyl group, 1,7-anthracenediyl group, 1,8-anthracenediyl group, 2,3-anthracenediyl group, 2,6-anthracenediyl group, 2,7-anthracenediyl group, 2,9-anthracenediyl group, 2,10-anthracenediyl group, and 9,10-anthracenediyl group; and groups derived from a linked-ring aromatic hydrocarbon compound through removal of two hydrogen atoms on the aromatic ring, such as 4,4′-biphenyldiyl group and 4,4″-p-terphenyldiyl group.

In Formula (2), b is preferably 0 or 1, more preferably 0,

In Formula (2), c is preferably 1.

Specific examples of the hydrolyzable silane of Formula (2) include, but are not limited to, methylenebistrimethoxysilane, methylenebistrichlorosilane, methylenebistriacetoxysilane, ethylenebistriethoxysilane, ethylenebistrichlorosilane, ethylenebistriacetoxysilane, propylenebistriethoxysilane, butylenebistrimethoxysilane, phenylenebistrimethoxysilane, phenylenebistriethoxysilane, phenylenebismethyldiethoxysilane, phenylenebismethyldimethoxysilane, naphthylenebistrimethoxysilane, bistrimethoxydisilane, bistriethoxydisilane, bisethyldiethoxydisilane, and bismethyldimethoxydisilane.

The polysiloxane [A] may be, for example, a hydrolysis condensate of a hydrolyzable silane containing an additional hydrolyzable silane described below in addition to the hydrolyzable silane of Formula (1) and/or the hydrolyzable silane of Formula (2).

Examples of the additional hydrolyzable silane include, but are not limited to, a silane compound having an onium group in the molecule, a silane compound having a sulfone group, a silane compound having a sulfonamide group, a silane compound having a cyclic urea structure in the molecule, and a silane compound having a cyclic amino group.

### <Silane Compound Having Onium Group in Molecule (Hydrolyzable Organosilane)>

A silane compound having an onium group in the molecule is expected to promote the crosslinking reaction of a hydrolyzable silane in an effective and efficient manner.

One preferred example of the silane compound having an onium group in the molecule is shown in the following Formula (3).

R¹¹_{f}R¹²_{g}Si(R¹³)_{4-(f+g)} (3)

R¹¹ is a group bonded to a silicon atom, and is an onium group or an organic group containing the onium group.

R¹² is a group bonded to a silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, or a cyano group, or any combination of these.

R¹³ is a group or atom bonded to a silicon atom, and is each independently an alkoxy group, an aralkyloxy group, an acyloxy group, or a halogen atom.

In Formula (3), f is 1 or 2; g is 0 or 1; and f and g satisfy a relation of 1≤f+g≤2.

Specific examples of the aforementioned alkyl group, aryl group, aralkyl group, halogenated alkyl group, halogenated aryl group, halogenated aralkyl group, alkoxyalkyl group, alkoxyaryl group, alkoxyaralkyl group, alkenyl group, and organic group containing an epoxy group, an acryloyl group, a methacryloyl group, a mercapto group, an amino group, or a cyano group, an alkoxy group, an aralkyloxy group, acyloxy group, and a halogen atom, and specific examples of the substituent of the alkyl group, the aryl group, the aralkyl group, the halogenated alkyl group, the halogenated aryl group, the halogenated aralkyl group, the alkoxyalkyl group, the alkoxyaryl group, the alkoxyaralkyl group, and the alkenyl group, and preferred carbon atom numbers thereof are the same as those described above regarding R¹(for R¹²) and regarding R² (for R¹³).

More specifically, the onium group is, for example, a cyclic ammonium group or a chain ammonium group, and is preferably a tertiary ammonium group or a quaternary ammonium group.

Preferred specific examples of the onium group or the organic group containing the onium group include a cyclic ammonium group or a chain ammonium group, or an organic group containing at least one of these ammonium groups. Preferred is a tertiary ammonium group or a quaternary ammonium group, or an organic group containing at least one of these ammonium groups.

When the onium group is a cyclic ammonium group, the nitrogen atom forming the ammonium group also serves as an atom forming the ring. In this case, the nitrogen atom forming the ring and the silicon atom are bonded directly or via a divalent linking group, or the carbon atom forming the ring and the silicon atom are bonded directly or via a divalent linking group.

In one preferred embodiment of the present invention, R¹¹ (i.e., the group bonded to a silicon atom) is a heteroaromatic cyclic ammonium group of the following Formula (Si).

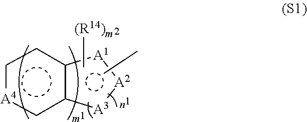

In Formula (Si), A¹, A², A³, and A⁴ are each independently a group of any of the following Formulae (J1) to (J3), and at least one of A¹ to A⁴ is a group of the following Formula (J2). Depending on the bonding between the silicon atom in Formula (3) and any of A¹ to A⁴, each of A¹ to A⁴ and the ring-forming atom adjacent thereto form a single bond or a double bond. This determines whether the thus-formed ring exhibits aromaticity.

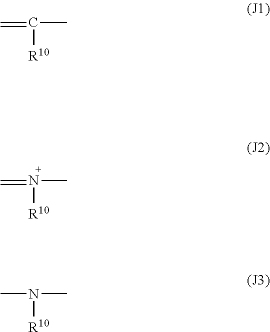

In Formulae (J1) to (J3), R¹⁰ is each independently a single bond, a hydrogen atom, an alkyl group, an aryl group, an aralkyl group, a halogenated alkyl group, a halogenated aryl group, a halogenated aralkyl group, or an alkenyl group. Specific examples of the alkyl group, the aryl group, the aralkyl group, the halogenated alkyl group, the halogenated aryl group, the halogenated aralkyl group, and the alkenyl group, and preferred carbon atom numbers thereof are the same as those described above.

In Formula (S1), R¹⁴ is each independently an alkyl group, an aryl group, an aralkyl group, a halogenated alkyl group, a halogenated aryl group, a halogenated aralkyl group, an alkenyl group, or a hydroxy group. When two or more R¹⁴s are present, the two R¹⁴s may be bonded together to form a ring, and the ring formed by the two R¹⁴s may have a crosslinked ring structure. In such a case, the cyclic ammonium group has, for example, an adamantane ring, a norbornene ring, or a spiro ring.

Specific examples of these alkyl group, aryl group, aralkyl group, halogenated alkyl group, halogenated aryl group, halogenated aralkyl group, and alkenyl group, and preferred carbon atom numbers thereof are the same as those described above.

In Formula (S1), n¹ is an integer of 1 to 8; m¹ is 0 or 1; and m² is 0 or a positive integer ranging from 1 to the possible maximum number of R¹⁴s substituted on a monocyclic or polycyclic ring.

When m¹ is 0, a (4+n¹)-membered ring including A¹ to A⁴ is formed. Specifically, when n¹ is 1, a 5-membered ring is formed; when n¹ is 2, a 6-membered ring is formed; when n¹ is 3, a 7-membered ring is formed; when n¹ is 4, a 8-membered ring is formed; when n¹ is 5, a 9-membered ring is formed; when n¹ is 6, a 10-membered ring is formed; when n¹ is 7, a 11-membered ring is formed; and when n¹ is 8, a 12-membered ring is formed.

When m¹ is 1, a condensed ring is formed by condensation between a (4+n¹)-membered ring including A¹ to A³ and a 6-membered ring including A⁴.

Since each of A¹ to A⁴ is any of the groups of Formulae (J1) to (J3), the ring-forming atom has or does not have a hydrogen atom. In each of A¹ to A⁴, when the ring-forming atom has a hydrogen atom, the hydrogen atom may be substituted with R¹⁴. Alternatively, a ring-forming atom other than the ring-forming atom in each of A¹ to A⁴ may be substituted with R¹⁴. Because of these circumstances, m² is 0 or an integer ranging from 1 to the possible maximum number of R¹⁴s substituted on a monocyclic or polycyclic ring.

The bonding hand of the heteroaromatic cyclic ammonium group of Formula (S1) is present on any carbon atom or nitrogen atom present in such a monocyclic or polycyclic ring, and is directly bonded to a silicon atom. Alternatively, the bonding hand is bonded to a linking group to form an organic group containing the cyclic ammonium group, and the organic group is bonded to a silicon atom.

Examples of the linking group include, but are not limited to, an alkylene group, an arylene group, and an alkenylene group.

Specific examples of the alkylene group and the arylene group, and preferred carbon atom numbers thereof are the same as those described above.

The alkenylene group is a divalent group derived from an alkenyl group through removal of one hydrogen atom. Specific examples of the alkenyl group are the same as those described above. No particular limitation is imposed on the carbon atom number of the alkenylene group, but the carbon atom number is preferably 40 or less, more preferably 30 or less, still more preferably 20 or less.

Specific examples of the alkenylene group include, but are not limited to, vinylene group, 1-methylvinylene group, propenylene group, 1-butenylene group, 2-butenylene group, 1-pentenylene group, and 2-pentenylene group.

Specific examples of the silane compound (hydrolyzable organosilane) of Formula (3) having the heteroaromatic cyclic ammonium group of Formula (S1) include, but are not limited to, silanes of the following Formulae (I-1) to (I-50).

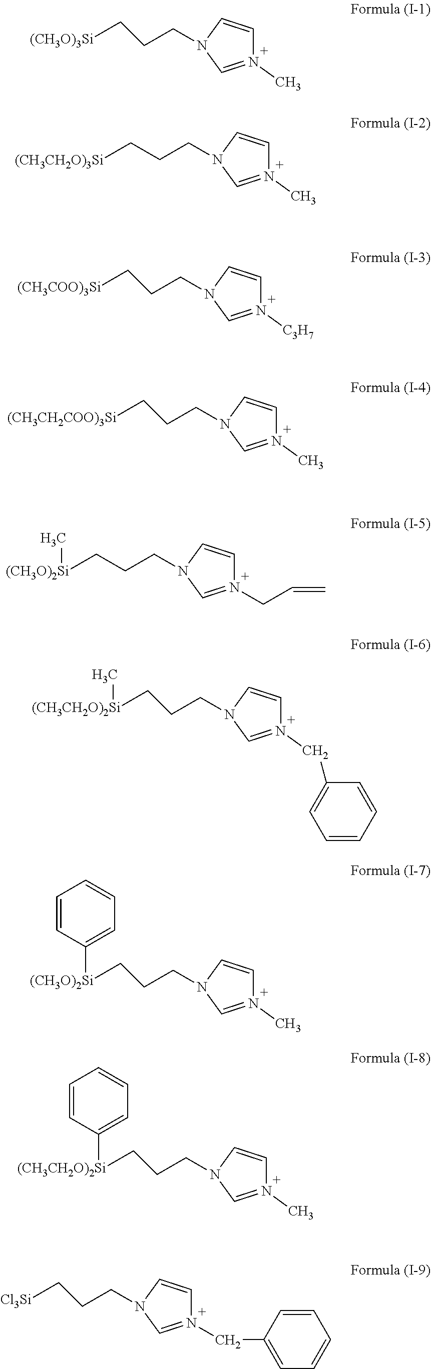

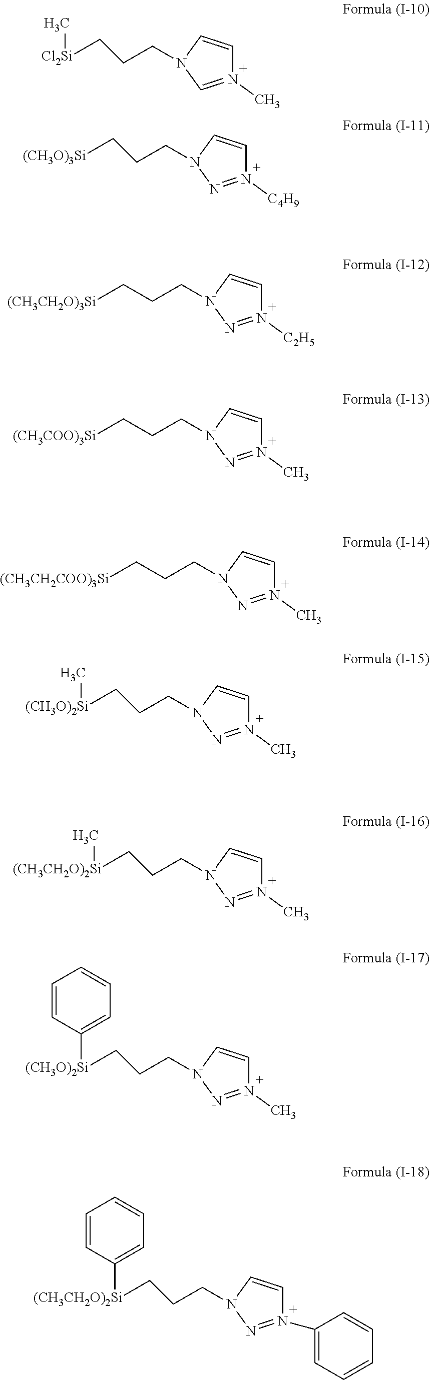

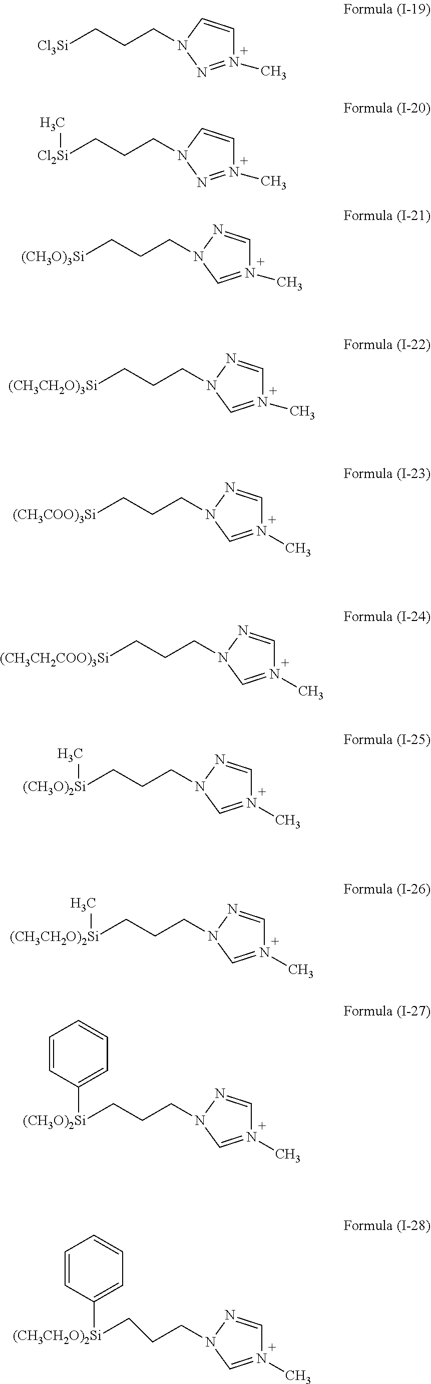

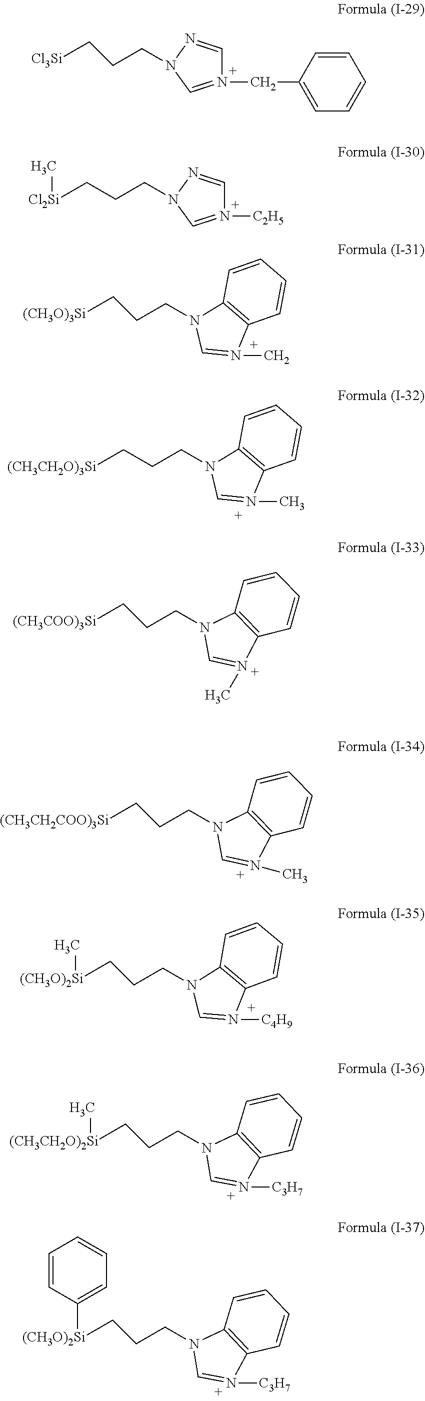

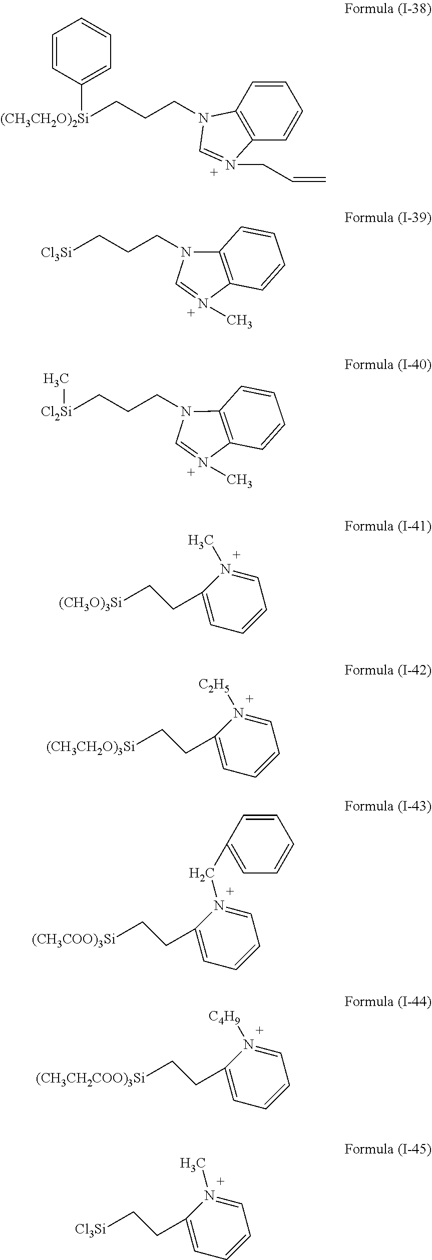

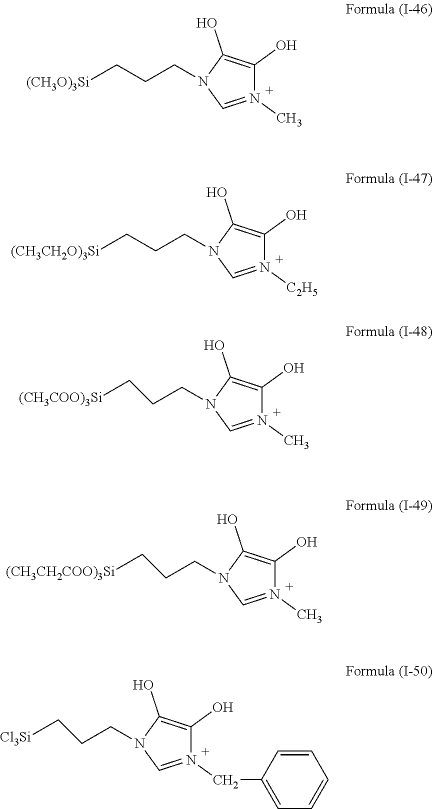

In another embodiment, R¹¹ (i.e., the group bonded to a silicon atom in Formula (3)) is a heteroaliphatic cyclic ammonium group of the following Formula (S2).

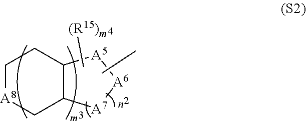

In Formula (S2), A⁵, A⁶, A⁷, and A⁸ are each independently a group of any of the following Formulae (J4) to (J6), and at least one of A⁵ to A⁸ is a group of the following Formula (J5). Depending on the bonding between the silicon atom in Formula (3) and any of A⁵ to A⁸, each of A⁵ to A⁸ and the ring-forming atom adjacent thereto form a single bond or a double bond. This determines whether the thus-formed ring exhibits anti-aromaticity.

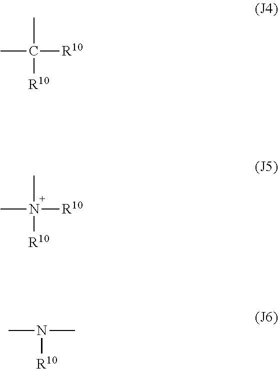

In Formulae (J4) to (J6), R¹⁰ is each independently a single bond, a hydrogen atom, an alkyl group, an aryl group, an aralkyl group, a halogenated alkyl group, a halogenated aryl group, a halogenated aralkyl group, or an alkenyl group. Specific examples of the alkyl group, the aryl group, the aralkyl group, the halogenated alkyl group, the halogenated aryl group, the halogenated aralkyl group, and the alkenyl group, and preferred carbon atom numbers thereof are the same as those described above.

In Formula (S2), R¹⁵ is each independently an alkyl group, an aryl group, an aralkyl group, a halogenated alkyl group, a halogenated aryl group, a halogenated aralkyl group, an alkenyl group, or a hydroxy group. When two or more R¹⁵s are present, the two R¹⁵s may be bonded together to form a ring, and the ring formed by the two R¹⁵s may have a crosslinked ring structure. In such a case, the cyclic ammonium group has, for example, an adamantane ring, a norbornene ring, or a spiro ring.

Specific examples of the alkyl group, the aryl group, the aralkyl group, the halogenated alkyl group, the halogenated aryl group, the halogenated aralkyl group, and the alkenyl group, and preferred carbon atom numbers thereof are the same as those described above.

In Formula (S2), n² is an integer of 1 to 8; m³ is 0 or 1; and m⁴ is 0 or a positive integer ranging from 1 to the possible maximum number of R¹⁵s substituted on a monocyclic or polycyclic ring.

When m³ is 0, a (4+n²)-membered ring including A⁵ to A⁸ is formed. Specifically, when n² is 1, a 5-membered ring is formed; when n² is 2, a 6-membered ring is formed; when n² is 3, a 7-membered ring is formed; when n² is 4, a 8-membered ring is formed; when n² is 5, a 9-membered ring is formed; when n² is 6, a 10-membered ring is formed; when n² is 7, a 11-membered ring is formed; and when n² is 8, a 12-membered ring is formed.

When m³ is 1, a condensed ring is formed by condensation between a (4+n²)-membered ring including A⁵ to A⁷ and a 6-membered ring including A⁸.

Since each of A⁵ to A⁸ is any of the groups of Formulae (J4) to (J6), the ring-forming atom has or does not have a hydrogen atom. In each of A⁵ to A⁸, when the ring-forming atom has a hydrogen atom, the hydrogen atom may be substituted with R¹⁵. Alternatively, a ring-forming atom other than the ring-forming atom in each of A⁵ to A⁸ may be substituted with R¹⁵.

Because of these circumstances, m⁴ is 0 or an integer ranging from 1 to the possible maximum number of R¹⁵s substituted on a monocyclic or polycyclic ring.

The bonding hand of the heteroaliphatic cyclic ammonium group of Formula (S2) is present on any carbon atom or nitrogen atom present in such a monocyclic or polycyclic ring, and is directly bonded to a silicon atom. Alternatively, the bonding hand is bonded to a linking group to form an organic group containing the cyclic ammonium group, and the organic group is bonded to a silicon atom.

The linking group is, for example, an alkylene group, an arylene group, or an alkenylene group. Specific examples of the alkylene group, the arylene group, and the alkenylene group, and preferred carbon atom numbers thereof are the same as those described above.

Specific examples of the silane compound (hydrolyzable organosilane) of Formula (3) having the heteroaliphatic cyclic ammonium group of Formula (S2) include, but are not limited to, silanes of the following Formulae (II-1) to (II-30).

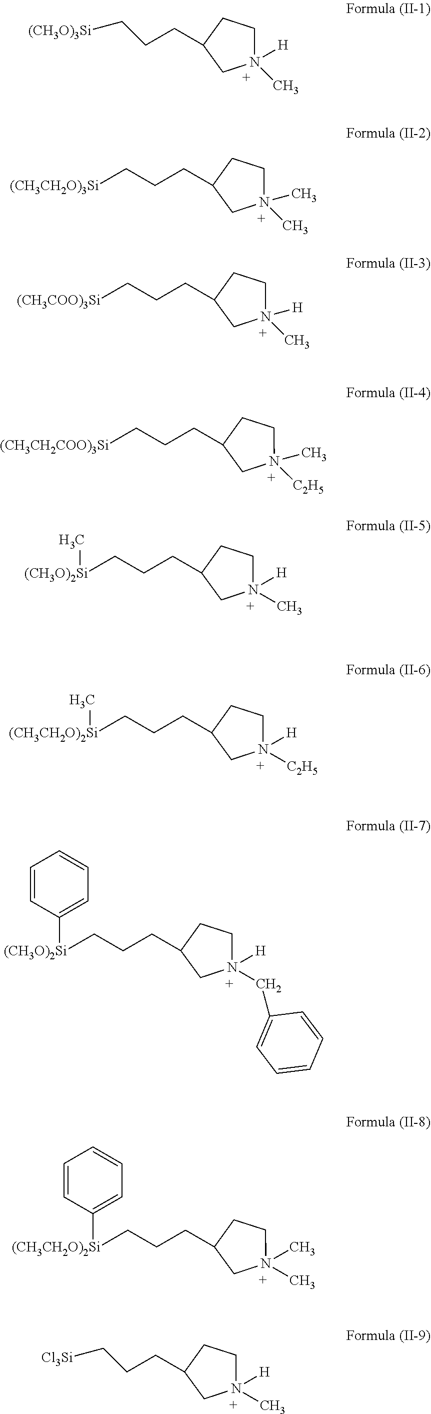

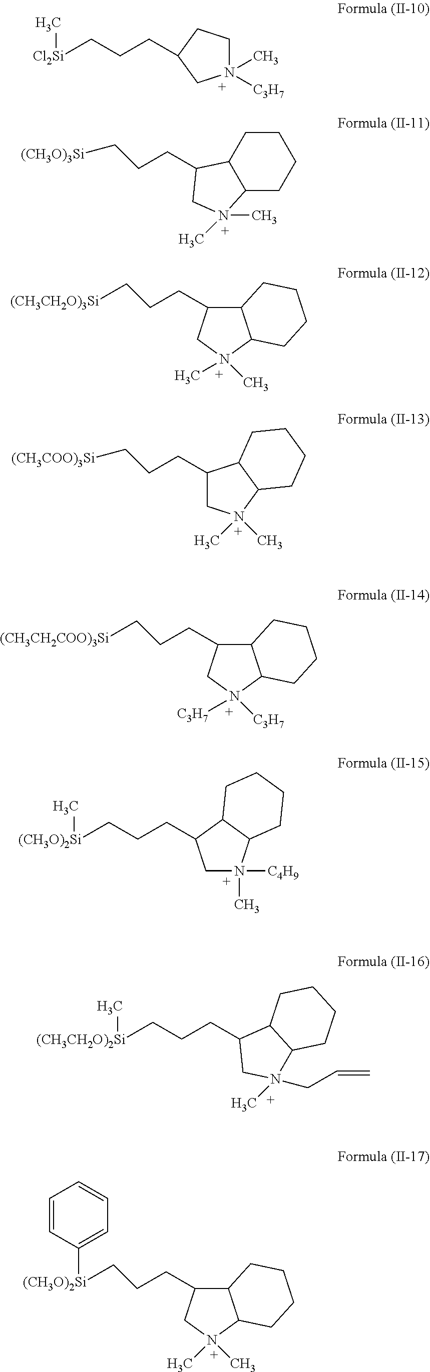

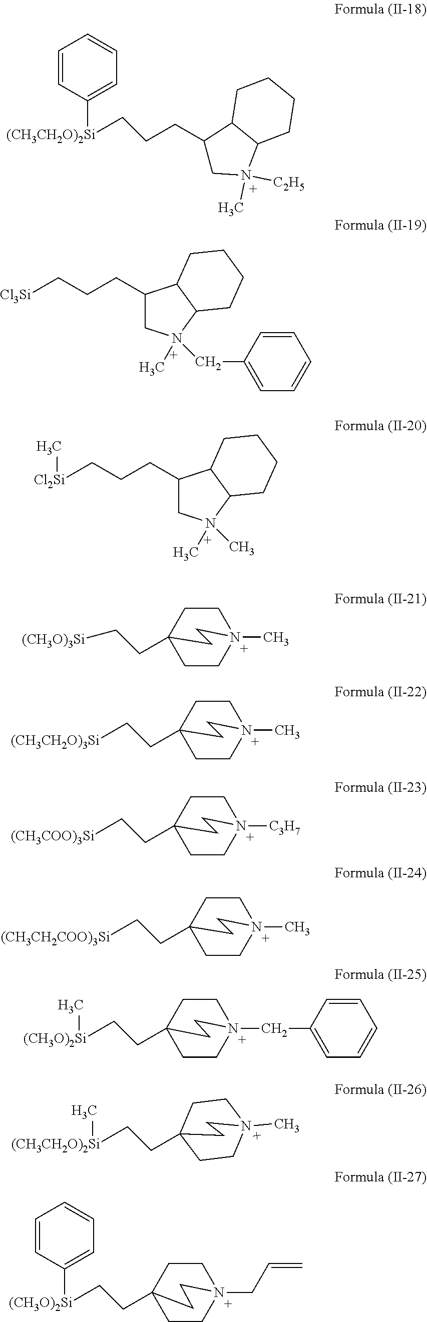

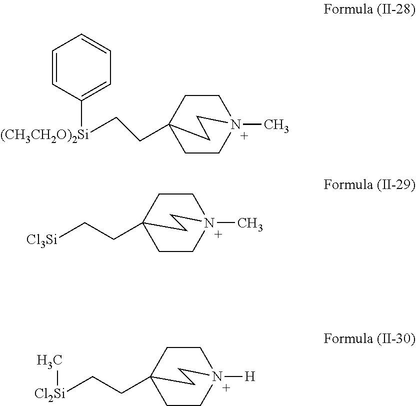

In yet another embodiment, R¹¹ (i.e., the group bonded to a silicon atom in Formula (3)) is a chain ammonium group of the following Formula (S3).

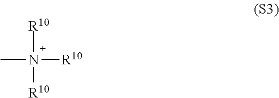

In Formula (S3), R¹⁰ is each independently a hydrogen atom, an alkyl group, an aryl group, an aralkyl group, a halogenated alkyl group, a halogenated aryl group, a halogenated aralkyl group, or an alkenyl group. Specific examples of the alkyl group, the aryl group, the aralkyl group, the halogenated alkyl group, the halogenated aryl group, the halogenated aralkyl group, and the alkenyl group, and preferred carbon atom numbers thereof are the same as those described above.

The chain ammonium group of Formula (S3) is directly bonded to a silicon atom. Alternatively, the chain ammonium group is bonded to a linking group to form an organic group containing the chain ammonium group, and the organic group is bonded to a silicon atom.

The linking group is, for example, an alkylene group, an arylene group, or an alkenylene group. Specific examples of the alkylene group, the arylene group, and the alkenylene group are the same as those described above.

Specific examples of the silane compound (hydrolyzable organosilane) of Formula (3) having the chain ammonium group of Formula (S3) include, but are not limited to, silanes of the following Formulae (III-1) to (III-28).

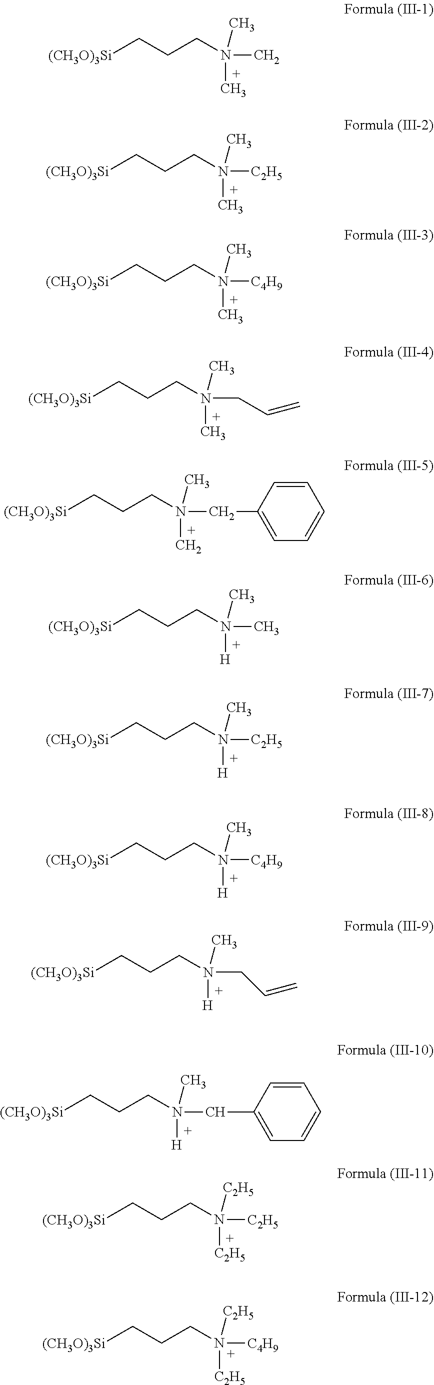

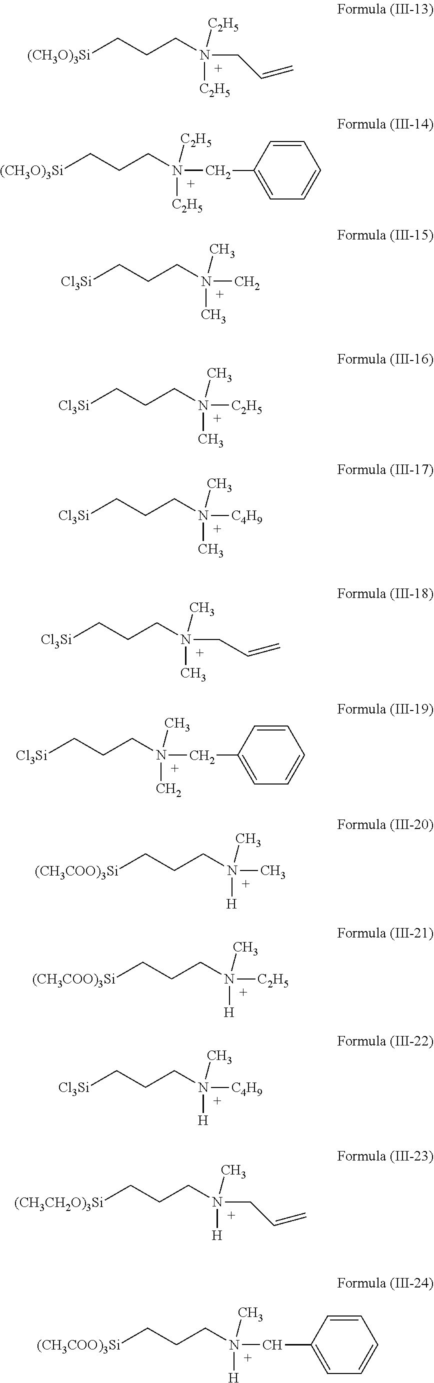

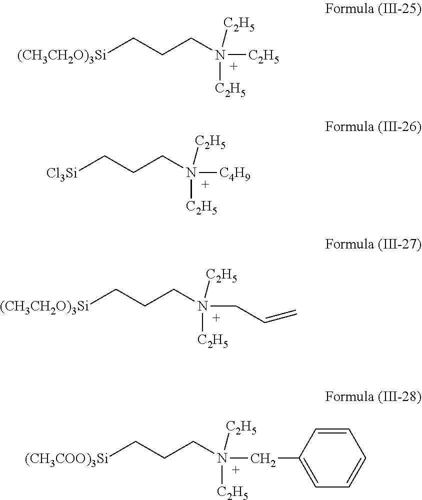

### <Silane Compound Having Sulfone Group or Sulfonamide Group (Hydrolyzable Organosilane)>

Examples of the silane compound having a sulfone group and the silane compound having a sulfonamide group include, but are not limited to, compounds of the following Formulae (B-1) to (B-36).

In the following Formulae, Me denotes a methyl group, and Et denotes an ethyl

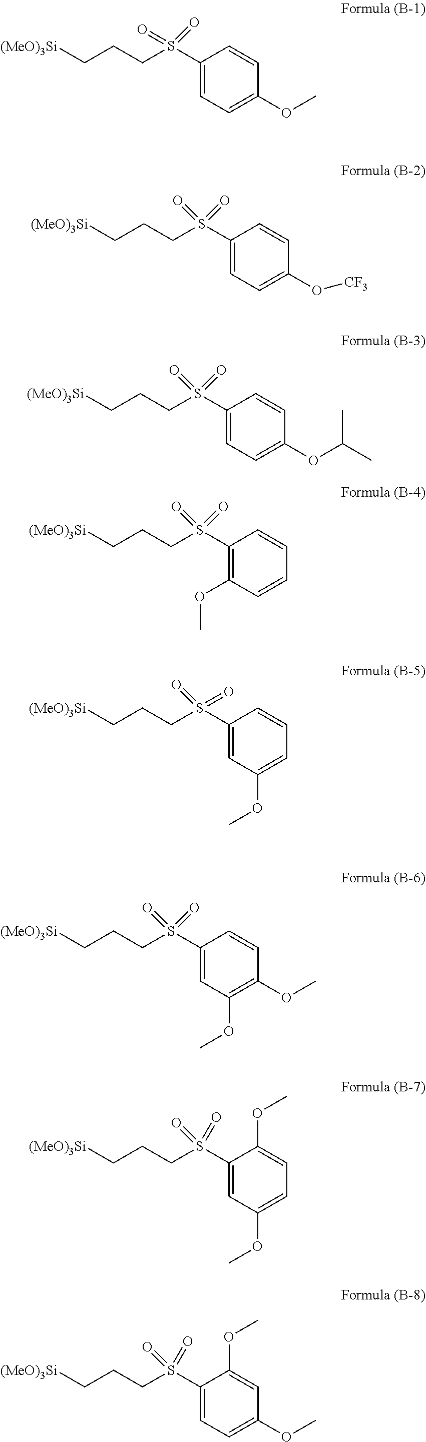

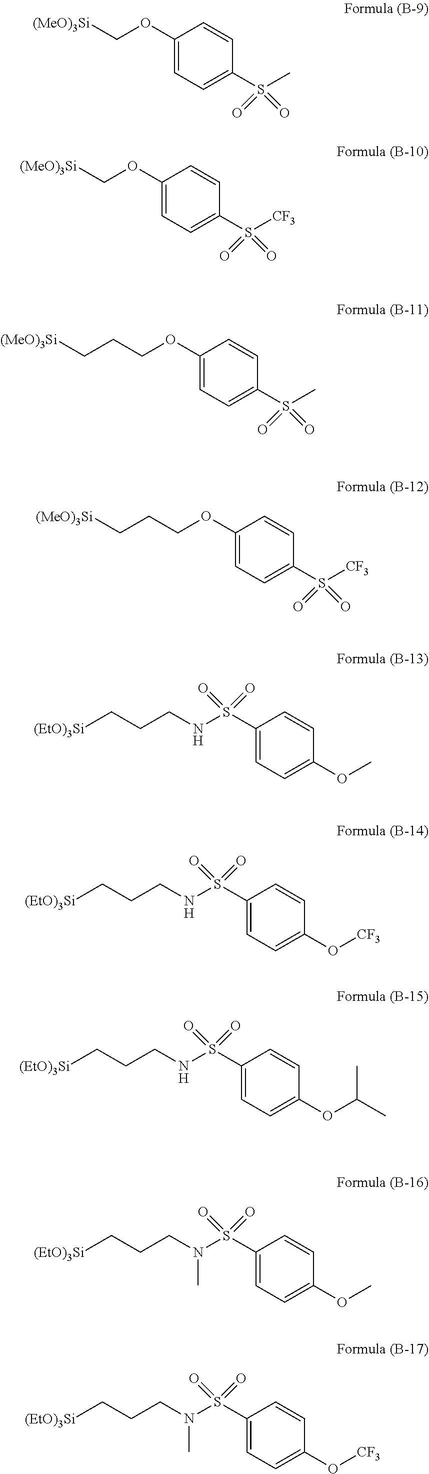

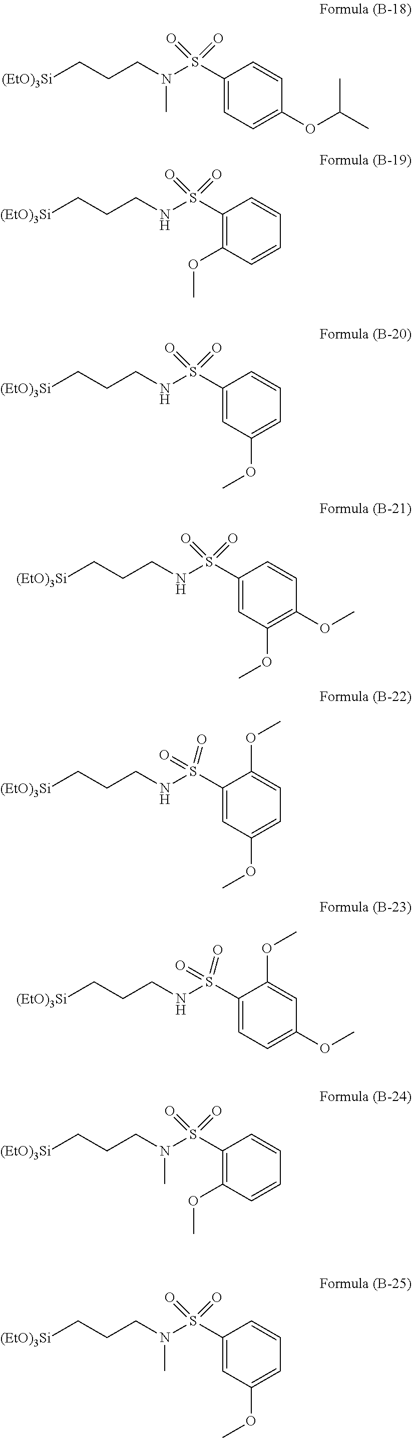

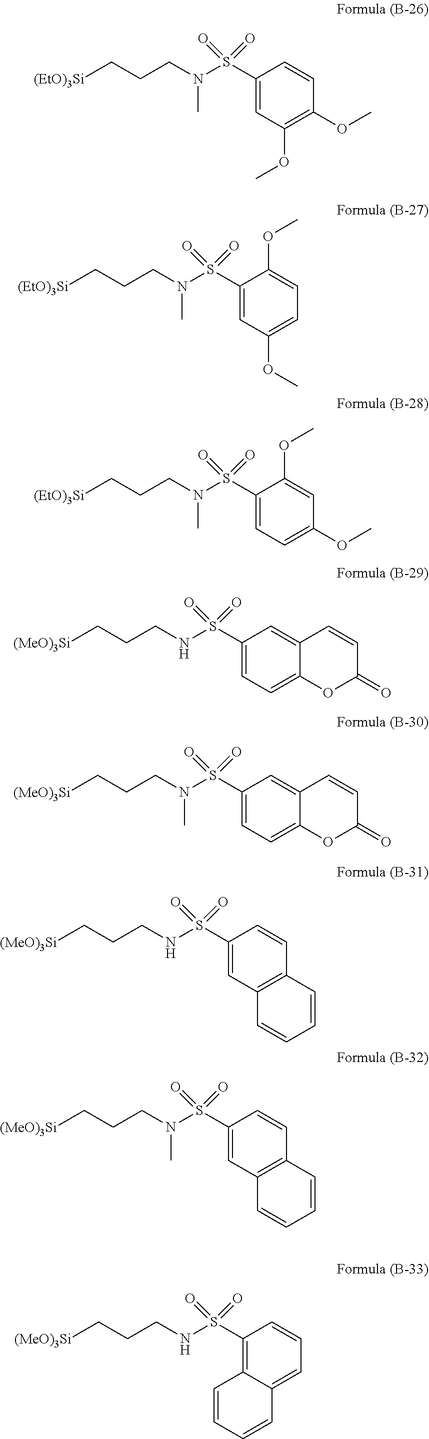

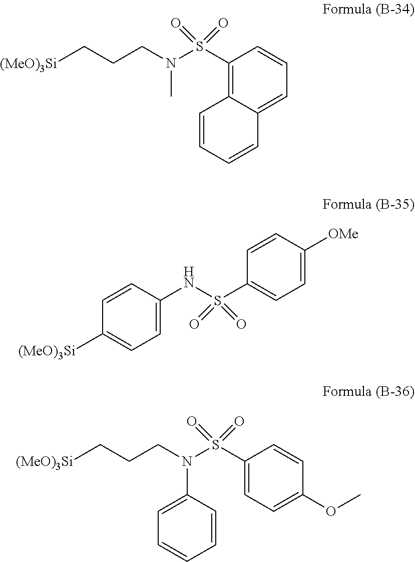

### <Silane Compound Having Cyclic Urea Structure in Molecule (Hydrolyzable Organosilane)>

The hydrolyzable organosilane having a cyclic urea structure in the molecule is, for example, a hydrolyzable organosilane of the following Formula (4-1).

R⁴⁰¹ₓR⁴⁰²_{y}Si(R⁴⁰³)_{4(x+y)} (4-1)

In Formula (4-1), R⁴⁰¹ is a group bonded to a silicon atom, and is each independently a group of the following Formula (4-2).

R⁴⁰² is a group bonded to a silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, or a cyano group.

R⁴⁰³ is a group or atom bonded to a silicon atom, and is each independently an alkoxy group, an aralkyloxy group, an acyloxy group, or a halogen atom.

In Formula (4-1), x is 1 or 2; y is 0 or 1; and x and y satisfy a relation of x+y≤2.

Specific examples of the alkyl group, aryl group, aralkyl group, halogenated alkyl group, halogenated aryl group, halogenated aralkyl group, alkoxyalkyl group, alkoxyaryl group, alkoxyaralkyl group, alkenyl group, and organic group containing an epoxy group, an acryloyl group, a methacryloyl group, a mercapto group, or a cyano group of R⁴⁰², the alkoxy group, aralkyloxy group, acyloxy group, and halogen atom of R⁴⁰³, and the substituent of each of these groups, and preferred carbon atom numbers thereof are the same as those described above regarding R¹ and R².

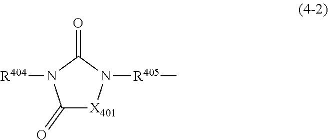

In Formula (4-2), R⁴⁰⁴ is each independently a hydrogen atom, a substitutable alkyl group, a substitutable alkenyl group, or an organic group containing an epoxy group or a sulfonyl group; and R⁴⁰⁵ is each independently an alkylene group, a hydroxyalkylene group, a sulfide bond (—S—), an ether bond (—O—), or an ester bond (—CO—O— or —O—CO—).

Specific examples of the substitutable alkyl group, substitutable alkenyl group, and organic group containing an epoxy group of R⁴⁰⁴, and preferred carbon atom numbers thereof are the same as those described above regarding R¹. Other preferred examples of the substitutable alkyl group of R⁴⁰⁴ include an alkyl group wherein the terminal hydrogen atom is substituted with a vinyl group. Specific examples of the alkyl group include allyl group, 2-vinylethyl group, 3-vinylpropyl group, and 4-vinylbutyl group.

No particular limitation is imposed on the organic group containing a sulfonyl group, so long as it contains a sulfonyl group. Examples of the organic group containing a sulfonyl group include substitutable alkylsulfonyl group, substitutable arylsulfonyl group, substitutable aralkylsulfonyl group, substitutable halogenated alkylsulfonyl group, substitutable halogenated arylsulfonyl group, substitutable halogenated aralkylsulfonyl group, substitutable alkoxyalkylsulfonyl group, substitutable alkoxyarylsulfonyl group, substitutable alkoxyaralkylsulfonyl group, and substitutable alkenylsulfonyl group.

Specific examples of the alkyl group, aryl group, aralkyl group, halogenated alkyl group, halogenated aryl group, halogenated aralkyl group, alkoxyalkyl group, alkoxyaryl group, alkoxyaralkyl group, and alkenyl group of the aforementioned groups, the substituent of these groups, and preferred carbon atom numbers thereof are the same as those described above regarding R¹.

The alkylene group of R⁴⁰⁵ is a divalent group derived from the aforementioned alkyl group through removal of one hydrogen atom, and may have a linear, branched, or cyclic structure. Specific examples of the alkylene group are the same as those described above. No particular limitation is imposed on the carbon atom number of the alkylene group, but the carbon atom number is preferably 40 or less, more preferably 30 or less, still more preferably 20 or less, much more preferably 10 or less.

The alkylene group of R⁴⁰⁵ may have one or more selected from among a sulfide bond, an ether bond, and an ester bond at an end or middle portion (preferably at a middle portion) of the alkylene group.

Specific examples of the alkylene group include, but are not limited to, linear alkylene groups, such as methylene group, ethylene group, trimethylene group, methylethylene, tetramethylene group, pentamethylene group, hexamethylene group, heptamethylene group, octamethylene group, nonamethylene group, and decamethylene group; branched alkylene groups, such as 1-methyltrimethylene group, 2-methyltrimethylene group, 1,1-dimethylethylene group, 1-methyltetramethylene group, 2-methyltetramethylene group, 1,1-dimethyltrimethylene group, 1,2-dimethyltrimethylene group, 2,2-dimethyltrimethylene group, and 1-ethyltrimethylene group; cyclic alkylene groups, such as 1,2-cyclopropanediyl group, 1,2-cyclobutanediyl group, 1,3-cyclobutanediyl group, 1,2-cyclohexanediyl group, and 1,3-cyclohexanediyl group; and alkylene groups containing an ether group, etc. such as —CH₂OCH₂—, —CH₂CH₂OCH₂—, —CH₂CH₂OCH₂CH₂—, —CH₂CH₂CH₂OCH₂CH₂—, —CH₂CH₂OCH₂CH₂CH₂—, —CH₂CH₂CH₂OCH₂CH₂CH₂—, —CH₂SCH₂—, —CH₂CH₂SCH₂—, —CH₂CH₂SCH₂CH₂—, —CH₂CH₂CH₂SCH₂CH₂—, —CH₂CH₂SCH₂CH₂CH₂—, —CH₂CH₂CH₂SCH₂CH₂CH₂—, and —CH₂OCH₂CH₂SCH₂—.

The hydroxyalkylene group is prepared by substitution of at least one hydrogen atom of the aforementioned alkylene group with a hydroxy group. Specific examples of the hydroxyalkylene group include, but are not limited to, hydroxymethylene group, 1-hydroxyethylene group, 2-hydroxyethylene group, 1,2-dihydroxyethylene group, 1-hydroxytrimethylene group, 2-hydroxytrimethylene group, 3-hydroxytrimethylene group, 1-hydroxytetramethylene group, 2-hydroxytetramethylene group, 3-hydroxytetramethylene group, 4-hydroxytetramethylene group, 1,2-dihydroxytetramethylene group, 1,3-dihydroxytetramethylene group, 1,4-dihydroxytetramethylene group, 2,3-dihydroxytetramethylene group, 2,4-dihydroxytetramethylene group, and 4,4-dihydroxytetramethylene group.

In Formula (4-2), X₄₀₁ is each independently a group of any of the following Formulae (4-3) to (4-5), and the carbon atom of the ketone group in each of the following Formulae (4-4) and (4-5) is bonded to a nitrogen atom bonded to R⁴⁰⁵ in Formula (4-2).

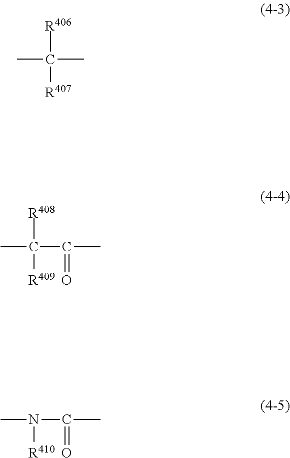

In Formulae (4-3) to (4-5), R⁴⁰⁶ to R⁴¹⁰ are each independently a hydrogen atom, a substitutable alkyl group, a substitutable alkenyl group, or an organic group containing an epoxy group or a sulfonyl group. Specific examples of the substitutable alkyl group, substitutable alkenyl group, and organic group containing an epoxy group or a sulfonyl group, and preferred carbon atom numbers thereof are the same as those described above regarding R⁴⁰⁴.

In particular, X₄₀₁ is preferably a group of Formula (4-5), from the viewpoint of achieving excellent lithographic property at high reproducibility.

At least one of R⁴⁰⁴ and R⁴⁰⁶ to R⁴¹⁰ is preferably an alkyl group wherein the terminal hydrogen atom is substituted with a vinyl group, from the viewpoint of achieving excellent lithographic property at high reproducibility.

The hydrolyzable organosilane of Formula (4-1) may be a commercially available product, or may be synthesized by a known method described in, for example, WO 2011/102470.

Specific examples of the hydrolyzable organosilane of Formula (4-1) include, but are not limited to, silanes of the following Formulae (4-1-1) to (4-1-29).

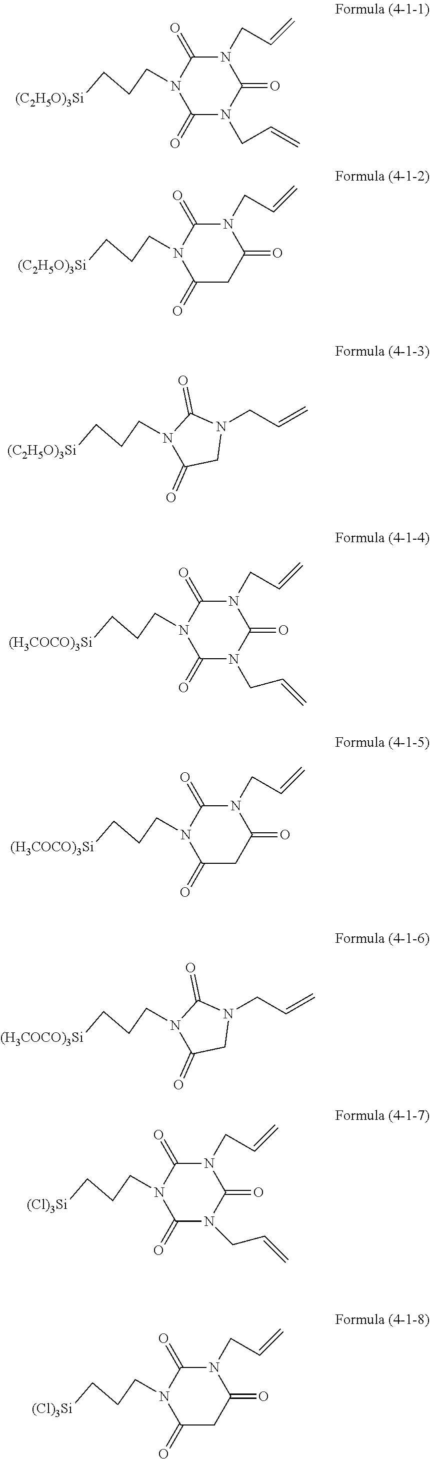

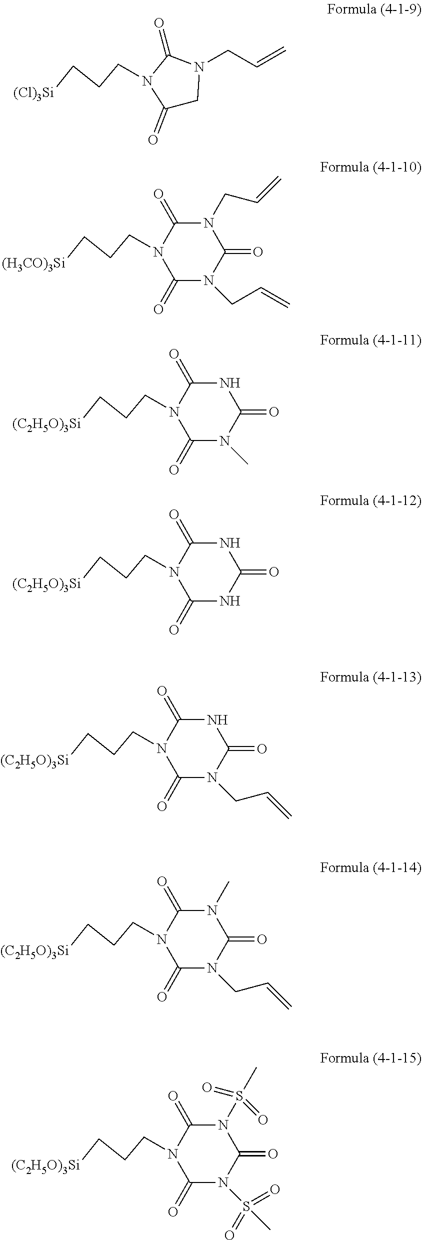

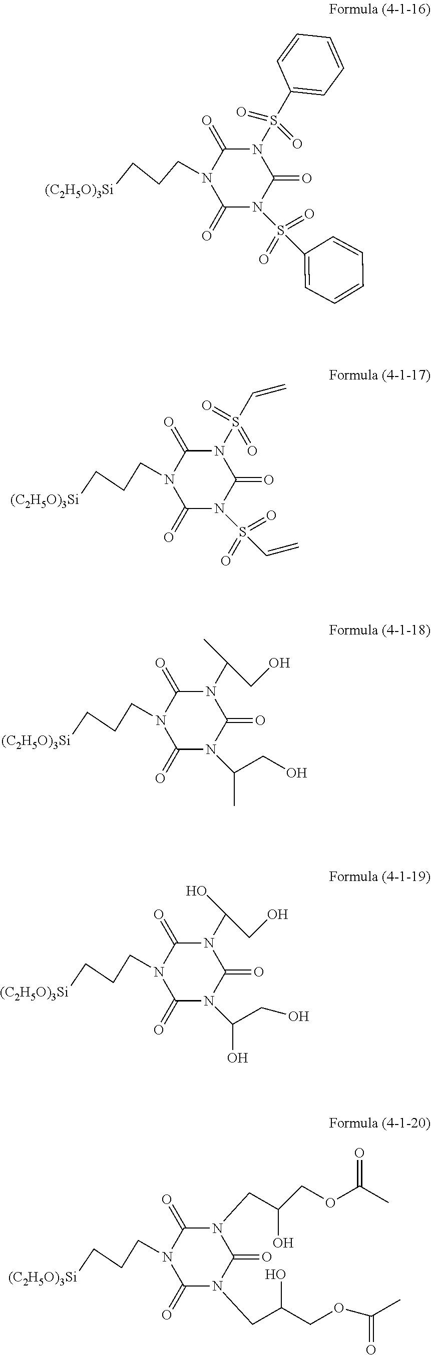

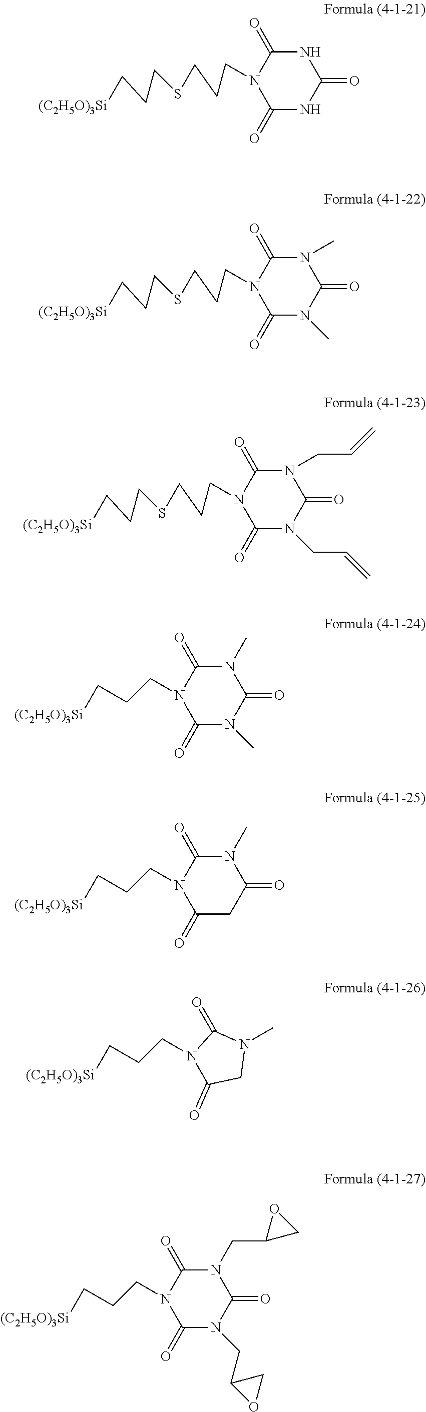

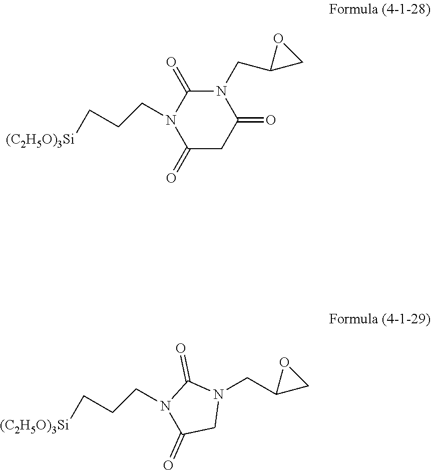

### <Silane Compound Having Cyclic Amino Group in Molecule (Hydrolyzable Organosilane)>

The hydrolyzable organosilane having a cyclic urea structure in the molecule is, for example, a hydrolyzable organosilane of the following Formula (5).

R¹⁶ⱼR¹⁷ₖSi(R¹⁸)₄₋₍ⱼ₊ₖ₎ (5)

R¹⁶ is a group bonded to a silicon atom, and is a cyclic amino group or an organic group containing the cyclic amino group.

R¹⁷ is a group bonded to a silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, or a cyano group, or any combination of these.

R¹⁸ is a group or atom bonded to a silicon atom, and is each independently an alkoxy group, an aralkyloxy group, an acyloxy group, or a halogen atom.

In Formula (5), j is 1 or 2; k is 0 or 1; and j and k satisfy a relation of 1≤j+k≤2.

Specific examples of the aforementioned alkyl group, aryl group, aralkyl group, halogenated alkyl group, halogenated aryl group, halogenated aralkyl group, alkoxyalkyl group, alkoxyaryl group, alkoxyaralkyl group, alkenyl group, and organic group containing an epoxy group, an acryloyl group, a methacryloyl group, a mercapto group, an amino group, or a cyano group, an alkoxy group, an aralkyloxy group, acyloxy group, and a halogen atom, and specific examples of the substituent of the alkyl group, the aryl group, the aralkyl group, the halogenated alkyl group, the halogenated aryl group, the halogenated aralkyl group, the alkoxyalkyl group, the alkoxyaryl group, the alkoxyaralkyl group, and the alkenyl group, and preferred carbon atom numbers thereof are the same as those described above regarding R¹ (for R¹⁷) and regarding R² (for R¹⁸).

In one preferred embodiment of the present invention, R¹⁶ (i.e., the group bonded to a silicon atom) is a heteroaromatic cyclic amino group of the following Formula (S11).

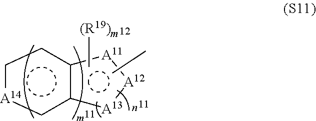

In Formula (S11), A¹¹, A¹², A¹³ and A¹⁴ are each independently a carbon atom or a nitrogen atom, and at least one of A¹¹ to A¹⁴ is a nitrogen atom. Preferably, one to three of A¹¹ to A¹⁴ are nitrogen atoms.

Depending on whether each of A¹¹ to A¹⁴ is a carbon atom or a nitrogen atom, or depending on the bonding between the silicon atom in Formula (5) and any of A¹¹ to A¹⁴, each of A¹¹ to A¹⁴ and the ring-forming atom adjacent thereto form a single bond or a double bond. This determines whether the thus-formed ring exhibits aromaticity. The bonding is determined by the valence of each atom such that the ring exhibits aromaticity.

In Formula (S11), R¹⁹ is each independently an alkyl group, an aryl group, an aralkyl group, a halogenated alkyl group, a halogenated aryl group, a halogenated aralkyl group, an alkenyl group, or a hydroxy group. When two or more R¹⁹s are present, the two R¹⁹s may be bonded together to form a ring, and the ring formed by the two R¹⁹s may have a crosslinked ring structure. In such a case, the cyclic ammonium group has, for example, an adamantane ring, a norbornene ring, or a spiro ring.

Specific examples of these alkyl group, aryl group, aralkyl group, halogenated alkyl group, halogenated aryl group, halogenated aralkyl group, and alkenyl group, and preferred carbon atom numbers thereof are the same as those described above.

In Formula (S11), n¹¹ is an integer of 1 to 8; m¹¹ is 0 or 1; and m¹² is 0 or a positive integer ranging from 1 to the possible maximum number of R¹⁹s substituted on a monocyclic or polycyclic ring.

When m¹¹ is 0, a (4+n¹¹)-membered ring including A¹¹ to A¹⁴ is formed. Specifically, when n¹¹ is 1, a 5-membered ring is formed; when n¹¹ is 2, a 6-membered ring is formed; when n¹¹ is 3, a 7-membered ring is formed; when n¹¹ is 4, a 8-membered ring is formed; when n¹¹ is 5, a 9-membered ring is formed; when n¹¹ is 6, a 10-membered ring is formed; when n¹¹ is 7, a 11-membered ring is formed; and when n¹¹ is 8, a 12-membered ring is formed.

When m¹¹ is 1, a condensed ring is formed by condensation between a (4+n¹¹)-membered ring including A¹¹ to A¹³ and a 6-membered ring including A¹⁴.

Depending on the bonding state of each of A¹¹ to A¹⁴, the ring-forming atom has or does not have a hydrogen atom. In each of A¹¹ to A¹⁴, when the ring-forming atom has a hydrogen atom, the hydrogen atom may be substituted with R¹⁹. Alternatively, a ring-forming atom other than the ring-forming atom in each of A¹¹ to A¹⁴ may be substituted with R¹⁹. Because of these circumstances, m¹² is 0 or an integer ranging from 1 to the possible maximum number of R¹⁹s substituted on a monocyclic or polycyclic ring.

The bonding hand of the heteroaromatic cyclic amino group of Formula (S11) is present on any carbon atom or nitrogen atom present in such a monocyclic or polycyclic ring, and is directly bonded to a silicon atom. Alternatively, the bonding hand is bonded to a linking group to form an organic group containing the cyclic amino group, and the organic group is bonded to a silicon atom.

Examples of the linking group include, but are not limited to, an alkylene group, an arylene group, and an alkenylene group.

Specific examples of the alkylene group, the arylene group and the alkenylene group, and preferred carbon atom numbers thereof are the same as those described above.

Specific examples of the silane compound (hydrolyzable organosilane) of Formula (5) having the heteroaromatic cyclic amino group of Formula (S11) include, but are not limited to, silanes of the following Formulae (XI-1) to (XI-70).

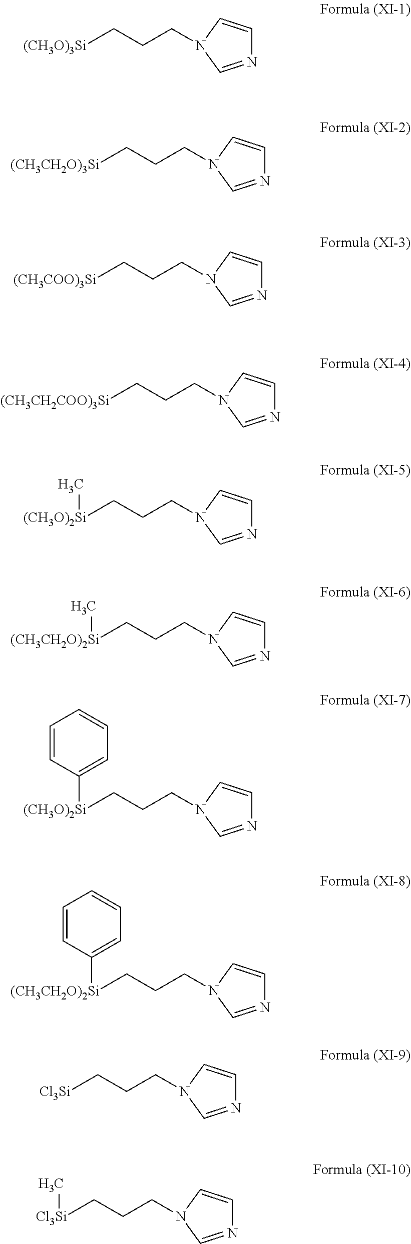

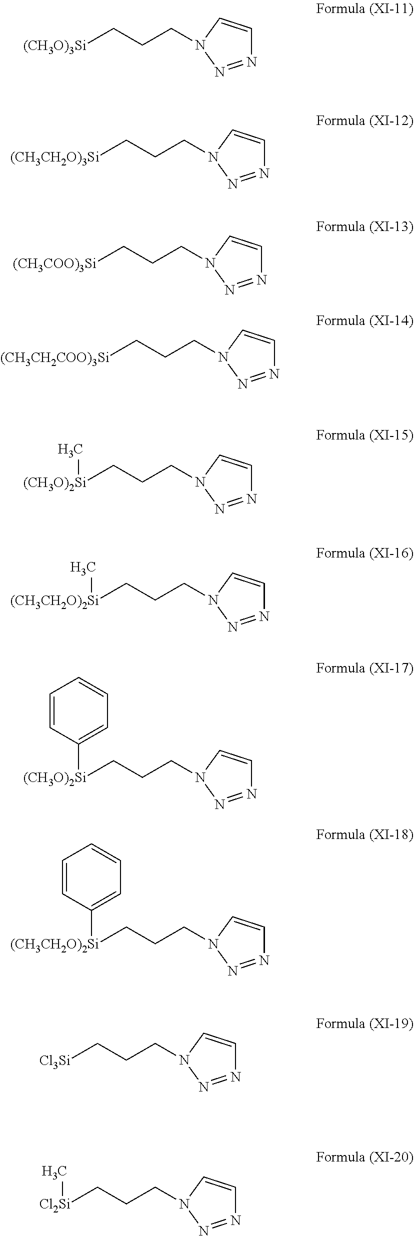

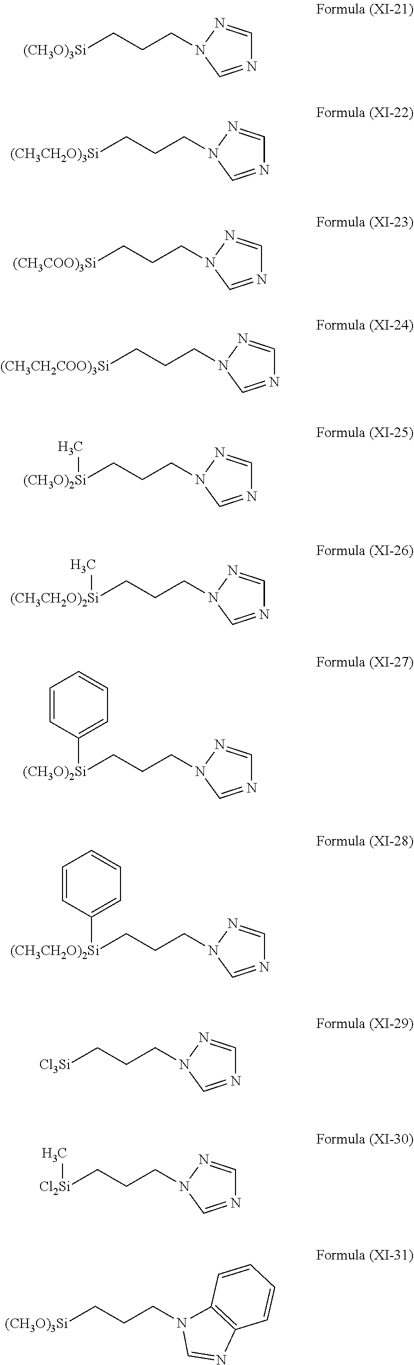

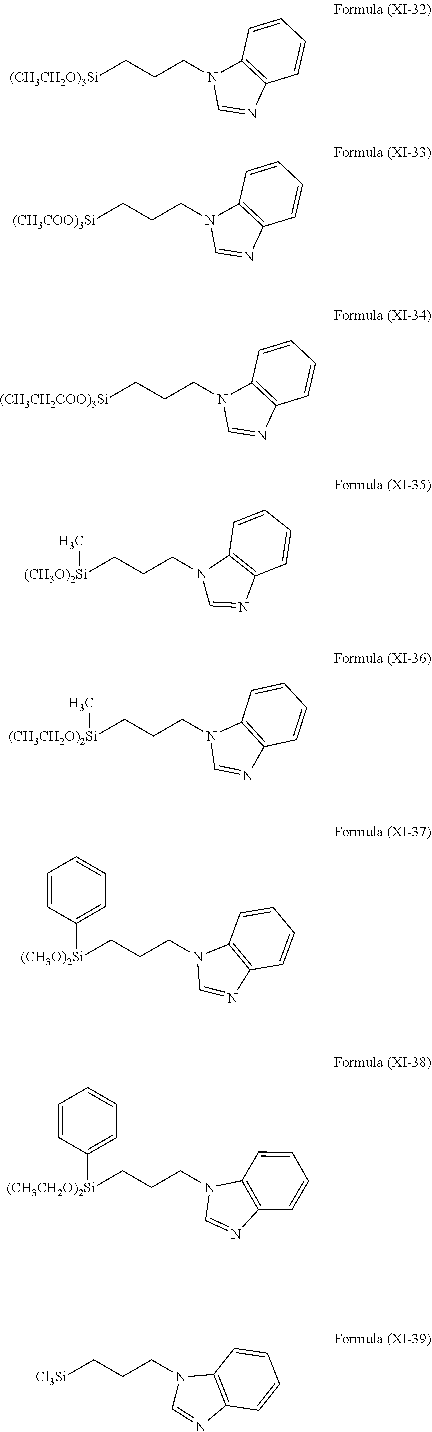

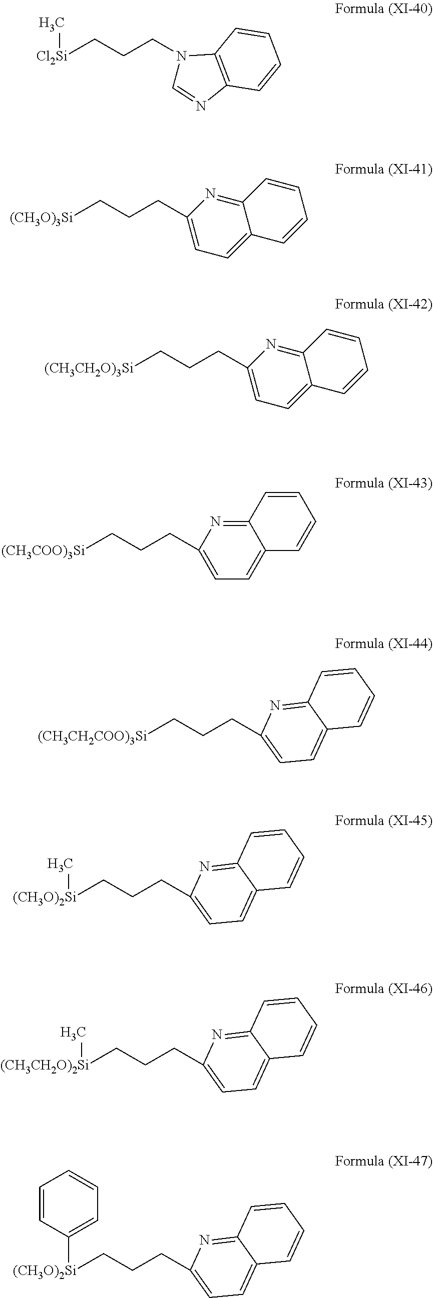

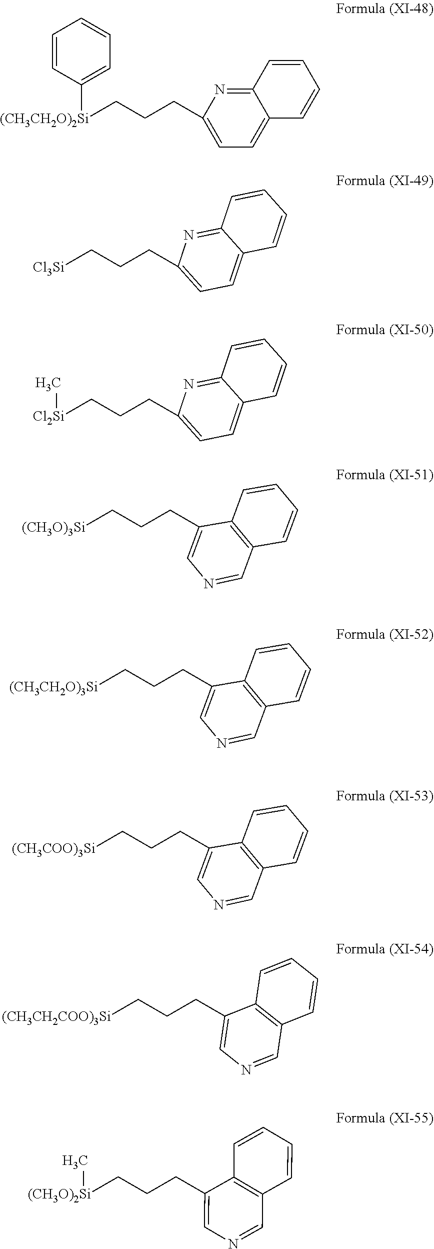

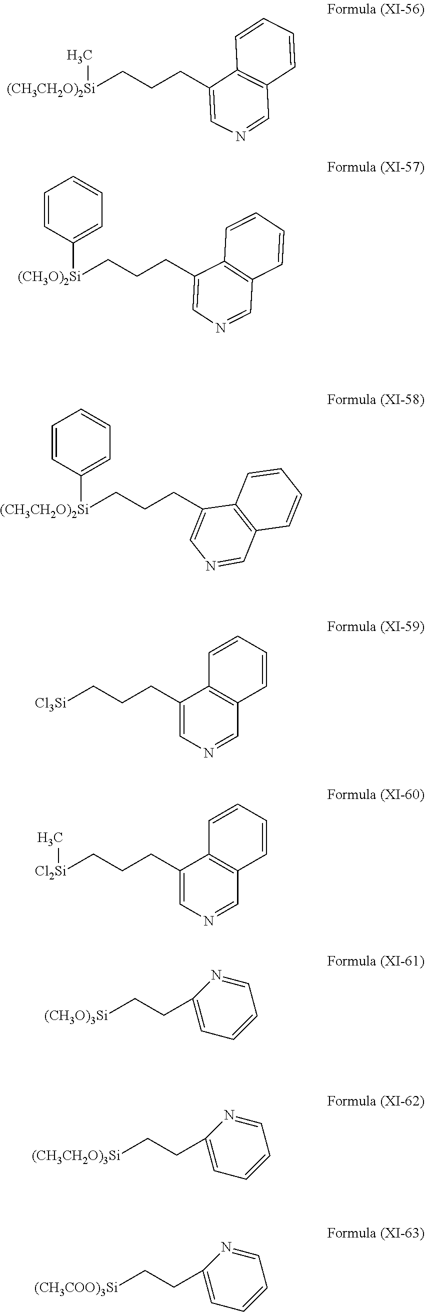

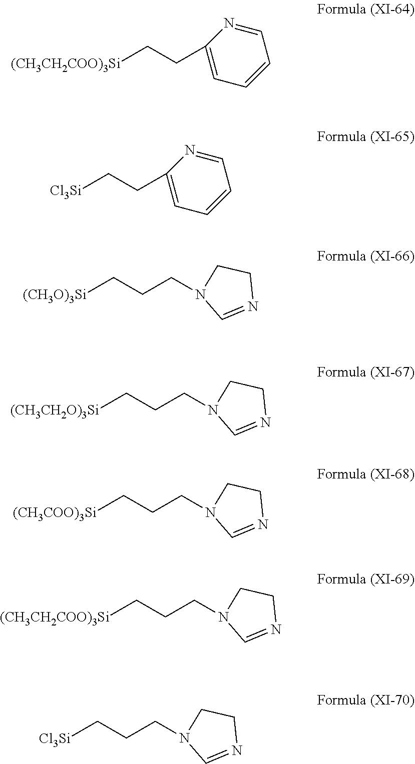

In another embodiment, R¹⁶ (i.e., the group bonded to a silicon atom in Formula (5)) is a heteroaliphatic cyclic amino group of the following Formula (S12).

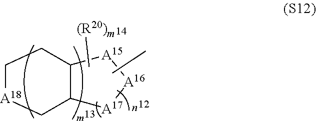

In Formula (S12), A¹⁵, A¹⁶, A¹⁷, and A¹⁸ are each independently a carbon atom or a nitrogen atom, and at least one of A¹⁵ to A¹⁸ is a nitrogen atom. Preferably, one to three of A¹⁵ to A¹⁸ are nitrogen atoms.

In Formula (S12), R²⁰ is each independently an alkyl group, an aryl group, an aralkyl group, a halogenated alkyl group, a halogenated aryl group, a halogenated aralkyl group, an alkenyl group, or a hydroxy group. When two or more R²⁰s are present, the two R²⁰s may be bonded together to form a ring, and the ring formed by the two R²⁰s may have a crosslinked ring structure. In such a case, the cyclic ammonium group has, for example, an adamantane ring, a norbornene ring, or a spiro ring.

Specific examples of the alkyl group, the aryl group, the aralkyl group, the halogenated alkyl group, the halogenated aryl group, the halogenated aralkyl group, and the alkenyl group, and preferred carbon atom numbers thereof are the same as those described above.

In Formula (S12), n¹² is an integer of 1 to 8; m¹³ is 0 or 1; and m¹⁴ is 0 or a positive integer ranging from 1 to the possible maximum number of R²⁰s substituted on a monocyclic or polycyclic ring.

When m¹³ is 0, a (4+n¹²)-membered ring including A¹⁵ to A¹⁸ is formed. Specifically, when n¹² is 1, a 5-membered ring is formed; when n¹² is 2, a 6-membered ring is formed; when n¹² is 3, a 7-membered ring is formed; when n¹² is 4, a 8-membered ring is formed; when n¹² is 5, a 9-membered ring is formed; when n¹² is 6, a 10-membered ring is formed; when n¹² is 7, a 11-membered ring is formed; and when n¹² is 8, a 12-membered ring is formed.

When m¹³ is 1, a condensed ring is formed by condensation between a (4+n¹²)-membered ring including A¹⁵ to A¹⁷ and a 6-membered ring including A¹⁸.

Depending on the bonding state of each of A¹⁵ to A¹⁸, the ring-forming atom has or does not have a hydrogen atom. In each of A¹⁵ to A¹⁸, when the ring-forming atom has a hydrogen atom, the hydrogen atom may be substituted with R²⁰. Alternatively, a ring-forming atom other than the ring-forming atom in each of A¹⁵ to A¹⁸ may be substituted with R²⁰.

Because of these circumstances, m¹⁴ is 0 or an integer ranging from 1 to the possible maximum number of R²⁰s substituted on a monocyclic or polycyclic ring.

The bonding hand of the heteroaliphatic cyclic amino group of Formula (S12) is present on any carbon atom or nitrogen atom present in such a monocyclic or polycyclic ring, and is directly bonded to a silicon atom. Alternatively, the bonding hand is bonded to a linking group to form an organic group containing the cyclic ammonium group, and the organic group is bonded to a silicon atom.

The linking group is, for example, an alkylene group, an arylene group, or an alkenylene group. Specific examples of the alkylene group, the arylene group, and the alkenylene group, and preferred carbon atom numbers thereof are the same as those described above.

Specific examples of the silane compound (hydrolyzable organosilane) of Formula (5) having the heteroaliphatic cyclic amino group of Formula (S12) include, but are not limited to, silanes of the following Formulae (XII-1) to (XII-30).

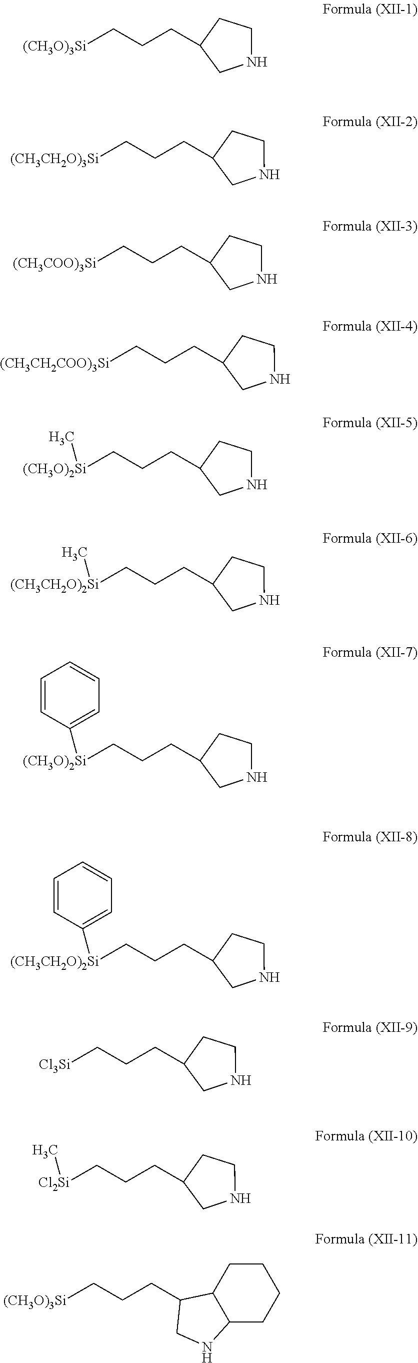

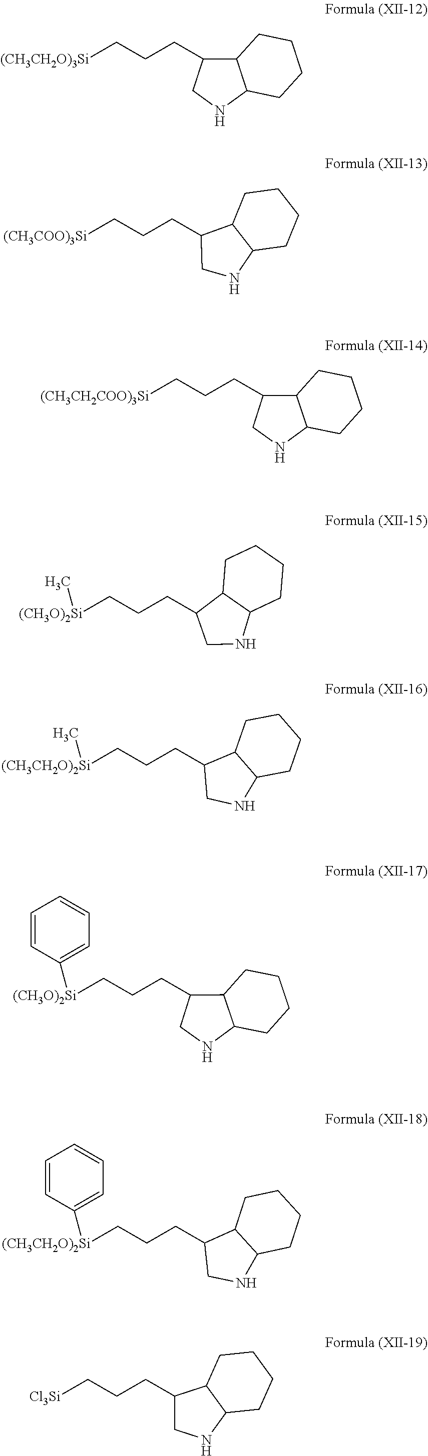

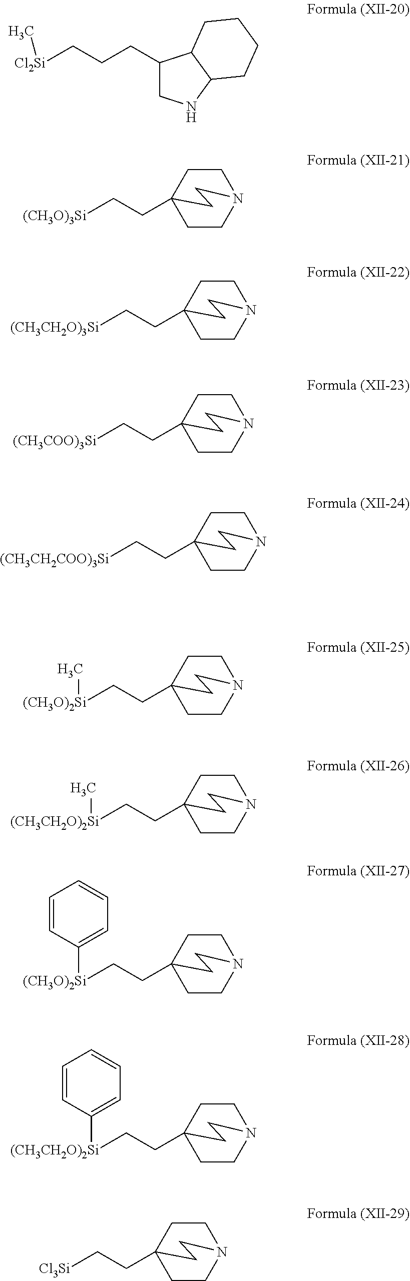

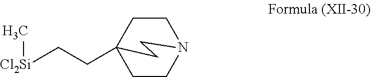

The polysiloxane [A] may be a hydrolysis condensate of a hydrolyzable silane containing a silane compound other than those exemplified above, so long as the effects of the present invention are not impaired.

As described above, the polysiloxane [A] may be a modified polysiloxane wherein at least some of silanol groups are modified. For example, the polysiloxane [A] may be a modified polysiloxane wherein some of silanol groups are modified with an alcohol, or a modified polysiloxane wherein some of silanol groups are protected with an acetal.

The modified polysiloxane may be, for example, a product prepared by reaction between a hydroxy group of an alcohol and at least some of silanol groups of the aforementioned hydrolysis condensate of hydrolyzable silane, a product prepared by dehydration reaction between the condensate and an alcohol, or a modified product prepared by protection of at least some of silanol groups of the condensate with an acetal group.

The aforementioned alcohol may be a monohydric alcohol. Examples of the monohydric alcohol include methanol, ethanol, 2-propanol, 1-butanol, 2-butanol, isobutyl alcohol, tert-butyl alcohol, 1-pentanol, 2-pentanol, 3-pentanol, 1-heptanol, 2-heptanol, tert-amyl alcohol, neopentyl alcohol, 2-methyl-1-propanol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-diethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, and cyclohexanol.

The aforementioned alcohol may be, for example, an alkoxy group-containing alcohol, such as 3-methoxybutanol, ethylene glycol monomethyl ether, ethylene glycol monoethyl ether, diethylene glycol monomethyl ether, diethylene glycol monoethyl ether, propylene glycol monomethyl ether (1-methoxy-2-propanol), propylene glycol monoethyl ether (1-ethoxy-2-propanol), or propylene glycol monobutyl ether (1-butoxy-2-propanol).

The reaction between silanol groups of the aforementioned condensate and hydroxy groups of the alcohol is performed by bringing the polysiloxane into contact with the alcohol. A modified polysiloxane containing capped silanol groups is prepared by performing the reaction at a temperature of 40 to 160° C. (e.g., 60° C.) for 0.1 to 48 hours (e.g., 24 hours). In this case, the alcohol serving as a capping agent may be used as a solvent in the composition containing the polysiloxane.

The product by dehydration reaction between the polysiloxane (containing the hydrolysis condensate of hydrolyzable silane) and the alcohol can be produced by reacting the polysiloxane with the alcohol in the presence of an acid serving as a catalyst to thereby cap silanol groups with the alcohol, and then removing water generated through the dehydration to the outside of the reaction system.

The aforementioned acid may be an organic acid having an acid dissociation constant (pka) of −1 to 5, preferably 4 to 5. Examples of the acid include trifluoroacetic acid, maleic acid, benzoic acid, isobutyric acid, and acetic acid. In particular, benzoic acid, isobutyric acid, or acetic acid may be used.

The aforementioned acid may be an acid having a boiling point of 70 to 160° C. Examples of the acid include trifluoroacetic acid, isobutyric acid, acetic acid, and nitric acid.

Preferably, the aforementioned acid has either an acid dissociation constant (pka) of 4 to 5 or a boiling point of 70 to 160° C. Thus, the acid to be used may be an acid having a weak acidity or having a strong acidity and a low boiling point.

Either of these properties (acid dissociation constant and boiling point) of the acid may be utilized.

The acetal protection of silanol groups of the aforementioned condensate can be performed with a vinyl ether; for example, a vinyl ether of the following Formula (6). Such a reaction can be performed to introduce a partial structure of the following Formula (7) into the polysiloxane.

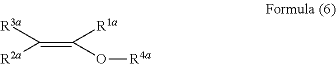

In Formula (6), R^{1a}, R^{2a}, and R^{3a} are each a hydrogen atom or a C₁₋₁₀ alkyl group; R^{4a} is a C₁₋₁₀ alkyl group; and R^{2a} and R^{4a} may be bonded together to form a ring. Examples of the alkyl group are the same as those described above.

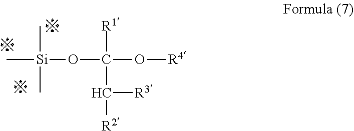

In Formula (7), R^{1′}, R^{2′}, and R^{3′} are each a hydrogen atom or a C₁₋₁₀ alkyl group; R^{4′} is a C₁₋₁₀ alkyl group; and R^{2′} and R^{4′} may be bonded together to form a ring. In Formula (7), * is a bond to the adjacent atom. The adjacent atom is, for example, an oxygen atom of a siloxane bond, or an oxygen atom of a silanol group. Examples of the alkyl group are the same as those described above.

Examples of the vinyl ether of Formula (6) include aliphatic vinyl ether compounds, such as methyl vinyl ether, ethyl vinyl ether, isopropyl vinyl ether, normal butyl vinyl ether, 2-ethylhexyl vinyl ether, tert-butyl vinyl ether, and cyclohexyl vinyl ether; and cyclic vinyl ether compounds, such as 2,3-dihydrofuran, 4-methyl-2,3-dihydrofuran, and 3,4-dihydro-2H-pyran. In particular, ethyl vinyl ether, propyl vinyl ether, butyl vinyl ether, ethylhexyl vinyl ether, cyclohexyl vinyl ether, 3,4-dihydro-2H-pyran, or 2,3-dihydrofuran is preferably used.

The aforementioned acetal protection of silanol groups can be performed by using the polysiloxane, the aforementioned vinyl ether, an aprotic solvent such as propylene glycol monomethyl ether acetate, ethyl acetate, dimethylformamide, tetrahydrofuran, or 1,4-dioxane, and a catalyst such as pyridium p-toluenesulfonate, trifluoromethanesulfonic acid, p-toluenesulfonic acid, methanesulfonic acid, hydrochloric acid, or sulfuric acid.

The capping of silanol groups with an alcohol or the acetal protection of silanol groups may be performed simultaneously with the hydrolysis and condensation of the hydrolyzable silane described below.

In one preferred embodiment of the present invention, the polysiloxane [A] contains at least one of a hydrolysis condensate of a hydrolyzable silane containing a hydrolyzable silane of Formula (1) and, if desired, a hydrolyzable silane of Formula (2) and an additional hydrolyzable silane, and a modified product of the hydrolysis condensate.

In one preferred embodiment, the polysiloxane [A] contains a product prepared by dehydration reaction between the aforementioned hydrolysis condensate and an alcohol.

The aforementioned hydrolysis condensate of hydrolyzable silane (which may contain a modified product) may have a weight average molecular weight of, for example, 500 to 1,000,000. From the viewpoint of, for example, preventing the precipitation of the hydrolysis condensate in the composition, the weight average molecular weight is preferably 500,000 or less, more preferably 250,000 or less, still more preferably 100,000 or less. From the viewpoint of, for example, the compatibility between storage stability and applicability, the weight average molecular weight is preferably 700 or more, more preferably 1,000 or more.

The weight average molecular weight is determined by GPC analysis in terms of polystyrene. The GPC analysis can be performed under, for example, the following conditions: GPC apparatus (trade name: HLC-8220GPC, available from Tosoh Corporation), GPC columns (trade name: Shodex (registered trademark) KF803L, KF802, and KF801, available from Showa Denko K.K.), a column temperature of 40° C., tetrahydrofuran serving as an eluent (elution solvent), a flow amount (flow rate) of 1.0 mL/min, and polystyrene (available from Showa Denko K.K.) as a standard sample.

The aforementioned hydrolysis condensate of hydrolyzable silane is prepared by hydrolysis and condensation of the aforementioned silane compound (hydrolyzable silane).

The aforementioned silane compound (hydrolyzable silane) contains an alkoxy group, aralkyloxy group, acyloxy group, or halogen atom directly bonded to a silicon atom; i.e., an alkoxysilyl group, an aralkyloxysilyl group, an acyloxysilyl group, or a halogenated silyl group (hereinafter such a group may be referred to as “hydrolyzable group”).

For the hydrolysis of the hydrolyzable group, generally 0.1 to 100 mol, for example, 0.5 to 100 mol (preferably 1 to 10 mol) of water is used per mol of the hydrolyzable group.

A hydrolysis catalyst may be used during the hydrolysis and condensation for the purpose of, for example, promoting the reaction. Alternatively, the hydrolysis and condensation may be performed without use of a hydrolysis catalyst. When a hydrolysis catalyst is used, the amount of the hydrolysis catalyst is generally 0.0001 to 10 mol, preferably 0.001 to 1 mol per mol of the hydrolyzable group.

The reaction temperature for the hydrolysis and condensation is generally equal to or higher than room temperature and equal to or lower than the reflux temperature (at ambient pressure) of an organic solvent usable for the hydrolysis. The reaction temperature may be, for example, 20 to 110° C., or, for example, 20 to 80° C.

The hydrolysis may be performed completely; i.e., all hydrolyzable groups may be converted into silanol groups, or may be performed partially; i.e., unreacted hydrolyzable groups may remain.

Examples of the hydrolysis catalyst usable for the hydrolysis and condensation include a metal chelate compound, an organic acid, an inorganic acid, an organic base, and an inorganic base.

Examples of the metal chelate compound serving as a hydrolysis catalyst include, but are not limited to, titanium chelate compounds, such as triethoxy-mono(acetylacetonato)titanium, tri-n-propoxy-mono(acetylacetonato)titanium, tri-i-propoxy-mono(acetylacetonato)titanium, tri-n-butoxy-mono(acetylacetonato)titanium, tri-sec-butoxy-mono(acetylacetonato)titanium, tri-t-butoxy-mono(acetylacetonato)titanium, diethoxy-bis(acetylacetonato)titanium, di-n-propoxy-bis(acetylacetonato)titanium, di-i-propoxy-bis(acetylacetonato)titanium, di-n-butoxy-bis(acetylacetonato)titanium, di-sec-butoxy-bis(acetylacetonato)titanium, di-t-butoxy-bis(acetylacetonato)titanium, monoethoxy-tris(acetylacetonato)titanium, mono-n-propoxy-tris(acetylacetonato)titanium, mono-i-propoxy-tris(acetylacetonato)titanium, mono-n-butoxy-tris(acetylacetonato)titanium, mono-sec-butoxy-tris(acetylacetonato)titanium, mono-t-butoxy-tris(acetylacetonato)titanium, tetrakis(acetylacetonato)titanium, triethoxy-mono(ethylacetoacetato)titanium, tri-n-propoxy-mono(ethylacetoacetato)titanium, tri-i-propoxy-mono(ethylacetoacetato)titanium, tri-n-butoxy-mono(ethylacetoacetato)titanium, tri-sec-butoxy-mono(ethylacetoacetato)titanium, tri-t-butoxy-mono(ethylacetoacetato)titanium, diethoxy-bis(ethylacetoacetato)titanium, di-n-propoxy-bis(ethylacetoacetato)titanium, di-i-propoxy-bis(ethylacetoacetato)titanium, di-n-butoxy-bis(ethylacetoacetato)titanium, di-sec-butoxy-bis(ethylacetoacetato)titanium, di-t-butoxy-bis(ethylacetoacetato)titanium, monoethoxy-tris(ethylacetoacetato)titanium, mono-n-propoxy-tris(ethylacetoacetato)titanium, mono-i-propoxy-tris(ethylacetoacetato)titanium, mono-n-butoxy-tris(ethylacetoacetato)titanium, mono-sec-butoxy-tris(ethylacetoacetato)titanium, mono-t-butoxy-tris(ethylacetoacetato)titanium, tetrakis(ethylacetoacetato)titanium, mono(acetylacetonato)tris(ethylacetoacetato)titanium, bis(acetylacetonato)bis(ethylacetoacetato)titanium, and tris(acetylacetonato)mono(ethylacetoacetato)titanium; zirconium chelate compounds, such as triethoxy-mono(acetylacetonato)zirconium, tri-n-propoxy-mono(acetylacetonato)zirconium, tri-i-propoxy-mono(acetylacetonato)zirconium, tri-n-butoxy-mono(acetylacetonato)zirconium, tri-sec-butoxy-mono(acetylacetonato)zirconium, tri-t-butoxy-mono(acetylacetonato)zirconium, diethoxy-bis(acetylacetonato)zirconium, di-n-propoxy-bis(acetylacetonato)zirconium, di-i-propoxy-bis(acetylacetonato)zirconium, di-n-butoxy-bis(acetylacetonato)zirconium, di-sec-butoxy-bis(acetylacetonato)zirconium, di-t-butoxy-bis(acetylacetonato)zirconium, monoethoxy-tris(acetylacetonato)zirconium, mono-n-propoxy-tris(acetylacetonato)zirconium, mono-i-propoxy-tris(acetylacetonato)zirconium, mono-n-butoxy-tris(acetylacetonato)zirconium, mono-sec-butoxy-tris(acetylacetonato)zirconium, mono-t-butoxy-tris(acetylacetonato)zirconium, tetrakis(acetylacetonato)zirconium, triethoxy-mono(ethylacetoacetato)zirconium, tri-n-propoxy-mono(ethylacetoacetato)zirconium, tri-i-propoxy-mono(ethylacetoacetato)zirconium, tri-n-butoxy-mono(ethylacetoacetato)zirconium, tri-sec-butoxy-mono(ethylacetoacetato)zirconium, tri-t-butoxy-mono(ethylacetoacetato)zirconium, diethoxy-bis(ethylacetoacetato)zirconium, di-n-propoxy-bis(ethylacetoacetato)zirconium, di-i-propoxy-bis(ethylacetoacetato)zirconium, di-n-butoxy-bis(ethylacetoacetato)zirconium, di-sec-butoxy-bis(ethylacetoacetato)zirconium, di-t-butoxy-bis(ethylacetoacetato)zirconium, monoethoxy-tris(ethylacetoacetato)zirconium, mono-n-propoxy-tris(ethylacetoacetato)zirconium, mono-i-propoxy-tris(ethylacetoacetato)zirconium, mono-n-butoxy-tris(ethylacetoacetato)zirconium, mono-sec-butoxy-tris(ethylacetoacetato)zirconium, mono-t-butoxy-tris(ethylacetoacetato)zirconium, tetrakis(ethylacetoacetato)zirconium, mono(acetylacetonato)tris(ethylacetoacetato)zirconium, bis(acetylacetonato)bis(ethylacetoacetato)zirconium, and tris(acetylacetonato)mono(ethylacetoacetato)zirconium; and aluminum chelate compounds, such as tris(acetylacetonato)aluminum and tris(ethylacetoacetato)aluminum.

Examples of the organic acid serving as a hydrolysis catalyst include, but are not limited to, acetic acid, propionic acid, butanoic acid, pentanoic acid, hexanoic acid, heptanoic acid, octanoic acid, nonanoic acid, decanoic acid, oxalic acid, maleic acid, methylmalonic acid, adipic acid, sebacic acid, gallic acid, butyric acid, mellitic acid, arachidonic acid, 2-ethylhexanoic acid, oleic acid, stearic acid, linoleic acid, linolenic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, sulfonic acid, phthalic acid, fumaric acid, citric acid, and tartaric acid.

Examples of the inorganic acid serving as a hydrolysis catalyst include, but are not limited to, hydrochloric acid, nitric acid, sulfuric acid, hydrofluoric acid, and phosphoric acid.

Examples of the organic base serving as a hydrolysis catalyst include, but are not limited to, pyridine, pyrrole, piperazine, pyrrolidine, piperidine, picoline, trimethylamine, triethylamine, monoethanolamine, diethanolamine, dimethylmonoethanolamine, monomethyldiethanolamine, triethanolamine, diazabicyclooctane, diazabicyclononane, diazabicycloundecene, tetramethylammonium hydroxide, tetraethylammonium hydroxide, tetrapropylammonium hydroxide, tetrabutylammonium hydroxide, trimethylphenylammonium hydroxide, benzyltrimethylammonium hydroxide, and benzyltriethylammonium hydroxide.

Examples of the inorganic base serving as a hydrolysis catalyst include, but are not limited to, ammonia, sodium hydroxide, potassium hydroxide, barium hydroxide, and calcium hydroxide.

Among these catalysts, a metal chelate compound, an organic acid, or an inorganic acid is preferred. These catalysts may be used alone or in combination of two or more species.

In particular, nitric acid can be suitably used as a hydrolysis catalyst in the present invention. The use of nitric acid enables an improvement in the storage stability of a reaction solution after the hydrolysis and condensation, and particularly enables suppression of a change in the molecular weight of a hydrolysis condensate. It is known that the stability of the hydrolysis condensate contained in the reaction solution depends on the pH of the solution. The present inventors have conducted extensive studies, and as a result have found that the pH of the reaction solution falls in a stable range by use of an appropriate amount of nitric acid.

As described above, nitric acid can also be used for preparation of a modified product of the hydrolysis condensate; for example, for capping of silanol groups with an alcohol. Thus, nitric acid is preferred from the viewpoint that it can contribute to the hydrolysis and condensation of the hydrolyzable silane, as well as the capping reaction of the hydrolysis condensate with an alcohol.

An organic solvent may be used for the hydrolysis and condensation. Specific examples of the organic solvent include, but are not limited to, aliphatic hydrocarbon solvents, such as n-pentane, i-pentane, n-hexane, i-hexane, n-heptane, i-heptane, 2,2,4-trimethylpentane, n-octane, i-octane, cyclohexane, and methylcyclohexane; aromatic hydrocarbon solvents, such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, and n-amylnaphthalene; monohydric alcohol solvents, such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, n-heptanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; polyhydric alcohol solvents, such as ethylene glycol, propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and glycerin; ketone solvents, such as acetone, methyl ethyl ketone, methyl-n-propyl ketone, methyl-n-butyl ketone, diethyl ketone, methyl-1-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, and fenchone; ether solvents, such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether (1-methoxy-2-propanol), propylene glycol monoethyl ether (1-ethoxy-2-propanol), propylene glycol monopropyl ether, propylene glycol monobutyl ether, propylene glycol monomethyl ether acetate (1-methoxy-2-propanol acetate), dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran; ester solvents, such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethylene glycol diacetate, triethylene glycol methyl ether acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate; nitrogen-containing solvents, such as N-methylformamide, N,N-dimethylformamide, N,N-diethylformamide, acetamide, N-methylacetamide, N,N-dimethylacetamide, N-methylpropionamide, and N-methyl-2-pyrrolidone; and sulfur-containing solvents, such as dimethyl sulfide, diethyl sulfide, thiophene, tetrahydrothiophene, dimethyl sulfoxide, sulfolane, and 1,3-propanesultone. These solvents may be used alone or in combination of two or more species.

After completion of the hydrolysis and condensation reactions, the reaction solution is used as is, or diluted or concentrated. The resultant reaction solution can be neutralized or treated with an ion-exchange resin, to thereby remove the hydrolysis catalyst (e.g., an acid or a base) used for the hydrolysis and condensation. Before or after such a treatment, alcohols (i.e., by-products), water, the used hydrolysis catalyst, etc. can be removed from the reaction solution through, for example, distillation under reduced pressure.

The thus-prepared hydrolysis condensate (hereinafter may be referred to as “polysiloxane”) is in the form of a polysiloxane varnish dissolved in an organic solvent. The polysiloxane varnish may be used as is for preparation of the silicon-containing underlayer film-forming composition described below. Thus, the aforementioned reaction solution may be used as is (or may be diluted) for preparation of the silicon-containing underlayer film-forming composition. In this case, the hydrolysis catalyst used for the hydrolysis and condensation, by-products, etc. may remain in the reaction solution, so long as the effects of the present invention are not impaired.

The silicon-containing underlayer film-forming composition is in a form not containing a strongly acidic additive. Thus, when the aforementioned hydrolysis catalyst is, for example, an inorganic acid or organic acid having a first acid dissociation constant of 1 or less in water, such as hydrochloric acid, nitric acid, p-toluenesulfonic acid, benzenesulfonic acid, trichloroacetic acid, or trifluoroacetic acid, such an acid must be removed by the aforementioned method.

The resultant polysiloxane varnish may be subjected to solvent replacement, or may be appropriately diluted with a solvent. If the resultant polysiloxane varnish does not exhibit poor storage stability, the organic solvent may be distilled off to thereby achieve a solid content concentration of 100%.

The organic solvent used for the solvent replacement or dilution of the polysiloxane varnish may be identical to or different from the organic solvent used for the hydrolysis and condensation reactions of the hydrolyzable silane. No particular limitation is imposed on the type of the solvent for dilution, and one solvent or two or more solvents may be arbitrarily selected and used.

### [B] Solvent

No particular limitation is imposed on the solvent [B] used in the silicon-containing underlayer film-forming composition of the present invention, so long as the solvent can dissolve and mix the aforementioned polysiloxane [A] and additional components described below.

Specific examples of the solvent [B] include methylcellosolve acetate, ethylcellosolve acetate, propylene glycol, propylene glycol monomethyl ether (1-methoxy-2-propanol), propylene glycol monoethyl ether (1-ethoxy-2-propanol), methyl isobutyl carbinol (4-methyl-2-pentanol), propylene glycol monobutyl ether, propylene glycol monomethyl ether acetate (1-methoxy-2-propanol monoacetate), propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropinoate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol mooethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methybutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, methyl propyl ketone, methyl butyl ketone, 2-heptanone, 3-heptanone, 4-heptanone, N,N-dimethylformamide, N-methylacetamide, N,N-dimethylacetamide, N-methyl-2-pyrrolidone, and γ-butyrolactone. These solvents may be used alone or in combination of two or more species.

The silicon-containing underlayer film-forming composition of the present invention may contain water as a solvent. When the composition contains water as a solvent, the amount of water is, for example, 30% by mass or less, preferably 20% by mass or less, more preferably 15% by mass or less, relative to the total mass of the solvents contained in the composition.

### [Strongly Acidic Additive]

The silicon-containing underlayer film-forming composition of the present invention contains the aforementioned polysiloxane [A] and solvent [B], and may contain additional components described below. However, the composition does not contain a strongly acidic additive.

The present inventors have found that when the composition for forming a silicon-containing underlayer film for a self-assembled film contains a strongly acidic additive, the strongly acidic additive excessively leaches to the surface of an underlayer film formed from the silicon-containing underlayer film-forming composition, and leaches through the underlayer film to the surface of an underlayer film (a neutral film described below) formed thereon for improving the alignment of the self-assembled film, to thereby considerably hinder the hydrophilicity/hydrophobicity of the neutral film.

The aforementioned strongly acidic additive may be a compound having a first acid dissociation constant of 1 or less in water.

The aforementioned strongly acidic additive may be an acid generator, for example, a photoacid generator.

Examples of the photoacid generator include an onium salt compound, a sulfonimide compound, and a disulfonyldiazomethane compound.

Specific examples of the onium salt compound include iodonium salt compounds, such as diphenyliodonium hexafluorophosphate, diphenyliodonium trifluoromethanesulfonate, diphenyliodonium nonafluoro normal butanesulfonate, diphenyliodonium perfluoro normal octanesulfonate, diphenyliodonium camphorsulfonate, bis(4-t-butylphenyl)iodonium camphorsulfonate, and bis(4-t-butylphenyl)iodonium trifluoromethanesulfonate; and sulfonium salt compounds, such as triphenylsulfonium hexafluoroantimonate, triphenylsulfonium nonafluoro normal butanesulfonate, triphenylsulfonium camphorsulfonate, triphenylsulfonium trifluoromethanesulfonate, triphenylsulfonium nitrate, triphenylsulfonium trifluoroacetate, triphenylsulfonium maleate, and triphenylsulfonium chloride.

Specific examples of the sulfonimide compound include N-(trifluoromethanesulfonyloxy)succinimide, N-(nonafluoro normal butane sulfonyloxy)succinimide, N-(camphorsulfonyloxy)succinimide, and N-(trifluoromethanesulfonyloxy)naphthalimide.

Specific examples of the disulfonyldiazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

The acid generator may be a thermal acid generator, for example, tetramethylammonium nitrate.

### [Preparation of Silicon-Containing Underlayer Film-Forming Composition]

The silicon-containing underlayer film-forming composition can be produced by mixing of the aforementioned polysiloxane [A] and solvent [B], and an additional component (if incorporated). In this case, a solution containing the polysiloxane [A] may be preliminarily prepared, and the solution may be mixed with the solvent [B] and an additional component. The reaction solution produced during preparation of the polysiloxane [A] may be used as is for preparation of the silicon-containing underlayer film-forming composition.

No particular limitation is imposed on the order of mixing of these components. For example, the solvent [B] may be added to and mixed with a solution containing the polysiloxane [A], and an additional component may be added to the resultant mixture. Alternatively, a solution containing the polysiloxane [A], the solvent [B], and an additional component may be mixed simultaneously.

If necessary, the solvent [B] may be finally added, or some components that can be relatively easily dissolved in the solvent [B] may be finally added without being incorporated into the mixture. However, from the viewpoint of preventing aggregation or separation of components to prepare a highly homogeneous composition with high reproducibility, the composition is preferably produced from a preliminarily prepared solution containing the well-dissolved polysiloxane [A]. It should be noted that the polysiloxane [A] may be aggregated or precipitated when mixed with the solvent [B] or an additional component, depending on, for example, the type or amount of the solvent [B], or the amount or nature of the component. It should also be noted that when a composition is prepared from a solution containing the polysiloxane [A], the concentration of the solution of the polysiloxane [A] or the amount of the solution used must be determined so as to achieve a desired amount of the polysiloxane [A] contained in the finally produced composition.

During preparation of the composition, the composition may be appropriately heated so long as the components are not decomposed or denatured.

In the present invention, the silicon-containing underlayer film-forming composition may be filtered with, for example, a submicrometer-order filter during production of the composition or after mixing of all the components. No limitation is imposed on the type of the material of the filter used. For example, a nylon-made filter or a fluororesin-made filter may be used.

The concentration of the solid content in the silicon-containing underlayer film-forming composition may be, for example, 0.1 to 50% by mass, 0.1 to 30% by mass, 0.1 to 25% by mass, or 0.5 to 20.0% by mass, relative to the total mass of the composition. The “solid content” as described above refers to the amount of all components (except for the solvent [B] component) contained in the composition.

The amount of the polysiloxane [A] in the solid content is generally 20% by mass to 100% by mass. From the viewpoint of, for example, achieving the aforementioned effects of the present invention at high reproducibility, the lower limit of the amount of the polysiloxane [A] is preferably 50% by mass, more preferably 60% by mass, still more preferably 70% by mass, much more preferably 80% by mass, and the upper limit of the amount is preferably 99% by mass. The balance may be an additive described below.

The silicon-containing underlayer film-forming composition preferably has a pH of 2 to 5, more preferably a pH of 3 to 4.

As described below, the silicon-containing underlayer film-forming composition of the present invention can be suitably used as a composition for forming an underlayer film for a self-assembled film for formation of a self-assembled pattern by directed self-assembly, in particular, a composition for forming an underlayer film underlying a neutral film for improving the alignment of a self-assembled film.

### [Additional Additive]

The silicon-containing underlayer film-forming composition of the present invention may contain various additives, so long as the effects of the present invention are not impaired.

Examples of the additives include known additives incorporated in materials (compositions) for forming various films (e.g., resist underlayer film, anti-reflective coating, and pattern reversing film) that can be used in the production of a semiconductor device, such as a curing catalyst (e.g., an ammonium salt, a phosphine compound, a phosphonium salt, a sulfonium salt, or a nitrogen-containing silane compound), a crosslinking agent, a crosslinking catalyst, a stabilizer (e.g., an organic acid, water, or an alcohol), an organic polymer compound, a surfactant (e.g., a nonionic surfactant, an anionic surfactant, a cationic surfactant, a silicon-containing surfactant, a fluorine-containing surfactant, or a UV-curable surfactant), a pH adjuster, a metal oxide, a rheology controlling agent, and an adhesion aid.

Examples of various additives include, but are not limited to, those described below. As described above, the silicon-containing underlayer film-forming composition of the present invention does not contain a strongly acidic additive. For example, a compound having a first acid dissociation constant of 1 or less in water, and an acid generator (in particular, a compound that functions as a photoacid generator) are excluded from various additives that may be incorporated into the composition of the present invention.

### <Curing Catalyst>

The silicon-containing underlayer film-forming composition of the present invention may contain a curing catalyst. Alternatively, the composition may contain no curing catalyst.

The aforementioned curing catalyst may be, for example, an ammonium salt, a phosphine compound, a phosphonium salt, or a sulfonium salt. The salt described below as an example of a curing catalyst may be added in the form of a salt, or may be a compound that forms a salt in the aforementioned composition (i.e., a compound that forms a salt in the reaction system, but is in a form different from the salt during addition).

Examples of the ammonium salt include:

a quaternary ammonium salt having a structure of the following Formula (D-1):

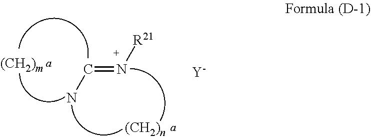

(wherein m^{a} is an integer of 2 to 11; n^{a} is an integer of 2 or 3; R²¹ is an alkyl group or an aryl group; and Y⁻ is an anion);

a quaternary ammonium salt having a structure of the following Formula (D-2):

R²²R²³R²⁴R²⁵N⁺Y⁻ Formula (D-2)

(wherein R²², R²³, R²⁴, and R²⁵ are each an alkyl group or an aryl group; N is a nitrogen atom; Y⁻ is an anion; and each of R²², R²³, R²⁴, and R²⁵ is bonded to a nitrogen atom);

a quaternary ammonium salt having a structure of the following Formula (D-3):

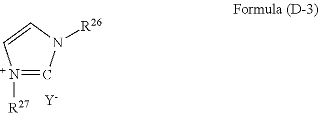

(wherein R²⁶ and R²⁷ are each an alkyl group or an aryl group; N is a nitrogen atom; and Y⁻ is an anion);

a quaternary ammonium salt having a structure of the following Formula (D-4):

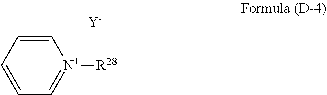

(wherein R²⁸ is an alkyl group or an aryl group; N is a nitrogen atom; and Y⁻ is an anion);

a quaternary ammonium salt having a structure of the following Formula (D-5):

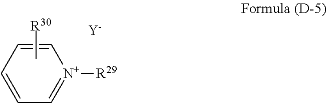

(wherein R²⁹ and R³⁰ are each an alkyl group or an aryl group; N is a nitrogen atom; and Y⁻ is an anion); and

a tertiary ammonium salt having a structure of the following Formula (D-6):

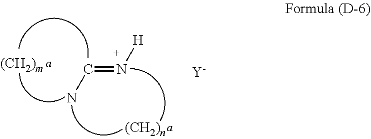

(wherein m^{a} is an integer of 2 to 11; n^{a} is an integer of 2 or 3; H is a hydrogen atom; N is a nitrogen atom; and Y⁻ is an anion).

Examples of the phosphonium salt include a quaternary phosphonium salt of the following Formula (D-7):

R³¹R³²R³³R³⁴P⁺Y⁻ Formula (D-7)

(wherein R³¹, R³², R³³, and R³⁴ are each an alkyl group or an aryl group; P is a phosphorus atom; Y⁻ is an anion; and each of R³¹, R³², R³³, and R³⁴ is bonded to a phosphorus atom).

Examples of the sulfonium salt include a tertiary sulfonium salt of the following Formula (D-8):

R³⁵R³⁶R³⁷S⁺Y⁻ Formula (D-8)

(wherein R³⁵, R³⁶, and R³⁷ are each an alkyl group or an aryl group; S is a sulfur atom; Y⁻ is an anion; and each of R³⁵, R³⁶, and R³⁷ is bonded to a sulfur atom).

The compound of Formula (D-1) is a quaternary ammonium salt derived from an amine. In Formula (D-1), m^{a} is an integer of 2 to 11, and n^{a} is an integer of 2 or 3. R²¹ of the quaternary ammonium salt is a C₁₋₁₈ (preferably C₂₋₁₀) alkyl group, or a C₆₋₁₈ aryl group. Examples thereof include linear alkyl groups, such as ethyl group, propyl group, and butyl group, benzyl group, cyclohexyl group, cyclohexylmethyl group, and dicyclopentadienyl group. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻).

The compound of Formula (D-2) is a quaternary ammonium salt having a structure of R²²R²³R²⁴R²⁵N⁺Y⁻. R²², R²³, R²⁴, and R²⁵ of the quaternary ammonium salt are each a C₁₋₁₈ alkyl group or a C₆₋₈ aryl group. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). The quaternary ammonium salt is commercially available, and examples of the quaternary ammonium salt include tetramethylammonium acetate, tetrabutylammonium acetate, triethylbenzylammonium chloride, triethylbenzylammonium bromide, trioctylmethylammonium chloride, tributylbenzylammonium chloride, and trimethylbenzylammonium chloride.

The compound of Formula (D-3) is a quaternary ammonium salt derived from 1-substituted imidazole. The carbon atom number of each of R²⁶ and R²⁷ is 1 to 18, and the total number of carbon atoms of R²⁶ and R²⁷ is preferably 7 or more. Examples of R²⁶ include methyl group, ethyl group, propyl group, phenyl group, and benzyl group. Examples of R²⁷ include benzyl group, octyl group, and octadecyl group. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). Although this compound is commercially available, the compound may be produced through, for example, reaction between an imidazole compound (e.g., 1-methylimidazole or 1-benzylimidazole) and an alkyl halide or an aryl halide (e.g., benzyl bromide or methyl bromide).

The compound of Formula (D-4) is a quaternary ammonium salt derived from pyridine. In Formula (D-4), R²⁸ is a C₁₋₁₈ (preferably C₄₋₁₈) alkyl group, or a C₆₋₁₈ aryl group. Examples thereof include butyl group, octyl group, benzyl group, and lauryl group. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). Although this compound is commercially available, the compound may be produced through, for example, reaction between pyridine and an alkyl halide or an aryl halide, such as lauryl chloride, benzyl chloride, benzyl bromide, methyl bromide, or octyl bromide. Examples of this compound include N-laurylpyridinium chloride and N-benzylpyridinium bromide.

The compound of Formula (D-5) is a quaternary ammonium salt derived from a substituted pyridine, such as picoline. In Formula (D-5), R²⁹ is a C₁₋₁₈ (preferably C₄₋₁₈) alkyl group, or a C₆₋₈ aryl group. Examples thereof include methyl group, octyl group, lauryl group, and benzyl group. R³⁰ is a C₁₋₁₈ alkyl group or a C₆₋₁₈ aryl group, and, for example, R³⁰ is a methyl group when the compound is a quaternary ammonium salt derived from picoline. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). Although this compound is commercially available, the compound may be produced through, for example, reaction between a substituted pyridine (e.g., picoline) and an alkyl halide or an aryl halide, such as methyl bromide, octyl bromide, lauryl chloride, benzyl chloride, or benzyl bromide. Examples of this compound include N-benzylpicolinium chloride, N-benzylpicolinium bromide, and N-laurylpicolinium chloride.

The compound of Formula (D-6) is a tertiary ammonium salt derived from an amine. In Formula (D-6), m^{a} is an integer of 2 to 11, and n^{a} is an integer of 2 or 3. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). The compound may be produced through, for example, reaction between an amine and a weak acid, such as a carboxylic acid or phenol. Examples of the carboxylic acid include formic acid and acetic acid. When formic acid is used, the anion (Y⁻) is (HCOO⁻). When acetic acid is used, the anion (Y⁻) is (CH₃COO⁻). When phenol is used, the anion (Y⁻) is (C₆H₅O⁻).

The compound of Formula (D-7) is a quaternary phosphonium salt having a structure of R³¹R³²R³³R³⁴P⁺Y⁻. R³¹, R³², R³³, and R³⁴ are each a C₁₋₁₈ alkyl group or a C₆₋₈ aryl group. Three of the four substituents R³¹ to R³⁴ are preferably a phenyl group or a substituted phenyl group, such as a phenyl group or a tolyl group. The remaining one substituent is a C₁₋₈ alkyl group or a C₆₋₁₈ aryl group. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). This compound is commercially available, and examples of the compound include tetraalkylphosphonium halides, such as tetra-n-butylphosphonium halides and tetra-n-propylphosphonium halides; trialkylbenzylphosphonium halides, such as triethylbenzylphosphonium halides; triphenylmonoalkylphosphonium halides, such as triphenylmethylphosphonium halides and triphenylethylphosphonium halides; triphenylbenzylphosphonium halides; tetraphenylphosphonium halides; tritolylmonoarylphosphonium halides; or tritolylmonoalkylphosphonium halides (wherein the halogen atom is a chlorine atom or a bromine atom). Particularly preferred are triphenylmonoalkylphosphonium halides, such as triphenylmethylphosphonium halides and triphenylethylphosphonium halides; triphenylmonoarylphosphonium halides, such as triphenylbenzylphosphonium halides; tritolylmonoarylphosphonium halides, such as tritolylmonophenylphosphonium halides; and tritolylmonoalkylphosphonium halides, such as tritolylmonomethylphosphonium halides (wherein the halogen atom is a chlorine atom or a bromine atom).

Examples of the phosphine compound include primary phosphines, such as methylphosphine, ethylphosphine, propylphosphine, isopropylphosphine, isobutylphosphine, and phenylphosphine; secondary phosphines, such as dimethylphosphine, diethylphosphine, diisopropylphosphine, diisoamylphosphine, and diphenylphosphine; and tertiary phosphines, such as trimethylphosphine, triethylphosphine, triphenylphosphine, methyldiphenylphosphine, and dimethylphenylphosphine.

The compound of Formula (D-8) is a tertiary sulfonium salt having a structure of R³⁵R³⁶R³⁷S⁺Y⁻. R³⁵, R³⁶, and R³⁷ are each a C₁₋₁₈ alkyl group or a C₆₋₁₈ aryl group. Two of the three substituents R³⁵ to R³⁷ are preferably a phenyl group or a substituted phenyl group, such as a phenyl group or a tolyl group. The remaining one substituent is a C₁₋₁₈ alkyl group or a C₆₋₈ aryl group. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), alcoholate (—O⁻), maleate anion, and nitrate anion. This compound is commercially available, and examples of the compound include trialkylsulfonium halides, such as tri-n-butylsulfonium halides and tri-n-propylsulfonium halides; dialkylbenzylsulfonium halides, such as diethylbenzylsulfonium halides; diphenylmonoalkylsulfonium halides, such as diphenylmethylsulfonium halides and diphenylethylsulfonium halides; triphenylsulfonium halides (wherein the halogen atom is a chlorine atom or a bromine atom); trialkylsulfonium carboxylates, such as tri-n-butylsulfonium carboxylate and tri-n-propylsulfonium carboxylate; dialkylbenzylsulfonium carboxylates, such as diethylbenzylsulfonium carboxylate; diphenylmonoalkylsulfonium carboxylates, such as diphenylmethylsulfonium carboxylate and diphenylethylsulfonium carboxylate; and triphenylsulfonium carboxylate. Triphenylsulfonium halides and triphenylsulfonium carboxylate are preferably used.

In the present invention, a nitrogen-containing silane compound may be added as a curing catalyst. Examples of the nitrogen-containing silane compound include silane compounds containing an imidazole ring, such as N-(3-triethoxysilylpropyl)-4,5-dihydroimidazole.

When a curing catalyst is used, the amount of the curing catalyst is 0.01 parts by mass to 10 parts by mass, or 0.01 parts by mass to 5 parts by mass, or 0.01 parts by mass to 3 parts by mass relative to 100 parts by mass of the polysiloxane [A].

### <Stabilizer>

The stabilizer may be incorporated for the purpose of, for example, stabilization of the aforementioned hydrolysis condensate of the hydrolyzable silane mixture. Specific examples of the stabilizer that may be incorporated include an organic acid, water, an alcohol, or any combination of these.

Examples of the organic acid include oxalic acid, malonic acid, methylmalonic acid, succinic acid, maleic acid, malic acid, tartaric acid, phthalic acid, citric acid, glutaric acid, lactic acid, and salicylic acid. Of these, oxalic acid or maleic acid is preferred. When an organic acid is incorporated, the amount thereof is 0.1 to 5.0% by mass relative to the mass of the aforementioned hydrolysis condensate of the hydrolyzable silane mixture. Such an organic acid may also serve as a pH adjuster.

The water may be, for example, pure water, ultrapure water, or ion-exchange water. When water is used, the amount thereof may be 1 part by mass to 20 parts by mass relative to 100 parts by mass of the silicon-containing underlayer film-forming composition.

The alcohol is preferably an alcohol that easily evaporates (volatilizes) by heating after application of the composition. Examples of the alcohol include methanol, ethanol, propanol, i-propanol, and butanol. When an alcohol is incorporated, the amount thereof may be 1 part by mass to 20 parts by mass relative to 100 parts by mass of the silicon-containing underlayer film-forming composition.

### <Organic Polymer>

Incorporation of the aforementioned organic polymer compound into the silicon-containing underlayer film-forming composition enables adjustment of, for example, the dry etching rate (the amount of reduction in film thickness per unit time), attenuation coefficient, or refractive index of a film (underlayer film) formed from the composition. No particular limitation is imposed on the organic polymer compound, and it is appropriately selected from among various organic polymers (polycondensation polymer and addition polymerization polymer) depending on the purpose of addition thereof.

Specific examples of the organic polymer compound include addition polymerization polymers and polycondensation polymers, such as polyester, polystyrene, polyimide, acrylic polymer, methacrylic polymer, polyvinyl ether, phenol novolac, naphthol novolac, polyether, polyamide, and polycarbonate.

In the present invention, an organic polymer having an aromatic or heteroaromatic ring that functions as a light-absorbing moiety (e.g., a benzene ring, a naphthalene ring, an anthracene ring, a triazine ring, a quinoline ring, or a quinoxaline ring) can also be suitably used in the case where such a function is required. Specific examples of such an organic polymer compound include, but are not limited to, addition polymerization polymers containing, as structural units, addition polymerizable monomers (e.g., benzyl acrylate, benzyl methacrylate, phenyl acrylate, naphthyl acrylate, anthryl methacrylate, anthrylmethyl methacrylate, styrene, hydroxystyrene, benzyl vinyl ether, and N-phenylmaleimide); and polycondensation polymers such as phenol novolac and naphthol novolac.

When an addition polymerization polymer is used as an organic polymer compound, the polymer compound may be a homopolymer or a copolymer.

An addition polymerizable monomer is used for the production of the addition polymerization polymer. Specific examples of the addition polymerizable monomer include, but are not limited to, acrylic acid, methacrylic acid, an acrylate ester compound, a methacrylate ester compound, an acrylamide compound, a methacrylamide compound, a vinyl compound, a styrene compound, a maleimide compound, maleic anhydride, and acrylonitrile.

Specific examples of the acrylate ester compound include, but are not limited to, methyl acrylate, ethyl acrylate, normal hexyl acrylate, i-propyl acrylate, cyclohexyl acrylate, benzyl acrylate, phenyl acrylate, anthrylmethyl acrylate, 2-hydroxyethyl acrylate, 3-chloro-2-hydroxypropyl acrylate, 2-hydroxypropyl acrylate, 2,2,2-trifluoroethyl acrylate, 2,2,2-trichloroethyl acrylate, 2-bromoethyl acrylate, 4-hydroxybutyl acrylate, 2-methoxyethyl acrylate, tetrahydrofurfuryl acrylate, 2-methyl-2-adamantyl acrylate, 5-acryloyloxy-6-hydroxynorbornene-2-carboxylic-6-lactone, 3-acryloxypropyltriethoxysilane, and glycidyl acrylate.

Specific examples of the methacrylate ester compound include, but are not limited to, methyl methacrylate, ethyl methacrylate, normal hexyl methacrylate, i-propyl methacrylate, cyclohexyl methacrylate, benzyl methacrylate, phenyl methacrylate, anthrylmethyl methacrylate, 2-hydroxyethyl methacrylate, 2-hydroxypropyl methacrylate, 2,2,2-trifluoroethyl methacrylate, 2,2,2-trichloroethyl methacrylate, 2-bromoethyl methacrylate, 4-hydroxybutyl methacrylate, 2-methoxyethyl methacrylate, tetrahydrofurfuryl methacrylate, 2-methyl-2-adamantyl methacrylate, 5-methacryloyloxy-6-hydroxynorbornene-2-carboxylic-6-lactone, 3-methacryloxypropyltriethoxysilane, glycidyl methacrylate, 2-phenylethyl methacrylate, hydroxyphenyl methacrylate, and bromophenyl methacrylate.

Specific examples of the acrylamide compound include, but are not limited to, acrylamide, N-methylacrylamide, N-ethylacrylamide, N-benzylacrylamide, N-phenylacrylamide, N,N-dimethylacrylamide, and N-anthrylacrylamide.

Specific examples of the methacrylamide compound include, but are not limited to, methacrylamide, N-methylmethacrylamide, N-ethylmethacrylamide, N-benzylmethacrylamide, N-phenylmethacrylamide, N,N-dimethylmethacrylamide, and N-anthrylmethacrylamide.

Specific examples of the vinyl compound include, but are not limited to, vinyl alcohol, 2-hydroxyethyl vinyl ether, methyl vinyl ether, ethyl vinyl ether, benzyl vinyl ether, vinylacetic acid, vinyltrimethoxysilane, 2-chloroethyl vinyl ether, 2-methoxyethyl vinyl ether, vinylnaphthalene, and vinylanthracene.

Specific examples of the styrene compound include, but are not limited to, styrene, hydroxystyrene, chlorostyrene, bromostyrene, methoxystyrene, cyanostyrene, and acetylstyrene.

Examples of the maleimide compound include, but are not limited to, maleimide, N-methylmaleimide, N-phenylmaleimide, N-cyclohexylmaleimide, N-benzylmaleimide, and N-hydroxyethylmaleimide.

When a polycondensation polymer is used as the polymer, the polymer is, for example, a polycondensation polymer composed of a glycol compound and a dicarboxylic acid compound. Examples of the glycol compound include diethylene glycol, hexamethylene glycol, and butylene glycol. Examples of the dicarboxylic acid compound include succinic acid, adipic acid, terephthalic acid, and maleic anhydride. Examples of the polymer include, but are not limited to, polyesters, polyamides, and polyimides, such as polypyromellitimide, poly(p-phenyleneterephthalamide), polybutylene terephthalate, and polyethylene terephthalate.

When the organic polymer compound contains a hydroxy group, the hydroxy group may be crosslinked with, for example, a hydrolysis condensate.

The organic polymer compound generally has a weight average molecular weight of 1,000 to 1,000,000. In the case of incorporation of the organic polymer compound, from the viewpoints of sufficiently achieving the functional effect of the polymer and preventing the precipitation of the polymer in the composition, the weight average molecular weight may be, for example, 3,000 to 300,000, or 5,000 to 300,000, or 10,000 to 200,000.

These organic polymer compounds may be used alone or in combination of two or more species.

When the silicon-containing underlayer film-forming composition of the present invention contains an organic polymer compound, the amount of the organic polymer compound cannot be univocally determined, since the amount should be appropriately determined in consideration of, for example, the function of the organic polymer compound. The amount of the organic polymer compound is generally 1 to 200% by mass relative to the mass of the aforementioned polysiloxane [A]. From the viewpoint of, for example, preventing the precipitation of the polymer compound in the composition, the amount is, for example, 100% by mass or less, preferably 50% by mass or less, more preferably 30% by mass or less. From the viewpoint of, for example, sufficiently achieving the effect of the polymer compound, the amount is, for example, 5% by mass or more, preferably 10% by mass or more, more preferably 30% by mass or more.

### <Surfactant>

When the silicon-containing underlayer film-forming composition is applied onto a substrate, a surfactant effectively prevents formation of, for example, pinholes and striations. Examples of the surfactant include a nonionic surfactant, an anionic surfactant, a cationic surfactant, a silicon-containing surfactant, a fluorine-containing surfactant, and a UV-curable surfactant. Specific examples of the surfactant include, but are not limited to, nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether, polyoxyethylene alkylallyl ethers, such as polyoxyethylene octylphenol ether and polyoxyethylene nonylphenol ether, polyoxyethylene-polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-containing surfactants, such as trade names EFTOP (registered trademark) EF301, EF303, and EF352 (available from Mitsubishi Materials Electronic Chemicals Co., Ltd. (former Tohkem Products Corporation)), trade names MEGAFACE (registered trademark) F171, F173, R-08, R-30, R-30N, and R-40LM (available from DIC Corporation), Fluorad FC430 and FC431 (available from 3M Japan Limited), trade name Asahi Guard (registered trademark) AG710 (available from AGC Inc.), and trade names SURFLON (registered trademark) 5-382, SC101, SC102, SC103, SC104, SC105, and SC106 (available from AGC Seimi Chemical Co., Ltd.); and Organosiloxane Polymer KP341 (available from Shin-Etsu Chemical Co., Ltd.).

These surfactants may be used alone or in combination of two or more species.

When the silicon-containing underlayer film-forming composition of the present invention contains a surfactant, the amount of the surfactant is generally 0.0001 to 5% by mass, preferably 0.001 to 4% by mass, more preferably 0.01 to 3% by mass, relative to the mass of the polysiloxane [A].

### <Rheology Controlling Agent>

The rheology controlling agent is added for the purpose of mainly improving the fluidity of the silicon-containing underlayer film-forming composition, in particular, improving the uniformity of the thickness of a film to be formed in a baking process. Specific examples of the rheology controlling agent include phthalic acid derivatives, such as dimethyl phthalate, diethyl phthalate, di-i-butyl phthalate, dihexyl phthalate, and butyl i-decyl phthalate; adipic acid derivatives, such as di-normal butyl adipate, di-i-butyl adipate, di-i-octyl adipate, and octyl decyl adipate; maleic acid derivatives, such as di-normal butyl maleate, diethyl maleate, and dinonyl maleate; oleic acid derivatives, such as methyl oleate, butyl oleate, and tetrahydrofurfuryl oleate; and stearic acid derivatives, such as normal butyl stearate and glyceryl stearate.

When such a rheology controlling agent is used, the amount of the rheology controlling agent added to the silicon-containing underlayer film-forming composition is generally less than 30% by mass relative to the total solid content of the composition.

### <Adhesion Aid>

The adhesion aid is added for the purpose of mainly improving the adhesion between a substrate or a film provided thereon (e.g., a neutral film or a brush film) and a film (underlayer film) formed from the silicon-containing underlayer film-forming composition. Specific examples of the adhesion aid include chlorosilanes, such as trimethylchlorosilane, dimethylvinylchlorosilane, methyldiphenylchlorosilane, and chloromethyldimethylchlorosilane; alkoxysilanes, such as trimethylmethoxysilane, dimethyldiethoxysilane, methyldimethoxysilane, and dimethylvinylethoxysilane; silazanes, such as hexamethyldisilazane, N,N′-bis(trimethylsilyl)urea, dimethyltrimethylsilylamine, and trimethylsilylimidazole; additional silanes, such as γ-chloropropyltrimethoxysilane, γ-aminopropyltriethoxysilane, and γ-glycidoxypropyltrimethoxysilane; heterocyclic compounds, such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine; and urea or thiourea compounds, such as 1,1-dimethylurea and 1,3-dimethylurea.

When such an adhesion aid is used, the amount of the adhesion aid added to the silicon-containing underlayer film-forming composition is generally less than 5% by mass, preferably less than 2% by mass, relative to the total solid content of the composition.

### <pH Adjuster>

The pH adjuster that may be added to the silicon-containing underlayer film-forming composition is an acid having one or two or more carboxylate groups, for example, an organic acid described above in <Stabilizer>, bisphenol S, or a bisphenol S derivative. When such a pH adjuster is used, the amount of the pH adjuster added may be 0.01 to 20 parts by mass, or 0.01 to 10 parts by mass, or 0.01 to 5 parts by mass, relative to 100 parts by mass of the polysiloxane [A].

Specific examples of the bisphenol S or the bisphenol S derivative include, but are not limited to, compounds of the following Formulae (C-1) to (C-23).

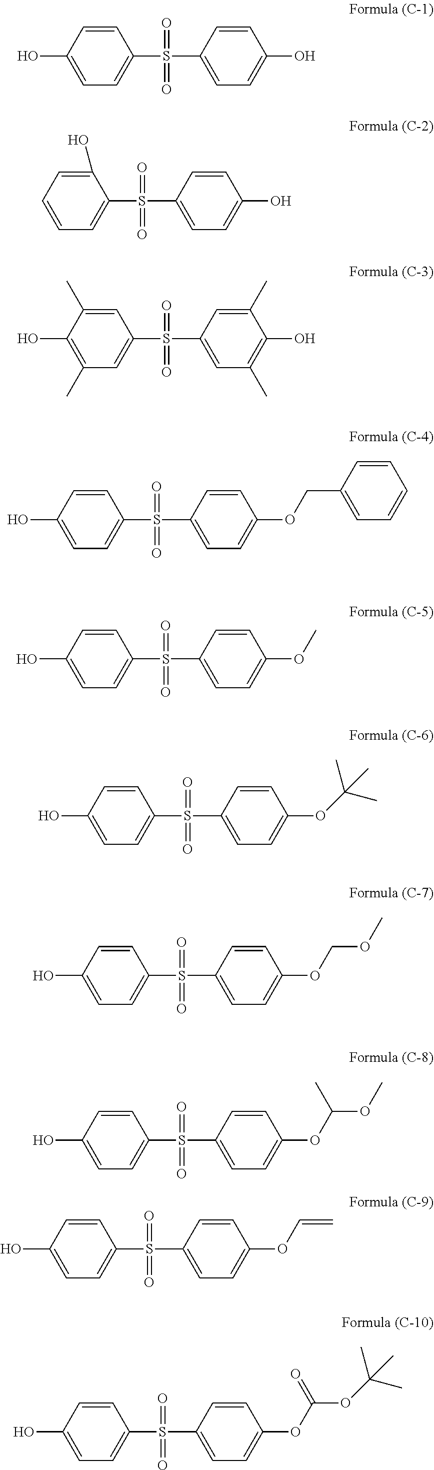

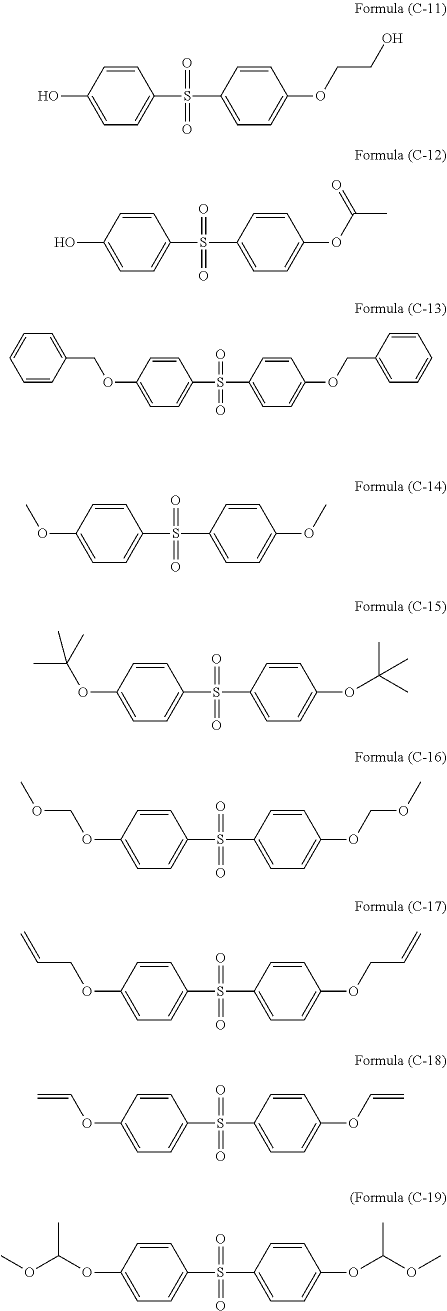

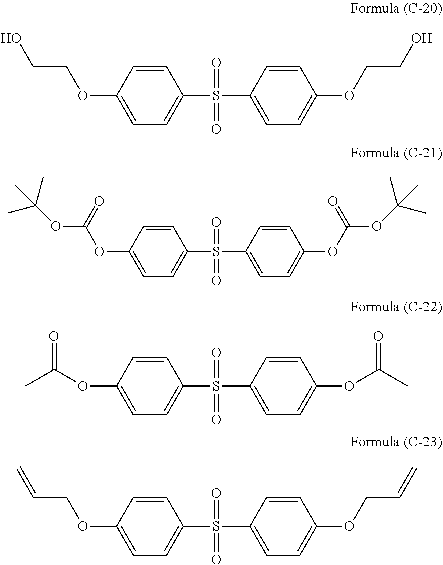

### <Metal Oxide>

Examples of the metal oxide that may be added to the silicon-containing underlayer film-forming composition of the present invention include, but are not limited to, oxides of a combination of one or more selected from among metals, such as tin (Sn), titanium (Ti), aluminum (Al), zirconium (Zr), zinc (Zn), niobium (Nb), tantalum (Ta), and W (tungsten), and semimetals, such as boron (B), silicon (Si), germanium (Ge), arsenic (As), antimony (Sb), and tellurium (Te).

### [Production Method for Substrate Having Self-Assembled Pattern]

The present invention is also directed to a self-assembled pattern formation method using the aforementioned silicon-containing underlayer film-forming composition. In particular, the present invention is directed to a production method for a substrate having a self-assembled pattern by directed self-assembly (DSA).

The production method for a substrate having a self-assembled pattern includes a step of forming, on a substrate, an underlayer film for a self-assembled film from the composition for forming a silicon-containing underlayer film for a self-assembled film of the present invention, and a step of forming a self-assembled film above the underlayer film to thereby form a self-assembled pattern (a pattern structure forming a self-assembled film, which may also be referred to as “microphase-separated structure”).

In a preferred embodiment, the layer on which the aforementioned self-assembled film is provided (e.g., the aforementioned underlayer film) is subjected to a neutralization treatment, and then the self-assembled film is formed to thereby form a self-assembled pattern.

The neutralization treatment in the art refers to a treatment for modifying the surface of a substrate, etc. on which the self-assembled film is formed so that the surface exhibits the affinity to any polymer constituting the block copolymer of the self-assembled film. The neutralization treatment can prevent the surface of a substrate, etc. from contacting with only a phase formed of a specific polymer resulting from phase separation. The neutralization treatment is important for forming, for example, a cylinder structure, a dot structure, or a gyroid structure freely oriented with respect to the substrate surface by phase separation.

Specifically, the neutralization treatment may involve the formation of a thin film (neutral film) containing a grounding agent exhibiting the affinity to any polymer constituting the block copolymer on the surface of a substrate, etc. on which the self-assembled film is formed.

For formation of the self-assembled pattern, a change in surface energy (hydrophilicity/hydrophobicity) is utilized for patterning the block copolymer into a cylindrical shape. Specifically, when the aforementioned neutral film is used, the water contact angle of the polymer in the neutral film preferably falls between the water contact angles of the respective polymer chains constituting the block copolymer in the self-assembled film.

In the present invention, the formation of the aforementioned self-assembled film may be preceded by formation of a neutral film that enables storage of pattern data by electron beam lithography or laser irradiation.

The formation of the self-assembled film may be preceded by lithography with use of a resist, or lithography without use of a resist. When the block copolymer itself has pattern formability by self-assembly, a resist may not be necessarily required for utilizing the ability.

In the present invention, for example, a silicon-containing underlayer film is formed on a substrate from the silicon-containing underlayer film-forming composition of the present invention, a neutral film is formed on the underlayer film, and a self-assembled film is formed on the neutral film, whereby patterning can be performed with the self-assembled film. The self-assembled film may be applied along a preset pattern guide, and the pattern guide may be formed by means of a photolithographic technique.

The self-assembled film provided by self-assembly along the pattern guide has a preferentially removable portion/unremovable portion by, for example, a developer or an etching gas, depending on the type of a unit structure in a polymer chain constituting the self-assembled film. The removable portion may be selectively removed to thereby achieve shrink of the pattern width or formation of a sidewall.

When the aforementioned neutral film is patterned, a stepped portion is formed between the patterned portion of the neutral film and an exposed (through patterning) portion of the underlying layer (silicon-containing underlayer film). A brush material may be used for eliminating the stepped portion and controlling hydrophilicity/hydrophobicity. The brush material is provided so as to prevent a self-assembled pattern from developing in a non-target portion. Thus, the brush material may be embedded into the exposed (through patterning) portion of the underlying layer (silicon-containing underlayer film), to thereby form a template film for a self-assembled pattern including the patterned neutral film and the brush film.

Next will be described an embodiment of the production method for a substrate having a self-assembled pattern using the aforementioned silicon-containing underlayer film, neutral film, and brush film.

According to the embodiment, the production method may include:

a step of forming, on a substrate, an underlayer film for a self-assembled film from the composition for forming a silicon-containing underlayer film for a self-assembled film;

a step of forming a neutral film on a portion of the underlayer film for a self-assembled film;

a step of forming a brush film on a portion of the underlayer film where the neutral film is not formed, to thereby form a template film for a self-assembled pattern from the neutral film and the brush film; and

a step of forming a self-assembled film on the template film for a self-assembled pattern, to thereby form a self-assembled pattern.

In another embodiment, an organic underlayer film may be formed below the underlayer film (silicon-containing underlayer film) of a self-assembled film. A resist pattern may be used in the aforementioned step of forming a neutral film on a portion of the underlayer film for a self-assembled film; i.e., the resist pattern may be used for forming a patterned neutral film. According to the embodiment, the production method may include:

a step of forming an organic underlayer film on a substrate;

a step of forming, on the organic underlayer film, an underlayer film for a self-assembled film from the composition for forming a silicon-containing underlayer film for a self-assembled film;

a step of forming a neutral film on the underlayer film for a self-assembled film;

a step of forming a resist film on the neutral film;

a step of irradiating the resist film with light, and developing the resist film, to thereby form a resist pattern;

a step of etching the neutral film by using the resist pattern as a mask;

a step of etching or stripping the resist pattern, to thereby pattern the neutral film on the underlayer film for a self-assembled film;

a step of forming a brush film on the underlayer film for a self-assembled film and on the patterned neutral film on the underlayer film;

a step of etching or stripping the brush film on the patterned neutral film, to thereby expose the neutral film and to form a template film for a self-assembled pattern including

the neutral film and the brush film; and a step of forming a self-assembled film on the template film for a self-assembled pattern, to thereby form a self-assembled pattern.

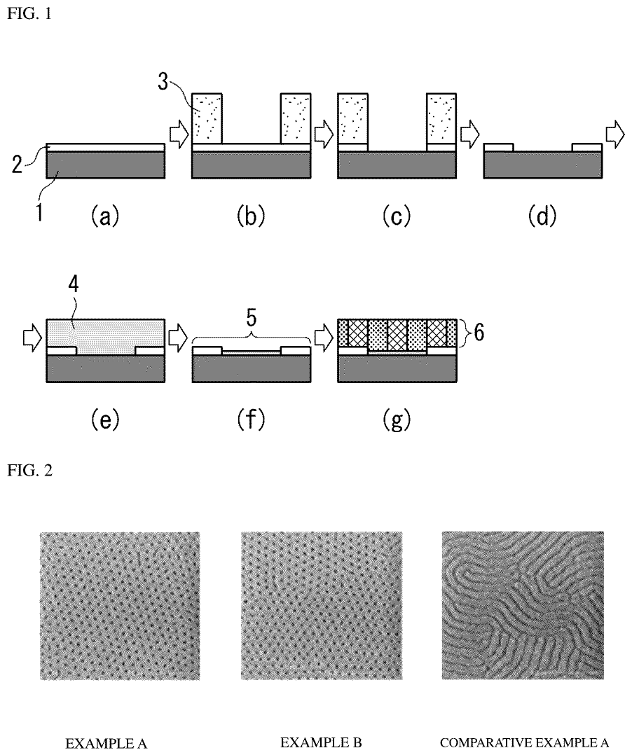

FIG. 1 shows one embodiment of the production method for a substrate having a self-assembled pattern (self-assembled pattern formation method) of the present invention.

Firstly, an underlayer film 1 of a self-assembled film is formed from the silicon-containing underlayer film-forming composition of the present invention (not illustrated), and then a neutral film 2 is formed on the underlayer film 1 (FIG. 1a).

Subsequently, a resist film is formed on the neutral film 2, and the resist film is exposed to light through a mask and then developed, to thereby form a desired resist pattern 3 (FIG. 1b). The neutral film 2 is patterned by using the resist pattern 3 as a mask (FIG. 1c), and then the resist pattern 3 used as the mask is removed, to thereby form a patterned neutral film 2 (FIG. 1d).

Thereafter, a brush film 4 is formed so as to cover the neutral film 2 and the underlayer film 1 (FIG. 1e), and then a portion of the brush film 4 on the neutral film 2 is removed to expose the neutral film 2, to thereby form a template film 5 for a self-assembled pattern including the neutral film 2 and the brush film 4 (FIG. if).

Finally, a self-assembled film 6 is formed on the template film 5, to thereby form a self-assembled pattern (FIG. 1g).

The respective steps according to the present invention will next be described.

### <Formation of Underlayer Film of Self-Assembled Film>

Firstly, the composition for forming a silicon-containing underlayer film for a self-assembled film of the present invention is applied onto a substrate used for the production of a precise integrated circuit device [e.g., a semiconductor substrate such as a silicon wafer coated with a silicon oxide film, a silicon nitride film, or a silicon oxynitride film, a silicon nitride substrate, a quartz substrate, a glass substrate (including alkali-free glass, low alkali glass, or crystallized glass), a glass substrate coated with an ITO (indium tin oxide) film or an IZO (indium zinc oxide) film, a plastic (e.g., polyimide or PET) substrate, a substrate coated with a low dielectric constant material (low-k material), or a flexible substrate] by an appropriate application method with, for example, a spinner or a coater. Thereafter, the composition is cured through baking by heating means (e.g., a hot plate), to thereby form a underlayer film for a self-assembled film. Hereinafter, the term “underlayer film” refers to a film formed from the silicon-containing underlayer film-forming composition of the present invention (may also be referred to as “silicon-containing underlayer film”).

The baking is performed under appropriately determined conditions; i.e., a baking temperature of 40° C. to 400° C. or 80° C. to 250° C. and a baking time of 0.3 minutes to 60 minutes. Preferably, the baking temperature is 150° C. to 250° C., and the baking time is 0.5 minutes to 2 minutes.

The thus-formed underlayer film has a thickness of, for example, 10 nm to 1,000 nm, or 20 nm to 500 nm, or 50 nm to 300 nm, or 100 nm to 200 nm, or 10 to 150 nm.

### <Formation of Organic Underlayer Film>

In an embodiment of the present invention, an organic underlayer film may be formed on the aforementioned substrate, and then the aforementioned underlayer film may be formed on the organic underlayer film.

No particular limitation is imposed on the organic underlayer film used herein, and the organic underlayer film may be arbitrarily selected from among those conventionally used in a lithographic process.

The organic underlayer film is formed by applying the below-described organic underlayer film-forming composition onto a substrate by the aforementioned appropriate coating method, and then baking and curing the composition.

The thickness of the organic underlayer film formed on the substrate may be appropriately adjusted; for example, may be adjusted to 0.01 to 30 μm.

### <Organic Underlayer Film-Forming Composition (SOC Composition)>

The organic underlayer film-forming composition may contain an organic underlayer film-forming compound (SOC compound) and a solvent, and, if necessary, may contain any additive such as a crosslinking agent, an acid, an acid generator (thermal acid generator or photoacid generator), a rheology controlling agent, an adhesion aid, or a surfactant.

Examples of the organic underlayer film-forming compound (SOC compound) include, but are not limited to, compounds and polymers described below. No particular limitation is imposed on the solvent, so long as the solvent can dissolve and disperse the below-described organic underlayer film-forming compound (SOC compound) or additional components. For example, any compound exemplified above in [Solvent] may be appropriately used.

The solid content of the organic underlayer film-forming composition may be, for example, 0.1 to 70% by mass or 0.1 to 60% by mass. The “solid content” as used herein refers to the amount of all components (except for the solvent component) contained in the organic underlayer film-forming composition.

The amount of the organic underlayer film-forming compound in the solid content may be, for example, 1 to 100% by mass, or 1 to 99.9% by mass, or 50 to 99.9% by mass.

### <<Organic Underlayer Film-Forming Compound (SOC Compound)>>

Examples of the compound for forming an organic underlayer film include, but are not limited to, organic underlayer film-forming compound 1 (SOC1 compound) to organic underlayer film-forming compound 28 (SOC28 compound).

### <<Organic Underlayer Film-Forming Compound 1>>

The organic underlayer film-forming compound 1 (SOC1 compound) may be any of compounds described in, for example, WO 2010/147155 (JP 5641253 B) and WO 2012/077640 (JP 5867732 B). The entire disclosure of WO 2010/147155 (JP 5641253 B) and WO 2012/077640 is incorporated herein by reference.

Specifically, the organic underlayer film-forming compound 1 may be, for example, a polymer containing a unit structure of the following Formula (SOC1-1).

Unless otherwise specified, the symbols of groups in the following Formula (SOC1-1) and the definitions of the symbols are limited only to those in Formula (SOC1-1); i.e., those in description of <<Organic Underlayer Film-Forming Compound 1>>.

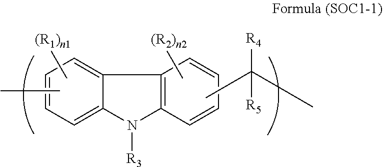

[In Formula (SOC1-1), R₁ and R₂ are each selected from the group consisting of a hydrogen atom, a halogen atom, a nitro group, an amino group, a hydroxy group, a C₁₋₁₀ alkyl group, a C₂₋₁₀ alkenyl group, a C₆₋₄₀ aryl group, and any combination of these, and the alkyl group, the alkenyl group, or the aryl group may contain an ether bond, a ketone bond, or an ester bond;

R₃ is selected from the group consisting of a hydrogen atom, a C₁₋₁₀ alkyl group, a C₂₋₁₀ alkenyl group, a C₆₋₄₀ aryl group, and any combination of these, and the alkyl group, the alkenyl group, or the aryl group may contain an ether bond, a ketone bond, or an ester bond;

R₄ is a hydrogen atom, or a C₆₋₄₀ aryl group or heterocyclic group substitutable with a halogen atom, a nitro group, an amino group, or a hydroxy group;

R₅ is a hydrogen atom, or a C₁₋₁₀ alkyl group, C₆₋₄₀ aryl group, or heterocyclic group substitutable with a halogen atom, a nitro group, an amino group, or a hydroxy group;

R₄ and R₅ may form a ring together with the carbon atom to which they are bonded; and

n1 and n2 are each an integer of 1 to 3.]

### <<Organic Underlayer Film-Forming Compound 2>>

The organic underlayer film-forming compound 2 (SOC2 compound) may be any of compounds described in, for example, PCT/JP2021/028713, PCT/JP2021/028714, and WO 2013/047516 (JP 6066092 B). The entire disclosure of PCT/JP2021/028713, PCT/JP2021/028714, and WO 2013/047516 (JP 6066092 B) is incorporated herein by reference.

Specifically, the organic underlayer film-forming compound 2 may be, for example, a polymer containing a unit structure of the following Formula (SOC2-1) and/or a unit structure of the following Formula (SOC2-1).

Unless otherwise specified, the symbols of groups in the following Formulae (SOC2-1) and (SOC2-2) and the definitions of the symbols are limited only to those in Formulae (SOC2-2) and (SOC2-2); i.e., those in description of <<Organic Underlayer Film-Forming Compound 2>.

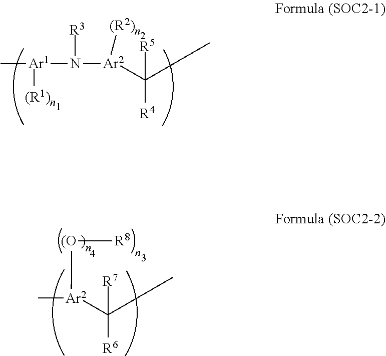

[In the Formulae,

Ar¹ and Ar² are each a benzene ring or a naphthalene ring, and Ar¹ and Ar² may bonded to each other via a single bond;

Ar³ is a C₆₋₆₀ aromatic compound that may contain a nitrogen atom;

R¹ and R² are each a substituent of a hydrogen atom on the rings of Ar¹ and Ar², and selected from the group consisting of a halogen atom, a nitro group, an amino group, a cyano group, a hydroxy group, a C₁₋₁₀ alkyl group, a C₂₋₁₀ alkenyl group, a C₂₋₁₀ alkynyl group, a C₆₋₄₀ aryl group, and any combination of these, and the alkyl group, the alkenyl group, the alkynyl group, and the aryl group may contain an ether bond, a ketone bond, or an ester bond;

R³ and R⁸ are each selected from the group consisting of a hydrogen atom, a C₁₋₁₀ alkyl group, a C₂₋₁₀ alkenyl group, a C₂₋₁₀ alkynyl group, a C₆₋₄₀ aryl group, and any combination of these, the alkyl group, the alkenyl group, the alkynyl group, and the aryl group may contain an ether bond, a ketone bond, or an ester bond, and the aryl group may be substituted with a C₁₋₁₀ alkyl group substituted with a hydroxy group;

R⁴ and R⁶ are each selected from the group consisting of a hydrogen atom, a C₁₋₁₀ alkyl group, a trifluoromethyl group, a C₆₋₄₀ aryl group, and a heterocyclic group, the aryl group and the heterocyclic group may be substituted with a halogen atom, a nitro group, an amino group, a cyano group, a trifluoromethyl group, a C₁₋₁₀ alkyl group, a C₁₋₁₀ alkoxy group, a C₂₋₁₀ alkenyl group, a C₂₋₁₀ alkynyl group, a C₆₋₄₀ aryl group, a formyl group, a carboxy group, or a hydroxy group, and the alkyl group, the alkenyl group, the alkynyl group, and the aryl group may contain an ether bond, a ketone bond, or an ester bond;

R⁵ and R⁷ are each selected from the group consisting of a hydrogen atom, a C₁₋₁₀ alkyl group, a trifluoromethyl group, a C₆₋₄₀ aryl group, and a heterocyclic group, the aryl group and the heterocyclic group may be substituted with a halogen atom, a nitro group, an amino group, a cyano group, a hydroxy group, a trifluoromethyl group, a C₁₋₁₀ alkyl group, a C₁₋₁₀ alkoxy group, a C₂₋₁₀ alkenyl group, a C₂₋₁₀ alkynyl group, or a C₆₋₄₀ aryl group, and the alkyl group, the alkenyl group, the alkynyl group, and the aryl group may contain an ether bond, a ketone bond, or an ester bond;

R⁴ and R⁵ or R⁶ and R⁷ may form a ring together with the carbon atom to which they are bonded;

n1 and n2 are each an integer of 0 to 3;

n3 is an integer of 1 or more and not more than the number of substituents substitutable on Ar³; and

n4 is 0 or 1, and when n4 is 0, R⁸ is bonded to a nitrogen atom contained in Ar³.]

### <<Organic Underlayer Film-Forming Compound 3>>

The organic underlayer film-forming compound 3 (SOC3 compound) may be a compound described in WO 2017/154921. The entire disclosure of WO 2017/154921 is incorporated herein by reference.

Specifically, the organic underlayer film-forming compound 3 may be, for example, a compound containing a partial structure (I) and a partial structure (II) described below.

The partial structure (I) may be at least one partial structure selected from the group consisting of partial structures of the following Formulae (SOC3-1-1) to (SOC3-1-5), or a partial structure formed of a combination between a partial structure of the following Formula (SOC3-1-6) and a partial structure of the following Formula (SOC3-1-7) or (SOC3-1-8). The partial structure (II) may be a partial structure of the following Formula (SOC3-2-1) or (SOC3-2-2).

Unless otherwise specified, the symbols of groups in the following Formulae (SOC3-1-1) to (SOC3-1-8) and (SOC3-2-1) to (SOC3-2-2) and the definitions of the symbols are limited only to those in these Formulae; i.e., those in description of

### <<Organic Underlayer Film-Forming Compound 3>>.

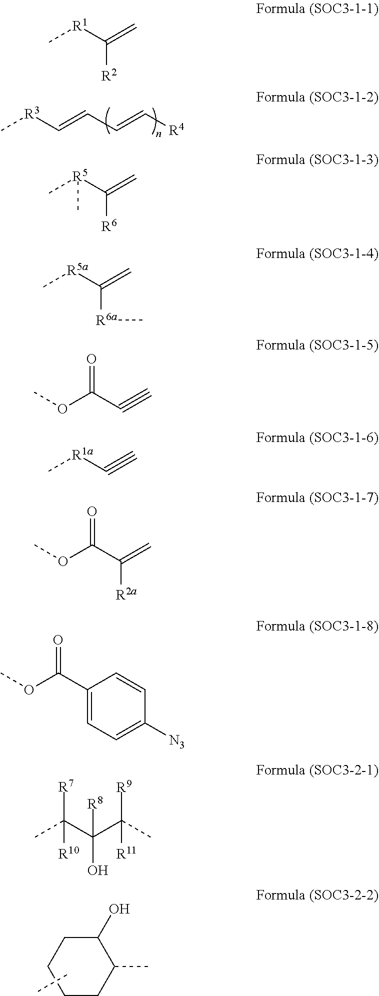

[In the Formulae, R¹, R^{1a}, R³, R⁵, R^{5a}, and R^{6a} are each a C₁₋₁₀ saturated hydrocarbon group, a C₆₋₄₀ aromatic hydrocarbon group, an oxygen atom, a carbonyl group, a sulfur atom, a nitrogen atom, an amide group, an amino group, or any combination of these; R², R²a, R⁴, and R⁶ are each a hydrogen atom, a C₁₋₁₀ saturated hydrocarbon group, a C₂₋₁₀ unsaturated hydrocarbon group, an oxygen atom, a carbonyl group, an amide group, an amino group, or any combination of these; R², R^{2a}, R⁴, and R⁶ are each a monovalent group; R¹, R^{1a}, R³, R^{5a}, and R^{6a} are each a divalent group; R⁵ is a trivalent group; R⁷, R⁸, R⁹, R¹⁰, and R¹¹ are each a hydrogen atom or a C₁₋₁₀ saturated hydrocarbon group; n is a repeating unit number of 1 to 10; and a dotted line is a chemical bond to the adjacent atom.]

### <<Organic Underlayer Film-Forming Compound 4>>

The organic underlayer film-forming compound 4 (SOC4 compound) may be, for example, a compound described in WO 2018/186310. The entire disclosure of WO 2018/186310 is incorporated herein by reference.

Specifically, the organic underlayer film-forming compound 4 may be, for example, a polymer having a unit structure of the following Formula (SOC4-1).

Unless otherwise specified, the symbols of groups in the following Formulae (SOC4-1) and (SOC4-2) and the definitions of the symbols are limited only to those in Formulae (SOC4-1) and (SOC4-1); i.e., those in description of <<Organic Underlayer Film-Forming Compound 4>>.

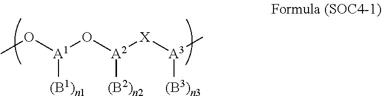

[In Formula (SOC4-1), A¹, A², and A³ are each independently a C₆₋₁₀₀ aromatic ring that may contain a heteroatom, or a hydrocarbon group containing a C₆₋₁₀₀ aromatic ring that may contain a heteroatom; B¹, B², and B³ are each independently a group of the following Formula (SOC4-2):

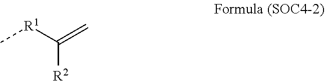

(in Formula (SOC4-2), R¹ is a C₁₋₁₀ alkylene group, a C₁₋₁₀ alkenylene group, a C₁₋₁₀ alkynylene group, a C₆₋₄₀ arylene group (the alkylene group, the alkenylene group, the alkynylene group, and the arylene group may be arbitrarily substituted with one or two or more cyano groups and/or one or two or more hydroxyl groups), an oxygen atom, a carbonyl group, a sulfur atom, —C(O)—O—, —C(O)—NR^{a}—, —NR^{b}—, or any combination of these, R^{a} is a hydrogen atom or a C₁₋₁₀ alkyl group; R^{b} is a hydrogen atom, a C₁₋₁₀ alkyl group, or a C₂₋₁₀ alkylcarbonyl group; R² is a hydrogen atom or a C₁₋₁₀ alkyl group; and a dotted line is a bond to A¹, A², or A³); X is a carbonyl group, a sulfonyl group, a —CR²₂— group, or a —C(CF₃)₂— group; n1 is an integer satisfying a relation of 1≤n1≤4; n2 is an integer satisfying a relation of 0≤n2≤4; n3 is an integer satisfying a relation of 0≤n3≤4; and n1+n2+n3 is an integer of 1 to 12.]

The organic underlayer film-forming compound 4 may be a polymer containing a unit structure of the following Formula (SOC4-3) in addition to a unit structure of Formula (SOC4-1).

Unless otherwise specified, the symbols of groups in the following Formula (SOC4-3) and the definitions of the symbols are limited only to those in Formula (SOC4-3); i.e., those in description of <<Organic Underlayer Film-Forming Compound 4>>.

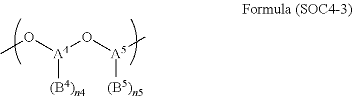

[In Formula (4-3), A⁴ and A⁵ are each a C₆₋₄₈ aromatic ring that may contain a heteroatom, or a hydrocarbon group containing a C₆₋₄₈ aromatic ring that may contain a heteroatom; B⁴ and B⁵ are the same groups as B¹, B², and B³ in Formula (2); n4 is an integer satisfying a relation of 1≤n4≤4; n5 is an integer satisfying a relation of 0≤n5≤4; and n4+n5 is an integer of 1 to 8.]

### <<Organic Underlayer Film-Forming Compound 5>>

The organic underlayer film-forming compound 5 (SOC5 compound) may be a polymer containing a unit structure formed of a reaction product between a condensed heterocyclic compound and a bicyclo ring compound, for example, a compound described in WO 2013/005797 (JP 6041104 B). The entire disclosure of WO 2013/005797 (JP 6041104 B) is incorporated herein by reference.

Specifically, the organic underlayer film-forming compound 5 may be, for example, a polymer containing a unit structure of the following Formula (SOC5-1), a unit structure of the following Formula (SOC5-2), a unit structure of the following Formula (SOC5-3), or any combination of these.

Unless otherwise specified, the symbols of groups in the following Formulae (SOC5-1) to (SOC5-3) and the definitions of the symbols are limited only to those in Formulae (SOC1-1) to (SOC5-3); i.e., those in description of <<Organic Underlayer Film-Forming Compound 5>>.

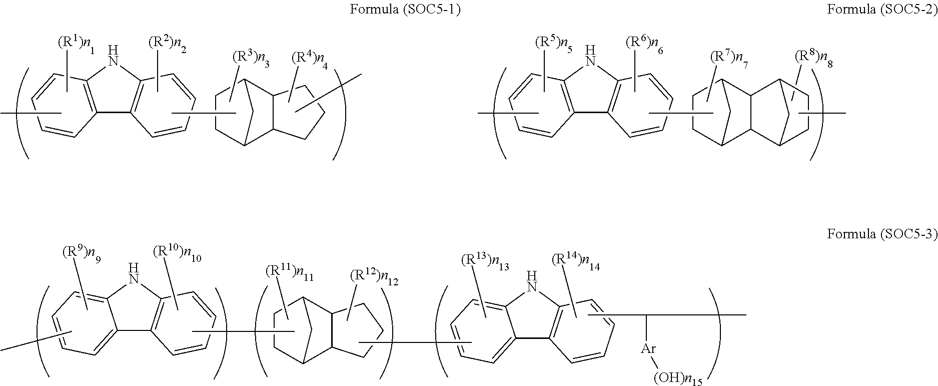

[In the Formulae, R¹ to R¹⁴ are each a substituent of a hydrogen atom and are each independently a halogen atom, a nitro group, an amino group, or a hydroxy group, or a C₁₋₁₀ alkyl group or C₆₋₄₀ aryl group substitutable with any of these groups; Ar is a C₆₋₄₀ aromatic ring group; n₁, n₂, n₅, n₆, n₉, n₁₀, n₁₃, n₁₄, and n₁₅ are each an integer of 0 to 3; and n₃, n₄, n₇, n₈, n₁₁, and n₁₂ are each an integer of 0 to 4.]

### <<Organic Underlayer Film-Forming Compound 6>>

The organic underlayer film-forming compound 6 (SOC6 compound) may be, for example, a compound described in WO 2021/172295. The entire disclosure of WO 2021/172295 is incorporated herein by reference.

Specifically, the organic underlayer film-forming compound 6 may be, for example, a polymer (SOC6 polymer) containing a plurality of the same or different structural units having a methoxymethyl group and an ROCH₂— group (other than a methoxymethyl group) (wherein R is a monovalent organic group, a hydrogen atom, or a combination of these, and, unless otherwise specified, the definition of R is limited only to that in the SOC6 compound), and a linking group that links the aforementioned structural units.

In the aforementioned SOC6 polymer, the monovalent organic group R is preferably a saturated or unsaturated linear or branched C₂₋₂₀ aliphatic hydrocarbon group, C₃₋₂₀ alicyclic hydrocarbon group, or combination thereof, wherein the hydrocarbon group may be substituted with a phenyl group, a naphthyl group, or an anthracenyl group, or may be interrupted by an oxygen atom or a carbonyl group. The term “combination” refers to the case where a plurality of different ROCH₂— groups may be present in a single structural unit, or ROCH₂— groups in two or more structural units may differ from one another.

Typical examples of the aforementioned saturated aliphatic hydrocarbon group include linear or branched alkyl groups having a carbon atom number of 2 to 20, and cyclic alkyl groups having a carbon atom number of 3 to 20.

Typical examples of the aforementioned unsaturated aliphatic hydrocarbon group include C₂₋₂₀ alkenyl groups.

The aforementioned saturated aliphatic hydrocarbon group, unsaturated aliphatic hydrocarbon group, or cyclic alkyl group may be interrupted once or twice or more by an oxygen atom and/or a carbonyl group. Particularly preferably, R is a —CH₂CH₂CH₂CH₃ group and a —CH(CH₃)CH₂OCH₃ group.

### <<Organic Underlayer Film-Forming Compound 7>>

The organic underlayer film-forming compound 7 (SOC7 compound) may be, for example, a compound described in WO 2020/184380. The entire disclosure of WO 2020/184380 is incorporated herein by reference.

Specifically, the organic underlayer film-forming compound 7 may be, for example, a copolymer having a repeating structural unit of the following Formula (SOC7-1) and/or a repeating unit of the following Formula (SOC7-2).

Unless otherwise specified, the symbols of groups in the following Formulae (SOC7-1), (SOC7-2) and (SOC7-3) and the definitions of the symbols are limited only to those in Formulae (SOC7-1), (SOC7-2) and (SOC7-3); i.e., those in description of <<Organic Underlayer Film-Forming Compound 7>>.

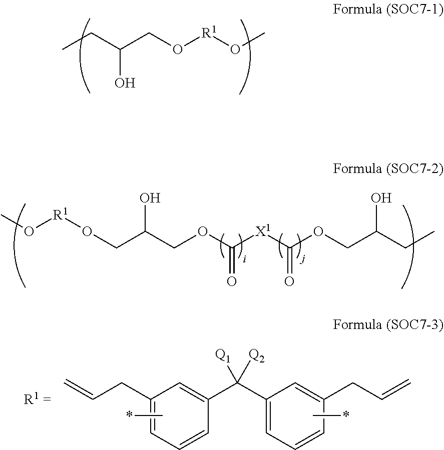

[In Formulae (SOC7-1) and (SOC7-2),

R¹ is a functional group of Formula (SOC7-3);

in Formula (SOC7-3), Q₁ and Q₂ are each independently a hydrogen atom or a C₁₋₅ alkyl group, and * is a point of bonding with an oxygen atom; and

in Formula (SOC7-2), X¹ is a C₁₋₅₀ organic group, and i and j are each independently 0 or 1.]

The group X¹ in Formula (SOC7-2) is, for example, a linear, branched, or cyclic divalent hydrocarbon group having a carbon atom number of 2 to 20, a linear, branched, or cyclic divalent organic group having a carbon atom number of 2 to 20 and having at least one sulfur atom or oxygen atom, or a divalent organic group containing at least one C₆₋₂₀ aromatic ring or C₃₋₁₂ heterocyclic ring, and the heterocyclic ring has at least one sulfur atom or oxygen atom.

### <<Organic Underlayer Film-Forming Compound 8>>

The organic underlayer film-forming compound 8 (SOC8 compound) may be, for example, a compound described in WO 2014/024836 (JP 6191831 B). The entire disclosure of WO 2014/024836 (JP 6191831 B) is incorporated herein by reference.

Specifically, the organic underlayer film-forming compound 8 may be, for example, a polymer having any one or two or more of repeating structural units of the following Formulae (SOC8-1a), (SOC8-1b), and (SOC8-1c).

Unless otherwise specified, the symbols of groups in the following Formulae (SOC8-1a), (SOC8-1b), (SOC8-1c), and (SOC8-2) and the definitions of the symbols are limited only to those in Formulae (SOC8-1a), (SOC8-1b), (SOC8-1c), and (SOC8-2); i.e., those in description of <<Organic Underlayer Film-Forming Compound 8>>.

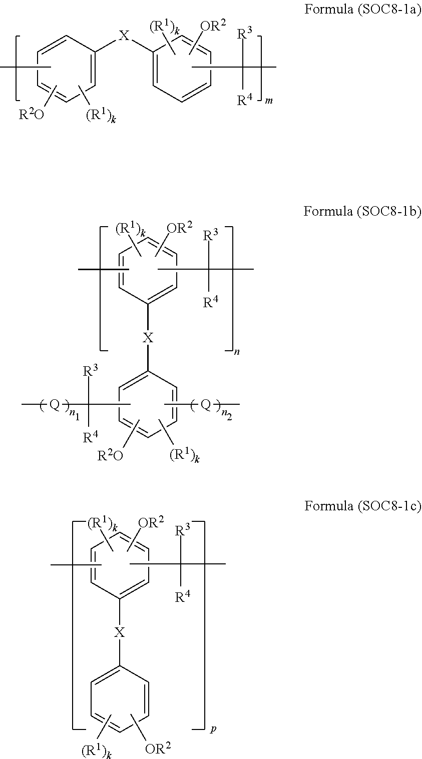

[In the Formulae,

two R¹s are each independently a C₁₋₁₀ alkyl group, a C₂₋₆ alkenyl group, an aromatic hydrocarbon group, a halogen atom, a nitro group, or an amino group; two R²s are each independently a hydrogen atom, a C₁₋₁₀ alkyl group, a C₂₋₆ alkenyl group, an acetal group, an acyl group, or a glycidyl group; R³ is an aromatic hydrocarbon group that may have a substituent; R⁴ is a hydrogen atom, a phenyl group, or a naphthyl group; when each of R³ and R⁴, which are bonded to the same carbon atom, is a phenyl group, they may be bonded together to form a fluorene ring; in Formula (1b), two groups of R³ may be different from each other, and two atoms or groups of R⁴ may be different from each other; two ks are each independently 0 or 1; m is an integer of 3 to 500; n, n₁, and n₂ are each an integer of 2 to 500; p is an integer of 3 to 500; X is a single bond or a heteroatom; and two Qs are each independently a structural unit of the following Formula (SOC8-2):

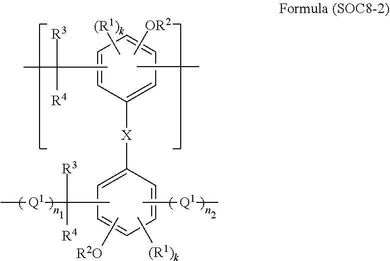

(in the Formula, two R¹s, two R²s, two R³s, two R⁴s, two ks, n₁, n₂, and X have the same meanings as defined in Formula (SOC8-1b), and two Q¹s are each independently a structural unit of Formula (SOC8-2)).]

### <<Organic Underlayer Film-Forming Compound 9>>

The organic underlayer film-forming compound 9 (SOC9 compound) may be, for example, a compound described in WO 2012/050064 (JP 5920588 B). The entire disclosure of WO 2012/050064 (JP 5920588 B) is incorporated herein by reference.

Specifically, the organic underlayer film-forming compound 9 may be, for example, a polymer containing a unit structure of the following Formula (SOC9-1), a unit structure of the following Formula (SOC9-2), or a combination of a unit structure of the following Formula (SOC9-1) and a unit structure of the following Formula (SOC9-2).

Unless otherwise specified, the symbols of groups in the following Formulae (SOC9-1) and (SOC9-2) and the definitions of the symbols are limited only to those in Formulae (SOC9-1) and (SOC9-2); i.e., those in description of <<Organic Underlayer Film-Forming Compound 9>>.

[symbol]

O—Ar₁ [symbol] Formula (SOC9-1)

[In Formula (SOC9-1), Ar₁ is an organic group containing a C₆₋₅₀ arylene group or a heterocyclic group.]

[symbol]

O—Ar₂—O—Ar₃-T-Ar₄ [symbol] Formula (SOC9-2)

[In Formula (SOC9-2), Ar₂, Ar₃, and Ar₄ are each independently an organic group containing a C₆₋₅₀ arylene group or a heterocyclic group, and T is a carbonyl group or a sulfonyl group.]

The unit structure of Formula (SOC9-1) is a unit structure having a polyether structure, and the unit structure of Formula (2) is a unit structure having a polyether ether ketone structure or a polyether ether sulfone structure.

The organic group of each of Ar₁ to Ar₄ may contain one arylene group or heterocyclic group, or a combination of two or more arylene groups or heterocyclic groups. The arylene group and the heterocyclic group are, for example, di- to tetravelent.

### <<Organic Underlayer Film-Forming Compound 10>>

The organic underlayer film-forming compound 10 (SOC10 compound) may be, for example, a compound described in PCT/JP2021/042066. The entire disclosure of PCT/JP2021/042066 is incorporated herein by reference.

Specifically, the organic underlayer film-forming compound 10 may be, for example, a polymer (SOC10 polymer) containing a repeating structural unit formed through alternate bonding, via a linking group —O—, of an aromatic compound A having an ROCH₂— group (wherein R is a monovalent organic group, a hydrogen atom, or a combination of these, and, unless otherwise specified, the definition of R is limited only to that in the SOC10 compound) and an aromatic compound B different from the compound A and having a carbon atom number of 120 or less, wherein one compound A is bonded to one to six compounds B.

The aforementioned SOC10 polymer is a polymer containing a repeating structural unit of the following Formula (SOC10-1).

Unless otherwise specified, the symbols of groups in the following Formula (SOC10-1) and the definitions of the symbols are limited only to those in Formula (SOC10-1); i.e., those in description of <<Organic Underlayer Film-Forming Compound 10>>.

[symbol]

A₁-O—B₁—O [symbol] Formula (SOC10-1)

[In Formula (SOC10-1), A₁ is an organic group derived from an aromatic compound A having an ROCH₂— group (wherein R is a monovalent organic group, a hydrogen atom, or a combination of these), and Bi is an organic group different from A₁ and derived from an aromatic compound B having a carbon atom number of 120 or less.]

B₁ in Formula (SOC10-1) may be a group of the following Formula (SOC10-2).

Unless otherwise specified, the symbols of groups in the following Formula (SOC10-2) and the definitions of the symbols are limited only to those in Formula (SOC10-2); i.e., those in description of <<Organic Underlayer Film-Forming Compound 10>>.

—C₁ [symbol] Y—C₂ [symbol] —ᵢ Formula (SOC10-2)

[In Formula (SOOC10-2),

C₁ and C₂ are each independently a C₆₋₄₈ aromatic ring that may contain a heteroatom, or a hydrocarbon group containing a C₆₋₄₈ aromatic ring that may contain a heteroatom;

Y is a single bond, a carbonyl group, a sulfonyl group, a —CR¹₂— group, or a —(CF₃)C(CF₃)— group;

R¹ is a C₁₋₁₀ alkyl group that may be interrupted by an oxygen atom, a carbonyl group, a nitrogen atom, a carbon-carbon double bond, or a carbon-carbon triple bond, or may be bonded to a carbon-carbon double bond or a carbon-carbon triple bond at the terminal, a hydroxy group, a hydrogen atom, a halogen, a C₆₋₂₀ aromatic hydrocarbon group, or —NR²₂;

R² is a chain or cyclic alkyl group having a carbon atom number of 1 to 10 that may be interrupted by a carbon-carbon double bond or a carbon-carbon triple bond, or may be bonded to a carbon-carbon double bond or a carbon-carbon triple bond at the terminal;

i is 0 or 1; and

a dotted line is a bond to an oxygen atom.]

### <<Organic Underlayer Film-Forming Compound 11>>

The organic underlayer film-forming compound 11 (SOC11 compound) may be, for example, a compound described in WO 2013/146670 (JP 6094767 B). The entire disclosure of WO 2013/146670 (JP 6094767 B) is incorporated herein by reference.

Specifically, the organic underlayer film-forming compound 11 may be, for example, a polymer containing a unit structure of the following Formula (SOC11-1).

Unless otherwise specified, the symbols of groups in the following Formula (SOC11-1) and the definitions of the symbols are limited only to those in Formula (SOC11-1); i.e., those in description of <<Organic Underlayer Film-Forming Compound 11>>.

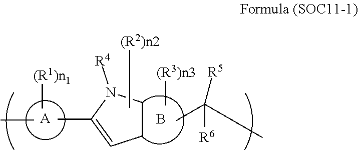

[In Formula (SOC11-1),

R¹, R², and R³ are substituents of hydrogen atoms of the rings, and are each independently a halogen atom, a nitro group, an amino group, a hydroxy group, a C₁₋₁₀ alkyl group, a C₂₋₁₀ alkenyl group, a C₆₋₄₀ aryl group, or any combination of these which may contain an ether bond, a ketone bond, or an ester bond; R⁴ is a hydrogen atom, a C₁₋₁₀ alkyl group, a C₂₋₁₀ alkenyl group, a C₆₋₄₀ aryl group, or any combination of these which may contain an ether bond, a ketone bond, or an ester bond; R⁵ is a hydrogen atom, or a C₆₋₄₀ aryl group or heterocyclic group substitutable with a halogen atom, a nitro group, an amino group, a formyl group, a carboxyl group, an alkyl carboxylic acid ester group, a phenyl group, a C₁₋₁₀ alkoxy group, or a hydroxy group; R⁶ is a hydrogen atom, or a C₁₋₁₀ alkyl group, C₆₋₄₀ aryl group, or heterocyclic group substitutable with a halogen atom, a nitro group, an amino group, a formyl group, a carboxyl group, an alkyl carboxylic acid ester group, or a hydroxy group; R⁵ and R⁶ may form a ring together with the carbon atom to which they are bonded; the ring A and the ring B are each a benzene ring, a naphthalene ring, or an anthracene ring; n1, n2, and n3 are each an integer ranging from 0 to the possible maximum number of the substituents substituted on the ring.]

### <<Organic Underlayer Film-Forming Compound 12>>

The organic underlayer film-forming compound 12 (SOC12 compound) may be, for example, a compound described in WO 2014/030579 (JP 6124025 B). The entire disclosure of WO 2014/030579 (JP 6124025 B) is incorporated herein by reference.

Specifically, the organic underlayer film-forming compound 12 may be, for example, a phenol novolac resin prepared by reaction in the presence of an acidic catalyst between an aromatic aldehyde or an aromatic ketone and a compound having a structure wherein at least three phenol groups are bonded to a tertiary carbon atom or the phenol groups are bonded to a quaternary carbon atom to which a methyl group is bonded.

More specifically, the aforementioned phenol novolac resin may be a resin containing a unit structure of the following Formula (SOC12-1), a unit structure of the following Formula (SOC12-2), a unit structure of the following Formula (SOC12-3), a unit structure of the following Formula (SOC12-4), or any combination of these unit structures.

Unless otherwise specified, the symbols of groups in the following Formulae (SOC12-1) to (SOC12-4) or (SOC12-5) and the definitions of the symbols are limited only to those in Formulae (SOC12-1) to (SOC12-5); i.e., those in description of <<Organic Underlayer Film-Forming Compound 12>>.

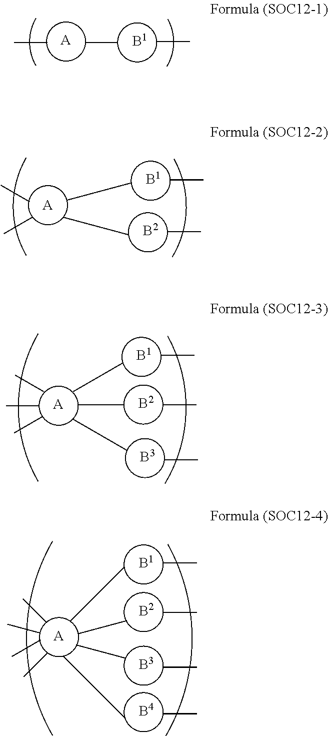

[In Formulae (SOC12-1), (SOC12-2), (SOC12-3), and (SOC12-4),

A is an organic group having a structure wherein at least three phenol groups are bonded to a tertiary carbon atom, and B¹, B², B³, and B⁴ are each a group of the following Formula (SOC12-5):

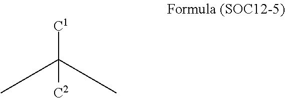

[in Formula (SOC12-5), C¹ is a C₆₋₄₀ aryl group or heterocyclic group substitutable with a halogen atom, a nitro group, an amino group, or a hydroxy group; C² is a hydrogen atom, or a C₁₋₁₀ alkyl group, C₆₋₄₀ aryl group, or heterocyclic group substitutable with a halogen atom, a nitro group, an amino group, or a hydroxy group; and C¹ and C² may form a ring together with the carbon atom to which they are bonded].]

### <<Organic Underlayer Film-Forming Compound 13>>

The organic underlayer film-forming compound 13 (SOC13 compound) may be, for example, a compound described in WO 2006/132088. The entire disclosure of WO 2006/132088 is incorporated herein by reference.

Specifically, the organic underlayer film-forming compound 13 may be, for example, a polymer containing any of unit structures of the following Formulae (SOC13-1) to (SOC13-5).

Unless otherwise specified, the symbols of groups in the following Formulae (SOC13-1) to (SOC13-5) and the definitions of the symbols are limited only to those in Formulae (SOC13-1) to (SOC13-5); i.e., those in description of <<Organic Underlayer Film-Forming Compound 13>>.

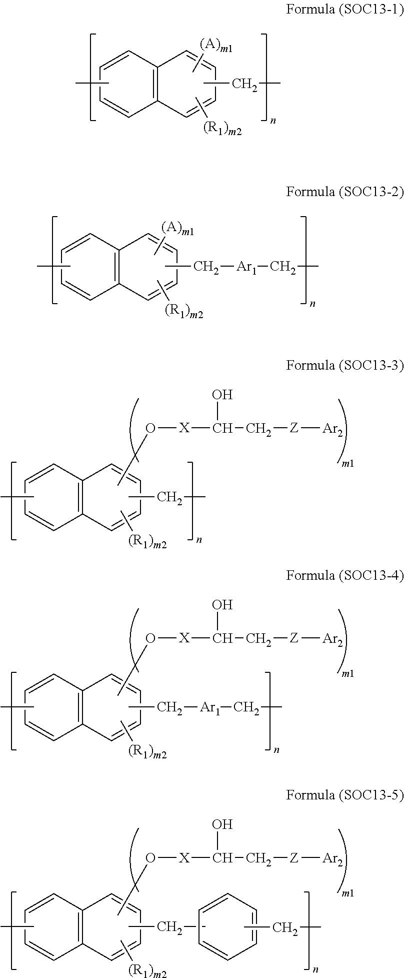

[In the aforementioned Formulae,

A is an organic group having an aromatic group;

Ar₁ is a substituted or unsubstituted aromatic group;

Ar₂ is an unsubstituted aromatic ring or an aromatic ring substituted with a carboxylic acid, a carboxylic acid ester group, a hydroxyl group, an alkyl group, an alkoxy group, a sulfonate group, or a halogen atom;

R₁ is a hydroxyl group, an alkyl group, an alkoxy group, a halogen atom, a thiol group, an amino group, or an amide group;

m1 is the number of A substituted on the naphthalene ring, and is an integer of 1 to 6;

m2 is the number of R₁ substituted on the naphthalene ring, and is an integer of 0 to 5;

the sum of m1+m2 is an integer of 1 to 6 (when the sum is not 6, the remainder corresponds to a hydrogen atom);

n is the number of repeating units (2 to 7,000);

X is a single bond, a methylene group, a C₂₋₁₀ alkylene group, a C₂₋₁₀ divalent hydrocarbon group having an ether bond, or a carbonyl group; and

Z is a linking group of —O— or —OC(═O)—.]

### <<Organic Underlayer Film-Forming Compound 14>>

The organic underlayer film-forming compound 14 (SOC14 compound) may be, for example, a compound described in WO 2016/072316. The entire disclosure of WO 2016/072316 is incorporated herein by reference.

Specifically, the organic underlayer film-forming compound 14 may be, for example, a polymer containing a unit structure of the following Formula (SOC14-1).

Unless otherwise specified, the symbols of groups in the following Formula (SOC14-1) and the definitions of the symbols are limited only to those in Formula (SOC14-1); i.e., those in description of <<Organic Underlayer Film-Forming Compound 14>>.

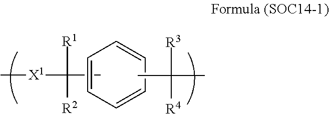

[In Formula (SOC14-1), R¹ to R⁴ are each independently a hydrogen atom or a methyl group, and X¹ is a divalent organic group containing at least one arylene group substitutable with an alkyl group, an amino group, or a hydroxyl group.]

X¹ in Formula (SOC14-1) may be, for example, an organic group of the following Formula (SOC14-2) (wherein a dotted line is a bond).

Unless otherwise specified, the symbols of groups in the following Formulae (SOC14-2) and (SOC14-3) and the definitions of the symbols are limited only to those in Formulae (SOC14-2) and (SOC14-3); i.e., those in description of <<Organic Underlayer Film-Forming Compound 14>>.

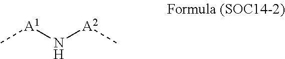

[In (SOC14-2), A¹ is a phenylene group or a naphthylene group; A² is a phenylene group, a naphthylene group, or an organic group of the following Formula (SOC14-3):

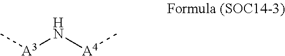

(in Formula (SOC14-3), A³ and A⁴ are each independently a phenylene group or a naphthylene group, and a dotted line is a bond.); and a dotted line is a bond.]

Specific examples of the respective groups in Formulae (SOC14-1) to (SOC14-3) are described below.

The aforementioned arylene group is preferably an arylene group derived from a C₆₋₄₀ aryl group. Examples of the arylene group include phenylene group, biphenylene group, terphenylene group, fluorenylene group, naphthylene group, anthrylene group, pyrenylene group, or carbazolylene group.

Examples of the aforementioned alkyl group include C₁₋₁₀ alkyl groups.

Examples of the aforementioned amino group include primary amino group, secondary amino group, and tertiary amino group. A secondary amino group is preferably used.

### <<Organic Underlayer Film-Forming Compound 15>>

The organic underlayer film-forming compound 15 (SOC15 compound) may be a novolac resin prepared by reaction between an aromatic compound and an aldehyde having a formyl group bonded to a secondary carbon atom or tertiary carbon atom of a C₂₋₂₆ alkyl group; for example, a compound described in WO 2017/069063. The entire disclosure of WO 2017/069063 is incorporated herein by reference.

Specifically, the organic underlayer film-forming compound 15 may be, for example, a polymer containing a unit structure of the following Formula (SOC15-1); more specifically, a polymer containing a unit structure of the following Formula (SOC15-2).

Unless otherwise specified, the symbols of groups in the following Formulae (SOC15-1) and (SOC15-2) and the definitions of the symbols are limited only to those in Formulae (SOC15-1) and (SOC15-2); i.e., those in description of <<Organic Underlayer Film-Forming Compound 15>>.

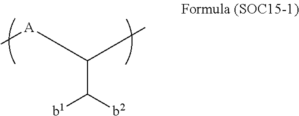

[In Formula (SOC15-1), A is a divalent group derived from a C₆₋₄₀ aromatic compound; b¹ is a C₁₋₁₆ alkyl group; and b² is a hydrogen atom or a C₁₋₉ alkyl group.]

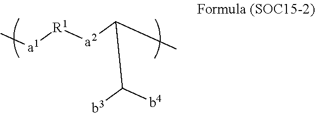

[In Formula (SOC15-2), a¹ and a² are each a substitutable benzene ring or naphthalene ring; R¹ is a secondary or tertiary amino group, a substitutable C₁₋₁₀ divalent hydrocarbon group, an arylene group, or a divalent group prepared by bonding of any of these groups; b³ is a C₁₋₁₆ alkyl group; and b⁴ is a hydrogen atom or a C₁₋₉ alkyl group.]

### <<Organic Underlayer Film-Forming Compound 16>>

The organic underlayer film-forming compound 16 (SOC16 compound) may be, for example, a compound described in WO 2017/094780. The entire disclosure of WO 2017/094780 is incorporated herein by reference.

Specifically, the organic underlayer film-forming compound 16 may be, for example, a polymer containing a unit structure of the following Formula (SOC16-1), in particular, a polymer containing a unit structure of the following Formula (SOC16-1) wherein the group A is a divalent group derived from a compound of the following Formula (SOC16-2).

Unless otherwise specified, the symbols of groups in the following Formulae (SOC16-1) and (SOC16-2) and the definitions of the symbols are limited only to those in Formulae (SOC16-1) and (SOC16-2); i.e., those in description of <<Organic Underlayer Film-Forming Compound 16>>.

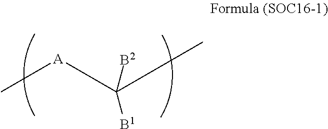

[In Formula (SOC16-1),

A is a divalent group having at least two amino groups, and is a group derived from a compound having a condensed ring structure and an aromatic group substituted for a hydrogen atom on the condensed ring; and

B¹ and B² are each independently a hydrogen atom, an alkyl group, a benzene ring group, a condensed ring group, or any combination of these, or B¹ and B² may form a ring together with the carbon atom to which they are bonded.]

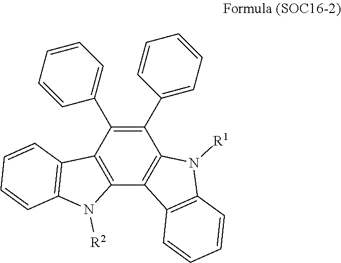

[In Formula (SOC16-2), R¹ and R² are each independently a hydrogen atom, a C₁₋₁₀ alkyl group, or a C₆₋₄₀ aryl group.]

### <<Organic Underlayer Film-Forming Compound 17>>

The organic underlayer film-forming compound 17 (SOC17 compound) may be, for example, a compound described in JP 2005-128509 A (JP 4355943 B). The entire disclosure of JP 2005-128509 A (JP 4355943 B) is incorporated herein by reference.

Specifically, the organic underlayer film-forming compound 17 may be, for example, a novolac resin having a repeating unit of the following Formula (SOC17-1a) or (SOC17-1b) and having a fluorene or tetrahydrospiroindene structure.

Unless otherwise specified, the symbols of groups in the following Formulae (SOC17-1a) and (SOC17-1b) and the definitions of the symbols are limited only to those in Formulae (SOC17-1a) and (SOC17-1b); i.e., those in description of <<Organic Underlayer Film-Forming Compound 17>>.

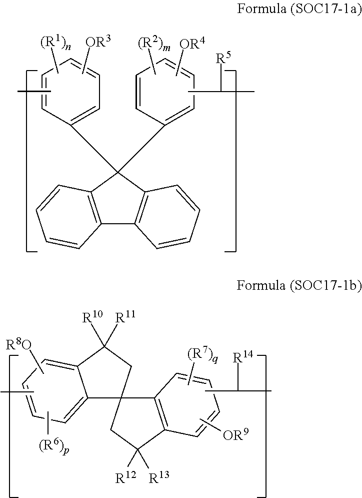

[In Formulae (SOC17-1a) and (SOC17-1b),

R¹, R², R⁶, and R⁷ are each independently a hydrogen atom, a linear, branched, or cyclic alkyl group having a carbon atom number of 1 to 10, a C₆₋₁₀ aryl group, an allyl group, or a halogen atom; R³, R⁴, R⁸, and R⁹ are each independently a hydrogen atom, a linear, branched, or cyclic alkyl group having a carbon atom number of 1 to 6, a linear, branched, or cyclic alkenyl group having a carbon atom number of 2 to 6, a C₆₋₁₀ aryl group, or a glycidyl group; R⁵ and R¹⁴ are each independently a hydrogen atom, a linear, branched, or cyclic alkyl group having a carbon atom number of 1 to 10, or a C₆₋₁₀ aryl group; n, m, p, and q are each an integer of 1 to 3; and R¹⁰ to R¹³ are each independently a hydrogen atom, a halogen atom, a hydroxy group, a linear, branched, or cyclic alkyl group having a carbon atom number of 1 to 6, or a linear, branched, or cyclic alkoxy group having a carbon atom number of 1 to 6.]

### <<Organic Underlayer Film-Forming Compound 18>>

The organic underlayer film-forming compound 18 (SOC18 compound) may be, for example, a compound described in JP 2006-259249 A (JP 4539845 B). The entire disclosure of JP 2006-259249 A (JP 4539845 B) is incorporated herein by reference.

Specifically, the organic underlayer film-forming compound 18 may be, for example, a compound of the following Formula (SOC18-1) having a bisphenol group, or a resin having a repeating unit of the following Formula (SOC18-2) prepared by converting a compound having a bisphenol group into novolac.

Unless otherwise specified, the symbols of groups in the following Formulae (SOC18-1) and (SOC18-2) and the definitions of the symbols are limited only to those in Formulae (SOC18-1) and (SOC18-2); i.e., those in description of <<Organic Underlayer Film-Forming Compound 18>>.

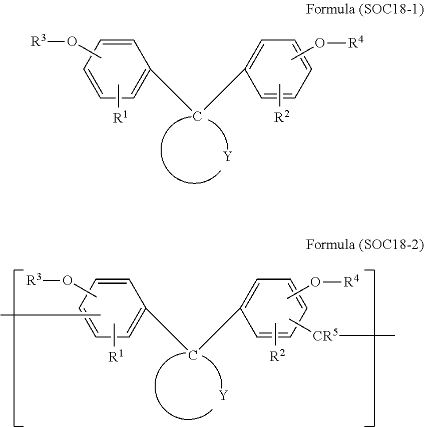

[In Formulae (SOC18-1) and (SOC18-2),

R¹ and R², which are identical to or different from each other, are each a hydrogen atom, a linear, branched, or cyclic alkyl group having a carbon atom number of 1 to 10, a C₆₋₁₀ aryl group, or a C₂₋₁₀ alkenyl group; R³ and R⁴ are each a hydrogen atom, a linear, branched, or cyclic alkyl group having a carbon atom number of 1 to 6, a linear, branched, or cyclic alkenyl group having a carbon atom number of 2 to 6, a C₆₋₁₀ aryl group, a C₂₋₆ acetal group, a C₂₋₆ acyl group, or a glycidyl group; Y is a C₄₋₃₀ divalent aliphatic or alicyclic hydrocarbon group; the ring of

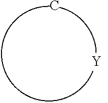

may be a bridged ring or may be intervened with a heteroatom; and R⁵ is a hydrogen atom, a linear, branched, or cyclic alkyl group having a carbon atom number of 1 to 10, or a C₆₋₁₀ aryl group.]

### <<Organic Underlayer Film-Forming Compound 19>>

The organic underlayer film-forming compound 19 (SOC19 compound) may be, for example, a compound described in JP 2006-259482 A (JP 4466854 B). The entire disclosure of JP 2006-259482 A (JP 4466854 B) is incorporated herein by reference.

Specifically, the organic underlayer film-forming compound 19 may be, for example, a compound of the following Formula (SOC19-1) containing a plurality of bisphenol groups, or a resin having a repeating unit of the following Formula (SOC19-2) prepared by converting a compound having a bisphenol group into novolac.

Unless otherwise specified, the symbols of groups in the following Formulae (SOC19-1) and (SOC19-2) and the definitions of the symbols are limited only to those in Formulae (SOC19-1) and (SOC19-2); i.e., those in description of <<Organic Underlayer Film-Forming Compound 19>>.

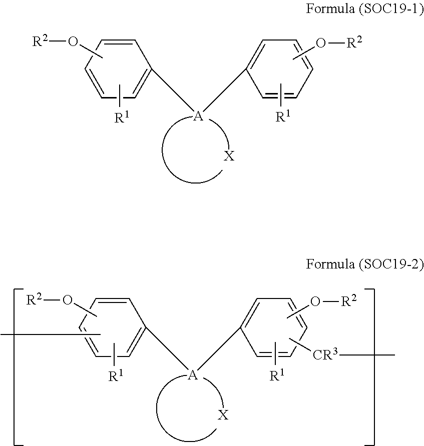

[In Formulae (SOC19-1) and (SOC19-2),

R¹s, which are identical to or different from each other, are each a hydrogen atom, a linear, branched, or cyclic alkyl group having a carbon atom number of 1 to 10, a C₆₋₁₀ aryl group, or a C₂₋₁₀ alkenyl group; R²s, which are identical to or different from each other, are each a hydrogen atom, a linear, branched, or cyclic alkyl group having a carbon atom number of 1 to 6, a linear, branched, or cyclic alkenyl group having a carbon atom number of 2 to 6, a C₆₋₁₀ aryl group, a C₂₋₆ acetal group, a C₂₋₆ acyl group, or a glycidyl group; n is an integer of 2 to 4; R³ is a hydrogen atom, a linear, branched, or cyclic alkyl group having a carbon atom number of 1 to 10, or a C₆₋₁₀ aryl group;

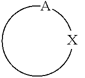

is a C₄₋₃₀ 2n-valent hydrocarbon group as a whole, and may contain one or two or more of an alicyclic hydrocarbon group, a bridged-ring hydrocarbon group, an aromatic hydrocarbon group, and a condensed polycyclic hydrocarbon group; A is a tetravalent carbon atom bonded to

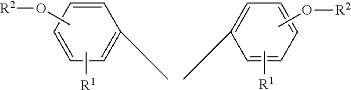

and
the number of As present in

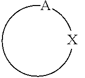

is n; and

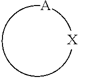

may be intervened with a heteroatom.]

### <<Organic Underlayer Film-Forming Compound 20>>

The organic underlayer film-forming compound 20 (SOC20 compound) may be, for example, a compound described in JP 2007-199653 A (JP 4659678 B). The entire disclosure of JP 2007-199653 A (JP 4659678 B) is incorporated herein by reference.

Specifically, the organic underlayer film-forming compound 20 may be, for example, a compound of the following Formula (SOC20-1) having a bisnaphthol group, or a resin of the following Formula (SOC20-2) prepared by converting a compound having a bisnaphthol group into novolac.

Unless otherwise specified, the symbols of groups in the following Formulae (SOC20-1) and (SOC20-2) and the definitions of the symbols are limited only to those in Formulae (SOC20-1) and (SOC20-2); i.e., those in description of <<Organic Underlayer Film-Forming Compound 20>>.

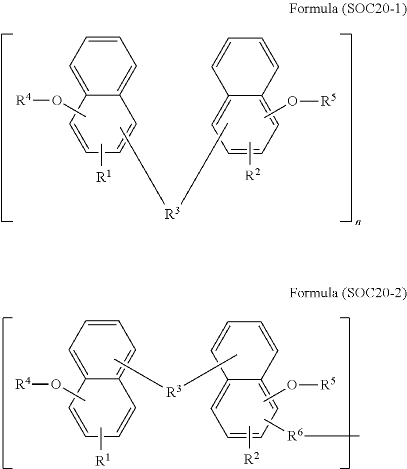

[In Formulae (SOC20-1) and (SOC20-2),

R¹ and R², which are identical to or different from each other, are each independently a hydrogen atom, a linear, branched, or cyclic alkyl group having a carbon atom number of 1 to 10, a C₆₋₁₀ aryl group, or a C₂₋₁₀ alkenyl group; R³ is a single bond, or a linear, branched, or cyclic alkylene group having a carbon atom number of 1 to 30, which may have a bridged-ring hydrocarbon group, a double bond, a heteroatom such as sulfur, or a C₆₋₃₀ aromatic group; R⁴ and R⁵ are each independently a hydrogen atom or a glycidyl group; R⁶ is a single bond or a linear or branched alkylene group having a carbon atom number of 1 to 10; and n is an integer of 1 to 4.]

### <<Organic Underlayer Film-Forming Compound 21>>

The organic underlayer film-forming compound 21 (SOC21 compound) may be, for example, a compound described in JP 2010-170013 A (JP 5118073 B). The entire disclosure of JP 2010-170013 A (JP 5118073 B) is incorporated herein by reference.

Specifically, the organic underlayer film-forming compound 21 may be, for example, a compound of the following Formula (SOC21-1) having a bisnaphthol group, or a resin of the following Formula (SOC21-2) prepared by converting a compound having a bisnaphthol group into novolac.

Unless otherwise specified, the symbols of groups in the following Formulae (SOC21-1) and (SOC21-2) and the definitions of the symbols are limited only to those in Formulae (SOC21-1) and (SOC21-2); i.e., those in description of <<Organic Underlayer Film-Forming Compound 21>>.

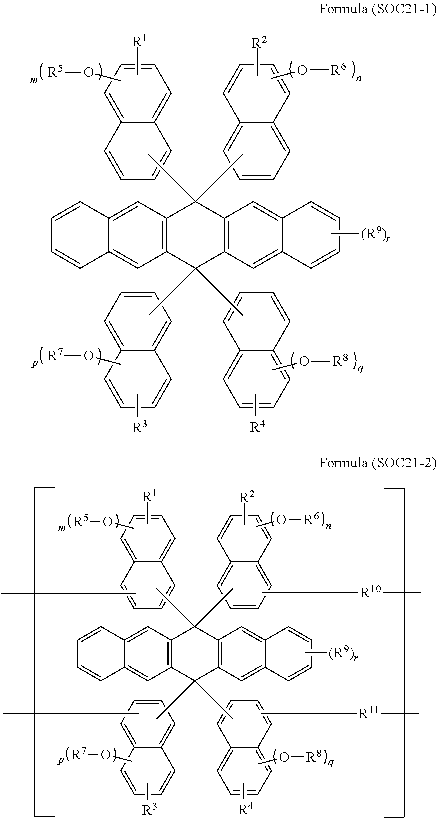

[In Formulae (SOC21-1) and (SOC21-2),

R¹ to R⁴, which are identical to or different from one another, are each a hydrogen atom, a linear, branched, or cyclic alkyl group having a carbon atom number of 1 to 10, a C₆₋₁₀ aryl group, or a C₂₋₁₀ alkenyl group; R⁵ to R⁸ are each a hydrogen atom, a linear, branched, or cyclic alkyl group having a carbon atom number of 1 to 6, an acyl group, or a glycidyl group; R⁹ is a hydrogen atom, a linear, branched, or cyclic alkyl group having a carbon atom number of 1 to 10, an alkoxy group, a C₂₋₁₀ alkenyl group, a C₆₋₁₀ aryl group, a halogen atom, an amino group, a C₁₋₄ alkylmethylamino group, a C₆₋₁₀ diarylamino group, a cyano group, or a nitro group; R¹⁰ and R¹¹ are each a linear or branched alkylene group having a carbon atom number of 1 to 10; m, n, p, q, and r are each an integer of 0 to 6; and m+n+p+q is an integer of 2 to 10.]

### <<Organic Underlayer Film-Forming Compound 22>>

The organic underlayer film-forming compound 22 (SOC22 compound) may be, for example, a compound described in JP 2010-122656 A (JP 5336306 B). The entire disclosure of JP 2010-122656 A (JP 5336306 B) is incorporated herein by reference.

Specifically, the organic underlayer film-forming compound 22 may be, for example, a compound of the following Formula (SOC22-1) having a bisnaphthol group, or a resin of the following Formula (SOC22-2) prepared by converting a compound having a bisnaphthol group into novolac.

Unless otherwise specified, the symbols of groups in the following Formulae (SOC22-1) and (SOC22-2) and the definitions of the symbols are limited only to those in Formulae (SOC22-1) and (SOC22-2); i.e., those in description of <<Organic Underlayer Film-Forming Compound 22>>.

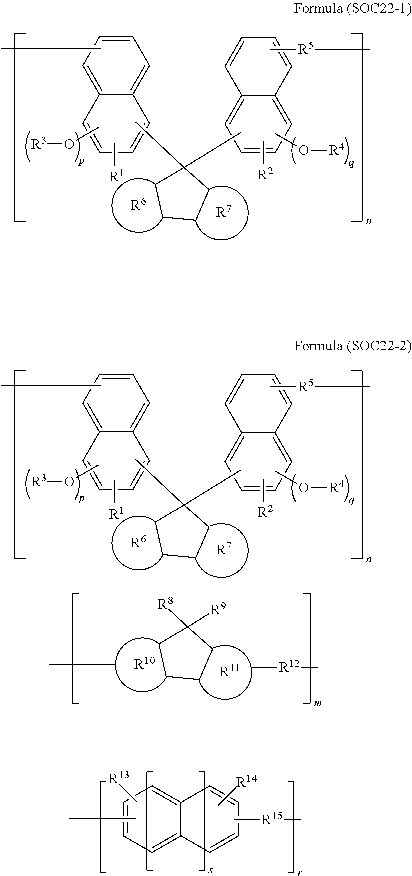

[In Formula (SOC22-1),

R¹ and R², which are identical to or different from each other, are each a hydrogen atom, a linear, branched, or cyclic alkyl group having a carbon atom number of 1 to 10, a C₆₋₂₀ aryl group, or a C₂₋₂₀ alkenyl group; R³ and R⁴ are each a hydrogen atom or a glycidyl group; R⁵ is a single bond or a linear or branched alkylene group having a carbon atom number of 1 to 10; R⁶ and R⁷ are each a benzene ring or a naphthalene ring; p and q are each 1 or 2; and n satisfies a relation of 0<n≤1.

In Formula (SOC22-2),

R¹ to R⁷, p, and q have the same meanings as defined above; R⁸ and R⁹ are each a hydrogen atom, a hydroxy group, a C₁₋₆ acyl group, a C₁₋₆ alkoxy group, a C₁₋₆ alkoxycarbonyl group, a carbonyl group, an amino group, an imino group, a hydroxy group substituted with an acid-labile group or a glycidyl group, a linear, branched, or cyclic alkyl group having a carbon atom number of 1 to 10, a C₆₋₂₀ aryl group, a C₂₋₁₀ alkenyl group, or a C₂₋₁₀ alkynyl group; R¹⁰ and R¹¹ are each a benzene ring or a naphthalene ring; R¹³ and R¹⁴ are each a hydrogen atom, a hydroxy group, or a linear, branched, or cyclic alkyl group having a carbon atom number of 1 to 10, and R¹³ and R¹⁴ may be bonded together to form a ring; R¹² and R¹⁵ are each a linear or branched alkylene group having a carbon atom number of 1 to 10; s is 1 or 2; and n, m, and r satisfy relations of 0<n<1.0, 0≤m<1.0, 0≤r<1.0, and 0<m+r<1.0.]

### <<Organic Underlayer Film-Forming Compound 23>>

The organic underlayer film-forming compound 23 (SOC23 compound) may be, for example, a compound described in JP 2016-018051 A (JP 6196190 B). The entire disclosure of JP 2016-018051 A (JP 6196190 B) is incorporated herein by reference.

Specifically, the organic underlayer film-forming compound 23 may be, for example, a resin of the following Formula (SOC23-1) prepared by converting a compound having a bisnaphthol group into novolac.

Unless otherwise specified, the symbols of groups in the following Formula (SOC23-1) and the definitions of the symbols are limited only to those in Formula (SOC23-1); i.e., those in description of <<Organic Underlayer Film-Forming Compound 23>>.

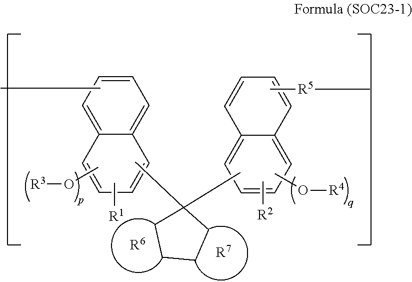

[In Formula (SOC23-1), R¹ and R² are each independently a hydrogen atom, a linear, branched, or cyclic alkyl group having a carbon atom number of 1 to 10, a C₆₋₂₀ aryl group, or a C₂₋₂₀ alkenyl group; R³ and R⁴ are each independently a hydrogen atom or a glycidyl group; R⁵ is a linear or branched alkylene group having a carbon atom number of 1 to 10; R⁶ and R⁷ are each independently a benzene ring or a naphthalene ring, and a hydrogen atom in the benzene ring or the naphthalene ring may be substituted with a C₁₋₆ hydrocarbon group; and p and q are each independently 1 or 2.]

### <<Organic Underlayer Film-Forming Compound 24>>

The organic underlayer film-forming compound 24 (SOC24 compound) may be, for example, a compound described in JP 2009-014816 A (JP 4877101 B). The entire disclosure of JP 2009-014816 A (JP 4877101 B) is incorporated herein by reference.

Specifically, the organic underlayer film-forming compound 24 may be, for example, a resin having a group of the following Formula (SOC24-1) and an aromatic hydrocarbon group; more specifically, a resin having a structural unit of the following Formula (SOC24-2).

Unless otherwise specified, the symbols of groups in the following Formulae (SOC24-1) and (SOC24-2) and the definitions of the symbols are limited only to those in Formulae (SOC24-1) and (SOC24-2); i.e., those in description of <<Organic Underlayer Film-Forming Compound 24>>.

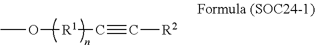

[In Formula (SOC24-1), n is 0 or 1; R¹ is a substitutable methylene group, a substitutable C₂₋₂₀ alkylene group, or a substitutable C₆₋₂₀ arylene group; and R² is a hydrogen atom, a substitutable C₁₋₂₀ alkyl group, or a substitutable C₆₋₂₀ aryl group.]

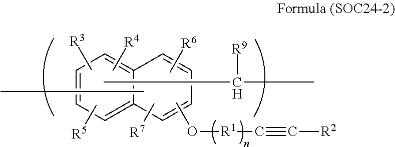

[In Formula (SOC24-2), n is 0 or 1; R¹ is a substitutable methylene group, a substitutable C₂₋₂₀ alkylene group, or a substitutable C₆₋₂₀ arylene group; R² is a hydrogen atom, a substitutable C₁₋₂₀ alkyl group, or a substitutable C₆₋₂₀ aryl group; R³ to R⁷ are each a hydroxy group, a substitutable C₁₋₆ alkyl group, a substitutable C₁₋₆ alkoxy group, a substitutable C₂₋₁₀ alkoxycarbonyl group, a substitutable C₆₋₁₄ aryl group, or a substitutable C₂₋₆ glycidyl ether group; and R⁹ is a hydrogen atom, a linear, branched, or cyclic alkyl group having a carbon atom number of 1 to 10, a linear, branched, or cyclic alkyl ether group having a carbon atom number of 1 to 10, or a C₆₋₁₀ aryl group.]

### <<Organic Underlayer Film-Forming Compound 25>>

The organic underlayer film-forming compound 25 (SOC25 compound) may be, for example, a compound described in JP 2019-041059 A (JP 6726142 B). The entire disclosure of JP 2019-041059 A (JP 6726142 B) is incorporated herein by reference.

Specifically, the organic underlayer film-forming compound 25 may be, for example, a polymer having a repeating unit of the following Formula (SOC25-1).

Unless otherwise specified, the symbols of groups in the following Formulae (SOC25-1) and (SOC25-2) and the definitions of the symbols are limited only to those in Formulae (SOC25-1) and (SOC25-2); i.e., those in description of <<Organic Underlayer Film-Forming Compound 25>>.

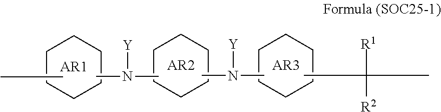

[In Formula (SOC25-1), AR1, AR2, and AR3 are each a benzene ring, naphthalene ring, or anthracene ring that may have a substituent, and carbon atoms on the aromatic rings AR1 and AR2 or AR2 and AR3 may be bonded directly or via a linking group to form a bridged structure; R¹ and R² are each independently a hydrogen atom or a C₁₋₃₀ organic group, and when each of R¹ and R² is the organic group, R¹ and R² may be bonded in the molecule to thereby form a cyclic organic group; and Y is a group of the following Formula (SOC25-2).]

—R³—C≡C—R⁴ Formula (SOC25-2)

[In Formula (SOC25-2), R³ is a single bond or a C₁₋₂₀ divalent organic group; R⁴ is a hydrogen atom or a C₁₋₂₀ monovalent organic group; and a broken line represents a bonding hand.]

### <<Organic Underlayer Film-Forming Compound 26>>

The organic underlayer film-forming compound 26 (SOC26 compound) may be, for example, a compound described in JP 2019-044022 A (JP 6940335 B). The entire disclosure of JP 2019-044022 A (JP 6940335 B) is incorporated herein by reference.

Specifically, the organic underlayer film-forming compound 26 may be, for example, a polymer having a repeating unit of the following Formula (SOC26-1).

Unless otherwise specified, the symbols of groups in the following Formulae (SOC26-1), (SOC26-2), and (SOC26-3) and the definitions of the symbols are limited only to those in Formulae (SOC26-1), (SOC26-2), and (SOC26-3); i.e., those in description of <<Organic Underlayer Film-Forming Compound 26>>.

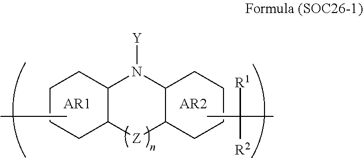

[In Formula (SOC26-1), AR1 and AR2 are each a benzene ring or naphthalene ring that may have a substituent; R¹ and R² are each independently a hydrogen atom or a C₁₋₃₀ organic group, and when each of R¹ and R² is the organic group, R¹ and R² may be bonded in the molecule to thereby form a cyclic organic group; n is 0 or 1, and when n is 0, the aromatic rings AR1 and AR2 do not form a bridged structure via Z, whereas when n is 1, the aromatic rings AR1 and AR2 form a bridged structure via Z; Z is a single bond or any of groups of the following Formula (SOC26-2); and Y is a group of the following Formula (SOC26-3).]

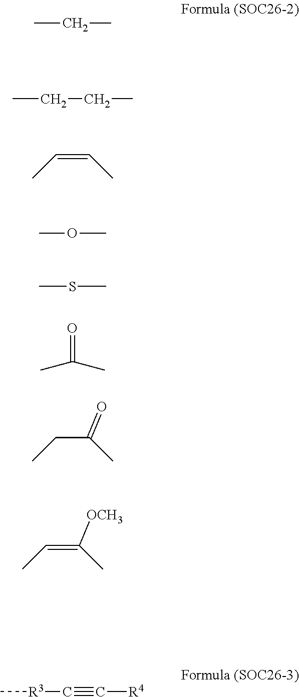

[In Formula (SOC26-3), R³ is a single bond or a C₁₋₂₀ divalent organic group; R⁴ is a hydrogen atom or a C₁₋₂₀ monovalent organic group; and a broken line represents a bonding hand.]

### <<Organic Underlayer Film-Forming Compound 27>>

The organic underlayer film-forming compound 27 (SOC27 compound) may be, for example, a compound described in JP 2021-015222 A. The entire disclosure of JP 2021-015222 A is incorporated herein by reference.

Specifically, the organic underlayer film-forming compound 27 may be, for example, a polymer having a partial structure of the following Formula (SOC27-1A) as a repeating unit; more specifically, a polymer having a partial structure of the following Formula (SOC27-1B) as a repeating unit.

Unless otherwise specified, the symbols of groups in the following Formulae (SOC27-1A) and (SOC27-1B) and the definitions of the symbols are limited only to those in Formulae (SOC27-1A) and (SOC27-1B); i.e., those in description of <<Organic Underlayer Film-Forming Compound 27>>.

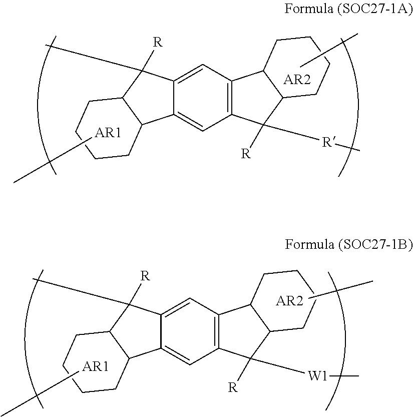

[In Formulae (SOC27-1A) and (SOC27-1B),

AR1 and AR2 are each a benzene ring or naphthalene ring that may have a substituent; R is a hydrogen atom or a C₂₋₁₀ monovalent organic group having an unsaturated bond; R′ is a single bond or W1; and W1 is a C₆₋₈₀ divalent organic group having one or more aromatic rings.]

### <<Organic Underlayer Film-Forming Compound 28>>

The organic underlayer film-forming compound 28 (SOC28 compound) may be, for example, a compound described in JP 2016-216367 A (JP 6372887 B).

Specifically, the organic underlayer film-forming compound 28 may be, for example, a compound of the following Formula (SOC28-1). The entire disclosure of JP 2016-216367 A (JP 6372887 B) is incorporated herein by reference.

Unless otherwise specified, the symbols of groups in the following Formulae (SOC28-1), (SOC28-2), and (SOC28-3) and the definitions of the symbols are limited only to those in Formulae (SOC28-1), (SOC28-2), and (SOC28-3); i.e., those in description of <<Organic Underlayer Film-Forming Compound 28>>.

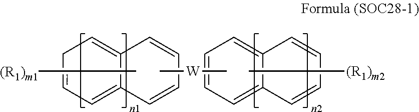

[In Formula (SOC28-1), n1 and n2 are each independently 0 or 1; W is a single bond or any of structures of the following Formula (SOC28-2); R₁ is any of structures of the following Formula (SOC28-3); m1 and m2 are each independently an integer of 0 to 7; and m1+m2 is 1 to 14.]

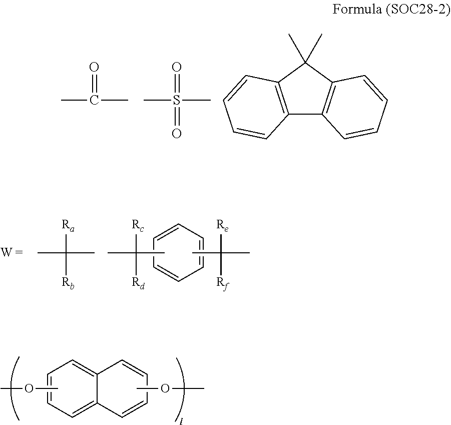

[In Formula (SOC28-2), 1 is an integer of 0 to 3; Rₐ to R_{f} are each independently a hydrogen atom, a C₁₋₁₀ alkyl group substitutable with fluorine, a phenyl group, or a phenylethyl group; and Rₐ and R_{b} may be bonded together to form a cyclic compound.]

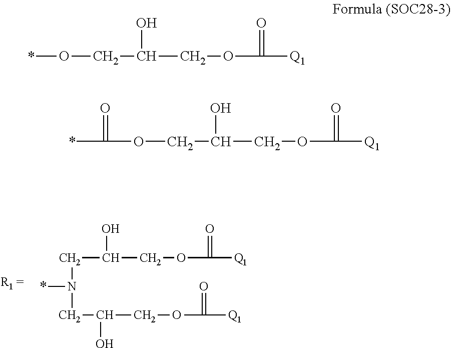

[In Formula (SOC28-3), * is a site of bonding to an aromatic ring; Q₁ is a linear or branched saturated or unsaturated hydrocarbon group having a carbon atom number of 1 to 30, a C₄₋₂₀ alicyclic group, or a substituted or unsubstituted phenyl group, naphthyl group, anthracenyl group, or pyrenyl group; and when Q₁ is a linear or branched saturated or unsaturated hydrocarbon group having a carbon atom number of 1 to 30, a methylene group constituting Q₁ may be substituted with an oxygen atom or a carbonyl group.]

### <<Crosslinking Agent>>

The aforementioned organic underlayer film-forming composition may contain a crosslinking agent.

The crosslinking agent is, for example, a melamine compound, a substituted urea compound, or a polymer compound thereof. The crosslinking agent is preferably a crosslinking agent having at least two crosslinkable substituents, such as a hydroxymethyl group and an alkoxymethyl group. Specific examples of the crosslinking agent (compound) include methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, methoxymethylated thiourea, or methoxymethylated thiourea. A condensate of such a compound may also be used.

The aforementioned crosslinking agent may be a crosslinking agent having high thermal resistance. The crosslinking agent having high thermal resistance is preferably a compound containing a crosslinkable substituent having an aromatic ring (e.g., a benzene ring or a naphthalene ring) in the molecule.

Examples of the compound include a compound having a partial structure of the following Formula (CLA1), and a polymer or oligomer having a repeating unit of the following Formula (CLA2).

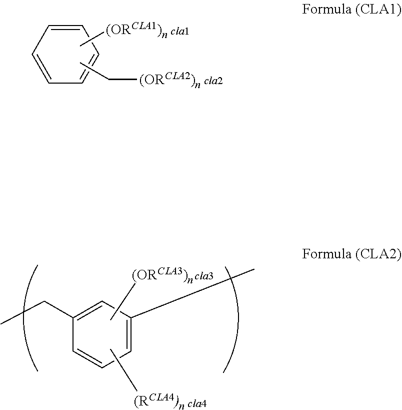

In Formula (CLA1), R^{CLA1} and R^{CLA2} are each independently a hydrogen atom, a C₁₋₁₀ alkyl group, or a C₆₋₂₀ aryl group; n^{cla1} is an integer of 1 to 4; n^{cla2} is an integer of 1 to (5-n^{cla1}); and (n^{cla1}+n^{cla2}) is an integer of 2 to 5.

In Formula (CLA2), R^{CLA3} is a hydrogen atom or a C₁₋₁₀ alkyl group; R^{CLA4} is a C₁₋₁₀ alkyl group; n^{cla3} is an integer of 1 to 4; n^{cla4} is 0 to (4-n^{cla3}); and (n+n^{cla4}) is an integer of 1 to 4. Each of the oligomer and the polymer may have 2 to 100 or 2 to 50 repeating unit structures.

Examples of the alkyl group and the aryl group are the alkyl and aryl groups exemplified above in <<Organic Underlayer Film-Forming Compound 1 (SOC Compound 1)>>.

Examples of the compound, polymer, and oligomer of Formulae (CLA1) and (CLA2) are as follows.

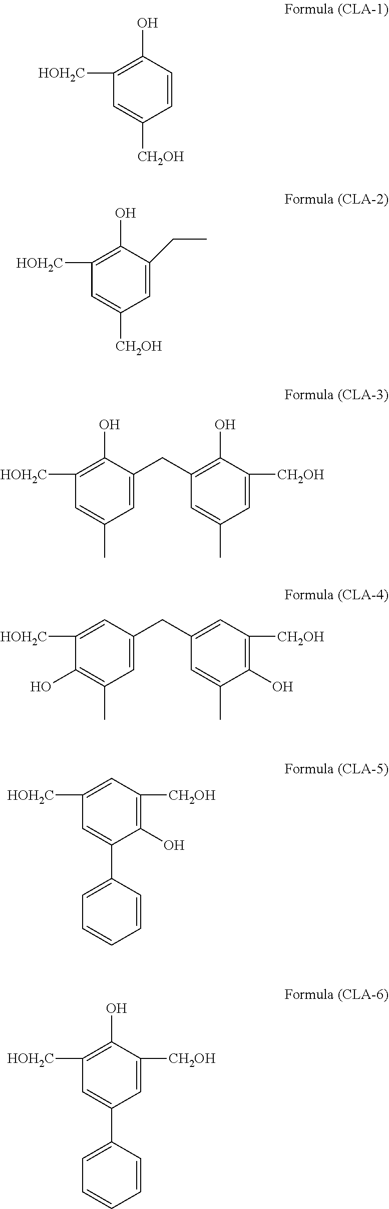 [SMILES: OCc1ccc(O)c(CO)c1 ; CCc1cc(CO)cc(CO)c1O ; Cc1cc(CO)c(O)c(Cc2cc(C)cc(CO)c2O)c1 ; Cc1cc(Cc2cc(C)c(O)c(CO)c2)cc(CO)c1O ; OCc1cc(CO)c(O)c(-c2ccccc2)c1 ; OCc1cc(-c2ccccc2)cc(CO)c1O]

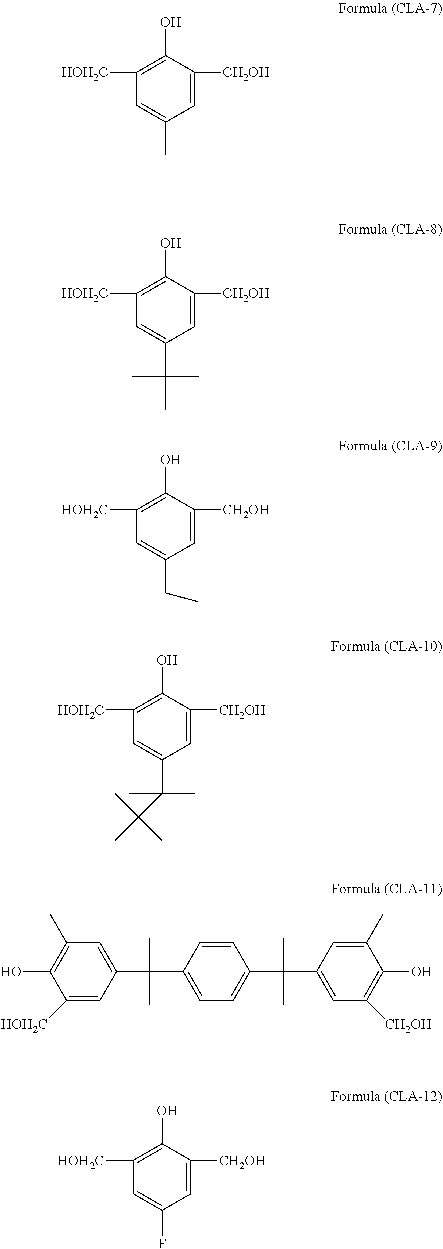 [SMILES: Cc1cc(CO)c(O)c(CO)c1 ; CC(C)(C)c1cc(CO)c(O)c(CO)c1 ; CCc1cc(CO)c(O)c(CO)c1 ; CC(C)(C)C(C)(C)c1cc(CO)c(O)c(CO)c1 ; Cc1cc(C(C)(C)c2ccc(C(C)(C)c3cc(C)c(O)c(CO)c3)cc2)cc(CO)c1O ; OCc1cc(F)cc(CO)c1O]

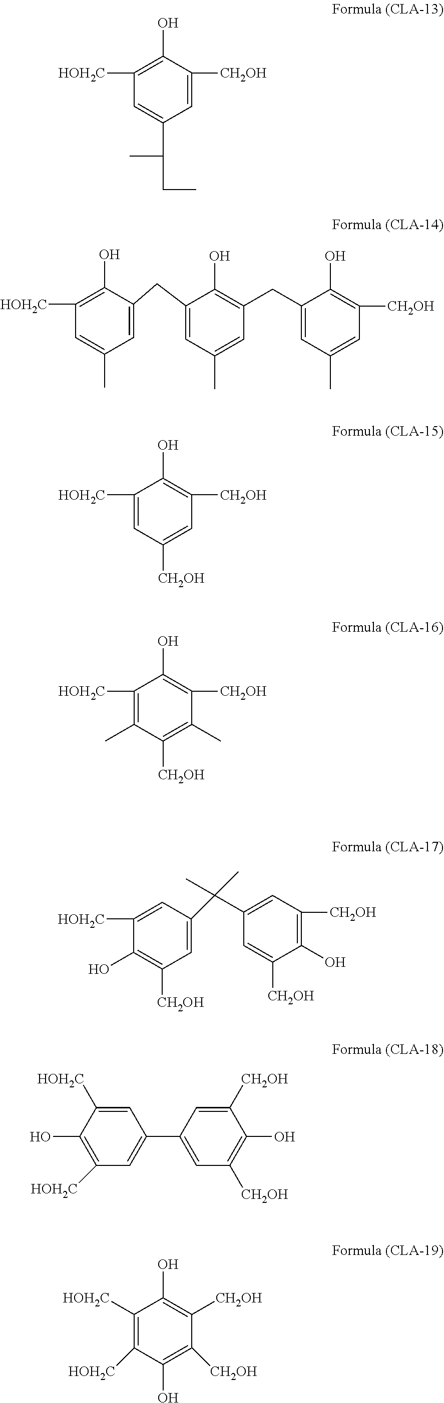

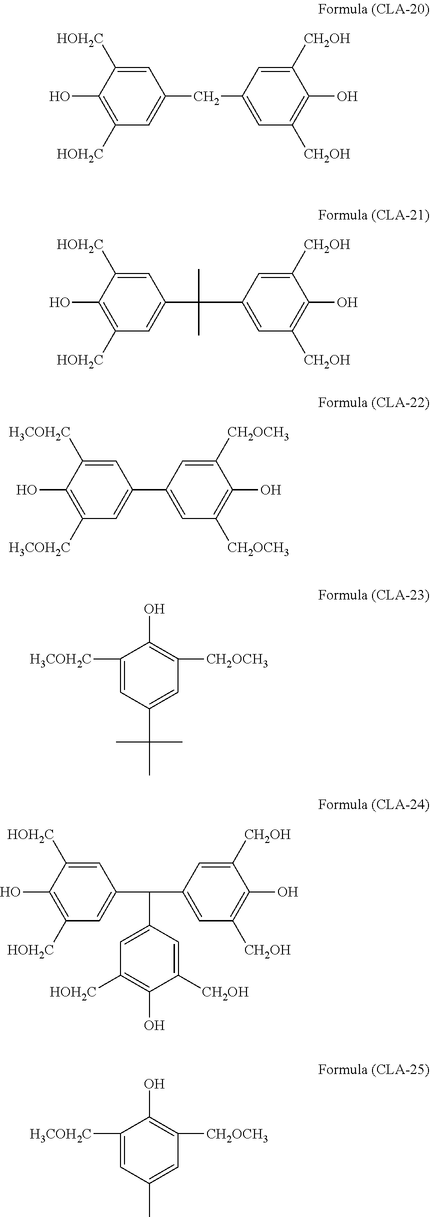

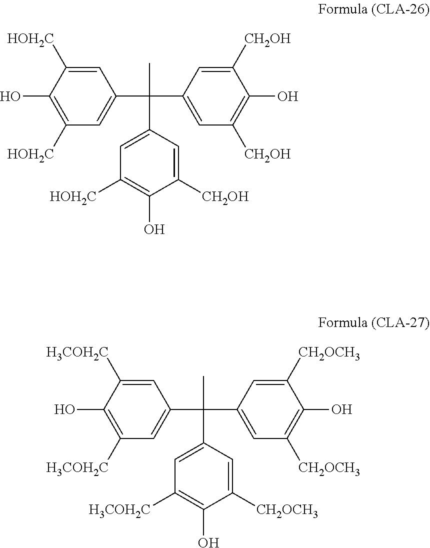

The aforementioned compounds can be obtained as products available from ASAHI YUKIZAI CORPORATION and Honshu Chemical Industry Co., Ltd. For example, among the aforementioned crosslinking agents, the compound of Formula (CLA-21) can be obtained as trade name TM-BIP-A available from ASAHI YUKIZAI CORPORATION.

The amount of the crosslinking agent added may vary depending on, for example, the type of a coating solvent used, the type of an underlying substrate used, the viscosity of a solution required, or the shape of a film required. The amount of the crosslinking agent is 0.001 to 80% by mass, preferably 0.01 to 50% by mass, more preferably 0.05 to 40% by mass, relative to the total solid content. Such a crosslinking agent may cause a crosslinking reaction by its self-condensation. When a crosslinkable substituent is present in the aforementioned polymer of the present invention, such a crosslinking agent may cause a crosslinking reaction with the crosslinkable substituent.

In the present invention, the organic underlayer film-forming composition may contain, as a catalyst for promoting the aforementioned crosslinking reaction, an acidic compound such as p-toluenesulfonic acid, trifluoromethanesulfonic acid, pyridinium p-toluenesulfonate, salicylic acid, sulfosalicylic acid, citric acid, benzoic acid, hydroxybenzoic acid, or naphthalenecarboxylic acid, and/or a thermal acid generator such as 2,4,4,6-tetrabromocyclohexadienone, benzoin tosylate, 2-nitrobenzyl tosylate, or an additional organic sulfonic acid alkyl ester. The amount contained is 0.0001 to 20% by mass, preferably 0.0005 to 10% by mass, preferably 0.01 to 3% by mass, relative to the total solid content.

The amount of the crosslinking agent added to the organic underlayer film-forming composition may vary depending on, for example, the type of a coating solvent used, the type of an underlying substrate used, the viscosity of a solution required, or the shape of a film required. The amount of the crosslinking agent is 0.001 to 80% by mass, preferably 0.01 to 50% by mass, more preferably 0.05 to 40% by mass, relative to the total solid content.

Such a crosslinking agent may cause a crosslinking reaction by its self-condensation. When a crosslinkable substituent is present in any of the aforementioned organic underlayer film-forming compounds 1 to 28 (SOC1 compound to SOC28 compound), such a crosslinking agent may cause a crosslinking reaction with the crosslinkable substituent.

### <<Acid or Acid Generator>>

The aforementioned organic underlayer film-forming composition may contain an acid or an acid generator as a catalyst for promoting the aforementioned crosslinking reaction. Thus, the organic underlayer film-forming composition may contain an acidic compound such as p-toluenesulfonic acid, trifluoromethanesulfonic acid, trifluoromethanesulfonic acid ammonium salt, pyridinium p-toluenesulfonate, pyridinium p-phenolsulfonate, salicylic acid, sulfosalicylic acid, citric acid, benzoic acid, hydroxybenzoic acid, or naphthalenecarboxylic acid, and/or a thermal acid generator such as 2,4,4,6-tetrabromocyclohexadienone, benzoin tosylate, 2-nitrobenzyl tosylate, or an additional organic sulfonic acid alkyl ester.

The amount contained is 0.0001 to 20% by mass, preferably 0.0005 to 10% by mass, more preferably 0.01 to 3% by mass, relative to the total solid content of the organic underlayer film-forming composition.

The aforementioned acid generator may be a photoacid generator besides the aforementioned thermal acid generator.

In the present invention, the photoacid generator contained in the organic underlayer film-forming composition is, for example, an onium salt compound, a sulfonimide compound, and a disulfonyldiazomethane compound.

Examples of the onium salt compound include iodonium salt compounds, such as diphenyliodonium hexafluorophosphate, diphenyliodonium trifluoromethanesulfonate, diphenyliodonium nonafluoro normal butanesulfonate, diphenyliodonium perfluoro normal octanesulfonate, diphenyliodonium camphorsulfonate, bis(4-tert-butylphenyl)iodonium camphorsulfonate, and bis(4-tert-butylphenyl)iodonium trifluoromethanesulfonate; and sulfonium salt compounds, such as triphenylsulfonium hexafluoroantimonate, triphenylsulfonium nonafluoro normal butanesulfonate, triphenylsulfonium camphorsulfonate, triphenylsulfonium trifluoromethanesulfonate, triphenylsulfonium nitrate, triphenylsulfonium trifluoroacetate, triphenylsulfonium maleate, and triphenylsulfonium chloride.

Examples of the sulfonimide compound include N-(trifluoromethanesulfonyloxy)succinimide, N-(nonafluoro normal butane sulfonyloxy)succinimide, N-(camphorsulfonyloxy)succinimide, and N-(trifluoromethanesulfonyloxy)naphthalimide.

Examples of the disulfonyldiazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

These photoacid generators may be used alone or in combination of two or more species.

When a photoacid generator is used, the amount thereof is 0.01 to 5 parts by mass, or 0.1 to 3 parts by mass, or 0.5 to 1 part by mass, relative to 100 parts by mass of the solid content of the organic underlayer film-forming composition.

### <<Additional Additive>>

The aforementioned organic underlayer film-forming composition may contain, besides the aforementioned components, a rheology controlling agent, an adhesion aid, a surfactant, etc. as appropriate. The organic underlayer film-forming composition may contain, as such an additive, any of the compounds exemplified above as a component that may be incorporated in the silicon-containing underlayer film-forming composition in an amount described above.

### <<Formation of Neutral Film>>

The neutral film can be formed by applying the below-described neutral film-forming composition onto the underlayer film by the aforementioned appropriate coating method, and then baking the composition (FIG. 1a).

The baking is performed under appropriately determined conditions; i.e., a baking temperature of 80° C. to 300° C. or 80° C. to 250° C. and a baking time of 0.3 to 60 minutes. Preferably, the baking temperature is 150° C. to 250° C., and the baking time is 0.5 to 2 minutes.

The thus-formed neutral film has a thickness of, for example, 10 to 1,000 nm, or 20 to 500 nm, or 10 to 300 nm, or 5 to 100 nm.

### <<Neutral Film-Forming Composition>>

The neutral film (NL film) used in the present invention may be formed from a material that has conventionally been used in an underlayer film for a self-assembled film for the purpose of facilitating alignment of the self-assembled film in a desired pattern. Examples of the usable material include, but are not limited to, a polymer containing an aromatic vinyl compound (neutral film-forming polymer 1) or a polymer having a unit structure containing in a main chain an aliphatic polycyclic structure of an aliphatic polycyclic compound (neutral film-forming polymer 2).

The composition forming the aforementioned neutral film (NL film) (the composition will be referred to as “neutral film-forming composition”) may contain the aforementioned neutral film-forming polymer and a solvent described below. In this case, the solid content of the neutral film-forming composition may be, for example, 0.01 to 20% by mass, or 0.01 to 15% by mass, or 0.1 to 15% by mass. The “solid content” as used herein refers to the amount of all components (except for the solvent and water) contained in the neutral film-forming composition.

The amount of the aforementioned polymer (neutral film-forming polymer 1 or neutral film-forming polymer 2) in the solid content is generally 50 to 100% by mass, 60 to 95% by mass in one embodiment, and 70 to 90% by mass in another embodiment.

### <<Neutral Film-Forming Polymer 1: Polymer Containing Aromatic Vinyl Compound>>

The neutral film-forming composition used in the present invention may contain, for example, a polymer (neutral film-forming polymer 1) wherein the amount of the unit structure of an aromatic vinyl compound is 20% by mole or more relative to the entire unit structure of the polymer, and the amount of the unit structure of a polycyclic aromatic vinyl compound is 1% by mole or more, 20% by mole to 100% by mole, or 50% by mole to 100% by mole relative to the entire unit structure of the aromatic vinyl compound.

The aforementioned aromatic vinyl compound preferably contains substitutable vinylnaphthalene, substitutable acenaphthylene, or substitutable vinylcarbazole, and the aforementioned polycyclic aromatic vinyl compound is preferably vinylnaphthalene, acenaphthylene, or vinylcarbazole.

The polymer used in the neutral film-forming composition contains a polycyclic aromatic vinyl compound as an essential component, and may arbitrarily contain an aromatic vinyl compound as a superordinate concept of the polycyclic aromatic vinyl compound.

Examples of the aforementioned polycyclic aromatic vinyl compound include vinylnaphthalene, vinylanthracene, acenaphthylene, and vinylcarbazole. Examples of other aromatic vinyl compounds include styrene.

The aforementioned aromatic vinyl compound preferably contains substitutable styrene, and substitutable vinylnaphthalene, substitutable acenaphthylene, or substitutable vinylcarbazole. In this case, the polycyclic aromatic vinyl compound may be vinylnaphthalene, acenaphthylene, or vinylcarbazole.

The aforementioned aromatic vinyl compound is preferably substitutable styrene, and substitutable vinylnaphthalene, substitutable acenaphthylene, or substitutable vinylcarbazole. In this case, the polycyclic aromatic vinyl compound may be substitutable vinylnaphthalene, substitutable acenaphthylene, or substitutable vinylcarbazole.

When the aforementioned aromatic vinyl compound contains only a polycyclic aromatic vinyl compound, the aromatic vinyl compound may be substitutable vinylnaphthalene, substitutable acenaphthylene, or substitutable vinylcarbazole.

In such a case, the amount of the unit structure of the aromatic vinyl compound is preferably 60 to 95% by mole relative to the entire unit structure of the aforementioned polymer.

The aforementioned aromatic vinyl compound and polycyclic aromatic vinyl compound may be copolymerized together to produce a polymer.

In the aforementioned aromatic vinyl compound and polycyclic aromatic vinyl compound, the substituent of an aromatic ring is, for example, an alkyl group, a hydroxy group, a carboxyl group, or a halogen group (e.g., fluorine atom, chlorine atom, bromine atom, or iodine atom). Examples of the aforementioned alkyl group include methyl group, ethyl group, n-propyl group, i-propyl group, n-butyl group, i-butyl group, s-butyl group, t-butyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, and 1-ethyl-2-methyl-n-propyl group. The aforementioned alkyl group may be a cyclic alkyl group. Examples of the cyclic alkyl group having a carbon atom number of 1 to 10 include cyclopropyl group, cyclobutyl group, 1-methyl-cyclopropyl group, 2-methyl-cyclopropyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, and 2-ethyl-3-methyl-cyclopropyl group.

The aforementioned polymer may further contain a unit structure having a crosslinkable group as a copolymerization component. When the polymer contains the unit structure having a crosslinkable group, the amount of the unit structure having a crosslinkable group may be 1 to 80% by mole, preferably 5 to 40% by mole relative to the entire unit structure of the polymer.

The aforementioned crosslinkable group may be a hydroxy group, an epoxy group, a protected hydroxy group, or a protected carboxyl group.

Examples of the monomer having a unit structure having a hydroxy group include a vinyl group-containing hydroxy group derived from hydroxyalkyl (meth)acrylate, vinyl alcohol, etc., and a phenolic hydroxy group of hydroxystyrene, etc. Examples of the alkyl group include the aforementioned alkyl groups, such as methyl group, ethyl group, propyl group, isopropyl group, and butyl group. The term “(meth)acrylate” as used herein refers to both methacrylate and acrylate.

Examples of the monomer having a unit structure having an epoxy group include a vinyl group-containing epoxy group derived from epoxy (meth)acrylate, glycidyl (meth)acrylate, etc.

Examples of the monomer having a unit structure having a protected hydroxy group include a monomer (4-tert-butoxystyrene) prepared by protecting a hydroxy group of hydroxystyrene with a tertiary butoxy (tert-butoxy) group. Other examples of the monomer include a monomer prepared by protecting a hydroxy group through reaction of a phenolic hydroxy group of hydroxystyrene, etc. with a vinyl ether compound, and a monomer prepared by protecting a hydroxy group through reaction of an alcoholic hydroxy group of hydroxyethyl methacrylate, etc. with a vinyl ether compound. Examples of the vinyl ether compound include aliphatic vinyl ether compounds having a C₁₋₁₀ alkyl chain and a vinyl ether group, such as methyl vinyl ether, ethyl vinyl ether, isopropyl vinyl ether, normal butyl vinyl ether, 2-ethylhexyl vinyl ether, tert-butyl vinyl ether, and cyclohexyl vinyl ether; and cyclic vinyl ether compounds such as 2,3-dihydrofuran, 4-methyl-2,3-dihydrofuran, and 2,3-dihydro-4H-pyran.

Examples of the monomer having a unit structure having a protected carboxyl group include a monomer prepared by protecting a carboxyl group through reaction of a carboxyl group of (meth)acrylic acid or vinylbenzoic acid with a vinyl ether compound. Examples of the usable vinyl ether compound include the above-exemplified vinyl ether compounds.

The neutral film-forming polymer 1 may be a polymer produced by copolymerization of the aforementioned unit structure of an aromatic vinyl compound, the aforementioned unit structure of a polycyclic aromatic vinyl compound, and the aforementioned unit structure having a crosslinkable group, and a vinyl compound serving as a unit structure. When the neutral film-forming polymer 1 has the unit structure of the vinyl compound, the amount of the vinyl compound-derived unit structure may be 1 to 80% by mole, preferably 5 to 40% by mole relative to the entire unit structure of the polymer.

Examples of the vinyl compound include methyl (meth)acrylate, ethyl (meth)acrylate, normal hexyl (meth)acrylate, isopropyl (meth)acrylate, cyclohexyl (meth)acrylate, benzyl (meth)acrylate, phenyl (meth)acrylate, anthrylmethyl (meth)acrylate, 2,2,2-trifluoroethyl (meth)acrylate, 2,2,2-trichloroethyl (meth)acrylate, 2-bromoethyl (meth)acrylate, 4-hydroxybutyl (meth)acrylate, 2-methoxyethyl (meth)acrylate, butoxy(2-ethyl) (meth)acrylate, 2-methyl-2-adamantyl (meth)acrylate, (meth)acrylamide, N-methyl(meth)acrylamide, N-ethyl(meth)acrylamide, N-benzyl(meth)acrylamide, N-phenyl(meth)acrylamide, N,N-dimethyl(meth)acrylamide, N-anthryl(meth)acrylamide, methyl vinyl ether, ethyl vinyl ether, benzyl vinyl ether, vinylacetic acid, vinyltrimethoxysilane, 2-chloroethyl vinyl ether, and 2-methoxyethyl vinyl ether.

In the present invention, the neutral film-forming polymer 1 used in the neutral film-forming composition may have a weight average molecular weight of 1,000 to 200,000, or 1,000 to 100,000, or 1,000 to 50,000.

The aforementioned weight average molecular weight can be measured by GPC. The GPC analysis can be performed under, for example, the following conditions: GPC apparatus (trade name: HLC-8220GPC, available from Tosoh Corporation), GPC columns (trade name: Shodex KF803L, KF802, and KF801, available from Showa Denko K.K.), a column temperature of 40° C., tetrahydrofuran serving as an eluent (elution solvent), a flow amount (flow rate) of 1.0 mL/min, and polystyrene (available from Showa Denko K.K.) as a standard sample.

### <<Neutral Film-Forming Polymer 2: Polymer Having Unit Structure Containing in Main Chain Aliphatic Polycyclic Structure of Aliphatic Polycyclic Compound>>

The neutral film-forming composition used in the present invention may contain a polymer having a unit structure containing in a main chain an aliphatic polycyclic structure of an aliphatic polycyclic compound (neutral film-forming polymer 2).

The aforementioned neutral film-forming polymer 2 may be a polymer having a unit structure containing, in a main chain of a polymerization chain, an aliphatic polycyclic structure of an aliphatic polycyclic compound and an aromatic ring structure of an aromatic ring-containing compound.

The aforementioned polymer may be a polymer having a unit structure containing in a main chain an aliphatic polycyclic structure of an aliphatic polycyclic compound and a polymerization chain derived from a vinyl group of a vinyl group-containing compound.

Examples of the vinyl group-containing compound include alkenes such as ethylene and propylene; and acrylates and methacrylates, such as methyl acrylate and methyl methacrylate.

The aforementioned polymer may have, for example, a selected structure of the following Formula (11).

[symbol]

Q-T [symbol] Formula (11)

In Formula (11), Q is a single bond, a divalent group having a polymerization chain formed of a vinyl structure derived from a vinyl group-containing compound, or a divalent group having a polymerization chain formed of an aromatic ring-containing structure derived from an aromatic ring-containing compound, and T is a divalent group having a polymerization chain formed of an aliphatic polycyclic structure derived from an aliphatic polycyclic compound.

The aforementioned polymer corresponds to a novolac resin, when in Formula (11) Q is a divalent group having a polymerization chain formed of an aromatic ring-containing structure derived from an aromatic ring-containing compound, and T is a divalent group having a polymerization chain formed of an aliphatic polycyclic structure derived from an aliphatic polycyclic compound.

In Formula (11), the group T is a divalent group having a polymerization chain formed of an aliphatic polycyclic structure derived from an aliphatic polycyclic compound. The aliphatic polycyclic compound preferably has at least two double bonds in the rings, and is typically a diene compound having two to six rings. Examples of the diene compound include a bicyclo ring compound, a tricyclo ring compound, a tetracyclo ring compound, a pentacyclo ring compound, and a hexacyclo ring compound.

Examples of the aforementioned aliphatic polycyclic compound include 2,5-norbornadiene, 3a,4,7,7a-tetrahydroindene, 1,3a,4,6a-tetrahydropentalene, and dicyclopentadiene. Preferred are 2,5-norbornadiene and dicyclopentadiene.

The aliphatic polycyclic compound may have any substituent. Examples of the substituent include an alkyl group, a phenyl group, a hydroxy group, a carboxyl group, a cyano group, a nitro group, and a halogen atom.

When Q is a divalent group having a polymerization chain formed of an aromatic ring-containing structure derived from an aromatic ring-containing compound in Formula (11), the aromatic ring-containing compound is a homocyclic compound or a heterocyclic compound. The homocyclic compound is, for example, substitutable benzene or substitutable naphthalene, and the heterocyclic compound is, for example, substitutable carbazole or substitutable phenothiazine.

The aromatic ring-containing compound is, for example, a compound having a hydroxy group or an amino group as an electron-donating organic group.

Examples of the aromatic ring-containing compound include phenol, cresol, 4-phenylphenol, 1-naphthol, catechol, resorcinol, hydroquinone, 4,4′-biphenol, 2,2′-biphenol, 2,2-bis(hydroxyphenyl)propane, 1,5-dihydroxynaphthalene, pyrogallol, phloroglucinol, aniline, carbazole, phenyl-1-naphthylamine, triphenylamine, 2-phenylindole, and phenothiazine. Preferred are phenol, carbazole, and phenothiazine.

The novolac resin wherein Q is a divalent group having a polymerization chain formed of an aromatic ring-containing structure derived from an aromatic ring-containing compound, and T is a divalent group having a polymerization chain formed of an aliphatic polycyclic structure derived from an aliphatic polycyclic compound in Formula (11) is a novolac resin prepared by condensation reaction between the aromatic ring-containing compound and the aliphatic polycyclic compound. In this condensation reaction, the aliphatic polycyclic compound having a diene structure may be used in an amount of 0.1 to 10 equivalents relative to 1 equivalent of the phenyl group contained in the aromatic ring-containing compound and participating in the reaction.

Examples of the acid catalyst used in the aforementioned condensation reaction include mineral acids such as sulfuric acid, phosphoric acid and perchloric acid; organic sulfonic acids such as methanesulfonic acid, trifluoromethanesulfonic acid, p-toluenesulfonic acid, and p-toluenesulfonic acid monohydrate; and carboxylic acids such as formic acid and oxalic acid. The amount of the acid catalyst used may vary depending on the type of the acid used. The amount of the acid is generally 0.001 to 10,000 parts by mass, preferably 0.01 to 1,000 parts by mass, more preferably 0.1 to 100 parts by mass, relative to 100 parts by mass of the total amount of the aromatic ring-containing compound and the diene-containing aliphatic polycyclic compound.

The aforementioned condensation reaction may be performed without use of a solvent, but the reaction is generally performed with use of a solvent. Any solvent may be used, so long as it does not inhibit the reaction. Examples of the solvent include toluene, 1,4-dioxane, propylene glycol monomethyl ether, propylene glycol monomethyl ether acetate, and butyl cellosolve. When the acid catalyst used is a liquid acid such as formic acid, the acid may also serve as a solvent.

The reaction temperature during condensation is generally 40° C. to 200° C. The reaction time may vary depending on the reaction temperature, and the reaction time is generally about 30 minutes to 50 hours.

The above-prepared novolac resin generally has a weight average molecular weight Mw of 500 to 1,000,000 or 600 to 200,000.

Examples of the aforementioned novolac resin include resins having structural units of the following Formulae (11-1) to (11-19).

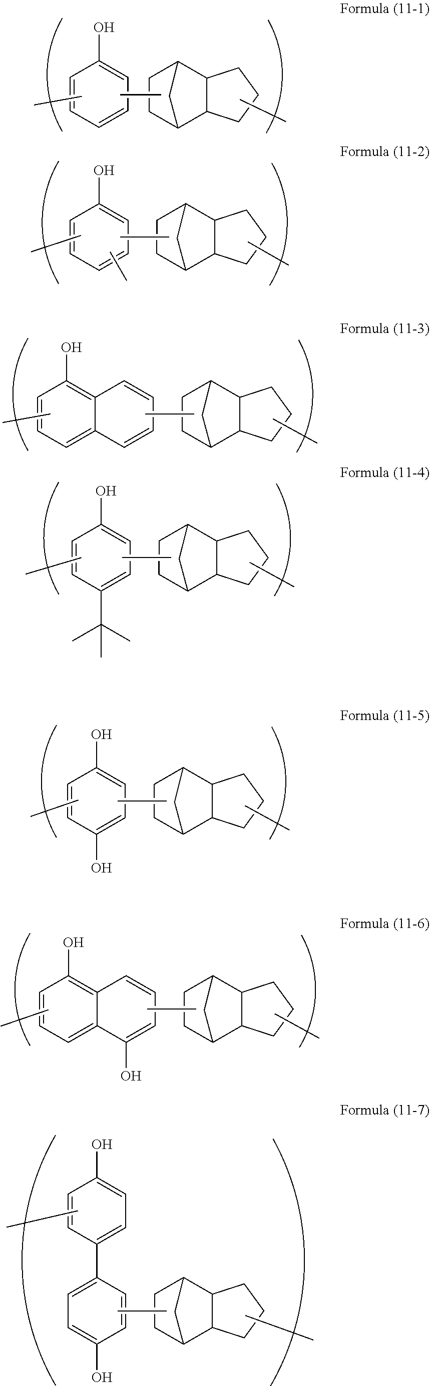

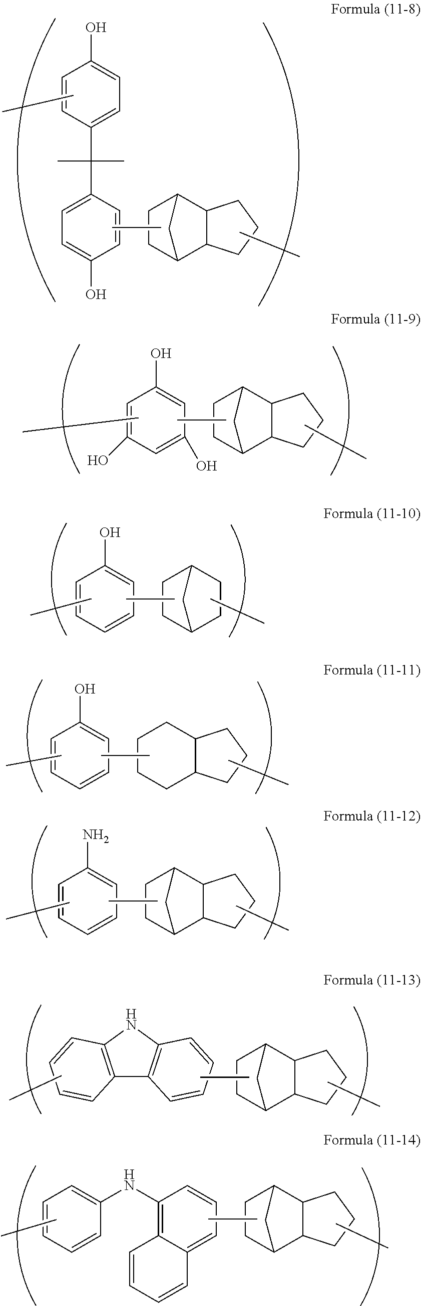

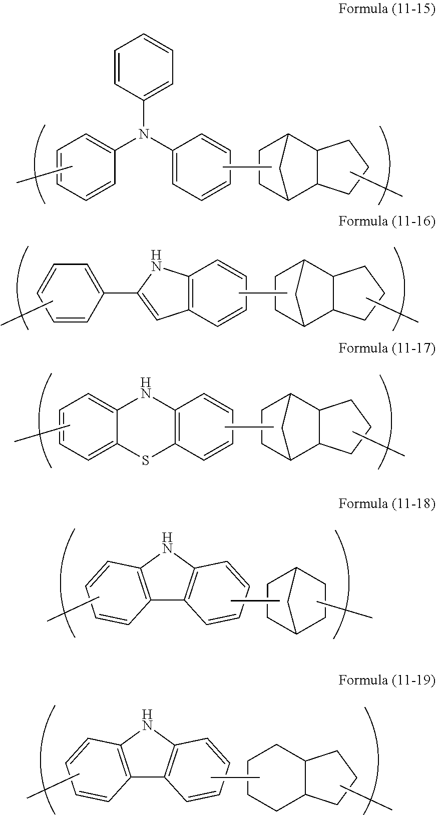

The aforementioned novolac resin may have an epoxy group.

Examples of the aforementioned novolac resin having an epoxy group include epoxyphenol-dicyclopentadiene resin, epoxycresol-dicyclopentadiene resin, epoxyphenol-norbornadiene resin, epoxynaphthol-dicyclopentadiene resin, and epoxydihydroxynaphthalene-dicyclopentadiene resin. In particular, the epoxyphenol-dicyclopentadiene resin is known as a commercially available product (dicyclopentadiene-type epoxy resin, trade name: EPICLON HP-7200H, available from DIC Corporation).

Examples of the aforementioned novolac resin having an epoxy group include resins having structural units of the following Formulae (12-1) to (12-5).

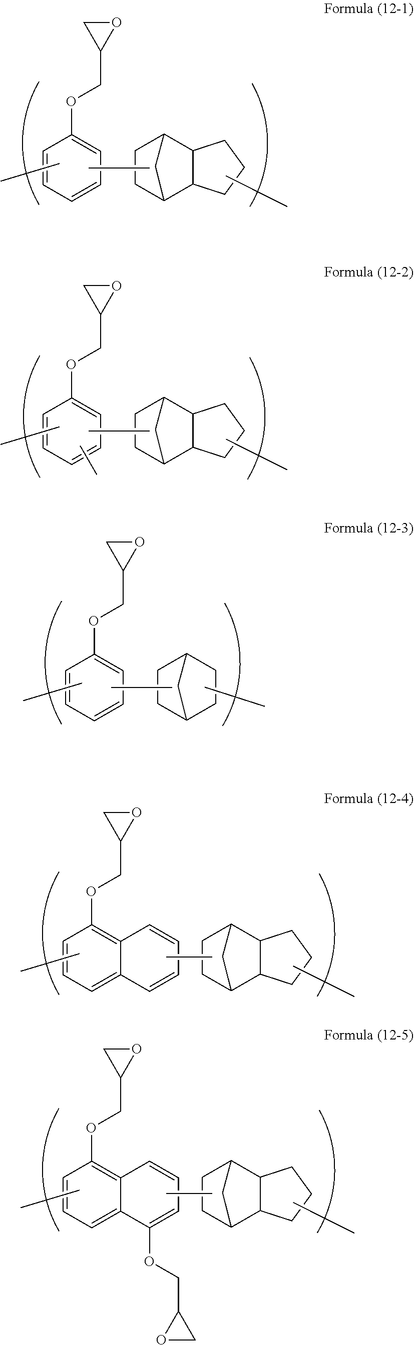

The aforementioned novolac resin having an epoxy group may contain an organic compound Z that reacts with the epoxy group. Examples of the organic compound Z include carboxylic acid, phenol, amine, and imide compounds.

Specific examples of the organic compound Z include benzoic acid, 4-toluic acid, 4-tert-butylbenzoic acid, 4-phenylbenzoic acid, salicylic acid, 4-hydroxybenzoic acid, 4-methoxycarboxylic acid, 4-tert-butoxybenzoic acid, 4-fluorobenzoic acid, 4-chlorobenzoic acid, 1-naphthoic acid, 9-anthracenecarboxylic acid, n-butanoic acid, n-hexanoic acid, n-octanoic acid, pivalic acid, cyclohexanecarboxylic acid, 1-methylcyclohexanecarboxylic acid, adamantanecarboxylic acid, cinnamic acid, succinic anhydride, phthalic anhydride, phenol, cresol, anisole, 4-tert-butylphenol, 4-phenylphenol, 1-naphthol, N-butylamine, N-dibutylamine, piperidine, aniline, succinimide, maleimide, phthalimide, and diallylisocyanuric acid. Particularly preferred are 4-tert-butylbenzoic acid, 4-phenylbenzoic acid, 1-naphthoic acid, 9-anthracenecarboxylic acid, n-butanoic acid, n-hexanoic acid, n-octanoic acid, pivalic acid, cyclohexanecarboxylic acid, 1-methylcyclohexanecarboxylic acid, cinnamic acid, 1-naphthol, and 4-phenylphenol.

In the reaction between the aforementioned novolac resin containing an epoxy group and the organic compound Z that can added to the epoxy group, the amount of the organic compound Z may be 0.1 to 1 equivalent relative to 1 equivalent of the epoxy group contained in the aforementioned epoxy group-containing novolac resin. Two or more organic compounds Z may be used in combination.

The catalyst for activating the epoxy group used in the aforementioned addition reaction is, for example, a quaternary phosphonium salt such as ethyltriphenylphosphonium bromide, or a quaternary ammonium salt such as benzyltriethylammonium chloride. The amount of such a catalyst is generally 0.001 to 1 equivalent relative to 1 equivalent of the epoxy group contained in the aforementioned novolac resin.

The aforementioned addition reaction may be performed without use of a solvent, but the reaction is generally performed with use of a solvent. Any solvent may be used, so long as it does not inhibit the reaction. For example, an alcohol such as propylene glycol monomethyl ether, an ester such as propylene glycol monomethyl ether acetate or ethyl lactate, or a ketone such as cyclohexanone is more preferably used, since such a solvent exhibits high solubility in the novolac resin.

The reaction temperature during addition reaction is generally 40° C. to 200° C. The reaction time may vary depending on the reaction temperature, and the reaction time is generally about 30 minutes to 50 hours.

The above-prepared novolac resin generally has a weight average molecular weight Mw of 500 to 1,000,000 or 600 to 200,000.

Examples of the adduct (novolac resin) prepared from the aforementioned novolac resin having an epoxy group and the organic compound Z include resins having structural units of the following Formulae (13-1) to (13-12).

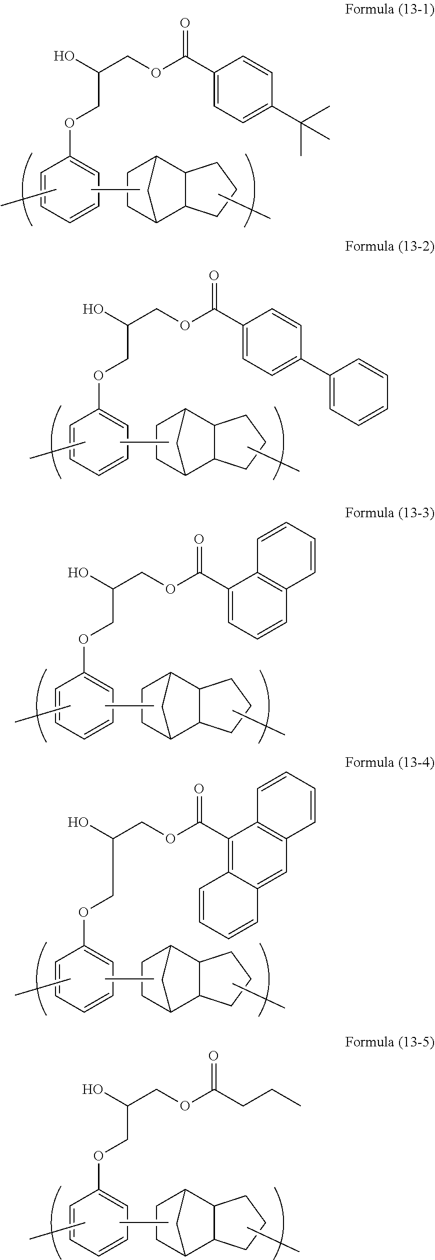

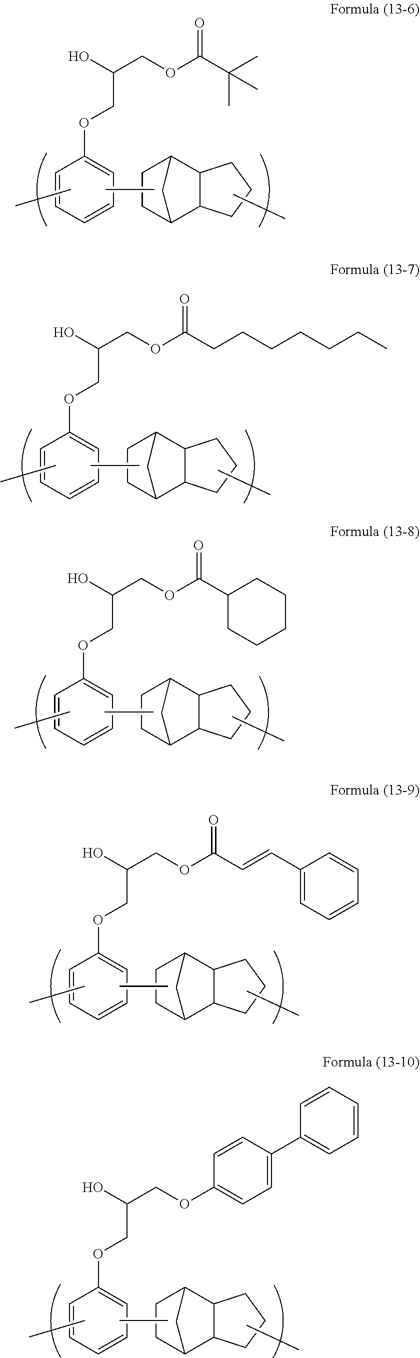

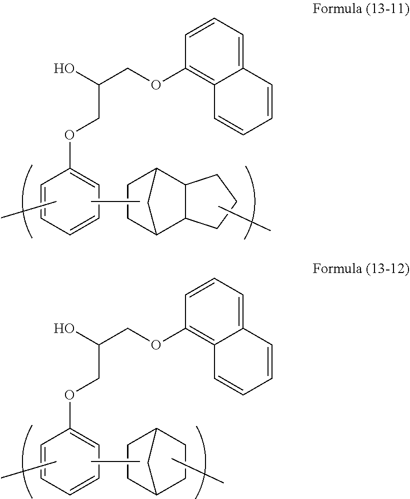

The neutral film-forming composition may contain an additional polymer besides the aforementioned neutral film-forming polymer 1 or neutral film-forming polymer 2, so long as the effects of the present invention are not impaired.

When the composition contains such an additional polymer, the amount of the polymer may vary depending on, for example, the type of a coating solvent used, the baking conditions for the neutral film-forming composition, the baking conditions for the self-assembled film formed above the neutral film, and the type of an underlying substrate used. The neutral film-forming composition may contain the additional polymer such that the amount of the aforementioned neutral film-forming polymer 1 or neutral film-forming polymer 2 is 0.1 to 100% by mass, preferably 5 to 100% by mass, more preferably 10 to 100% by mass, relative to the mass of all the polymers contained in the neutral film-forming composition.

### <<Crosslinking Agent Component>>

The aforementioned neutral film-forming composition may contain a crosslinking agent component.

The crosslinking agent is, for example, a melamine compound, a substituted urea compound, or a polymer compound thereof. The crosslinking agent is preferably a crosslinking agent having at least two crosslinkable substituents, such as a hydroxymethyl group and an alkoxymethyl group. Specific examples of the crosslinking agent (compound) include methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, methoxymethylated thiourea, or methoxymethylated thiourea. A condensate of such a compound may also be used.

The amount of the crosslinking agent added to the neutral film-forming composition may vary depending on, for example, the type of a coating solvent used, the type of an underlying substrate used, the viscosity of a solution required, or the shape of a film required. The amount of the crosslinking agent is 0.001 to 80% by mass, preferably 0.01 to 50% by mass, more preferably 0.05 to 40% by mass, relative to the total solid content.

Such a crosslinking agent may cause a crosslinking reaction by its self-condensation. When a crosslinkable substituent is present in the aforementioned polymer (neutral film-forming polymer 1 or neutral film-forming polymer 2), such a crosslinking agent may cause a crosslinking reaction with the crosslinkable substituent.

### <<Acid or Acid Generator>>

The aforementioned neutral film-forming composition may contain an acid or an acid generator as a catalyst for promoting the aforementioned crosslinking reaction. Thus, the neutral film-forming composition may contain an acidic compound such as p-toluenesulfonic acid, trifluoromethanesulfonic acid, pyridinium p-toluenesulfonate, salicylic acid, sulfosalicylic acid, citric acid, benzoic acid, hydroxybenzoic acid, or naphthalenecarboxylic acid, and/or a thermal acid generator such as 2,4,4,6-tetrabromocyclohexadienone, benzoin tosylate, 2-nitrobenzyl tosylate, or an additional organic sulfonic acid alkyl ester.

The amount of such a catalyst is 0.0001 to 20% by mass, preferably 0.0005 to 10% by mass, more preferably 0.01 to 3% by mass, relative to the total solid content of the neutral film-forming composition.

The aforementioned acid generator may be a photoacid generator besides the aforementioned thermal acid generator.

A photoacid generator generates an acid during the exposure of a resist. Thus, the acidity of a neutral film can be adjusted. This is one method for adjusting the acidity of a neutral film to the acidity of a self-assembled film serving as an upper layer of the neutral film. Furthermore, the adjustment of the acidity of a neutral film enables the control of the pattern shape of a self-assembled film formed as an upper layer of the neutral film.

In the present invention, the photoacid generator contained in the neutral film-forming composition is, for example, an onium salt compound, a sulfonimide compound, and a disulfonyldiazomethane compound.

Examples of the onium salt compound include iodonium salt compounds, such as diphenyliodonium hexafluorophosphate, diphenyliodonium trifluoromethanesulfonate, diphenyliodonium nonafluoro normal butanesulfonate, diphenyliodonium perfluoro normal octanesulfonate, diphenyliodonium camphorsulfonate, bis(4-tert-butylphenyl)iodonium camphorsulfonate, and bis(4-tert-butylphenyl)iodonium trifluoromethanesulfonate; and sulfonium salt compounds, such as triphenylsulfonium hexafluoroantimonate, triphenylsulfonium nonafluoro normal butanesulfonate, triphenylsulfonium camphorsulfonate, triphenylsulfonium trifluoromethanesulfonate, triphenylsulfonium nitrate, triphenylsulfonium trifluoroacetate, triphenylsulfonium maleate, and triphenylsulfonium chloride.

Examples of the sulfonimide compound include N-(trifluoromethanesulfonyloxy)succinimide, N-(nonafluoro normal butane sulfonyloxy)succinimide, N-(camphorsulfonyloxy)succinimide, and N-(trifluoromethanesulfonyloxy)naphthalimide.

Examples of the disulfonyldiazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

These photoacid generators may be used alone or in combination of two or more species.

When a photoacid generator is used, the amount thereof is 0.01 to 5 parts by mass, or 0.1 to 3 parts by mass, or 0.5 to 1 part by mass, relative to 100 parts by mass of the solid content of the neutral film-forming composition.

### <<Additional Additive>>

The aforementioned neutral film-forming composition may contain, besides the aforementioned components, a rheology controlling agent, an adhesion aid, a surfactant, etc. as appropriate. The neutral film-forming composition may contain, as such an additive, any of the compounds exemplified above as a component that may be incorporated in the silicon-containing underlayer film-forming composition in an amount described above.

### <<Patterning of Neutral Film>>

In one embodiment for inducing a microphase-separated structure in a desired pattern, a template film for a self-assembled pattern can be formed from the neutral film and the below-described brush film. In this case, patterning with a photoresist can be utilized for forming a desired pattern in the neutral film.

For patterning with a photoresist, firstly, a photoresist material layer (resist film) is formed on the aforementioned neutral film. The resist film can be formed by a well-known method. Specifically, the resist film can be formed by application of a coating-type resist material (e.g., a photoresist film-forming composition) onto the neutral film, and subsequent baking of the resist material. The baking may be performed under, for example, the following conditions: a baking temperature of 70 to 150° C. and a baking time of 0.5 to 5 minutes.

The resist film has a thickness of, for example, 10 nm to 10,000 nm, or 100 nm to 2,000 nm, or 200 nm to 1,000 nm, or 30 nm to 200 nm.

No particular limitation is imposed on the photoresist material used for the resist film, so long as the material is sensitive to light used for exposure (e.g., KrF excimer laser or ArF excimer laser). The material may be either of negative photoresist and positive photoresist materials. Examples of the material include a positive photoresist material formed of a novolac resin and a 1,2-naphthoquinone diazide sulfonic acid ester; a chemically amplified photoresist material formed of a binder having a group that decomposes with an acid to thereby increase the alkali dissolution rate and a photoacid generator; a chemically amplified photoresist material formed of a low-molecular-weight compound that decomposes with an acid to thereby increase the alkali dissolution rate of the photoresist material, an alkali-soluble binder, and a photoacid generator; and a chemically amplified photoresist material formed of a binder having a group that decomposes with an acid to thereby increase the alkali dissolution rate, a low-molecular-weight compound that decomposes with an acid to thereby increase the alkali dissolution rate of the photoresist material, and a photoacid generator.

Specific examples of commercially available products include, but are not limited to, trade name APEX-E (available from Shipley), trade name PAR710 (available from Sumitomo Chemical Company, Limited), trade name AR2772JN (available from JSR Corporation), and trade name SEPR430 (available from Shin-Etsu Chemical Co., Ltd.). Other examples include fluorine atom-containing polymer-based photoresist materials described in, for example, Proc. SPIE, Vol. 3999, 330-334 (2000), Proc. SPIE, Vol. 3999, 357-364 (2000), and Proc. SPIE, Vol. 3999, 365-374 (2000).

The aforementioned resist film may be, in place of the photoresist film, a resist film for electron beam lithography (may also be referred to as “electron beam resist film”) or a resist film for EUV lithography (may also be referred to as “EUV resist film”).

The electron beam resist material may be either of negative and positive materials. Specific examples of the resist material include a chemically amplified resist material formed of an acid generator and a binder having a group that decomposes with an acid to thereby change the alkali dissolution rate; a chemically amplified resist material formed of an alkali-soluble binder, an acid generator, and a low-molecular-weight compound that decomposes with an acid to thereby change the alkali dissolution rate of the resist material; a chemically amplified resist material formed of an acid generator, a binder having a group that decomposes with an acid to thereby change the alkali dissolution rate, and a low-molecular-weight compound that decomposes with an acid to thereby change the alkali dissolution rate of the resist material; a non-chemically amplified resist material formed of a binder having a group that decomposes with electron beams to thereby change the alkali dissolution rate; and a non-chemically amplified resist material formed of a binder having a moiety that is cut with electron beams to thereby change the alkali dissolution rate. Also in the case of use of such an electron beam resist material, a resist film pattern can be formed by using electron beams as an irradiation source in the same manner as in the case of using the photoresist material.

The EUV resist material may be a methacrylate resin-based resist material.

Subsequently, light exposure is performed on the thus-formed resist film through a predetermined mask (reticle). The light exposure may involve the use of, for example, a KrF excimer laser (wavelength: 248 nm), an ArF excimer laser (wavelength: 193 nm), an F2 excimer laser (wavelength: 157 nm), EUV (wavelength: 13.5 nm), or electron beams.

After the light exposure, post exposure bake may be performed if necessary. The post exposure bake is performed under appropriately determined conditions; i.e., a heating temperature of 70° C. to 150° C. and a heating time of 0.3 minutes to 10 minutes.

Subsequently, development is performed with a developer (e.g., an alkaline developer). When, for example, a positive photoresist film is used, an exposed portion of the photoresist film is removed to thereby form a pattern of the photoresist film (FIG. 1b).

Examples of the developer (alkaline developer) include alkaline aqueous solutions (alkaline developers), for example, aqueous solutions of alkali metal hydroxides, such as potassium hydroxide and sodium hydroxide; aqueous solutions of quaternary ammonium hydroxides, such as tetramethylammonium hydroxide, tetraethylammonium hydroxide, and choline; and aqueous solutions of amines, such as ethanolamine, propylamine, and ethylenediamine. Such a developer may further contain a surfactant, etc. The development is performed under appropriately determined conditions; i.e., a temperature of 5 to 50° C. and a time of 10 seconds to 600 seconds.

The developer may be an organic solvent, and development is performed with a developer (solvent) after light exposure. When, for example, a negative photoresist film is used, an unexposed portion of the photoresist film is removed to thereby form a pattern of the photoresist film.

Examples of the developer (organic solvent) include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Such a developer may further contain a surfactant, etc. The development is performed under appropriately determined conditions; i.e., a temperature of 5° C. to 50° C. and a time of 10 seconds to 600 seconds.

Subsequently, the neutral film is etched by using the resist film pattern as a protective film, to thereby pattern the neutral film (see FIG. 1c).

The removal (patterning) of the neutral film is performed by dry etching with an oxygen-containing gas (e.g., oxygen gas or oxygen/nitrogen (N2) mixed gas). This is because the silicon-containing underlayer film, which underlies the neutral film and contains numerous silicon atoms, is less likely to be removed by dry etching with an oxygen-containing gas.

Thereafter, the resist film (pattern) serving as a protective film is removed by etching or stripping, to thereby form a patterned neutral film (see FIG. 1d).

The resist film may be removed by plasma or ozone etching, or by using an existing resist remover in accordance with the type of the aforementioned photoresist.

### <Formation of Template Film for Self-Assembled Pattern Including Neutral Film and Brush Film>

For formation of a template film for the aforementioned self-assembled pattern, firstly, a brush film-forming material is applied by the aforementioned appropriate coating method onto the silicon-containing underlayer film (exposed portion) formed through the aforementioned step and the patterned neutral film on the underlayer film so as to cover the underlayer film and the patterned neutral film. Thereafter, the brush film-forming material is baked to thereby form a brush film on the entire surface of the substrate (FIG. 1e).

The baking is performed under appropriately determined conditions; i.e., a baking temperature of 80° C. to 300° C. or 80° C. to 250° C. and a baking time of 0.3 to 60 minutes. Preferably, the baking temperature is 80° C. to 100° C., and the baking time is 0.5 to 2 minutes.

The film formed in this step should have a thickness enough to cover the aforementioned patterned neutral film.

The aforementioned brush film is provided so as to prevent a self-assembled pattern from developing in a non-target portion. In order to achieve such a function, the brush film is required to have such a property that it sufficiently adheres to the aforementioned silicon-containing underlayer film, but does not adhere to the neutral film.

The aforementioned brush film-forming material may be a polymer material known as a brush material in the art. For example, a hydroxyl-terminated polystyrene polymer (PS, available from POLYMER SOURCE. INC.) may be used.

After formation of the brush film on the entire surface of the substrate, a portion of the brush film on the patterned neutral film is removed by etching or stripping to expose the neutral film, to thereby form a template film for a self-assembled pattern including the neutral film and the brush film (FIG. 1f).

The brush film may be removed by using, for example, a mixed solution of propylene glycol monomethyl ether and propylene glycol monomethyl ether acetate (e.g., OK73 Thinner, available from TOKYO OHKA KOGYO CO., LTD.).

### <Formation of Self-Assembled Film and Formation of Self-Assembled Pattern>

A self-assembled film can be formed by applying the below-described self-assembled film-forming composition onto the aforementioned neutral film (preferably, the template film formed through the aforementioned step) by the aforementioned appropriate coating method, and then baking the composition (FIG. 1g).

The baking is performed under appropriately determined conditions; for example, a baking temperature of 80 to 140° C. and a baking time of 0.3 to 60 minutes. Preferably, the baking temperature is 80 to 120° C., and the baking time is about 0.5 to 2 minutes.

The self-assembled film has a thickness of, for example, 30 to 10,000 nm, or 20 to 2,000 nm, or about 10 to 200 nm.

The above-formed self-assembled film is subjected to a treatment for providing realignment of a block copolymer material, for example, ultrasonic treatment, solvent treatment, or thermal annealing, to thereby generate a microphase-separated structure and to form a self-assembled pattern.

In many applications, simple heating or so-called thermal annealing may be selected for achieving the phase separation of a block copolymer layer. The thermal annealing may be performed in air or inert gas at ambient pressure, reduced pressure, or under pressurized conditions.

No particular limitation is imposed on the thermal annealing conditions, and the thermal annealing may be performed in air at, for example, 180° C. to 300° C., 190 to 280° C., or, for example, 260° C.

No particular limitation is imposed on the aforementioned treatment time, and the treatment time is generally 1 to 30 minutes, for example, 3 to 10 minutes.

### [Self-Assembled Film and Self-Assembled Film-Forming Composition]

The self-assembled film used in the present invention may contain a block copolymer containing an organic polymer chain (A) containing an organic monomer (a) as a unit structure, and an organic polymer chain (B) containing, as a unit structure, an organic monomer (b) different from the organic monomer (a), wherein the organic polymer chain (B) is bonded to the organic polymer chain (A).

The composition for forming the aforementioned self-assembled film (will be referred to as “self-assembled film-forming composition”) may contain the aforementioned block copolymer and the below-described organic solvent, and the solid content of the self-assembled film-forming composition may be 0.1 to 70% by mass, or 0.1 to 50% by mass, or 0.1 to 30% by mass. The “solid content” refers to the amount of all components (except for the solvent) contained in the self-assembled film-forming composition.

The amount of the aforementioned block copolymer in the total solid content of the self-assembled film-forming composition is generally 30 to 100% by mass. From the viewpoint of achieving the effects of the present invention at high reproducibility, the amount of the block copolymer is preferably 50% by mass or more, more preferably 70% by mass or more, still more preferably 80% by mass or more. In one embodiment, the upper limit of the amount is 95% by mass, whereas in another embodiment, the upper limit of the amount is 90% by mass.

Two types or three or more types of blocks may be present in the aforementioned block copolymer. The number of blocks present in the block copolymer may be two or three or more.

The aforementioned block copolymer may contain, in place of the aforementioned organic polymer chain (B), for example, an organic polymer chain (C) containing an organic monomer (c) as a unit structure.

Thus, the aforementioned block copolymer may have a pattern of AB, ABAB, ABA, ABC, etc.

One synthesis method for the block copolymer may be, for example, living radical polymerization, living cationic polymerization, or living anionic polymerization wherein the polymerization process includes only an initiation reaction and a propagation reaction, and does not involve side reactions for inactivating the growing end. In such a polymerization reaction, the growing end can continue to maintain the growth active reaction during the polymerization reaction. Thus, organic polymer chains (A) of uniform length can be produced from the organic monomer (a) by preventing chain transfer.

Subsequently, when the organic monomer (b) different from the organic monomer (a) is added, the polymerization proceeds in the presence of the organic monomer (b) by utilizing the growth end of the organic polymer chain (A), whereby a block copolymer (AB) can be formed.

When, for example, two types of blocks A and B are used, the ratio by mole of the organic polymer chain (A) to the organic polymer chain (B) may be 1:9 to 9:1, preferably 3:7 to 5:5.

The homopolymer A or B formed of only the organic monomer (a) or (b) is a polymerizable compound having at least one radical polymerizable reactive group (vinyl group or vinyl group-containing organic group).

The block copolymer used in the self-assembled film-forming composition preferably has a weight average molecular weight Mw of 1,000 to 100,000 or 5,000 to 100,000. A weight average molecular weight of less than 1,000 may cause poor applicability of the composition to an underlying substrate (underlying layer), whereas a weight average molecular weight of 100,000 or more may cause poor solubility of the composition in a solvent.

Each of the aforementioned monomer (a) and (b) forming the aforementioned block copolymer is, for example, a compound selected from among acrylic acid and an alkyl ester thereof, methacrylic acid and an alkyl ester thereof, N,N-dimethyl(meth)acrylamide, quaternizable dimethylaminoethyl (meth)acrylate, (meth)acrylamide, N-t-butyl(meth)acrylamide, maleic acid and a hemiester thereof, maleic anhydride, crotonic acid, itaconic acid, hydroxylated (meth)acrylate, diallyldimethylammonium chloride, N-vinyl-2-pyrrolidone, vinyl ether, maleimide, vinylpyridine, vinylimidazole, heterocyclic vinyl compounds, styrene sulfonate, allyl alcohol, vinyl alcohol, acrylic or methacrylic esters of C₁₋₁₃ alcohols, fluoroacrylate, styrene, vinyl acetate, vinyl chloride, vinylidene chloride, vinyl propionate, α-methylstyrene, t-butylstyrene, isoprene, butadiene, cyclohexadiene, ethylene, propylene, and vinyltoluene.

The self-assembled film-forming composition used in the present invention may contain a block copolymer having or not having a crosslinkable group such as a hydroxy group, an epoxy group, a protected hydroxy group, or a protected carboxyl group. Specifically, the composition contains a block copolymer formed of any of combinations, for example, polystyrene (A) and poly(methyl methacrylate) (B), polystyrene (A) and polyisoprene (B), polystyrene (A) and polybutadiene (B), polystyrene (A) and polydimethylsiloxane (B), polystyrene (A) and polyethylene oxide (B), and polystyrene (A) and polyvinylpyridine (B).

In particular, preferred is polystyrene/poly(methyl methacrylate) copolymer, polystyrene/polyisoprene copolymer, or polystyrene/polybutadiene copolymer.

The aforementioned self-assembled film-forming composition may contain, besides the aforementioned block copolymer and an organic solvent, for example, a crosslinkable compound, a crosslinking catalyst, a light-absorbing compound, a surfactant, a hardness-controlling polymer compound, an antioxidant, a thermal polymerization inhibitor, a surface modifier, and a defoamer as appropriate.

The aforementioned self-assembled film-forming composition may further contain an additional component such as β-diketone, colloidal silica, colloidal alumina, an organic polymer, a surfactant, a silane coupling agent, a radical generator, a triazene compound, or an alkaline compound.

The aforementioned self-assembled film-forming composition is generally prepared by dissolving or dispersing the aforementioned block copolymer containing two homopolymer chains (A) and (B) in an organic solvent.

The organic solvent used in the composition is, for example, at least one selected from the group consisting of an aliphatic hydrocarbon solvent, an aromatic hydrocarbon solvent, an alcohol solvent, a ketone solvent, an ether solvent, an ester solvent, a nitrogen-containing solvent, and a sulfur-containing solvent.

Specific examples of the organic solvent include aliphatic hydrocarbon solvents such as n-pentane, i-pentane, n-hexane, i-hexane, n-heptane, i-heptane, 2,2,4-trimethylpentane, n-octane, i-octane, cyclohexane, and methylcyclohexane; aromatic hydrocarbon solvents such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, and n-amylnaphthalene; monohydric alcohol solvents such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, heptanol-3, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; polyhydric alcohol solvents such as ethylene glycol, propylene glycol, 1,3-butylene glycol, 2,4-pentanediol, 2-methylpentane-2,4-diol, 2,5-hexanediol, 2,4-heptanediol, 2-ethylhexane-1,3-diol, diethylene glycol, dipropylene glycol, triethylene glycol, tripropylene glycol, and glycerin; ketone solvents such as acetone, methyl ethyl ketone, methyl-n-propyl ketone, methyl-n-butyl ketone, diethyl ketone, methyl-1-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, and fenchone; ether solvents such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethyl butyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran; ester solvents such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate; nitrogen-containing solvents such as N-methylformamide, N,N-dimethylformamide, N,N-diethylformamide, acetamide, N-methylacetamide, N,N-dimethylacetamide, N-methylpropionamide, and N-methyl-2-pyrrolidone; and sulfur-containing solvents such as dimethyl sulfide, diethyl sulfide, thiophene, tetrahydrothiophene, dimethyl sulfoxide, sulfolane, and 1,3-propane sultone.

Of these organic solvents, propylene glycol monomethyl ether, propylene glycol monoethyl ether, propylene glycol monopropyl ether, propylene glycol monobutyl ether, propylene glycol dimethyl ether, propylene glycol diethyl ether, propylene glycol monomethyl ether acetate, propylene glycol monoethyl ether acetate, and propylene glycol monopropyl ether acetate are particularly preferred from the viewpoint of the storage stability of the solution of the self-assembled film-forming composition.

A catalyst may be used for thermal curing of the self-assembled film-forming composition. The catalyst used for the thermal curing may be an acid or acid generator used for formation (curing) of a neutral film from the aforementioned neutral film-forming composition.

In order to improve, for example, adhesion, wettability to an underlying substrate, flexibility, and flattening property, if necessary, the self-assembled film-forming composition containing the aforementioned block copolymer may be mixed with a polymer prepared by radical polymerization of the below-described polymerizable compound and containing no block copolymer. When the aforementioned polymer containing no block copolymer is used, the amount of the polymer mixed with the composition may be, for example, 10 to 1,000 parts by mass, preferably 10 to 100 parts by mass, relative to 100 parts by mass of the block copolymer.

The polymer containing no block copolymer may be a crosslinkable polymer. Examples of the polymer include polymers of polymerizable compounds such as hydroxystyrene, tris-(2-hydroxyethyl)-isocyanuric acid, and tris-(2-hydroxyethyl)-isocyanuric acid ester (meth)acrylate.

Specific examples of polymerizable compounds (other than those described above) for forming the polymer containing no block copolymer include ethylene glycol di(meth)acrylate, diethylene glycol di(meth)acrylate, triethylene glycol di(meth)acrylate, tetraethylene glycol di(meth)acrylate, nonaethylene glycol di(meth)acrylate, polyethylene glycol di(meth)acrylate, tripropylene glycol di(meth)acrylate, tetrapropylene glycol di(meth)acrylate, nonapropylene glycol di(meth)acrylate, polypropylene glycol di(meth)acrylate, 2,2-bis[4-(acryloxydiethoxy)phenyl]propane, 2,2-bis[4-(methacryloxydiethoxy)phenyl]propane, 3-phenoxy-2-propanoyl acrylate, 1,6-bis(3-acryloxy-2-hydroxypropyl)-hexyl ether, pentaerythritol tri(meth)acrylate, trimethylolpropane tri(meth)acrylate, glycerol tri(meth)acrylate, pentaerythritol tetra(meth)acrylate, dipentaerythritol penta(meth)acrylate, and dipentaerythritol hexa(meth)acrylate.

The polymerizable compound for forming the polymer containing no block copolymer may be a polymerizable compound having an ethylenically unsaturated bond. Examples of the polymerizable compound include a urethane compound that can be prepared by reaction between a polyvalent isocyanate compound and a hydroxyalkyl unsaturated carboxylic acid ester compound, a compound that can be prepared by reaction between a polyvalent epoxy compound and a hydroxyalkyl unsaturated carboxylic acid ester compound, a diallyl ester compound such as diallyl phthalate, and a divinyl compound such as divinyl phthalate.

The polymerizable compound for forming the polymer containing no block copolymer may be a polymerizable compound having a vinyl ether structure. Specific examples of the polymerizable compound include vinyl-2-chloroethyl ether, vinyl-normal butyl ether, 1,4-cyclohexanedimethanol divinyl ether, vinyl glycidyl ether, bis(4-(vinyloxymethyl)cyclohexylmethyl) glutarate, tri(ethylene glycol) divinyl ether, adipic acid divinyl ester, diethylene glycol divinyl ether, tris(4-vinyloxy)butyl trimellitate, bis(4-(vinyloxy)butyl) terephthalate, bis(4-(vinyloxy)butyl isophthalate, ethylene glycol divinyl ether, 1,4-butanediol divinyl ether, tetramethylene glycol divinyl ether, tetraethylene glycol divinyl ether, neopentyl glycol divinyl ether, trimethylolpropane trivinyl ether, trimethylolethane trivinyl ether, hexanediol divinyl ether, 1,4-cyclohexanediol divinyl ether, tetraethylene glycol divinyl ether, pentaerythritol divinyl ether, pentaerythritol trivinyl ether, and cyclohexanedimethanol divinyl ether.

The aforementioned self-assembled film-forming composition may contain a crosslinking agent as an arbitrary component.

Examples of the aforementioned crosslinking agent include nitrogen-containing compounds containing a nitrogen atom substituted with a hydroxymethyl group or alkoxymethyl groups such as a methoxymethyl group, an ethoxymethyl group, a butoxymethyl group, and a hexyloxymethyl group. The crosslinking agent may form a bridge with the block copolymer or the crosslinkable polymer (containing no block copolymer). When the block copolymer does not have a crosslinkable group, the crosslinking agent may form a matrix by self-crosslinking to thereby immobilize the block copolymer.

When the crosslinking agent is used, the amount thereof may be, for example, 1 to 50 parts by mass, or 3 to 50 parts by mass, or 5 to 50 parts by mass, or 10 to 40 parts by mass, or 20 to 30 parts by mass, relative to 100 parts by mass of the block copolymer. The elastic modulus or the step coatability may be controlled by varying the type or amount of the crosslinking agent.

The aforementioned self-assembled film-forming composition may further contain a crosslinking catalyst that generates cations or radicals through thermal baking (heating) to thereby promote the thermal polymerization reaction of the aforementioned self-assembled film. The use of the crosslinking catalyst promotes the reaction of the aforementioned crosslinking agent.

The aforementioned crosslinking catalyst may be any of acid compounds such as p-toluenesulfonic acid, trifluoromethanesulfonic acid, pyridinium-p-toluenesulfonate, salicylic acid, camphorsulfonic acid, sulfosalicylic acid, citric acid, benzoic acid, and hydroxybenzoic acid.

The aforementioned crosslinking catalyst may be an aromatic sulfonic acid compound. Specific examples of the aromatic sulfonic acid compound include p-toluenesulfonic acid, pyridinium-p-toluenesulfonate, sulfosalicylic acid, 4-chlorobenzenesulfonic acid, 4-hydroxybenzenesulfonic acid, benzenedisulfonic acid, 1-naphthalenesulfonic acid, and pyridinium-1-naphthalenesulfonate.

These crosslinking catalysts may be used alone or in combination of two or more species.

The aforementioned crosslinking catalyst may be used in an amount of 0.01 to 10 parts by mass, or 0.05 to 5 parts by mass, or 0.1 to 3 parts by mass, or 0.3 to 2 parts by mass, or 0.5 to 1 part by mass, relative to 100 parts by mass of the block copolymer.

In the aforementioned self-assembled pattern, a predetermined portion of the microphase-separated block copolymer may be preferentially removed by etching. The etching may be performed with, for example, any of gasses such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, and dichloroborane.

A to-be-processed substrate can be provided with a desired fine pattern through etching by utilizing a self-assembled pattern formed from the composition for forming a silicon-containing underlayer film for a self-assembled film according to the present invention, whereby a semiconductor device, etc. can be produced.

### [Semiconductor Device Production Method]

The present invention is also directed to a semiconductor device production method. The production method includes the following steps (1) to (5):

step (1): a step of forming, on a substrate, an underlayer film from the composition for forming a silicon-containing underlayer film for a self-assembled film of the present invention;

step (2): a step of forming a block copolymer-containing layer on the underlayer film;

step (3): a step of phase-separating the block copolymer;

step (4): a step of removing a portion of the phase-separated block copolymer; and

step (5): a step of etching the substrate.

The semiconductor device production method of the present invention may further include, between the steps (2) and (3), a step of forming an upper layer film on the block copolymer-containing layer.

The step (1) is as described above in <Formation of Underlayer Film of Self-Assembled Film> of [Production Method for Substrate Having Self-Assembled Pattern].

The steps (2) and (3) are as described above in <Formation of Self-Assembled Film and Formation of Self-Assembled Pattern>. The aforementioned <self-assembled film> can be read as <block copolymer-containing layer>.

### <Step (4)>

The step (4) is a step of removing a portion of the phase-separated block copolymer.

The layer containing the phase-separated block copolymer has, for example, a plurality of phases containing plural types of blocks constituting the block copolymer. The step (4) involves selective removal of at least one phase of these phases.

The selective removal of a block-containing phase is performed by, for example, a method involving oxygen plasma treatment or hydrogen plasma treatment of the layer containing the phase-separated block copolymer.

The step (4) forms a three-dimensional pattern corresponding to a domain shape from the layer containing the phase-separated block copolymer.

### <Step (5)>

The step (5) is a step of etching the substrate.

The step (5) involves selective etching of the substrate by using the three-dimensional pattern formed through the step (4) as a mask.

The to-be-processed substrate can be provided with a desired pattern through etching by utilizing the three-dimensional pattern formed from the layer containing the phase-separated block copolymer, whereby a suitable semiconductor device can be produced.

The etching may be performed with, for example, a gas such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, or dichloroborane.

A halogen-containing gas is preferably used, and a fluorine-containing gas is more preferably used. Examples of the fluorine-containing gas include tetrafluoromethane (CF₄), perfluorocyclobutane (C₄F₈), perfluoropropane (C₃F₈), trifluoromethane, and difluoromethane (CH₂F₂).

### EXAMPLES

The present invention will next be described in more detail with reference to Examples and Comparative Examples, but the present invention should not be construed as being limited to the following Examples.

The weight average molecular weight (Mw) of each of the polymers shown below in Synthesis Examples is measured by gel permeation chromatography (GPC). The measurement is performed with a GPC apparatus available from Tosoh Corporation under the following conditions.

Measuring apparatus: HLC-8020GPC [trade name] (available from Tosoh Corporation)

GPC columns: TSKgel G2000HXL; two columns, G3000HXL: one column, G4000HXL; one column [trade name] (all are available from Tosoh Corporation)

Column temperature: 40° C.

Solvent: tetrahydrofuran (THF)

Flow rate: 1.0 mL/minute

Standard sample: polystyrene (available from Tosoh Corporation)

### Preparation Example 1: Preparation of Self-Assembled Film-Forming Composition 1

0.5 g of polystyrene/poly(methyl methacrylate) copolymer (block copolymer) (available from POLYMER SOURCE. INC., PS (Mw: 39,800, Mn: 37,500)-b-PMMA (Mw: 19,100, Mn: 18,000), polydispersity=1.06) was dissolved in 24.5 g of propylene glycol monomethyl ether acetate, to thereby prepare a 2% by mass solution. Thereafter, the solution was filtered with a polyethylene-made microfilter (pore size: 0.02 μm), to thereby prepare a self-assembled film-forming composition 1 containing a block copolymer 1.

### Preparation Example 2: Preparation of Self-Assembled Film-Forming Composition 2

The same procedure as in the preparation of the self-assembled film-forming composition 1 was performed, except that polystyrene/poly(methyl methacrylate) copolymer (block copolymer) (available from POLYMER SOURCE. INC., PS (Mw: 39,800, Mn: 37,500)-b-PMMA (Mw: 19,100, Mn: 18,000), polydispersity=1.06) was replaced with polystyrene/poly(methyl methacrylate) copolymer (available from POLYMER SOURCE. INC., PS (Mw: 35,500, Mn: 33,000)-b-PMMA (Mw: 36,400, Mn: 33,000), polydispersity=1.09), and the replaced copolymer was dissolved in 24.5 g of propylene glycol monomethyl ether acetate, to thereby prepare a self-assembled film-forming composition 2.

### Synthesis Example 1: Synthesis of Polymer 1

6.23 g of 2-vinylnaphthalene (ratio by mole to the entire polymer 1:85%), 0.93 g of hydroxyethyl methacrylate (ratio by mole to the entire polymer 1:15%), and 0.36 g of 2,2′-azobisisobutyronitrile were dissolved in 22.50 g of propylene glycol monomethyl ether acetate, and then the solution was heated and stirred at 85° C. for about 24 hours. The resultant reaction liquid was added dropwise to methanol, and the resultant precipitate was recovered by suction filtration, followed by reduced-pressure drying at 60° C., to thereby recover a polymer 1. The polymer 1 was found to have a weight average molecular weight Mw of 6,000 as determined by GPC in terms of polystyrene.

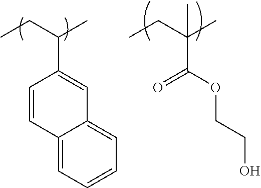

### Synthesis Example 2: Synthesis of Polymer 2

4.77 g of 2-vinylnaphthalene (ratio by mole to the entire polymer 2:60%), 1.34 g of hydroxyethyl methacrylate (ratio by mole to the entire polymer 2:20%), 1.03 g of methyl methacrylate (ratio by mole to the entire polymer 2:20%), and 0.36 g of 2,2′-azobisisobutyronitrile were dissolved in 22.50 g of propylene glycol monomethyl ether acetate, and then the solution was heated and stirred at 85° C. for about 24 hours. The resultant reaction liquid was added dropwise to methanol, and the resultant precipitate was recovered by suction filtration, followed by reduced-pressure drying at 60° C., to thereby recover a polymer 2. The polymer 2 was found to have a weight average molecular weight Mw of 6,000 as determined by GPC in terms of polystyrene.

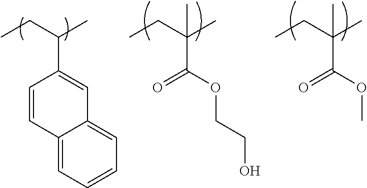

### Synthesis Example 3: Synthesis of Polymer 3

2.57 g of 2-vinylnaphthalene (ratio by mole to the entire polymer 3:50%), 2.06 g of benzyl methacrylate (ratio by mole to the entire polymer 3:35%), 0.72 g of hydroxyethyl methacrylate (ratio by mole to the entire polymer 3:15%), and 0.33 g of 2,2′-azobisisobutyronitrile were dissolved in 22.50 g of propylene glycol monomethyl ether acetate, and then the solution was heated and stirred at 85° C. for about 24 hours. The resultant reaction liquid was added dropwise to methanol, and the resultant precipitate was recovered by suction filtration, followed by reduced-pressure drying at 60° C., to thereby recover a polymer 3. The polymer 3 was found to have a weight average molecular weight Mw of 5,900 as determined by GPC in terms of polystyrene.

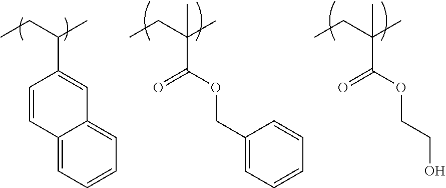

### Synthesis Example 4: Synthesis of Polymer 4

6.13 g of 2-vinylnaphthalene (ratio by mole to the entire polymer 4:85%), 1.01 g of hydroxypropyl methacrylate (ratio by mole to the entire polymer 4:15%), and 0.36 g of 2,2′-azobisisobutyronitrile were dissolved in 22.50 g of propylene glycol monomethyl ether acetate, and then the solution was heated and stirred at 85° C. for about 24 hours. The resultant reaction liquid was added dropwise to methanol, and the resultant precipitate was recovered by suction filtration, followed by reduced-pressure drying at 60° C., to thereby recover a polymer 4. The polymer 4 was found to have a weight average molecular weight Mw of 6,200 as determined by GPC in terms of polystyrene.

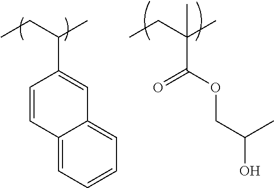

### Synthesis Example 5: Synthesis of Polymer 5

11.00 g of vinylcarbazole (ratio by mole to the entire polymer 5:80%), 1.85 g of hydroxyethyl methacrylate (ratio by mole to the entire polymer 5:20%), and 0.39 g of 2,2′-azobisisobutyronitrile were dissolved in 30.89 g of propylene glycol monomethyl ether acetate, and then the solution was heated and stirred at 85° C. for about 19 hours. The resultant polymer 5 was found to have a weight average molecular weight Mw of 6,950 as determined by GPC in terms of polystyrene.

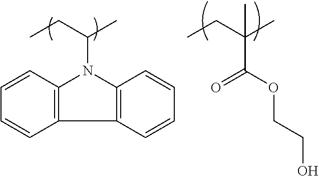

### Synthesis Example 6: Synthesis of Polymer 6

5.00 g of a dicyclopentadiene-type epoxy resin (trade name: EPICLON HP-7200H, available from DIC Corporation), 3.58 g of 4-phenylbenzoic acid, and 0.17 g of ethyltriphenylphosphonium bromide were added to 34.98 g of propylene glycol monomethyl ether, and the resultant mixture was refluxed under heating in a nitrogen atmosphere for 16 hours. The resultant polymer 6 was found to have a weight average molecular weight Mw of 1,800 as determined by GPC in terms of polystyrene.

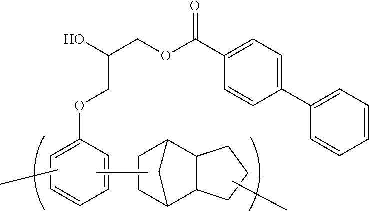

### Synthesis Example 7: Synthesis of Polymer 7

5.50 g of a dicyclopentadiene-type epoxy resin (trade name: EPICLON HP-7200H, available from DIC Corporation), 3.54 g of 4-tert-butylbenzoic acid, and 0.18 g of ethyltriphenylphosphonium bromide were added to 36.89 g of propylene glycol monomethyl ether, and the resultant mixture was refluxed under heating in a nitrogen atmosphere for 15 hours. The resultant polymer 7 was found to have a weight average molecular weight Mw of 2,000 as determined by GPC in terms of polystyrene.

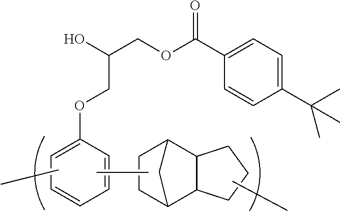

### Synthesis Example 8: Synthesis of Polymer 8

A flask was charged with 35.00 g of carbazole (available from Tokyo Chemical Industry Co., Ltd.), 32.72 g of 1-naphthaldehyde (available from Tokyo Chemical Industry Co., Ltd.), 2.01 g of methanesulfonic acid (available from Tokyo Chemical Industry Co., Ltd., hereinafter abbreviated as “MSA”), and 162.71 g of propylene glycol monomethyl ether acetate (hereinafter abbreviated as “PGMEA”). Thereafter, the resultant mixture was heated to 120° C. in a nitrogen atmosphere, and reaction was allowed to proceed for about seven hours. After termination of the reaction, the reaction mixture was precipitated in methanol, and the precipitate was dried to thereby yield a compound. The compound was found to have a weight average molecular weight Mw of about 2,600 as determined by GPC in terms of polystyrene. The resultant resin was dissolved in PGMEA, and the solution was subjected to ion exchange with a cation-exchange resin and an anion-exchange resin for four hours, to thereby prepare a target compound solution.

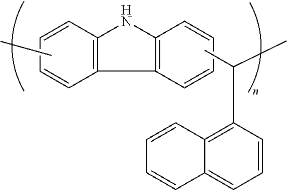

### Synthesis Example 8-1

A flask was charged with 10.0 g of the polymer of Synthesis Example 8, 6.89 g of propargyl bromide (available from Tokyo Chemical Industry Co., Ltd., hereinafter abbreviated as “PBr”), 3.21 g of tetrabutylammonium iodide (available from Tokyo Chemical Industry Co., Ltd., hereinafter abbreviated as “TBAI”), 22.61 g of tetrahydrofuran (hereinafter abbreviated as “THF”), and 7.54 g of 25% aqueous sodium hydroxide solution. Thereafter, the resultant mixture was heated to 55° C. in a nitrogen atmosphere, and reaction was allowed to proceed for about 18 hours. After termination of the reaction, the reaction mixture was repeatedly subjected to a phase separation operation with methyl isobutyl ketone (available from KANTO CHEMICAL CO., INC., hereinafter abbreviated as “MIBK”) and water, and the resultant organic phase was concentrated. The concentrate was redissolved in PGMEA and then reprecipitated in methanol, and the precipitate was dried to thereby yield a compound. The compound was found to have a weight average molecular weight Mw of about 3,000 as determined by GPC in terms of polystyrene. The resultant resin was dissolved in PGMEA, and the solution was subjected to ion exchange with a cation-exchange resin and an anion-exchange resin for four hours, to thereby prepare a target compound solution.

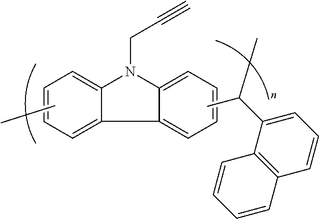

### Synthesis Example 8-2

A flask was charged with 35.00 g of diphenylamine (available from Tokyo Chemical Industry Co., Ltd.), 21.97 g of benzaldehyde (available from Tokyo Chemical Industry Co., Ltd.), 0.60 g of MSA, and 230.25 g of PGMEA. Thereafter, the resultant mixture was heated to 115° C. in a nitrogen atmosphere, and reaction was allowed to proceed for about seven hours. After termination of the reaction, the reaction mixture was precipitated in methanol, and the precipitate was dried to thereby yield a compound. The compound was found to have a weight average molecular weight Mw of about 5,100 as determined by GPC in terms of polystyrene. The resultant resin was dissolved in PGMEA, and the solution was subjected to ion exchange with a cation-exchange resin and an anion-exchange resin for four hours, to thereby prepare a target compound solution.

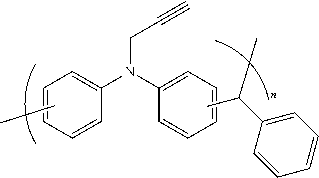

### Synthesis Example 8-3

A flask was charged with 10.00 g of the polymer of Synthesis Example 8-2, 6.97 g of PBr, 2.17 g of TBAI, 21.53 g of THF, and 7.18 g of 25% aqueous sodium hydroxide solution. Thereafter, the resultant mixture was heated to 55° C. in a nitrogen atmosphere, and reaction was allowed to proceed for about 15 hours. After termination of the reaction, the reaction mixture was repeatedly subjected to a phase separation operation with MIBK and water, and the resultant organic phase was concentrated. The concentrate was redissolved in PGMEA and then reprecipitated in methanol, and the precipitate was dried to thereby yield a compound. The compound was found to have a weight average molecular weight Mw of about 6,100 as determined by GPC in terms of polystyrene. The resultant resin was dissolved in PGMEA, and the solution was subjected to ion exchange with a cation-exchange resin and an anion-exchange resin for four hours, to thereby prepare a target compound solution.

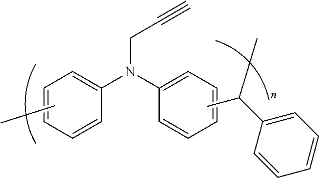

### Synthesis Example 8-4

A flask was charged with 60.00 g of 9,9-bis(4-hydroxyphenyl)fluorene (available from Tokyo Chemical Industry Co., Ltd.), 18.17 g of benzaldehyde (available from Tokyo Chemical Industry Co., Ltd.), 3.29 g of MSA, and 99.56 g of PGMEA. Thereafter, the resultant mixture was heated until reflux in a nitrogen atmosphere, and reaction was allowed to proceed for about four hours. After termination of the reaction, the reaction mixture was diluted with PGMEA and precipitated in water/methanol, and the precipitate was dried to thereby yield a compound. The compound was found to have a weight average molecular weight Mw of about 4,100 as determined by GPC in terms of polystyrene. The resultant resin was dissolved in PGMEA, and the solution was subjected to ion exchange with a cation-exchange resin and an anion-exchange resin for four hours, to thereby prepare a target compound solution.

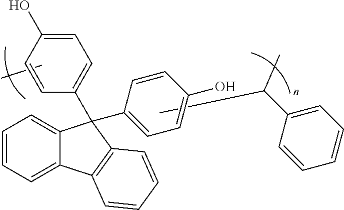

### Synthesis Example 8-5

A flask was charged with 15.00 g of the polymer of Synthesis Example 8-4, 13.57 g of PBr, 6.32 g of TBAB, 39.25 g of THF, and 13.08 g of 25% aqueous sodium hydroxide solution. Thereafter, the resultant mixture was heated to 55° C. in a nitrogen atmosphere, and reaction was allowed to proceed for about 16 hours. After termination of the reaction, the reaction mixture was repeatedly subjected to a phase separation operation with MIBK and water, and the resultant organic phase was concentrated. The concentrate was redissolved in PGMEA and then reprecipitated in water/methanol, and the precipitate was dried to thereby yield a compound. The compound was found to have a weight average molecular weight Mw of about 4,600 as determined by GPC in terms of polystyrene. The resultant resin was dissolved in PGMEA, and the solution was subjected to ion exchange with a cation-exchange resin and an anion-exchange resin for four hours, to thereby prepare a target compound solution.

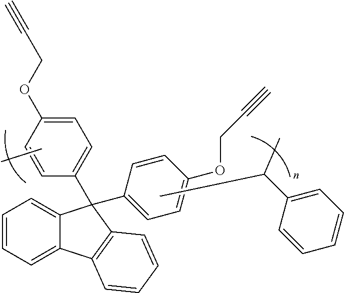

### Synthesis Example 8-6

A flask was charged with 12.50 g of 1,5-dihydroxynaphthalene (available from Tokyo Chemical Industry Co., Ltd.), 5.59 g of formaldehyde (available from Tokyo Chemical Industry Co., Ltd.), 0.35 g of p-toluenesulfonic acid (available from Tokyo Chemical Industry Co., Ltd.), and 77.60 g of propylene glycol monomethyl ether (hereinafter abbreviated as “PGME”). Thereafter, the resultant mixture was heated to 70° C. in a nitrogen atmosphere, and reaction was allowed to proceed for about five hours. The reaction mixture was repeatedly subjected to a phase separation operation with ethyl acetate (available from KANTO CHEMICAL CO., INC.) and water, and the resultant organic phase was concentrated. The concentrate was reprecipitated in water/methanol, and the precipitate was dried to thereby yield a compound. The compound was found to have a weight average molecular weight Mw of about 1,500 as determined by GPC in terms of polystyrene. The resultant resin was dissolved in PGME, and the solution was subjected to ion exchange with a cation-exchange resin and an anion-exchange resin for four hours, to thereby prepare a target compound solution.

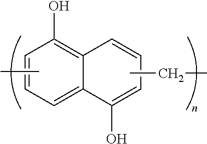

### Synthesis Example 8-7

A flask was charged with 10.00 g of the polymer of Synthesis Example 8-6, 2.20 g of PBr, 1.10 g of potassium carbonate (available from FUJIFILM Wako Pure Chemical Corporation), and 40.0 g of dimethylformamide (available from KANTO CHEMICAL CO., INC.). Thereafter, the resultant mixture was heated to 60° C. in a nitrogen atmosphere, and reaction was allowed to proceed for about five hours. After termination of the reaction, the reaction mixture was repeatedly subjected to a phase separation operation with MIBK and water, and the resultant organic phase was concentrated. The concentrate was reprecipitated in heptane, and the precipitate was dried to thereby yield a compound. The compound was found to have a weight average molecular weight Mw of about 2,700 as determined by GPC in terms of polystyrene. The resultant resin was dissolved in PGMEA, and the solution was subjected to ion exchange with a cation-exchange resin and an anion-exchange resin for four hours, to thereby prepare a target compound solution.

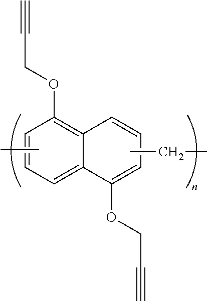

### Synthesis Example 8-8

A flask was charged with 10.00 g of 2,2-biphenol (available from Tokyo Chemical Industry Co., Ltd.), 9.68 g of fluorenone (available from Tokyo Chemical Industry Co., Ltd.), 1.29 g of MSA, and 20.97 g of PGMEA. Thereafter, the resultant mixture was heated to 150° C. in a nitrogen atmosphere, and reaction was allowed to proceed for about 12.5 hours. After termination of the reaction, the reaction mixture was precipitated in methanol, and the precipitate was dried to thereby yield a compound. The compound was found to have a weight average molecular weight Mw of about 1,900 as determined by GPC in terms of polystyrene. The resultant resin was dissolved in PGMEA, and the solution was subjected to ion exchange with a cation-exchange resin and an anion-exchange resin for four hours, to thereby prepare a target compound solution.

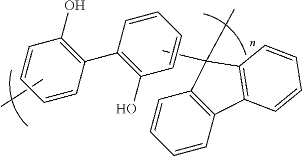

### Synthesis Example 8-9

A flask was charged with 7.91 g of dicyclopentadiene (available from Tokyo Chemical Industry Co., Ltd.), 10.00 g of carbazole, 18.00 g of PGMEA, and 0.09 g of trifluoromethanesulfonic acid (available from Tokyo Chemical Industry Co., Ltd.). Thereafter, the resultant mixture was heated to 150° C. and stirred under reflux for about 12 hours. After completion of the reaction, the solution was precipitated in methanol, and the precipitate was dried to thereby yield a compound. The compound was found to have a weight average molecular weight Mw of 3,000 as determined by GPC in terms of polystyrene. The resultant resin was dissolved in PGMEA, and the solution was subjected to ion exchange with a cation-exchange resin and an anion-exchange resin for four hours, to thereby prepare a target compound solution.

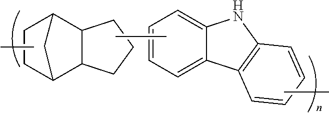

### Synthesis Example 8-10

A flask was charged with 50.0 g of 1,1,1-tris(4-hydroxyphenyl)ethane (available from Tokyo Chemical Industry Co., Ltd.), 35.6 g of 4,4-difluorobenzophenone (available from Tokyo Chemical Industry Co., Ltd.), 31.37 g of potassium carbonate, and 272.9 g of N-methyl-2-pyrrolidone (available from KANTO CHEMICAL CO., INC.). Thereafter, the resultant mixture was heated to 150° C. and stirred for about 2.5 hours. After completion of the reaction, the reaction mixture was diluted with 180.8 g of N-methyl-2-pyrrolidone, and potassium carbonate was removed by filtration. The resultant filtrate was neutralized by addition of 1N—HCl, and then the mixture was stirred for a while. The thus-diluted mixture was reprecipitated in methanol/water, and the precipitate was dried to thereby yield a compound. The compound was found to have a weight average molecular weight Mw of 2,900 as determined by GPC in terms of polystyrene. The resultant resin was dissolved in PGMEA, and the solution was subjected to ion exchange with a cation-exchange resin and an anion-exchange resin for four hours, to thereby prepare a target compound solution.

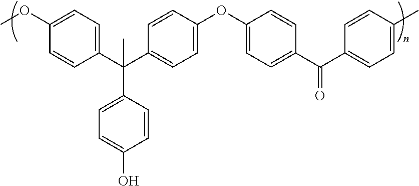

### Synthesis Example 8-11

A flask was charged with 72.46 g of PGMEA, 26.00 g of RE810-NM (available from Nippon Kayaku Co., Ltd.), 20.81 g of BPA-CA (available from Konishi Chemical Ind. Co., Ltd.), 2.18 g of ethyltriphenylphosphonium bromide (available from Hokko Chemical Industry Co., Ltd.), and 0.32 g of hydroquinone (available from Tokyo Chemical Industry Co., Ltd.), and then reaction was allowed to proceed at 140° C. for 24 hours, to thereby yield a solution containing a reaction product. The reaction product was found to have a weight average molecular weight Mw of 18,000 as determined by GPC in terms of polystyrene. The reaction product was diluted with PGME, and then subjected to ion exchange with a cation-exchange resin and an anion-exchange resin for four hours, to thereby prepare a target compound solution.

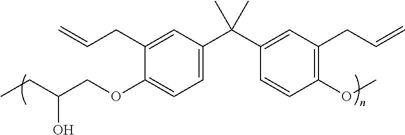

### Synthesis Example 8-12

A flask was charged with 8.74 g of 3,7-dihydroxy-2-naphthoic acid, 10.00 g of NC-7300L (available from Nippon Kayaku Co., Ltd.), 0.40 g of ethyltriphenylphosphonium bromide, and 44.7 g of PGME. Thereafter, the resultant mixture was heated to 120° C., and reaction was allowed to proceed for about 18 hours, to thereby yield a solution containing a reaction product. The reaction product was found to have a weight average molecular weight Mw of 1,100 as determined by GPC in terms of polystyrene. The reaction product was diluted with PGME, and then subjected to ion exchange with a cation-exchange resin and an anion-exchange resin for four hours, to thereby prepare a target compound solution.

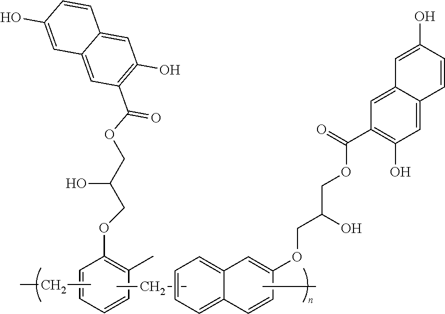

### Synthesis Example 8-13

40.00 g of YX4000 (available from Mitsubishi Chemical Corporation), 19.54 g of Cis-1,2-cyclohexanedicarboxylic acid (available from Tokyo Chemical Industry Co., Ltd.), and 4.01 g of ethyltriphenylphosphonium bromide were added to 148.30 g of PGME, and then reaction was allowed to proceed at 140° C. for 24 hours, to thereby yield a solution containing a reaction product. The reaction product was found to have a weight average molecular weight Mw of 2,000 as determined by GPC in terms of polystyrene. The reaction product was diluted with PGME, and then subjected to ion exchange with a cation-exchange resin and an anion-exchange resin for four hours, to thereby prepare a target compound solution.

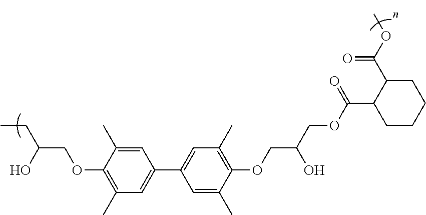

### Synthesis Example 8-14

10.00 g of EPICLON HP-4700 (available from DIC Corporation), 4.37 g of acrylic acid (available from Tokyo Chemical Industry Co.. Ltd.). 0.56 g of ethyltriphenylphosphonium bromide, and 0.03 g of hydroquinone were added to 34.91 g of PGME, and reaction was allowed to proceed at 100° C. for 21 hours in a nitrogen atmosphere, to thereby yield a solution containing a reaction product. The reaction product was found to have a weight average molecular weight Mw of 1,400 as determined by GPC in terms of polystyrene. The reaction product was subjected to ion exchange with a cation-exchange resin and an anion-exchange resin for four hours, to thereby prepare a target compound solution.

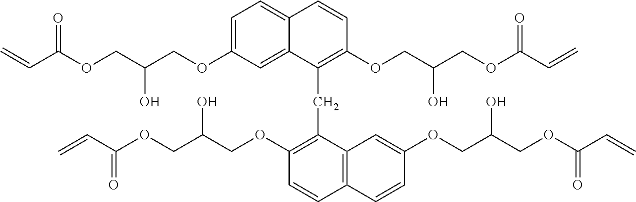 [SMILES: C=CC(=O)OCC(O)COc1ccc2ccc(OCC(O)COC(=O)C=C)c(Cc3c(OCC(O)COC(=O)C=C)ccc4ccc(OCC(O)COC(=O)C=C)cc34)c2c1]

### Synthesis Example 8-15

A flask was charged with 260.00 g of TMOM-BP (available from Honshu Chemical Industry Co., Ltd.) and 1,430 g of PGME. Thereafter, the mixture was heated to about 90° C. in a nitrogen atmosphere, and a solution of 17.26 g of MSA in 130.00 g of PGME was added dropwise to the mixture. After the elapse of about 45 hours, the resultant reaction mixture was precipitated in methanol and water, and the precipitate was dried to thereby yield a compound. The compound was found to have a weight average molecular weight Mw of about 4,500 as determined by GPC in terms of polystyrene. The introduction of PGME was determined by ¹H-NMR. The resultant resin was dissolved in PGMEA, and the solution was subjected to ion exchange with a cation-exchange resin and an anion-exchange resin for four hours, to thereby prepare a target polymer solution.

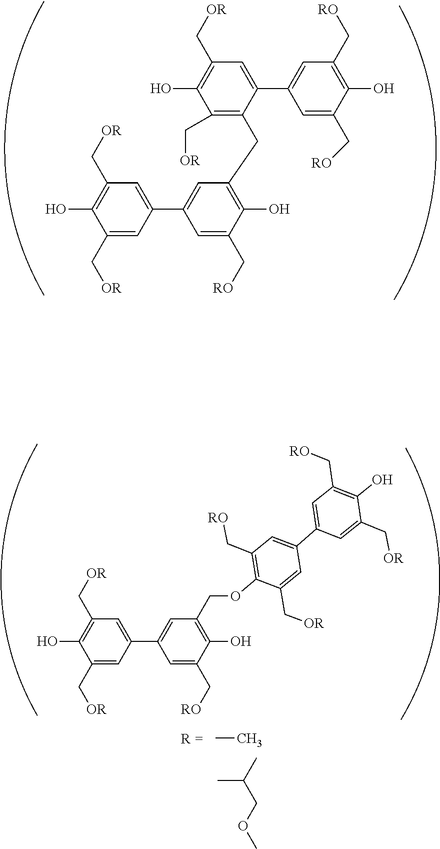

### Synthesis Example 8-16

4.00 g of 4-hydroxyphenylmethacrylamide, 5.80 g of γ-butyrolactone methacrylate (available from OSAKA ORGANIC CHEMICAL INDUSTRY LTD.), 9.90 g of benzyl methacrylate (available from Tokyo Chemical Industry Co., Ltd.), and 1.40 g of 2,2′-azobisisobutyronitrile (available from Tokyo Chemical Industry Co., Ltd.) were added to and dissolved in 190.0 g of PGME, and then the solution was heated and stirred at 85° C. for about 15 hours. After completion of the reaction, the resultant reaction mixture was precipitated in ethyl acetate/hexane, and the precipitate was dried to thereby yield a compound. The compound was found to have a weight average molecular weight Mw of about 6,000 as determined by GPC in terms of polystyrene. The resultant resin was dissolved in PGME, and the solution was subjected to ion exchange with a cation-exchange resin and an anion-exchange resin for four hours, to thereby prepare a target polymer solution.

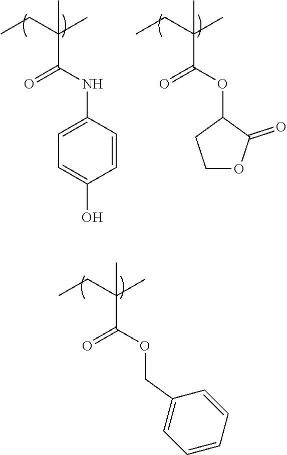

### Synthesis Example 9: Synthesis of Polymer 9

A 500-mL flask was charged with 4.94 g of phenyltrimethoxysilane, 71.58 g of tetraethoxysilane, 22.20 g of methyltriethoxysilane, 1.20 g of methoxybenzyltrimethoxysilane, 0.68 g of triethoxysilylpropyl-4,5-dihydroimidazole, and 150 g of acetone, and these materials were mixed for dissolution. While the resultant mixed solution was stirred with a magnetic stirrer, the mixed solution was heated and refluxed. Subsequently, an aqueous solution of 0.31 g of nitric acid dissolved in 33.09 g of ultrapure water was added to the mixed solution. Reaction was allowed to proceed for 240 minutes, and then the resultant reaction solution was cooled to room temperature. Thereafter, 200 g of propylene glycol monoethyl ether was added to the reaction solution, and ethanol and methanol (i.e., reaction by-products), acetone, water, and nitric acid were distilled off under reduced pressure, to thereby yield a hydrolysis condensate (polymer 9) solution.

The resultant polymer 9 was found to be a polysiloxane containing siloxane unit structures of the following Formula, wherein the amount of a siloxane unit structure having a cyclic amino group was 0.50% by mole relative to the entire siloxane unit structures. The polymer was found to have a weight average molecular weight Mw of 2,200 as determined by GPC in terms of polystyrene.

The solvent was removed from the hydrolysis condensate solution at 140° C., and the resultant residue was defined as a solid content. Propylene glycol monoethyl ether was added to the residue for adjustment of the concentration, to thereby prepare a 15% by mass solution.

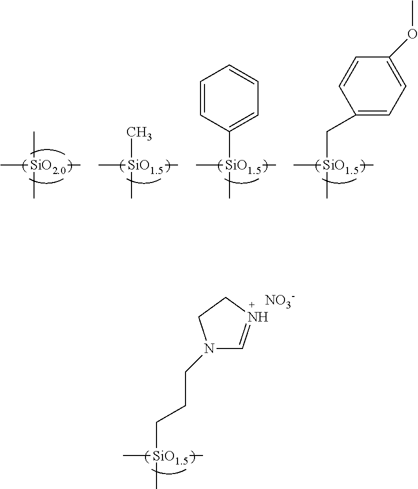

### Synthesis Example 10: Synthesis of Polymer 10

A 500-mL flask was charged with 4.9 g of phenyltrimethoxysilane, 71.6 g of tetraethoxysilane, 22.2 g of methyltriethoxysilane, 1.2 g of methoxybenzyltrimethoxysilane, and 150 g of acetone. While the resultant mixed solution was stirred with a magnetic stirrer, 33.1 g of 0.01 mol/L hydrochloric acid was added dropwise to the mixed solution.

After completion of the dropwise addition, the flask was transferred to an oil bath set at 85° C., and reaction was allowed to proceed under reflux with heating for four hours. Thereafter, the reaction solution was cooled to room temperature, and 200 g of propylene glycol monomethyl ether acetate was added to the reaction solution. Methanol (i.e., reaction by-product), ethanol, water, and hydrochloric acid were distilled off under reduced pressure, and the residue was concentrated, to thereby yield a hydrolysis condensate (polymer 10) solution.

Propylene glycol monoethyl ether was added to the solution so that the solvent ratio of propylene glycol monomethyl ether acetate/propylene glycol monoethyl ether was adjusted to 20/80.

The resultant polymer 10 was found to contain a polysiloxane having a structure of the following Formula, and to have a weight average molecular weight Mw of 2,200 as determined by GPC in terms of polystyrene.

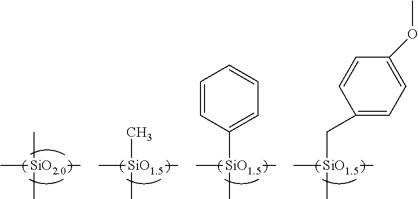

### <Preparation of Neutral Film-Forming Composition 1>

0.39 g of the polymer 1 produced in Synthesis Example 1 was mixed with 0.10 g of tetramethoxymethyl glycoluril (PL-LI) and 0.05 g of pyridinium-p-toluenesulfonate (Py-PTS), and then 69.65 g of propylene glycol monomethyl ether acetate (PGMEA) and 29.37 g of propylene glycol monomethyl ether (PGME) were added to and dissolved in the mixture. Thereafter, the resultant solution was filtered with a polyethylene-made microfilter (pore size: 0.02 m), to thereby prepare a neutral film-forming composition 1.

### <Preparation of Neutral Film-Forming Compositions 2 to 7>

The same procedure as in the preparation of the neutral film-forming composition 1 was performed, except that the polymer 1 produced in Synthesis Example 1 was replaced with the polymers 2 to 7 produced in Synthesis Examples 2 to 7, to thereby prepare neutral film-forming compositions 2 to 7.

### <Preparation of Silicon-Containing Underlayer Film-Forming Composition 1>

1.33 g of the polymer 10 produced in Synthesis Example 10 was mixed with 0.006 g of maleic acid (MA) and 0.0012 g of benzyltriethylammonium chloride (BTEAC), and then 0.68 g of propylene glycol monomethyl ether acetate (PGMEA), 0.79 g of propylene glycol monomethyl ether (PGME), 9.10 g of 1-ethoxy-2-propanol (PGEE), and 1.30 g of ultrapure water (DIW) were added to and dissolved in the mixture. Thereafter, the resultant solution was filtered with a fluororesin-made microfilter (pore size: 0.1 m), to thereby prepare a silicon-containing underlayer film-forming composition.

### <Preparation of Silicon-Containing Underlayer Film-Forming Compositions 2 and 3>

The same procedure as in the preparation of the silicon-containing underlayer film-forming composition 1 was performed, except that benzyltriethylammonium chloride (BTEAC) was replaced with triethoxysilylpropyl-4,5-dihydroimidazole (IMIDTOES) or triphenylsulfonium nitrate (TPSNO3) as shown in Table 1, to thereby prepare silicon-containing underlayer film-forming compositions 2 and 3.

TABLE 1

| | Polymer | Additive 1 | Additive 2 | Solvent | | | |
|---|---|---|---|---|---|---|---|
| Si composition 1 | Synthesis | MA | BTEAC | PGMEA | PGME | PGEE | DIW |
| | Example 10 | | | | | | |
| (g) | 1.33 | 0.006 | 0.0024 | 0.68 | 0.79 | 9.10 | 1.30 |
| Si composition 2 | Synthesis | MA | IMIDTOES | PGMEA | PGME | PGEE | DIW |
| | Example 10 | | | | | | |
| (g) | 1.33 | 0.006 | 0.0020 | 0.68 | 0.79 | 9.10 | 1.30 |
| Si composition 3 | Synthesis | MA | TPSNO3 | PGMEA | PGME | PGEE | DIW |
| | Example 10 | | | | | | |
| (g) | 1.33 | 0.006 | 0.0040 | 0.68 | 0.79 | 9.10 | 1.30 |

### <Preparation of Brush Film-Forming Composition>

0.3 g of a hydroxyl-terminated polystyrene polymer (available from POLYMER SOURCE. INC., PS (Mw: 10,000, Mn: 9,430, polydispersity=1.06)), serving as a brush material polymer, was dissolved in 29.7 g of propylene glycol monomethyl ether acetate to thereby prepare a 1% by mass solution. Thereafter, the solution was filtered with a polyethylene-made microfilter (pore size: 0.02 m), to thereby prepare a brush film-forming composition containing a brush polymer 1.

### <Preparation of Organic Underlayer Film-Forming Composition>

Each of the polymers produced in Synthesis Examples 8 to 8-16, tetramethoxymethyl glycoluril (trade name: Powderlink 1174 (PL-LI), available from Cytec Industries Japan LLC (former Mitsui Cytec Ltd.)) or 3,3′,5,5′-tetrakis(methoxymethyl)-[1,1′-biphenyl]-4,4′-diol (trade name: TMOM-BP, available from Honshu Chemical Industry Co., Ltd.) serving as a crosslinking agent, pyridinium p-toluenesulfonate (Py-PTS), pyridinium p-phenolsulfonate (Py-PSA), or trifluoromethanesulfonic acid quaternary ammonium salt (trade name: TAG-2689, available from King Industries, Inc.) serving as a catalyst, and MEGAFACE R-30 (trade name, available from DIC Corporation) serving as a surfactant were mixed in proportions shown in Table 2, and the resultant mixture was dissolved in a mixed solvent of propylene glycol monomethyl ether acetate/propylene glycol monomethyl ether/CYH (cyclohexanone)=6/2/2 (vol/vol/vol) or a mixed solvent of PGME/PGME=7/3 (vol/vol), to thereby prepare a solution. Thereafter, the solution was filtered with a polyethylene-made microfilter (pore size: 0.10 μm) and then further filtered with a polyethylene-made microfilter (pore size: 0.05 m), to thereby prepare organic underlayer film-forming compositions (SOC compositions) 1 to 18.

TABLE 2

| | | | | | Solvent (total: 100 | | |
|---|---|---|---|---|---|---|---|
| (Parts by mass) | Polymer | Additive 1 | Additive 2 | Additive 3 | parts by mass) | | |
| SOC | Synthesis | PL-LI | Py-PTS | Surfactant | PGMEA | PGME | CYH |
| composition 1 | Example 8 | | | | | | |
| | 100 | 15 | 1.5 | 0.1 | 60 | 20 | 20 |
| SOC | Synthesis | PL-LI | Py-PTS | Surfactant | PGMEA | PGME | |
| composition 2 | Example 8-1 | | | | | | |
| | 100 | 20 | 3.0 | 0.1 | 70 | 30 | |
| SOC | Synthesis | TMOM-BP | Py-PSA | Surfactant | PGMEA | PGME | |
| composition 3 | Example 8-2 | | | | | | |
| | 100 | 20 | 3.0 | 0.1 | 70 | 30 | |
| SOC | Synthesis | PL-LI | Py-PTS | Surfactant | PGMEA | PGME | |
| composition 4 | Example 8-3 | | | | | | |
| | 100 | 20 | 3.0 | 0.1 | 70 | 30 | |
| SOC | Synthesis | TMOM-BP | Py-PSA | Surfactant | PGMEA | PGME | |
| composition 5 | Example 8-4 | | | | | | |
| | 100 | 20 | 3.0 | 0.1 | 70 | 30 | |
| SOC | Synthesis | PL-LI | Py-PTS | Surfactant | PGMEA | PGME | |
| composition 6 | Example 8-5 | | | | | | |
| | 100 | 20 | 3.0 | 0.1 | 70 | 30 | |
| SOC | Synthesis | PL-LI | Py-PTS | Surfactant | PGMEA | PGME | |
| composition 7 | Example 8-6 | | | | | | |
| | 100 | 20 | 3.0 | 0.1 | 30 | 70 | |
| SOC | Synthesis | PL-LI | Py-PTS | Surfactant | PGMEA | PGME | |
| composition 8 | Example 8-7 | | | | | | |
| | 100 | 20 | 3.0 | 0.1 | 70 | 30 | |
| SOC | Synthesis | PL-LI | Py-PTS | Surfactant | PGMEA | PGME | |
| composition 9 | Example 8-8 | | | | | | |
| | 100 | 20 | 3.0 | 0.1 | 70 | 30 | |
| SOC | Synthesis | PL-LI | Py-PTS | Surfactant | PGMEA | PGME | |
| composition 10 | Example 8-9 | | | | | | |
| | 100 | 20 | 3.0 | 0.1 | 70 | 30 | |
| SOC | Synthesis | PL-LI | Py-PTS | Surfactant | PGMEA | PGME | |
| composition 11 | Example 8-10 | | | | | | |
| | 100 | 20 | 3.0 | 0.1 | 70 | 30 | |
| SOC | Synthesis | PL-LI | Py-PTS | Surfactant | PGMEA | PGME | |
| composition 12 | Example 8-11 | | | | | | |
| | 100 | 20 | 3.0 | 0.1 | 30 | 70 | |
| SOC | Synthesis | PL-LI | Py-PTS | Surfactant | PGMEA | PGME | |
| composition 13 | Example 8-12 | | | | | | |
| | 100 | 20 | 3.0 | 0.1 | 30 | 70 | |
| SOC | Synthesis | PL-LI | Py-PTS | Surfactant | PGMEA | PGME | |
| composition 14 | Example 8-13 | | | | | | |
| | 100 | 20 | 3.0 | 0.1 | 30 | 70 | |
| SOC | Synthesis | PL-LI | Py-PTS | Surfactant | PGMEA | PGME | |
| composition 15 | Example 8-14 | | | | | | |
| | 100 | 20 | 3.0 | 0.1 | 30 | 70 | |
| SOC | Synthesis | — | — | Surfactant | PGMEA | PGME | |
| composition 16 | Example 8-15 | | | | | | |
| | 100 | — | — | 0.1 | 70 | 30 | |
| SOC | Synthesis | TMOM-BP | TAG2689 | Surfactant | PGMEA | PGME | |
| composition 17 | Example 8-16 | | | | | | |
| | 100 | 20.0 | 3.0 | 0.1 | 70 | 30 | |
| SOC | Synthesis | PL-LI | Py-PTS | Surfactant | PGMEA | PGME | |
| composition 18 | Example 8-16 | | | | | | |
| | 100 | 20 | 3.0 | 0.1 | 30 | 70 | |

### <Evaluation of Self-Assembly of Block Copolymer>

As described below, the self-assembly (microphase separation) of a self-assembled film (block copolymer-containing layer) was evaluated by a simulation process of the production method for a substrate having a self-assembled pattern.

### Example A

The above-prepared silicon-containing underlayer film-forming composition 1 was applied onto a silicon wafer and heated on a hot plate at 240° C. for one minute, to thereby form an underlayer film having a thickness of 15 to 25 nm.

The neutral film-forming composition 1 was applied onto the underlayer film and heated on a hot plate at 240° C. for one minute, to thereby form a neutral film having a thickness of 5 to 10 nm. The entire surface of the neutral film was exposed to light with an ArF exposure apparatus (Nikon) under predetermined conditions. After the light exposure, baking (PEB) was performed at 100° C. for 60 seconds. Subsequently, the neutral film was cooled to room temperature on a cooling plate, and then subjected to immersion treatment (development with no pattern) with butyl acetate and NMD-3 (tetramethylammonium hydroxide-based developer, available from TOKYO OHKA KOGYO CO., LTD.).

Thereafter, the brush film-forming composition was applied onto the thus-treated film and heated on a hot plate at 200° C. for two minutes, to thereby form a film. Subsequently, the film was cooled to room temperature on a cooling plate, and the formed film (unreacted brush film-forming composition) was removed with OK73 Thinner (mixed solution of propylene glycol monomethyl ether and propylene glycol monomethyl ether acetate, available from TOKYO OHKA KOGYO CO., LTD.).

The self-assembled film-forming composition 1 containing the block copolymer 1 was applied onto the brush film with a spin coater, and the composition was heated on a hot plate at 260° C. for five minutes in a nitrogen atmosphere, to thereby induce a microphase-separated structure of a self-assembled film having a thickness of 40 nm.

### <Observation of Microphase-Separated Structure>

The silicon wafer provided with the induced microphase-separated structure was subjected to etching for three seconds with an etching apparatus (Lam 2300 Versys Kiyo45) available from Lam Research Co., Ltd. using O₂/N₂ gas serving as an etching gas, to thereby preferentially etch a poly(methyl methacrylate) region. Subsequently, the shape of the etched product was observed with an electron microscope (critical dimension scanning electron microscope CG-4100, available from Hitachi High-Tech Corporation).

### Example B

The same procedure as in Example A was performed, except that the silicon-containing underlayer film-forming composition 1 was replaced with the silicon-containing underlayer film-forming composition 2, to thereby induce a microphase-separated structure of a self-assembled film and to observe the microphase-separated structure.

### Comparative Example A

The same procedure as in Example A was performed, except that the silicon-containing underlayer film-forming composition 1 was replaced with the silicon-containing underlayer film-forming composition 3, to thereby induce a microphase-separated structure of a self-assembled film and to observe the microphase-separated structure.

### Referential Example

The same procedure as in Example 1 was performed, except that the silicon-containing underlayer film-forming composition 1 was not used, and the neutral film-forming composition 1 was applied directly onto a silicon wafer, to thereby induce a microphase-separated structure of a self-assembled film and to observe the microphase-separated structure.

### <Determination of Alignment of Block Copolymer>

The block copolymer (BC) in each of Examples A and B, Comparative Example A, and Referential Example described above was determined for its alignment. The results are shown in Table 3. FIG. 2 shows micrographs (magnification: 200 K) in Examples A and B and Comparative Example A.

TABLE 3

| | Silicon-containing underlayer | | |
|---|---|---|---|
| | film-forming composition | BC alignment | |
| Example A | Si composition 1 (BTEAC) | Vertical | Perpendicular |
| | | alignment | alignment |
| Example B | Si composition 2 | Vertical | Perpendicular |
| | (IMIDTOES) | alignment | alignment |
| Comparative | Si composition 3 (TPSNO3) | Horizontal | Misalignment |
| Example A | | alignment | |
| Referential | None | Vertical | Perpendicular |
| Example | | alignment | alignment |

### Examples C1 to C18

Each of the above-prepared organic underlayer film-forming compositions (SOC compositions) 1 to 18 was applied onto a silicon wafer and heated on a hot plate at 240° C. for one minute, to thereby form an organic underlayer film having a thickness of 55 to 65 nm.

The above-prepared silicon-containing underlayer film-forming composition 1 was applied onto the organic underlayer film and heated on a hot plate at 240° C. for one minute, to thereby form an underlayer film having a thickness of 15 to 25 nm.

The neutral film-forming composition 1 was applied onto the underlayer film and heated on a hot plate at 240° C. for one minute, to thereby form a neutral film having a thickness of 5 to 10 nm. The entire surface of the neutral film was exposed to light with an ArF exposure apparatus (Nikon) under predetermined conditions. After the light exposure, baking (PEB) was performed at 100° C. for 60 seconds. Subsequently, the neutral film was cooled to room temperature on a cooling plate, and then developed with butyl acetate and NMD-3 (tetramethylammonium hydroxide-based developer, available from TOKYO OHKA KOGYO CO., LTD.).

Thereafter, the brush film-forming composition was applied onto the thus-treated film and heated on a hot plate at 200° C. for two minutes, and then cooled to room temperature on a cooling plate. Subsequently, the unreacted brush film-forming composition was removed with OK73 Thinner (mixed solution of propylene glycol monomethyl ether and propylene glycol monomethyl ether acetate, available from TOKYO OHKA KOGYG CO., LTD.).

The self-assembled film-forming composition 1 containing the block copolymer 1 was applied onto the brush film with a spin coater, and the composition was heated on a hot plate at 260° C. for five minutes in a nitrogen atmosphere, to thereby induce a microphase-separated structure of a self-assembled film having a thickness of 40 nm.

Thereafter, the microphase-separated structure was observed through the same procedure as in Example A. The results are shown in Table 4.

TABLE 4

| | Organic underlayer | Silicon-containing | | |
|---|---|---|---|---|
| | film-forming | underlayer film-forming | | |
| | composition | composition | BC alignment | |
| Example C-1 | SOC composition 1 | Si composition 1 (BTEAC) | Vertical | Perpendicular |
| | | | alignment | alignment |
| Example C-2 | SOC composition 2 | Si composition 1 (BTEAC) | Vertical | Perpendicular |
| | | | alignment | alignment |
| Example C-3 | SOC composition 3 | Si composition 1 (BTEAC) | Vertical | Perpendicular |
| | | | alignment | alignment |
| Example C-4 | SOC composition 4 | Si composition 1 (BTEAC) | Vertical | Perpendicular |
| | | | alignment | alignment |
| Example C-5 | SOC composition 5 | Si composition 1 (BTEAC) | Vertical | Perpendicular |
| | | | alignment | alignment |
| Example C-6 | SOC composition 6 | Si composition 1 (BTEAC) | Vertical | Perpendicular |
| | | | alignment | alignment |
| Example C-7 | SOC composition 7 | Si composition 1 (BTEAC) | Vertical | Perpendicular |
| | | | alignment | alignment |
| Example C-8 | SOC composition 8 | Si composition 1 (BTEAC) | Vertical | Perpendicular |
| | | | alignment | alignment |
| Example C-9 | SOC composition 9 | Si composition 1 (BTEAC) | Vertical | Perpendicular |
| | | | alignment | alignment |
| Example C-10 | SOC composition 10 | Si composition 1 (BTEAC) | Vertical | Perpendicular |
| | | | alignment | alignment |
| Example C-11 | SOC composition 11 | Si composition 1 (BTEAC) | Vertical | Perpendicular |
| | | | alignment | alignment |
| Example C-12 | SOC composition 12 | Si composition 1 (BTEAC) | Vertical | Perpendicular |
| | | | alignment | alignment |
| Example C-13 | SOC composition 13 | Si composition 1 (BTEAC) | Vertical | Perpendicular |
| | | | alignment | alignment |
| Example C-14 | SOC composition 14 | Si composition 1 (BTEAC) | Vertical | Perpendicular |
| | | | alignment | alignment |
| Example C-15 | SOC composition 15 | Si composition 1 (BTEAC) | Vertical | Perpendicular |
| | | | alignment | alignment |
| Example C-16 | SOC composition 16 | Si composition 1 (BTEAC) | Vertical | Perpendicular |
| | | | alignment | alignment |
| Example C-17 | SOC composition 17 | Si composition 1 (BTEAC) | Vertical | Perpendicular |
| | | | alignment | alignment |
| Example C-18 | SOC composition 18 | Si composition 1 (BTEAC) | Vertical | Perpendicular |
| | | | alignment | alignment |
| Example A | — | Si composition 1 (BTEAC) | Vertical | Perpendicular |
| (re-described) | | | alignment | alignment |

As shown in Table 3, in Examples A and B, intended vertical alignment (i.e., alignment perpendicular to the horizontal plane of the substrate) of the block copolymer was achieved as in the case of Referential Example wherein the silicon-containing underlayer film was not provided. As shown in Table 4, in Examples C-1 to C-18 wherein the organic underlayer film was provided below the silicon-containing underlayer film, intended vertical alignment of the block copolymer was achieved as in the case of Example A.

In contrast, in the case where the underlayer film containing a strongly acidic additive (photoacid generator) was formed (Comparative Example A), horizontal alignment (i.e., alignment parallel to the horizontal plane of the substrate) of the block copolymer was occurred, resulting in misalignment. The results indicated that the underlayer film containing no strongly acidic additive does not affect the alignment of the block copolymer, and achieves intended alignment thereof.

The above-described results indicated that when an underlayer film for a self-assembled film formed from the composition for forming a silicon-containing underlayer film for a self-assembled film of the present invention is provided below a neutral film (and a brush film) for inducing microphase separation, intended vertical alignment of a block copolymer can be induced without inhibiting the performance of the neutral film.

### INDUSTRIAL APPLICABILITY

According to the present invention, the microphase-separated structure of a layer containing a block copolymer can be induced over the entire surface of a coating film in a direction perpendicular to a substrate without causing misalignment of the microphase-separated block copolymer. Thus, the present invention is very useful in industry.

### DESCRIPTION OF THE REFERENCE NUMERALS

1: Underlayer film (silicon-containing underlayer film)
2: Neutral film (NL film)
3: Resist pattern
4: Brush film
5: Template film
6: Self-assembled film

1. A composition for forming a silicon-containing underlayer film for a self-assembled film, the composition comprising:
[A] a polysiloxane; and
[B] a solvent, but not comprising a strongly acidic additive.

2. The composition for forming a silicon-containing underlayer film for a self-assembled film according to claim 1, wherein the strongly acidic additive is a strongly acidic additive having a first acid dissociation constant of 1 or less in water.

3. The composition for forming a silicon-containing underlayer film for a self-assembled film according to claim 1, wherein the strongly acidic additive is an acid generator.

4. The composition for forming a silicon-containing underlayer film for a self-assembled film according to claim 1, wherein the strongly acidic additive is a photoacid generator.

5. The composition for forming a silicon-containing underlayer film for a self-assembled film according to claim 1, wherein the composition is used for forming a self-assembled pattern.

6. The composition for forming a silicon-containing underlayer film for a self-assembled film according to claim 1, wherein the polysiloxane [A] contains at least one selected from the group consisting of a hydrolysis condensate of a hydrolyzable silane containing at least one hydrolyzable silane of the following Formula (1):
R¹ₐSi(R²)₄₋ₐ (1)
(wherein R¹ is a group bonded to a silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, an amide group, an alkoxy group, a sulfonyl group, or a cyano group, or any combination of these; R² is a group or atom bonded to a silicon atom, and is each independently an alkoxy group, an aralkyloxy group, an acyloxy group, or a halogen atom; and a is an integer of 0 to 3), a modified hydrolysis condensate prepared by modification of at least some of silanol groups of the condensate of the hydrolyzable silane with an alcohol, a modified hydrolysis condensate prepared by protection of at least some of silanol groups of the condensate of the hydrolyzable silane with an acetal, and a product prepared by dehydration reaction between the condensate of the hydrolyzable silane and an alcohol.

7. The composition for forming a silicon-containing underlayer film for a self-assembled film according to claim 1, wherein the composition further comprises a pH adjuster.

8. The composition for forming a silicon-containing underlayer film for a self-assembled film according to claim 1, wherein the composition further comprises a surfactant.

9. A production method for a substrate having a self-assembled pattern, the production method comprising:
a step of forming, on a substrate, an underlayer film for a self-assembled film from a composition for forming a silicon-containing underlayer film for a self-assembled film; and
a step of forming a self-assembled film above the underlayer film to thereby form a self-assembled pattern, wherein:
the composition for forming a silicon-containing underlayer film for a self-assembled film contains [A] a polysiloxane and [B] a solvent, but does not contain a strongly acidic additive.

10. A production method for a substrate having a self-assembled pattern, the production method comprising:
a step of forming, on a substrate, an underlayer film for a self-assembled film from a composition for forming a silicon-containing underlayer film for a self-assembled film;
a step of forming a neutral film on the underlayer film for a self-assembled film; and
a step of forming a self-assembled film on the neutral film to thereby form a self-assembled pattern, wherein:
the composition for forming a silicon-containing underlayer film for a self-assembled film contains [A] a polysiloxane and [B] a solvent, but does not contain a strongly acidic additive.

11. A production method for a substrate having a self-assembled pattern, the production method comprising:
a step of forming, on a substrate, an underlayer film for a self-assembled film from a composition for forming a silicon-containing underlayer film for a self-assembled film;
a step of forming a neutral film on a portion of the underlayer film for a self-assembled film;
a step of forming a brush film on a portion of the underlayer film where the neutral film is not formed, to thereby form a template film for a self-assembled pattern from the neutral film and the brush film; and
a step of forming a self-assembled film on the template film for a self-assembled pattern, to thereby form a self-assembled pattern, wherein:
the composition for forming a silicon-containing underlayer film for a self-assembled film contains [A] a polysiloxane and [B] a solvent, but does not contain a strongly acidic additive.

12. A production method for a substrate having a self-assembled pattern, the production method comprising:
a step of forming an organic underlayer film on a substrate;
a step of forming, on the organic underlayer film, an underlayer film for a self-assembled film from a composition for forming a silicon-containing underlayer film for a self-assembled film;
a step of forming a neutral film on a portion of the underlayer film for a self-assembled film;
a step of forming a brush film on a portion of the underlayer film where the neutral film is not formed, to thereby form a template film for a self-assembled pattern from the neutral film and the brush film; and
a step of forming a self-assembled film on the template film for a self-assembled pattern, to thereby form a self-assembled pattern, wherein:
the composition for forming a silicon-containing underlayer film for a self-assembled film contains [A] a polysiloxane and [B] a solvent, but does not contain a strongly acidic additive.

13. A production method for a substrate having a self-assembled pattern, the production method comprising:
a step of forming an organic underlayer film on a substrate;
a step of forming, on the organic underlayer film, an underlayer film for a self-assembled film from a composition for forming a silicon-containing underlayer film for a self-assembled film;
a step of forming a neutral film on the underlayer film for a self-assembled film;
a step of forming a resist film on the neutral film;
a step of irradiating the resist film with light, and developing the resist film, to thereby form a resist pattern;
a step of etching the neutral film by using the resist pattern as a mask;
a step of etching or stripping the resist pattern, to thereby pattern the neutral film on the underlayer film for a self-assembled film;
a step of forming a brush film on the underlayer film for a self-assembled film and on the patterned neutral film on the underlayer film;
a step of etching or stripping the brush film on the patterned neutral film, to thereby expose the neutral film and to form a template film for a self-assembled pattern including the neutral film and the brush film; and
a step of forming a self-assembled film on the template film for a self-assembled pattern, to thereby form a self-assembled pattern, wherein:
the composition for forming a silicon-containing underlayer film for a self-assembled film contains [A] a polysiloxane and [B] a solvent, but does not contain a strongly acidic additive.

14. The production method for a substrate having a self-assembled pattern according to claim 9, wherein the production method is used for forming a self-assembled pattern by directed self-assembly (DSA).

15. The production method for a substrate having a self-assembled pattern according to claim 9, wherein the strongly acidic additive is a photoacid generator.

16. The production method for a substrate having a self-assembled pattern according to claim 9, wherein the polysiloxane [A] contains at least one selected from the group consisting of a hydrolysis condensate of a hydrolyzable silane containing at least one hydrolyzable silane of the following Formula (1):
R¹ₐSi(R²)₄₋ₐ (1)
(wherein R¹ is a group bonded to a silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, an amide group, an alkoxy group, a sulfonyl group, or a cyano group, or any combination of these; R² is a group or atom bonded to a silicon atom, and is each independently an alkoxy group, an aralkyloxy group, an acyloxy group, or a halogen atom; and a is an integer of 0 to 3), a modified hydrolysis condensate prepared by modification of at least some of silanol groups of the condensate of the hydrolyzable silane with an alcohol, a modified hydrolysis condensate prepared by protection of at least some of silanol groups of the condensate of the hydrolyzable silane with an acetal, and a product prepared by dehydration reaction between the condensate of the hydrolyzable silane and an alcohol.

17. The production method for a substrate having a self-assembled pattern according to claim 9, wherein the composition for forming a silicon-containing underlayer film for a self-assembled film further contains a pH adjuster.

18. The production method for a substrate having a self-assembled pattern according to claim 9, wherein the composition for forming a silicon-containing underlayer film for a self-assembled film further contains a surfactant.

19. A semiconductor device production method comprising:
(1) a step of forming, on a substrate, an underlayer film from the composition for forming a silicon-containing underlayer film for a self-assembled film according to claim 1;
(2) a step of forming a block copolymer-containing layer on the underlayer film;
(3) a step of phase-separating the block copolymer;
(4) a step of removing a portion of the phase-separated block copolymer; and
(5) a step of etching the substrate.
